(19) United States
(12) Patent Application Publication
(10) Pub. No.: US 2026/0333999 A1
(43) Pub. Date: Oct. 22, 2026

(54) Light-Emitting Device

(71) Applicant: Semiconductor Energy Laboratory Co., Ltd., Kanagawa-ken (JP)

(72) Inventors: Nobuharu OHSAWA, Zama (JP); Hiromi SEO, Sagamihara (JP); Toshiki SASAKI, Kawasaki (JP); Shinya FUKUZAKI, Atsugi (JP); Kunihiko SUZUKI, Kawasaki (JP)

(73) Assignee: Semiconductor Energy Laboratory Co., Ltd., Kanagawa-ken (JP)

(21) Appl. No.: 19/641,796

(22) Filed: Apr. 8, 2026

(30) Foreign Application Priority Data
Apr. 11, 2025 (JP) 2025-065794
Jul. 25, 2025 (JP) 2025-124768

(51) Int. Cl. H10K 50/19; H10K 59/12; H10K 85/30; H10K 85/60; H10K 101/40; H10K 102/00

(52) U.S. Cl. CPC H10K 50/19; H10K 59/1201; H10K 85/342; H10K 85/371; H10K 85/381; H10K 85/615; H10K 85/633; H10K 85/654; H10K 85/6572; H10K 85/6576; H10K 2101/40; H10K 2102/351

(57) ABSTRACT

Alight-emitting device having favorable characteristics is provided. The light-emitting device includes a first electrode, a second electrode, a light-emitting layer, and a first layer. The light-emitting layer is between the first electrode and the second electrode. The first layer is between the light-emitting layer and the second electrode. The first layer includes a first organic compound, a second organic compound, and at least one of a metal and a metal compound. An absorption spectrum of a first mixed film including the first organic compound, the second organic compound, and the at least one of the metal and the metal compound includes a wavelength region having a higher absorption intensity than an absorption spectrum of a second mixed film including one of the first organic compound and the second organic compound and the at least one of the metal and the metal compound and having a difference in thickness of less than or equal to 10% from a thickness of the first mixed film.

### BACKGROUND OF THE INVENTION

### 1. Field of the Invention

One embodiment of the present invention relates to a light-emitting device, a light-emitting apparatus, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an image capturing device, an input device (e.g., a touch sensor), an input/output device (e.g., a touch panel), a driving method thereof, and a manufacturing method thereof.

### 2. Description of the Related Art

Display apparatuses are being developed into a variety of applications these days. For example, a television device for home use (also referred to as TV or television receiver), digital signage, and a public information display (PID) are being developed as large-sized display apparatuses, and a smartphone and a tablet terminal each provided with a touch panel are being developed as small-sized display apparatuses.

At the same time, an increase in the resolution of display apparatuses is also required. For example, devices for virtual reality (VR), augmented reality (AR), substitutional reality (SR), or mixed reality (MR) are given as devices requiring high-resolution display apparatuses and are being developed actively.

Development is actively conducted on light-emitting devices (also referred to as light-emitting elements) as display elements used in display apparatuses. Light-emitting devices utilizing electroluminescence (hereinafter referred to as EL; such devices are also referred to as EL devices or EL elements), particularly organic EL devices that mainly use organic compounds, are suitable for display apparatuses because of having features such as ease of reduction in thickness and weight, high-speed response to input signals, and driving with a constant DC voltage power source.

In order to obtain a higher-resolution display apparatus using an organic EL device, patterning of an organic compound layer by a photolithography method instead of an evaporation method using a metal mask has been studied. By using the photolithography method, a high-resolution display apparatus in which the distance between organic compound layers is several micrometers can be obtained (see Patent Document 1, for example). [Reference]
[Patent Document 1] Japanese Translation of PCT International Application No. 2018-521459

### SUMMARY OF THE INVENTION

It has been conventionally known that a cathode and an organic compound layer of an organic EL device exposed to atmospheric components such as water and oxygen affect initial characteristics or reliability, and thus it has been common knowledge that an organic EL device is manufactured in an inert gas atmosphere or a near-vacuum atmosphere. Meanwhile, in a step of processing an organic compound layer by a lithography method such as a photolithography method as described above (hereinafter, this step is sometimes referred to as a lithography step) in the middle of the manufacture of an organic EL device, the organic compound layer is sometimes exposed to an atmospheric component such as water or oxygen, or water, a chemical solution, or the like used for a photolithography method. Thus, development of an organic EL device including an organic compound layer highly resistant to such an environment is required.

An object of one embodiment of the present invention is to provide a novel light-emitting device. Another object of one embodiment of the present invention is to provide a highly efficient light-emitting device. Another object of one embodiment of the present invention is to provide a highly reliable light-emitting device. Another object of one embodiment of the present invention is to provide a highly efficient and highly reliable light-emitting device.

Another object of one embodiment of the present invention is to provide a novel light-emitting device manufactured by a lithography method. Another object of one embodiment of the present invention is to provide a highly efficient light-emitting device manufactured by a lithography method. Another object of one embodiment of the present invention is to provide a highly reliable light-emitting device manufactured by a lithography method. Another object of one embodiment of the present invention is to provide a high-emission-efficiency and highly reliable light-emitting device manufactured by a lithography method.

Another object of one embodiment of the present invention is to provide a novel light-emitting device that can be used in a high-resolution display apparatus. Another object of one embodiment of the present invention is to provide a highly efficient light-emitting device that can be used in a high-resolution display apparatus. Another object of one embodiment of the present invention is to provide a highly reliable light-emitting device that can be used in a high-resolution display apparatus. Another object of one embodiment of the present invention is to provide a high-emission-efficiency and highly reliable light-emitting device that can be used in a high-resolution display apparatus.

Note that the description of these objects does not preclude the existence of other objects. One embodiment of the present invention does not necessarily achieve all of these objects. Other objects can be derived from the description of the specification, the drawings, and the claims.

One embodiment of the present invention is a light-emitting device including a first electrode, a second electrode, a light-emitting layer, and a first layer. The light-emitting layer is between the first electrode and the second electrode. The first layer is between the light-emitting layer and the second electrode. The first layer includes a first organic compound, a second organic compound, and at least one of a metal and a metal compound. An absorption spectrum of a first mixed film including the first organic compound, the second organic compound, and the at least one of the metal and the metal compound includes a wavelength region having a higher absorption intensity than an absorption spectrum of a second mixed film including one of the first organic compound and the second organic compound and the at least one of the metal and the metal compound and having a difference in thickness of less than or equal to 10% from a thickness of the first mixed film.

Another embodiment of the present invention is a light-emitting device including a first electrode, a second electrode, a light-emitting layer, and a first layer. The light-emitting layer is between the first electrode and the second electrode. The first layer is between the light-emitting layer and the second electrode. The first layer includes a first organic compound, a second organic compound, and at least one of a metal and a metal compound. An absorption spectrum of a first mixed film including the first organic compound, the second organic compound, and the at least one of the metal and the metal compound includes a wavelength region having a higher absorption intensity than an absorption spectrum of a third mixed film including the first organic compound and the at least one of the metal and the metal compound and having a difference in thickness of less than or equal to 10% from a thickness of the first mixed film. The absorption spectrum of the first mixed film includes a wavelength region having a higher absorption intensity than an absorption spectrum of a fourth mixed film including the second organic compound and the at least one of the metal and the metal compound and having a difference in thickness of less than or equal to 10% from the thickness of the first mixed film.

Another embodiment of the present invention is a light-emitting device including a first electrode, a second electrode, a first light-emitting layer, a first layer, and a second light-emitting layer. The first light-emitting layer and the second light-emitting layer are between the first electrode and the second electrode. The first layer is between the first light-emitting layer and the second light-emitting layer. The first layer includes a first organic compound, a second organic compound, and at least one of a metal and a metal compound. An absorption spectrum of a first mixed film including the first organic compound, the second organic compound, and the at least one of the metal and the metal compound includes a wavelength region having a higher absorption intensity than an absorption spectrum of a second mixed film including one of the first organic compound and the second organic compound and the at least one of the metal and the metal compound and having a difference in thickness of less than or equal to 10% from a thickness of the first mixed film.

Another embodiment of the present invention is a light-emitting device including a first electrode, a second electrode, a first light-emitting layer, a first layer, and a second light-emitting layer. The first light-emitting layer and the second light-emitting layer are between the first electrode and the second electrode. The first layer is between the first light-emitting layer and the second light-emitting layer. The first layer includes a first organic compound, a second organic compound, and at least one of a metal and a metal compound. An absorption spectrum of a first mixed film including the first organic compound, the second organic compound, and the at least one of the metal and the metal compound includes a wavelength region having a higher absorption intensity than an absorption spectrum of a third mixed film including the first organic compound and the at least one of the metal and the metal compound and having a difference in thickness of less than or equal to 10% from a thickness of the first mixed film. The absorption spectrum of the first mixed film includes a wavelength region having a higher absorption intensity than an absorption spectrum of a fourth mixed film including the second organic compound and the at least one of the metal and the metal compound and having a difference in thickness of less than or equal to 10% from the thickness of the first mixed film.

In the light-emitting device of one embodiment of the present invention having the above-described structure, the absorption spectrum of the first mixed film includes the wavelength region having a higher absorption intensity than the absorption spectrum of the second mixed film in a region at longer wavelengths than an absorption edge on the long wavelength side of an absorption spectrum of a film of an organic compound included in the second mixed film.

In the light-emitting device of one embodiment of the present invention having the above-described structure, the absorption spectrum of the first mixed film includes the wavelength region having a higher absorption intensity than the absorption spectrum of the third mixed film in a region at longer wavelengths than an absorption edge on the long wavelength side of an absorption spectrum of a film including the first organic compound, and the absorption spectrum of the first mixed film includes the wavelength region having a higher absorption intensity than the absorption spectrum of the fourth mixed film in a region at longer wavelengths than an absorption edge on the long wavelength side of an absorption spectrum of a film including the second organic compound.

In the light-emitting device of one embodiment of the present invention having the above-described structure, the at least one of the metal and the metal compound includes a metal element belonging to any of Group 3 to Group 14 of the periodic table.

In the light-emitting device of one embodiment of the present invention having the above-described structure, the at least one of the metal and the metal compound includes a metal element belonging to Group 3, Group 11, or Group 13 of the periodic table.

The light-emitting device of one embodiment of the present invention having the above-described structure may further include a second layer. The second layer is between the first layer and the second electrode. The second layer includes a third organic compound and a fourth organic compound. The third organic compound is an organic compound having a π-electron rich heteroaromatic ring or an aromatic amine. The fourth organic compound includes at least one of a halogen group and a cyano group.

In the light-emitting device of one embodiment of the present invention having the above-described structure, a LUMO level of the first organic compound is higher than a LUMO level of the second organic compound.

In the light-emitting device of one embodiment of the present invention having the above-described structure, a HOMO level of the first organic compound is higher than a HOMO level of the second organic compound.

In the light-emitting device of one embodiment of the present invention having the above-described structure, each of the first organic compound and the second organic compound includes a heteroaromatic ring.

In the light-emitting device of one embodiment of the present invention having the above-described structure, the heteroaromatic ring included in the first organic compound and the heteroaromatic ring included in the second organic compound each independently include at least one of a pyridine ring, a pyrazine ring, a pyrimidine ring, a pyridazine ring, a triazine ring, an imidazole ring, a pyrazole ring, an oxazole ring, a thiazole ring, and a triazole ring.

In the light-emitting device of one embodiment of the present invention having the above-described structure, the first organic compound includes an electron-donating group.

In the light-emitting device of one embodiment of the present invention having the above-described structure, the electron-donating group is at least one of an alkyl group, an alkoxy group, an aryloxy group, an alkylamino group, an arylamino group, and a heterocyclic amino group.

With one embodiment of the present invention, a novel light-emitting device can be provided. With another embodiment of the present invention, a highly efficient light-emitting device can be provided. With one embodiment of the present invention, a highly reliable light-emitting device can be provided. With one embodiment of the present invention, a highly efficient and highly reliable light-emitting device can be provided.

With one embodiment of the present invention, a novel light-emitting device manufactured by a lithography method can be provided. With another embodiment of the present invention, a highly efficient light-emitting device manufactured by a lithography method can be provided. With one embodiment of the present invention, a highly reliable light-emitting device manufactured by a lithography method can be provided. With one embodiment of the present invention, a high-emission-efficiency and highly reliable light-emitting device manufactured by a lithography method can be provided.

With one embodiment of the present invention, a novel light-emitting device that can be used in a high-resolution display apparatus can be provided. With one embodiment of the present invention, a highly efficient light-emitting device that can be used in a high-resolution display apparatus can be provided. With one embodiment of the present invention, a highly reliable light-emitting device that can be used in a high-resolution display apparatus can be provided. With one embodiment of the present invention, a high-emission-efficiency and highly reliable light-emitting device that can be used in a high-resolution display apparatus can be provided.

The description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A and 1B illustrate a structure of a light-emitting device of an embodiment.

FIG. 2 illustrates a structure of a light-emitting device of an embodiment.

FIGS. 3A to 3C illustrate results of analyzing the spin density distributions of composite materials in the ground state.

FIG. 4 illustrates results of analyzing the spin density distribution of a composite material in the ground state.

FIGS. 5A and 5B illustrate results of analyzing the electrostatic potential maps of organic compounds in the ground state.

FIGS. 6A to 6C illustrate results of analyzing the electrostatic potential maps of composite materials in the ground state.

FIG. 7 illustrates results of analyzing the electrostatic potential map of a composite material in the ground state.

FIGS. 8A to 8D each illustrate a structure of a light-emitting device of an embodiment.

FIGS. 9A and 9B are a top view and a cross-sectional view of a light-emitting apparatus.

FIGS. 10A to 10E are cross-sectional views illustrating an example of a method for manufacturing a light-emitting apparatus.

FIGS. 11A and 11B are cross-sectional views illustrating the example of the method for manufacturing the light-emitting apparatus.

FIGS. 12A to 12D are cross-sectional views illustrating the example of the method for manufacturing the light-emitting apparatus.

FIGS. 13A to 13C are cross-sectional views illustrating the example of the method for manufacturing the light-emitting apparatus.

FIGS. 14A to 14C are cross-sectional views illustrating the example of the method for manufacturing the light-emitting apparatus.

FIGS. 15A to 15C are cross-sectional views illustrating the example of the method for manufacturing the light-emitting apparatus.

FIGS. 16A and 16B are perspective views illustrating a structure example of a display module.

FIGS. 17A and 17B are cross-sectional views each illustrating a structure example of a light-emitting apparatus.

FIG. 18 is a perspective view illustrating a structure example of a light-emitting apparatus.

FIG. 19 is a cross-sectional view illustrating a structure example of a light-emitting apparatus.

FIGS. 20A and 20B each illustrate an example of an electronic appliance.

FIGS. 21A to 21F each illustrate an example of an electronic appliance.

FIGS. 22A and 22B each illustrate a structure of a light-emitting device of an example.

FIGS. 23A to 23C each illustrate a structure of a light-emitting device of an embodiment.

FIGS. 24A and 24B each illustrate a structure of a light-emitting device of an embodiment.

FIGS. 25A and 25B illustrate absorption spectra of mixed films 1 to 4 and a single film 3.

FIGS. 26A and 26B illustrate absorption spectra of single films 1 and 2.

FIGS. 27A and 27B illustrate absorption spectra of mixed films 5 to 7 and a single film 4.

FIGS. 28A and 28B illustrate absorption spectra of a mixed film 8, the mixed film 2, a mixed film 9, a mixed film 10, and the single film 3.

FIGS. 29A and 29B illustrate absorption spectra of the single film 1 and a single film 5.

FIGS. 30A to 30C illustrate an LDI-MS spectrum of a co-evaporated film containing Hid2Phen, 6,6′(P-Bqn)2BPy, and In.

FIG. 31 is a plane SEM image of an analysis sample 1.

FIG. 32 is a plane SEM image of an analysis sample 2.

FIGS. 33A and 33B are cross-sectional STEM images of an analysis sample 3.

FIGS. 34A and 34B illustrate cross-sectional STEM-EDX line analysis results of the analysis sample 3.

FIG. 35 is a cross-sectional STEM image of an analysis sample 4a.

FIG. 36 is a cross-sectional STEM image of an analysis sample 4b.

FIG. 37 is a cross-sectional STEM image of an analysis sample 5a.

FIG. 38 is a cross-sectional STEM image of an analysis sample 5b.

FIG. 39 illustrates SIMS analysis results of the analysis samples 4a and 4b.

FIG. 40 illustrates SIMS analysis results of the analysis samples 5a and 5b.

FIG. 41 illustrates external quantum efficiency-current density characteristics of analysis devices 1a and 1b.

FIG. 42 illustrates current density-voltage characteristics of the analysis devices 1a and 1b.

FIG. 43 illustrates external quantum efficiency-current density characteristics of analysis devices 2a and 2b.

FIG. 44 illustrates current density-voltage characteristics of the analysis devices 2a and 2b.

FIG. 45 illustrates luminance-current density characteristics of a device 1 and comparative devices 2 and 3.

FIG. 46 illustrates luminance-voltage characteristics of the device 1 and the comparative devices 2 and 3.

FIG. 47 illustrates current efficiency-luminance characteristics of the device 1 and the comparative devices 2 and 3.

FIG. 48 illustrates current density-voltage characteristics of the device 1 and the comparative devices 2 and 3.

FIG. 49 illustrates electroluminescence spectra of the device 1 and the comparative devices 2 and 3.

FIGS. 50A and 50B illustrate absorption spectra of mixed films 11, 12, 13, and 14 and a single film 8.

FIGS. 51A and 51B illustrate absorption spectra of single films 6 and 7.

FIG. 52 illustrates PL spectra of the single films 6 and 7 and the mixed film 14.

FIG. 53 is a cross-sectional STEM image of an analysis sample 6a.

FIG. 54 is a cross-sectional STEM image of an analysis sample 6b.

FIG. 55 illustrates SIMS analysis results of analysis samples 6c and 6d.

FIG. 56 illustrates external quantum efficiency-current density characteristics of an analysis device 3 and the analysis device 1b.

FIG. 57 illustrates current density-voltage characteristics of the analysis devices 3 and 1b.

FIG. 58 illustrates luminance-current density characteristics of devices 4 and 5.

FIG. 59 illustrates luminance-voltage characteristics of the devices 4 and 5.

FIG. 60 illustrates current efficiency-luminance characteristics of the devices 4 and 5.

FIG. 61 illustrates current density-voltage characteristics of the devices 4 and 5.

FIG. 62 illustrates electroluminescence spectra of the devices 4 and 5.

FIG. 63 illustrates luminance changes over driving time of the devices 4 and 5.

FIG. 64 illustrates luminance-current density characteristics of a device 6 and a comparative device 7.

FIG. 65 illustrates luminance-voltage characteristics of the device 6 and the comparative device 7.

FIG. 66 illustrates current efficiency-luminance characteristics of the device 6 and the comparative device 7.

FIG. 67 illustrates current density-voltage characteristics of the device 6 and the comparative device 7.

FIG. 68 illustrates electroluminescence spectra of the device 6 and the comparative device 7.

FIG. 69 illustrates luminance changes over driving time of the device 6 and the comparative device 7.

FIGS. 70A and 70B illustrate absorption spectra of mixed films 15, 16, and 17 and a single film 9.

FIG. 71 illustrates luminance-current density characteristics of a device 8.

FIG. 72 illustrates luminance-voltage characteristics of the device 8.

FIG. 73 illustrates current efficiency-luminance characteristics of the device 8.

FIG. 74 illustrates current density-voltage characteristics of the device 8.

FIG. 75 illustrates an electroluminescence spectrum of the device 8.

FIGS. 76A to 76D illustrate calculation results in an example.

FIG. 77 illustrates calculation results in an example.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

Ordinal numbers such as “first” and “second” in this specification and the like are used in order to avoid confusion among components and do not denote the priority or the order such as the order of steps, the stacking order, or the order of placement. A term without an ordinal number in this specification might be provided with an ordinal number in a claim in order to avoid confusion among components. A term with an ordinal number in this specification might not be provided with any ordinal number in a claim. A term with an ordinal number in this specification might be provided with a different ordinal number in a claim.

In this specification and the like, a device manufactured using a metal mask or a fine metal mask (FMM, or a high-resolution metal mask) is sometimes referred to as a device having a metal mask (MM) structure. In this specification and the like, a device manufactured without using a metal mask or an FMM is sometimes referred to as a device having a metal maskless (MML) structure.

In this specification and the like, a light-emitting device (also referred to as a light-emitting element) includes an EL layer (also referred to as an organic compound layer) between a pair of electrodes. The EL layer includes at least a light-emitting layer.

In this specification and the like, a tapered shape indicates a shape such that at least part of a side surface of a structure is inclined relative to a substrate surface. For example, a tapered shape preferably includes a region where the angle formed between the inclined side surface and the substrate surface (such an angle is also referred to as a taper angle) is less than 90°. Note that the side surface of a component and the substrate surface are not necessarily completely flat, and may have a substantially planar shape with a small curvature or slight unevenness.

Note that in this specification and the like, a photoluminescence (PL) spectrum refers to a spectrum obtained by scanning the wavelength of light emission while an excitation wavelength of excitation light is fixed in a fluorometry. Such a spectrum is also referred to as an emission spectrum in some cases. Note that an emission spectrum may include a fluorescence component and a phosphorescence component. In this specification and the like, an emission spectrum including a fluorescence component is particularly referred to as a fluorescence spectrum, and an emission spectrum including a phosphorescence component is particularly referred to as a phosphorescence spectrum in some cases.

### Embodiment 1

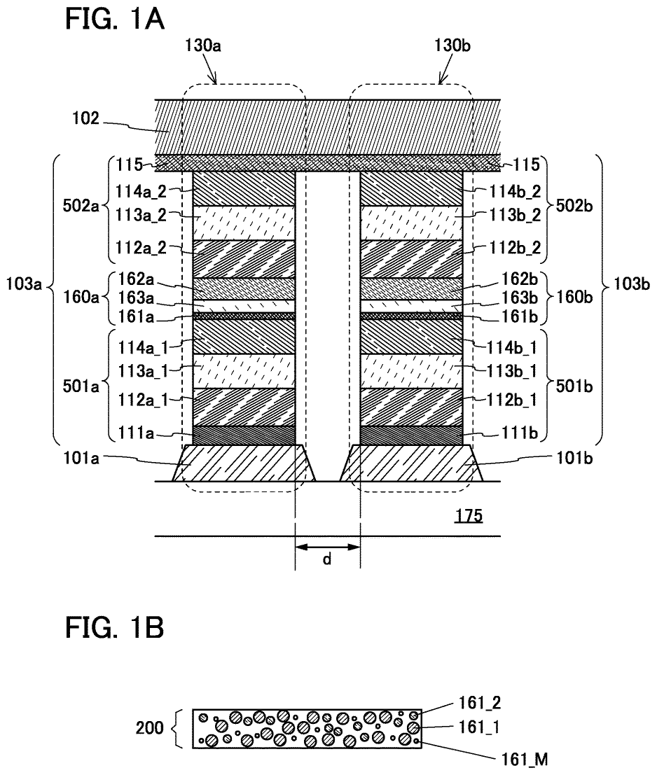

In this embodiment, a light-emitting device of one embodiment of the present invention will be described with reference to FIGS. 1A and 1B, FIG. 2, FIGS. 3A to 3C, FIG. 4, FIGS. 5A and 5B, FIGS. 6A to 6C, and FIG. 7.

For description of a light-emitting device of one embodiment of the present invention, FIG. 1A schematically illustrates light-emitting devices 130a and 130b included in a light-emitting apparatus, which are formed over one insulating surface and adjacent to each other. In each of the light-emitting devices 130a and 130b, part of an organic compound layer is processed by a lithography method. The light-emitting devices 130a and 130b are each a tandem light-emitting device having a structure in which a plurality of light-emitting units are stacked with an intermediate layer therebetween.

The light-emitting device 130a is positioned over an insulating layer 175 and includes a first electrode 101a that includes an anode, a second electrode 102 that includes a cathode, and an organic compound layer 103a. The organic compound layer 103a is positioned between the first electrode 101a and the second electrode 102. In the organic compound layer 103a, a first light-emitting unit 501a and a second light-emitting unit 502a are stacked with an intermediate layer 160a sandwiched therebetween. The first light-emitting unit 501a includes a first light-emitting layer 113a_1. The intermediate layer 160a includes a first layer 161a and a second layer 162a. The second light-emitting unit 502a includes a second light-emitting layer 113a_2 and an electron-injection layer 115. It can be said that the intermediate layer 160a is positioned between the first light-emitting layer 113a_1 and the second light-emitting layer 113a_2.

In the organic compound layer 103a of the light-emitting device 130a, layers other than the electron-injection layer 115 are processed by a lithography method. Thus, the layers other than the electron-injection layer 115 in the organic compound layer 103a are separate from those in an organic compound layer 103b of the adjacent light-emitting device 130b. End portions (contours) of the layers other than the electron-injection layer 115 in the organic compound layer 103a are aligned or substantially aligned with each other in a direction perpendicular to a substrate. In other words, the first light-emitting layer 113a_1, the intermediate layer 160a (the first layer 161a and the second layer 162a), and the second light-emitting layer 113a_2 are separate from a first light-emitting layer 113b_1, an intermediate layer 160b (a first layer 161b and a second layer 162b), and a second light-emitting layer 113b_2. End portions (contours) of the first light-emitting layer 113a_1, the intermediate layer 160a (the first layer 161a and the second layer 162a), and the second light-emitting layer 113a_2 are aligned or substantially aligned with each other in a direction perpendicular to the substrate.

The light-emitting device 130b is positioned over the insulating layer 175 and includes a first electrode 101b that includes an anode, the second electrode 102 that includes the cathode, and the organic compound layer 103b. The organic compound layer 103b is positioned between the first electrode 101b and the second electrode 102. In the organic compound layer 103b, a first light-emitting unit 501b and a second light-emitting unit 502b are stacked with the intermediate layer 160b sandwiched therebetween. The first light-emitting unit 501b includes the first light-emitting layer 113b_1. The intermediate layer 160b includes the first layer 161b and the second layer 162b. The second light-emitting unit 502b includes the second light-emitting layer 113b_2 and the electron-injection layer 115. It can be said that the intermediate layer 160b is positioned between the first light-emitting layer 113b_1 and the second light-emitting layer 113b_2.

In the organic compound layer 103b of the light-emitting device 130b, layers other than the electron-injection layer 115 are processed by a lithography method. Thus, the layers other than the electron-injection layer 115 in the organic compound layer 103b are separate from (also regarded as being isolated from) those in the organic compound layer 103a of the adjacent light-emitting device 130a. End portions (contours) of the layers other than the electron-injection layer 115 in the organic compound layer 103b are aligned or substantially aligned with each other in a direction perpendicular to the substrate. In other words, the first light-emitting layer 113b_1, the intermediate layer 160b (the first layer 161b and the second layer 162b), and the second light-emitting layer 113b_2 are separate from the first light-emitting layer 113a_1, the intermediate layer 160a (the first layer 161a and the second layer 162a), and the second light-emitting layer 113a_2. End portions (contours) of the first light-emitting layer 113b_1, the intermediate layer 160b (the first layer 161b and the second layer 162b), and the second light-emitting layer 113b_2 are aligned or substantially aligned with each other in a direction perpendicular to the substrate.

The electron-injection layer 115 and the second electrode 102 are preferably formed after the layers other than the electron-injection layer 115 in the organic compound layer 103a and the layers other than the electron-injection layer 115 in the organic compound layer 103b are processed by a lithography method. In other words, the electron-injection layer 115 and the second electrode 102 are each preferably a continuous layer shared by the light-emitting devices 130a and 130b.

The electron-injection layer 115 is preferably formed using a material having a donor property typified by an alkali metal, an alkaline earth metal, or a compound thereof, to reduce the voltage of the light-emitting device. Note that in the case where an organic compound layer whose outermost surface is an electron-injection layer including such a donor substance is processed by a lithography method, oxygen or water in the air or a chemical solution or water used during the process sometimes effects a considerable increase of driving voltage or a significant reduction of current efficiency of a light-emitting device.

Meanwhile, when a light-emitting device is manufactured by a method where the electron-injection layer 115 and the second electrode 102 are formed after the layers other than the electron-injection layer 115 in the organic compound layer are processed by a lithography method as in the light-emitting devices 130a and 130b, the electron-injection layer 115 is unlikely to be affected by oxygen or water in the air or a chemical solution or water used during the process, whereby the light-emitting device can have favorable characteristics.

The distance between the organic compound layers can be shorter in the case where the organic compound layers are processed by a lithography method than in the case of employing mask vapor deposition. Specifically, a distance d between the layers other than the electron-injection layer 115 in the organic compound layer 103a and the layers other than the electron-injection layer 115 in the organic compound layer 103b can be shortened to less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm. Using a light exposure apparatus for LSI can further shorten the distance d to less than or equal to 500 nm, less than or equal to 200 nm, less than or equal to 100 nm, or even less than or equal to 50 nm, for example, in a process over a Si wafer.

It is preferable that an insulating layer be provided in a gap between the layers other than the electron-injection layer 115 in the organic compound layer 103a and the layers other than the electron-injection layer 115 in the organic compound layer 103b to separate the layers other than the electron-injection layer 115 in the organic compound layer 103a from the layers other than the electron-injection layer 115 in the organic compound layer 103b. In that case, the light-emitting apparatus includes a region where the insulating layer is in contact with the electron-injection layer 115 or the second electrode 102.

In the light-emitting device 130a, the first light-emitting unit 501a preferably includes a hole-injection layer 11a, a first hole-transport layer 112a_1, and a first electron-transport layer 114a_1 in addition to the first light-emitting layer 113a_1. The second light-emitting unit 502a preferably includes a second hole-transport layer 112a_2 and a second electron-transport layer 114a_2 in addition to the second light-emitting layer 113a_2 and the electron-injection layer 115. The intermediate layer 160a can include a third layer 163a between the first layer 161a and the second layer 162a. In the case where the surface of the light-emitting unit on the anode side is in contact with the intermediate layer 160a as in the second light-emitting unit 502a, the second layer 162a, which is positioned on the cathode side in the intermediate layer 160a, can also function as a hole-injection layer for the second light-emitting unit 502a, and thus, providing a hole-injection layer in such a light-emitting unit is optional.

In the light-emitting device 130b, the first light-emitting unit 501b preferably includes a hole-injection layer 111b, a first hole-transport layer 112b_1, and a first electron-transport layer 114b_1 in addition to the first light-emitting layer 113b_1. The second light-emitting unit 502b preferably includes a second hole-transport layer 112b_2 and a second electron-transport layer 114b_2 in addition to the second light-emitting layer 113b_2 and the electron-injection layer 115. The intermediate layer 160b can include a third layer 163b between the first layer 161b and the second layer 162b. In the case where the surface of the light-emitting unit on the anode side is in contact with the intermediate layer 160b as in the second light-emitting unit 502b, the second layer 162b, which is positioned on the cathode side in the intermediate layer 160b, can also function as a hole-injection layer for the second light-emitting unit 502b, and thus, providing a hole-injection layer in such a light-emitting unit is optional.

As illustrated in FIG. 1A, the uppermost one of the layers other than the electron-injection layer 115 in the organic compound layer 103a is preferably the second electron-transport layer 114a_2. Similarly, the uppermost one of the layers other than the electron-injection layer 115 in the organic compound layer 103b is preferably the second electron-transport layer 114b_2. In the case where the organic compound layers including the second electron-transport layers 114a_2 and 114b_2 as the outermost surfaces are formed by a lithography method, the second electron-transport layers 114a_2 and 114b_2 provided over the second light-emitting layers 113a_2 and 113b_2 can diminish the influence of oxygen or water in the air or a chemical solution or water used during the process on the second light-emitting layers 113a_2 and 113b_2, as compared with the case where organic compound layers including the second light-emitting layers 113a_2 and 113b_2 as the outermost surfaces are formed. That is, in formation of the organic compound layers, processing by a lithography method is preferably performed at least after a layer or layers above the second light-emitting layers 113a_2 and 113b_2 is/are formed, and is further preferably performed with the second electron-transport layers 114a_2 and 114b_2 as the uppermost layers. In this way, degradation of the characteristics of the light-emitting devices due to the manufacture by a lithography method can be more easily avoided.

Although FIG. 1A illustrates an example in which each of the organic compound layers includes two light-emitting units, one embodiment of the present invention is not limited to this example. Each of the organic compound layers may include three or more light-emitting units. When a plurality of light-emitting units are stacked between a pair of electrodes with an intermediate layer sandwiched between the plurality of light-emitting units, the light-emitting device can perform high-luminance light emission with the current density kept low and can have high reliability. In addition, the light-emitting device can have low power consumption. Although not illustrated in FIG. 1A, each of the light-emitting units may include a hole-injection layer, a hole-transport layer, an electron-blocking layer, a hole-blocking layer, an electron-transport layer, an electron-injection layer, or the like in addition to the above-described components. Each layer may have a stacked-layer structure of two or more layers.

Note that in this specification, description referring to the structure of one of the light-emitting devices 130a and 130b can apply to the structure of the other of the light-emitting devices 130a and 130b.

The intermediate layer 160a sandwiched between the first light-emitting unit 501a and the second light-emitting unit 502a injects electrons into one of the light-emitting units and injects holes into the other of the light-emitting units when a voltage is applied between the first electrode 101a and the second electrode 102, for example. When a voltage is applied such that the potential of the second electrode 102 is higher than that of the first electrode 101a in FIG. 1A, for example, the intermediate layer 160a injects electrons into the first light-emitting unit 501a and injects holes into the second light-emitting unit 502a.

In the light-emitting device 130a illustrated as an example in FIG. 1A, when a voltage is applied between the pair of electrodes (the first electrode 101a and the second electrode 102), electrons are injected from the cathode into the electron-injection layer 115 and holes are injected from the anode into the hole-injection layer 111a, so that a current flows. Furthermore, electrons are injected from the first layer 161a, which is positioned on the anode side in the intermediate layer 160a, into the first electron-transport layer 114a_1 of the first light-emitting unit 501a, and holes are injected from the second layer 162a, which is positioned on the cathode side in the intermediate layer 160a, into the second hole-transport layer 112a_2 of the second light-emitting unit 502a. By recombination of the injected carriers (electrons and holes), excitons are formed. When carriers (electrons and holes) recombine and excitons are formed in the first light-emitting layer 113a_1 and the second light-emitting layer 113a_2 including light-emitting materials, the light-emitting materials included in the first light-emitting layer 113a_1 and the second light-emitting layer 113a_2 are brought into an excited state, causing light emission from the light-emitting materials.

It is preferable that the first layer 161a, which is positioned on the anode side in the intermediate layer 160a, be adjacent to the first electron-transport layer 114a_1 and be provided between the first electron-transport layer 114a_1 and the second light-emitting unit 502a as illustrated in FIG. 1A. With such a structure, electrons can be efficiently injected into the first light-emitting unit 501a.

In a preferable structure for a lower driving voltage and more efficient light emission of the light-emitting device, a barrier against electron injection from the intermediate layer into the first electron-transport layer is lowered and electrons generated in the intermediate layer are smoothly injected and transported into the first electron-transport layer. In view of this, an alkali metal or an alkaline earth metal, which has a low work function, or a compound of an alkali metal or an alkaline earth metal is generally used for the first layer of the intermediate layer. However, the metal and the compound easily deteriorate by oxygen or water in the air and water or a chemical solution used during the lithography process, causing a considerably increased driving voltage or significantly reduced current efficiency in a light-emitting device. Alternatively, a method can be employed in which a metal that is stable with respect to oxygen and water in the air and is resistant to water and a chemical solution is used for the first layer of the intermediate layer. However, such a metal which is stable and has a low electron-injection property forms a barrier against electron injection between the intermediate layer 160a and the first electron-transport layer 114a_1, leading to a problem such as an increase in driving voltage or a decrease in emission efficiency of the light-emitting device in some cases. Therefore, in such a light-emitting device, a material that is resistant to water and a chemical solution used in the process is preferably used for the intermediate layer.

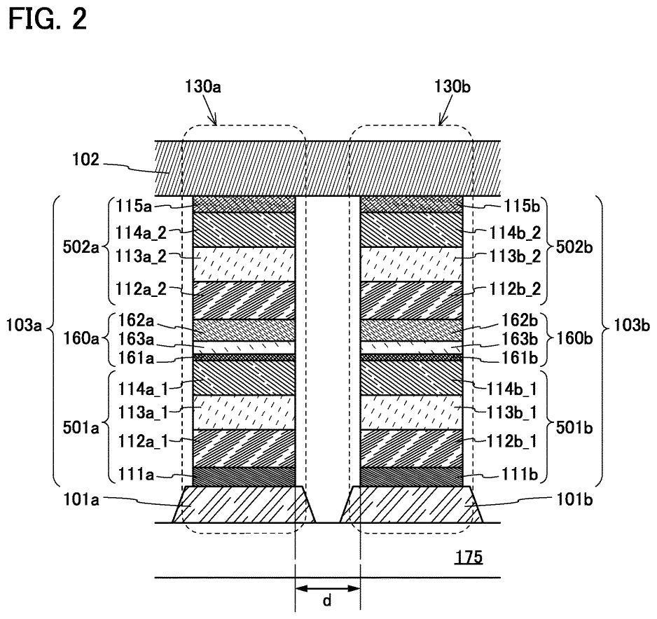

FIG. 2 schematically illustrates a variation example of the light-emitting devices 130a and 130b illustrated in FIG. 1A. In each of the light-emitting devices 130a and 130b, the whole organic compound layer including the electron-injection layer is processed by a lithography method.

The organic compound layer 103a of the light-emitting device 130a illustrated in FIG. 2 is separate from the organic compound layer 103b of the adjacent light-emitting device 130b and includes an electron-injection layer 115a having an end portion (contour) that is aligned or substantially aligned with those of the other layers in a direction perpendicular to the substrate. Similarly, the organic compound layer 103b of the light-emitting device 130b illustrated in FIG. 2 is separate from the organic compound layer 103a of the adjacent light-emitting device 130a and includes an electron-injection layer 115b having an end portion (contour) that is aligned or substantially aligned with those of the other layers in a direction perpendicular to the substrate. Note that the structures of the light-emitting devices 130a and 130b and their surroundings illustrated in FIG. 2 are similar to those illustrated in FIG. 1A, and thus the description thereof is omitted.

As illustrated in FIG. 2, in the light-emitting devices obtained by processing the whole organic compound layer including the electron-injection layer by a lithography method, a material having resistance to water and a chemical solution used during the process is preferably used for the electron-injection layer and the intermediate layer.

Thus, in the light-emitting device of one embodiment of the present invention, at least one of the first layer (161a and 161b) of the intermediate layer (160a and 160b) or the electron-injection layer (115, 115a, and 115b) described above employs a structure of a layer 200 described below.

### [Layer 200]

As illustrated in FIG. 1B, the layer 200 includes a first organic compound 161_1, a second organic compound 161_2, and a metal material 161_M, and these materials form a composite material in the layer 200. In the composite material, the first organic compound 161_1 and the metal material 161_M interact with each other to form a donor level (singly occupied molecular orbital (SOMO) level or highest occupied molecular orbital (HOMO) level), and can function as electron donors with respect to the second organic compound 161_2. Such a structure enables the formation of a layer having favorable electron-injection characteristics and resistance to oxygen and water in the air and water and a chemical solution used during a lithography process.

A mixed layer including the first organic compound 161_1, the second organic compound 161_2, and the metal material 161_M is preferably used as the layer 200. When the layer 200 has such a structure, interaction between these substances is facilitated, whereby the first organic compound 161_1 and the metal material 161_M can function as electron donors with respect to the second organic compound 161_2. Moreover, the layer 200 with such a structure is less likely to be crystallized than the layer with a stacked-layer structure. Accordingly, the organic compound layer including such a layer is not easily crystallized even when affected by oxygen or water in the air or a chemical solution or water during processing of part of the organic compound layer by a lithography method. Furthermore, an increase in driving voltage or a reduction in current efficiency of the light-emitting device due to crystallization of the intermediate layer or the electron-injection layer can be prevented. Thus, the mixed layer can be suitably used for at least one of the intermediate layer and the electron-injection layer of the light-emitting device in which part of the organic compound layer is processed by a lithography method, as compared with the case where the stacked-layer structure is employed.

In the layer 200, the first organic compound 161_1 and the metal material 161_M interact with each other to form a donor level, and function as an electron donor to the second organic compound 161_2. Thus, when the layer 200 is used as the first layer (161a and 161b) of the intermediate layer (160a and 160b), electrons generated in the first layer can be easily injected into the first light-emitting unit. Electrons generated in the second layer (the second layer 162a and the second layer 162b), which is positioned on the cathode side in the intermediate layer, can be easily injected into the first light-emitting unit 501a side. This facilitation of electron injection into the first light-emitting unit 501a enables a reduced driving voltage and increased emission efficiency of the light-emitting device. Moreover, using the layer 200 as the electron-injection layer (115, 115a, and 115b) can lower a barrier against electron injection from the second electrode 102 to the organic compound layer (103a and 103b) and can smoothly inject and transport electrons injected from the second electrode 102 to the light-emitting layer (113a and 113b) side, whereby a light-emitting device with reduced driving voltage and high emission efficiency can be obtained.

The metal material 161_M is at least one of a metal and a metal compound. At least one of the metal and the metal compound preferably includes at least one selected from metal elements belonging to Group 3 to Group 14 of the periodic table. These metal elements have low reactivity with oxygen and water in the air and water and a chemical solution used during a lithography process. Thus, using at least one of the metal and the metal compound including such a metal element for a light-emitting device is advantageous in reducing deterioration due to water and oxygen and thus is preferable.

Note that since the metal elements belonging to Group 3 to Group 14 in the periodic table have a low electron-injection property, the use of the metal elements in normal structures hardly improves the characteristics of the light-emitting devices, which might cause a decrease in emission efficiency, an increase in driving voltage, and a reduction in driving lifetime, for example. Meanwhile, in one embodiment of the present invention, the layer 200 includes the first organic compound 161_1, the second organic compound 161_2, and the metal material 161_M, and these materials form a composite material in the layer 200. In the composite material, the first organic compound 161_1 and the metal material 161_M interact with each other to form a donor level (SOMO level or HOMO level) and supply electrons to the second organic compound 161_2. Thus, in the case where such a layer 200 is used as the first layer (161a and 161b) of the intermediate layer (160a and 160b), a barrier against electron injection from the intermediate layer (160a and 160b) to the first electron-transport layer (114a_1 and 114b_1) can be lowered and electrons generated in the intermediate layer (160a and 160b) can be injected and transported smoothly to the first electron-transport layers (114a_1 and 114b_1). Furthermore, in the case where such a layer 200 is used as the electron-injection layer (115, 115a, and 115b), a barrier against electron injection from the second electrode 102 to the organic compound layer (103a and 103b) can be lowered and electrons injected from the second electrode 102 can be injected and transported smoothly to the light-emitting layer (113a and 113b) side. The above structure is preferably employed, in which case a layer having resistance to oxygen and water in the air and water and a chemical solution used during the lithography process can be formed. Thus, one embodiment of the present invention can provide a light-emitting device having high moisture resistance, high water resistance, high oxygen resistance, high chemical resistance, a low driving voltage, and high emission efficiency.

It is further preferable that the metal material 161_M contain a metal element belonging to an odd-numbered group in the periodic table. Such a structure is preferable because it enables a lower stabilization energy when the first organic compound 161_1 and the metal material 161_M interact with each other and can form a high donor level (SOMO level or HOMO level).

The first organic compound 161_1 and the second organic compound 161_2 are preferably organic compounds that can form a charge-transfer complex by being combined with the metal material 161_M. The charge-transfer complex is in a state formed from two or more kinds of substances, and is formed by charge transfer from one substance to the other substance due to interaction between the substances. When the combination of the first organic compound 161_1, the second organic compound 161_2, and the metal material 161_M can form a charge-transfer complex, the first organic compound 161_1 is likely to function as an electron donor to the second organic compound 161_2 via the metal material 161_M. That is, when a combination of organic compounds that can form a charge-transfer complex with the metal material 161_M is selected to be used as the first organic compound 161_1 and the second organic compound 161_2, electrons can be easily donated to the second organic compound 161_2 from the donor level formed by the first organic compound 161_1 and the metal material 161_M.

When the charge-transfer complex is formed, an absorption band that is different from the absorption bands of the individual substances that form the charge-transfer complex is observed. Thus, when a film in which substances are mixed is formed and the absorption spectrum of the film is measured, whether the combination of the substances can form a charge-transfer complex can be determined.

For example, the absorption spectrum of a first mixed film that includes the first organic compound 161_1, the second organic compound 161_2, and the metal material 161_M preferably includes a wavelength region having a higher absorption intensity than the absorption spectrum of a second mixed film that includes one of the first organic compound 161_1 and the second organic compound 161_2 and the metal material 161_M and has a thickness equivalent to the thickness of the first mixed film, with a difference in thickness of, for example, less than or equal to 10% from the thickness of the first mixed film. In such a case, it can be said that the first organic compound 161_1, the second organic compound 161_2, and the metal material 161_M can easily interact with each other in combination. Furthermore, such a case means that the combination of the first organic compound 161_1, the second organic compound 161_2, and the metal material 161_M forms a charge-transfer complex.

The absorption spectrum of the first mixed film further preferably includes a wavelength region having a higher absorption intensity than the absorption spectrum of the second mixed film in a region at longer wavelengths than an absorption edge on the long wavelength side of the absorption spectrum of a film of an organic compound included in the second mixed film (i.e., one of the first organic compound 161_1 and the second organic compound 161_2). In such a case, it becomes more apparent that a new absorption band different from those of the individual substances of the first mixed film that form a charge-transfer complex is generated; thus, it becomes more easy to determine that the combination of the first organic compound 161_1, the second organic compound 161_2, and the metal material 161_M forms a charge-transfer complex.

For example, the absorption spectrum of the first mixed film that includes the first organic compound 161_1, the second organic compound 161_2, and the metal material 161_M preferably includes a wavelength region having a higher absorption intensity than the absorption spectrum of a third mixed film that includes the first organic compound 161_1 and the metal material 161_M and has a thickness equivalent to the thickness of the first mixed film, with a difference in thickness of, for example, less than or equal to 10% from the thickness of the first mixed film. In addition, the absorption spectrum of the first mixed film preferably includes a wavelength region having a higher absorption intensity than the absorption spectrum of a fourth mixed film that includes the second organic compound 161_2 and the metal material 161_M and has a thickness equivalent to the thickness of the first mixed film, with a difference in thickness of, for example, less than or equal to 10% from the thickness of the first mixed film. In such a case, it can be said that the first organic compound 161_1, the second organic compound 161_2, and the metal material 161_M can easily interact with each other in combination. Furthermore, such a case means that the combination of the first organic compound 161_1, the second organic compound 161_2, and the metal material 161_M forms a charge-transfer complex.

In the light-emitting device having the above-described structure of one embodiment of the present invention, the absorption spectrum of the first mixed film includes a wavelength region having a higher absorption intensity than the absorption spectrum of the third mixed film in a region at longer wavelengths than an absorption edge on the long wavelength side of the absorption spectrum of a film including the first organic compound 161_1. In addition, the absorption spectrum of the first mixed film includes a wavelength region having a higher absorption intensity than the absorption spectrum of the fourth mixed film in a region at longer wavelengths than an absorption edge on the long wavelength side of the absorption spectrum of a film including the second organic compound 161_2. In such a case, it becomes more apparent that a new absorption band different from those of the individual substances of the first mixed film that form a charge-transfer complex is generated; thus, it becomes more easy to determine that the combination of the first organic compound 161_1, the second organic compound 161_2, and the metal material 161_M forms a charge-transfer complex.

Note that the absorption edge on the long wavelength side of the absorption spectrum can be determined as the intersection between a tangent and the horizontal axis or the baseline. The tangent is drawn at a point at which the slope on the long wavelength side of the longest-wavelength peak (or the longest-wavelength shoulder peak) of the absorption spectrum has the maximum absolute value.

Note that the intensity of the absorption spectrum depends on the thickness of a sample used for the measurement. Thus, in the case where the absorption spectrum of the first mixed film is compared with the absorption spectrum of the second mixed film, the third mixed film, or the fourth mixed film, the second mixed film, the third mixed film, or the fourth mixed film preferably has a thickness equivalent to the thickness of the first mixed film, with a difference in thickness of, for example, less than or equal to 10%, preferably less than or equal to 7%, further preferably less than or equal to 5%, most preferably less than or equal to 3% from the thickness of the first mixed film. This enables more accurate determination of whether the combination of the substances can form a charge-transfer complex.

It is preferable that an organic compound having a higher lowest unoccupied molecular orbital (LUMO) level than the second organic compound 161_2 be used as the first organic compound 161_1. In this case, the first organic compound 161_1 and the second organic compound 161_2 easily interact with each other, and thus electrons can be easily donated to the second organic compound 161_2 from the donor level formed by the first organic compound 161_1 and the metal material 161_M. The first organic compound 161_1 preferably has a LUMO level higher than that of the second organic compound 161_2 by 0.05 eV or more. Alternatively, the first organic compound 161_1 preferably has a LUMO level higher than that of the second organic compound 161_2 by 0.1 eV or more, further preferably 0.2 eV or more.

For example, the LUMO level of the organic compound used as the first organic compound 161_1 is preferably higher than or equal to −3.0 eV and lower than or equal to −2.0 eV, further preferably higher than or equal to −2.7 eV and lower than or equal to −2.0 eV. In that case, electrons can be easily donated from the donor level formed by the first organic compound 161_1 and the metal material 161_M to the second organic compound 161_2. The LUMO level of the organic compound used as the second organic compound 161_2 is preferably higher than or equal to −3.0 eV and lower than or equal to −2.0 eV, further preferably higher than or equal to −3.0 eV and lower than or equal to −2.5 eV. This can increase the electron-transport property of the second organic compound 161_2.

As the first organic compound 161_1, an organic compound having a HOMO level higher than that of the second organic compound 161_2 is preferably used. In this case, the first organic compound 161_1 and the second organic compound 161_2 easily interact with each other, and thus electrons can be easily donated to the second organic compound 161_2 from the donor level formed by the first organic compound 161_1 and the metal material 161_M. The first organic compound 161_1 preferably has a HOMO level higher than that of the second organic compound 161_2 by 0.05 eV or more. Alternatively, the first organic compound 161_1 preferably has a HOMO level higher than that of the second organic compound 161_2 by 0.1 eV or more, further preferably 0.2 eV or more.

Note that the HOMO level and the LUMO level of an organic compound are generally estimated by cyclic voltammetry (CV), photoelectron spectroscopy, optical absorption spectroscopy, inverse photoemission spectroscopy, or the like. When values of different compounds are compared with each other, using values estimated by the same measurement is preferable.

As each of the first organic compound 161_1 and the second organic compound 161_2, an organic compound having an electron-transport property is preferably used. Examples of the organic compound having an electron-transport property include an organic compound having a heteroaromatic ring. As the heteroaromatic ring, specifically, a π-electron deficient heteroaromatic ring such as a pyridine ring, a pyrazine ring, a pyrimidine ring, a pyridazine ring, a triazine ring, an imidazole ring, a pyrazole ring, an oxazole ring, a thiazole ring, a triazole ring, or a condensed ring including any of these rings is preferable because it is electrochemically stable and has a high electron-transport property.

The heteroaromatic rings listed above each include a nitrogen atom having an unshared electron pair and thus are preferable because they can easily interact with the metal material 161_M.

As the first organic compound 161_1, an organic compound having an electron-donating group is preferably used. The use of the organic compound having an electron-donating group as the first organic compound 161_1 facilitates the interaction between the first organic compound 161_1 and the metal material 161_M. Furthermore, electrons can be easily donated to the second organic compound 161_2 from the donor level formed by the first organic compound 161_1 and the metal material 161_M.

Details of substances that can be used for the metal material 161_M, the first organic compound 161_1, and the second organic compound 161_2 will be described later.

### <Analysis of the Interaction Between Each Organic Compound and Metal Material by Quantum Chemistry Calculation>

Here, analysis by quantum chemistry calculation is performed on a case where the metal material 161_M, the first organic compound 161_1, and the second organic compound 161_2 interact with one another.

### <<Estimation of Interaction Between Each Organic Compound and Metal Material>>

First, the spin density and the electrostatic potential (ESP) at the time of interaction between the metal material 161_M, the first organic compound 161_1, and the second organic compound 161_2 are analyzed by quantum chemistry calculation. In the calculation, 4,7-di-1-pyrrolidinyl-1,10-phenanthroline (abbreviation: Pyrrd-Phen) is used as the first organic compound 161_1, 2,9-di(naphthalen-2-yl)-4,7-diphenyl-1,10-phenanthroline (abbreviation: NBPhen) or 2,2′-([2,2′-bipyridine]-6,6′-diyl)bis(4-phenylbenzo[h]quinazoline) (abbreviation: 6,6′(P-Bqn)2BPy) is used as the second organic compound 161_2, and silver (Ag) is used as the metal material 161_M. The following are structural formulae of Pyrrd-Phen, NBPhen, and 6,6′(P-Bqn)2BPy. Note that the phenanthroline ring in the structural formulae of Pyrrd-Phen and NBPhen is illustrated with positional numbers.

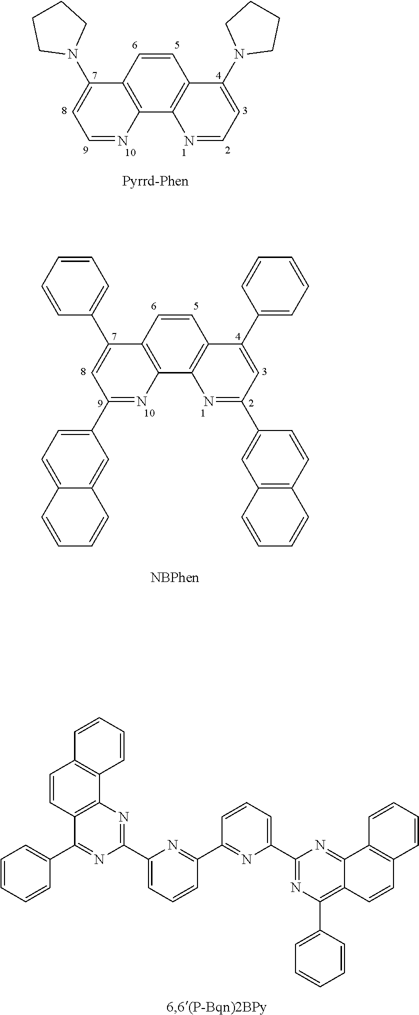 [SMILES: c1cc(N2CCCC2)c2ccc3c(N4CCCC4)ccnc3c2n1 ; c1ccc(-c2cc(-c3ccc4ccccc4c3)nc3c2ccc2c(-c4ccccc4)cc(-c4ccc5ccccc5c4)nc23)cc1 ; c1ccc(-c2nc(-c3cccc(-c4cccc(-c5nc(-c6ccccc6)c6ccc7ccccc7c6n5)n4)n3)nc3c2ccc2ccccc23)cc1]

As the quantum chemistry computational program, Gaussian 09 is used. The most stable structures of organic compounds and composite materials in the ground state are calculated by a density functional theory (DFT) using SGI 8600 produced by Hewlett Packard Enterprise (HPE). As basis functions, 6-311G(d,p) and LanL2DZ are used, and as a functional, B3LYP is used. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

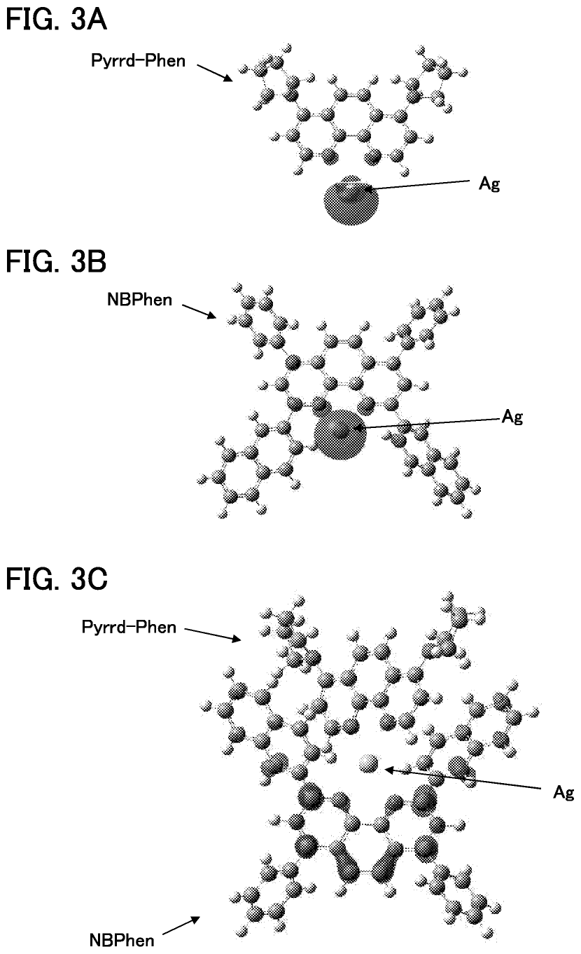

FIGS. 3A, 3B, and 3C illustrate results of analyzing the spin density distributions of composite materials in the ground state in the case where Pyrrd-Phen is used as the first organic compound 161_1, NBPhen is used as the second organic compound 161_2, and Ag is used as the metal material 161_M, and illustrate the spin density distributions of a composite material of the first organic compound (Pyrrd-Phen) and the metal material (Ag), a composite material of the second organic compound (NBPhen) and the metal material (Ag), and a composite material of the first organic compound (Pyrrd-Phen), the second organic compound (NBPhen), and the metal material (Ag), respectively. In the diagrams, spheres represent atoms included in the compounds. Clouds around some of the atoms represent the spin density distribution at the time when the density value in atomic units is 0.003 e/a₀³ (where e represents elementary charge (1 e=1.60218×10⁻¹⁹ C) and a₀ represents a Bohr radius (1 a₀=5.29177×10⁻¹¹ m)), showing localization of the doublet ground state in the compounds. Note that no spin density distribution is observed in Pyrrd-Phen in the ground state and NBPhen in the ground state because the ground states of Pyrrd-Phen and NBPhen are singlet ground states.

FIG. 3A illustrates the result of analyzing the spin density distribution of the composite material of the first organic compound (Pyrrd-Phen) and the metal material (Ag) in the ground state. In the composite material of the first organic compound (Pyrrd-Phen) and the metal material (Ag) in the doublet ground state, the first organic compound (Pyrrd-Phen) interacts with the metal material (Ag), and the metal material (Ag) is coordinated to the nitrogen atoms (N) having unshared electron pairs at the 1- and 10-positions in the 1,10-phenanthroline ring of the first organic compound (Pyrrd-Phen), which leads to stabilization of the composite material. Accordingly, as illustrated in FIG. 3A, some spins attributed to an unpaired electron of Ag are distributed over part of the 1,10-phenanthroline ring of Pyrrd-Phen, particularly the nitrogen atoms (N) having unshared electron pairs at the 1- and 10-positions. However, the interaction is weak, and thus, most spin densities are distributed over Ag. Hereinafter, the nitrogen atoms (N) having unshared electron pairs at the 1- and 10-positions in the 1,10-phenanthroline ring are referred to as N1 and N10 in some cases.

FIG. 3B illustrates the result of analyzing the spin density distribution of the composite material of the second organic compound (NBPhen) and the metal material (Ag) in the ground state. In the composite material of the second organic compound (NBPhen) and the metal material (Ag) in the doublet ground state, the second organic compound (NBPhen) interacts with the metal material (Ag), and the metal material (Ag) is coordinated to the N1 and the N10 of the second organic compound (NBPhen), which leads to stabilization of the composite material. Accordingly, as illustrated in FIG. 3B, some spins attributed to an unpaired electron of Ag are distributed over part of the 1,10-phenanthroline ring of NBPhen, particularly N1 and N10. However, the interaction is weak, and thus, most spin densities are distributed over Ag.

FIG. 3C illustrates the result of analyzing the spin density distribution of the composite material of the first organic compound (Pyrrd-Phen), the second organic compound (NBPhen), the metal material (Ag) in the ground state. In the composite material of the first organic compound (Pyrrd-Phen), the second organic compound (NBPhen), and the metal material (Ag) in the doublet ground state, the first organic compound (Pyrrd-Phen), the second organic compound (NBPhen), and the metal material (Ag) interact with one another, and the metal material (Ag) is coordinated to the N1 and the N10 of the first organic compound (Pyrrd-Phen) and the N1 and the N10 of the second organic compound (NBPhen), which leads to stabilization of the composite material. Accordingly, as illustrated in FIG. 3C, spins attributed to an unpaired electron of Ag are localized in NBPhen. Furthermore, no spin density distribution is observed in Ag. It is thus found that NBPhen is in a radical anion state owing to the interaction between Pyrrd-Phen, NBPhen, and Ag.

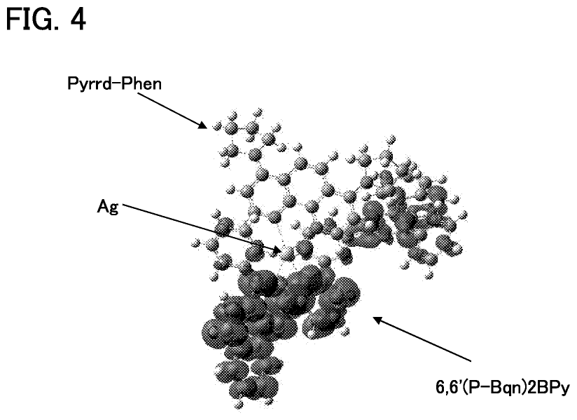

FIG. 4 illustrates a result of analyzing the spin density distribution of a composite material in the ground state of the first organic compound 161_1, the second organic compound 161_2, and the metal material 161_M in the case where Ag is used as the metal material 161_M, Pyrrd-Phen is used as the first organic compound 161_1, and 6,6′(P-Bqn)2BPy is used as the second organic compound 161_2. In the diagram, spheres represent atoms included in the compounds, and clouds around some of the atoms represent the spin density distribution at the time when the density threshold value (isovalue) is 0.0004 e/a₀³. The clouds represent localization of the doublet ground state in the compounds. Note that no spin density distribution is observed in Pyrrd-Phen in the ground state and 6,6′(P-Bqn)2BPy in the ground state because the ground states of Pyrrd-Phen and 6,6′(P-Bqn)2BPy are singlet ground states.

In the composite material of the first organic compound (Pyrrd-Phen), the second organic compound (6,6′(P-Bqn)2BPy), and the metal material (Ag) in the doublet ground state, the first organic compound (Pyrrd-Phen), the second organic compound (6,6′(P-Bqn)2BPy), and the metal material (Ag) interact with one another, and the metal material (Ag) is coordinated to the N1 and the N10 of the first organic compound (Pyrrd-Phen) and nitrogen atoms having unshared electron pairs in a pyridine ring and benzo[h]quinazoline ring of the second organic compound (6,6′(P-Bqn)2BPy), which leads to stabilization of the composite material. Accordingly, as illustrated in FIG. 4, spins attributed to an unpaired electron of Ag are localized in 6,6′(P-Bqn)2BPy. Furthermore, no spin density distribution is observed in Ag. This indicates that the second organic compound, 6,6′(P-Bqn)2Bpy, is in a radical anion state owing to the interaction between Pyrrd-Phen, 6,6′(P-Bqn)2BPy, and Ag.

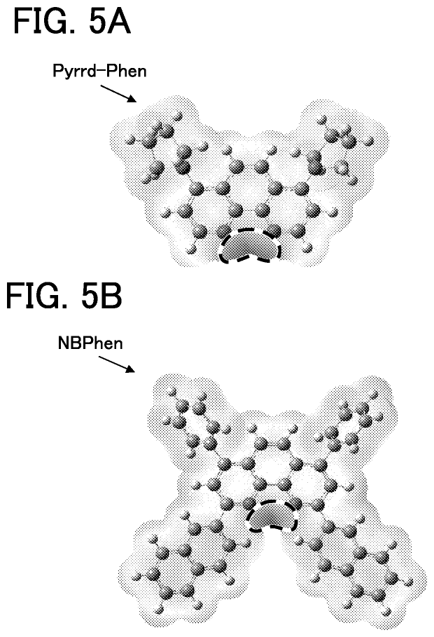

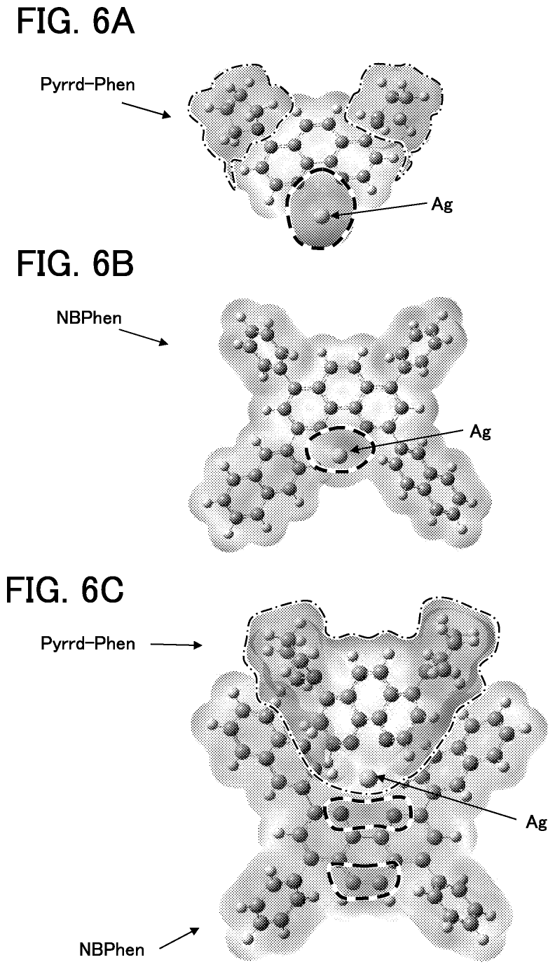

FIG. 5A, FIG. 5B, FIG. 6A, FIG. 6B, and FIG. 6C illustrate results of analyzing electrostatic potential maps of materials in the ground state in the case where Ag is used as the metal material 161_M, Pyrrd-Phen is used as the first organic compound 161_1, and NBPhen is used as the second organic compound 161_2, and illustrate the electrostatic potential maps of the first organic compound (Pyrrd-Phen), the second organic compound (NBPhen), the composite material of the first organic compound (Pyrrd-Phen) and the metal material (Ag), the composite material of the second organic compound (NBPhen) and the metal material (Ag), and the composite material of the first organic compound (Pyrrd-Phen), the second organic compound (NBPhen), and the metal material (Ag), respectively. In the diagrams, spheres represent atoms included in the compounds, and clouds around some of the atoms represent ESPs in electron density distribution at the time when the density value in atomic units is 0.003 e/a₀³. An ESP is the energy of interaction between a positive point charge with unit quantity of electricity and electron distribution of a molecule. An electrostatic potential map denotes ESPs on an electron density isosurface in colors; in the map, a region with a negative ESP is denoted in red, a region with a positive ESP is denoted in blue, an atom in the region with a negative ESP has negative charge, and an atom in the region with a positive ESP has positive charge. To show a region with a negative ESP and a region with a positive ESP in FIGS. 5A and 5B and FIGS. 6A to 6C, which are grayscale images, a deep red portion (i.e., the region with a negative ESP) is surrounded by a thick dotted line, and a deep blue portion (i.e., the region with a positive ESP) is surrounded by a thin dashed-dotted line.

FIG. 5A illustrates the result of analyzing the electrostatic potential map of the first organic compound (Pyrrd-Phen) in the ground state. According to FIG. 5A, ESPs around the N1 and the N10 in the first organic compound (Pyrrd-Phen) in the singlet ground state are negative. The N1 and the N10 each have a negative Mulliken partial charge of −0.29 e in atomic units. These results reveal that the N1 and the N10 in the first organic compound (Pyrrd-Phen) in the singlet ground state each have a negative partial charge.

FIG. 5B illustrates the result of analyzing the electrostatic potential map of the second organic compound (NBPhen) in the ground state. According to FIG. 5B, ESPs around the N1 and the N10 in the second organic compound (NBPhen) in the singlet ground state are negative. The N1 and the N10 each have a negative Mulliken partial charge of −0.34 e in atomic units. These results reveal that the N1 and the N10 in the second organic compound (NBPhen) in the singlet ground state each have a negative partial charge.

FIG. 6A illustrates the result of analyzing the electrostatic potential map of the composite material of the first organic compound (Pyrrd-Phen) and the metal material (Ag) in the ground state. In the composite material of the first organic compound (Pyrrd-Phen) and the metal material (Ag) in the doublet ground state, the first organic compound (Pyrrd-Phen) interacts with the metal material (Ag), and the metal material (Ag) is coordinated to the N1 and N10 of the first organic compound (Pyrrd-Phen), which leads to stabilization of the composite material. As a result, as illustrated in FIG. 6A, ESPs around the N1 and the N10 of Pyrrd-Phen and Ag are found to be negative. The N1 and the N10 each have a negative Mulliken partial charge of −0.37 e in atomic units. Moreover, Ag has a negative Mulliken partial charge of −0.18 e in atomic units. These results reveal that the N1, the N10, and Ag in the composite material of the first organic compound (Pyrrd-Phen) and the metal material (Ag) in the doublet ground state each have a negative partial charge.

FIG. 6B illustrates the result of analyzing the electrostatic potential map of the composite material of the second organic compound (NBPhen) and the metal material (Ag) in the ground state. In the composite material of the second organic compound (NBPhen) and the metal material (Ag) in the doublet ground state, the second organic compound (NBPhen) interacts with the metal material (Ag), and the metal material (Ag) is coordinated to the N1 and the N10 of the second organic compound (NBPhen), which leads to stabilization of the composite material. As a result, as illustrated in FIG. 6B, ESPs around the N1 and the N10 of NBPhen and Ag are found to be negative. The N1 and the N10 respectively have negative Mulliken partial charges of −0.45 e and −0.39 e in atomic units, and the metal material (Ag) has a negative Mulliken partial charge of −0.06 e in atomic units. These results reveal that the N1, the N10, and Ag in the composite material of the second organic compound (NBPhen) and the metal material (Ag) in the doublet ground state each have a negative partial charge.

FIG. 6C illustrates the result of analyzing the electrostatic potential map of the composite material of the first organic compound (Pyrrd-Phen), the second organic compound (NBPhen), and the metal material (Ag) in the ground state. In the composite material of the first organic compound (Pyrrd-Phen), the second organic compound (NBPhen), and the metal material (Ag) in the doublet ground state, the first organic compound (Pyrrd-Phen), the second organic compound (NBPhen), and the metal material (Ag) interact with one another, and the metal material (Ag) is coordinated to the N1 and the N10 of the first organic compound (Pyrrd-Phen) and the N1 and the N10 of the second organic compound (NBPhen), which leads to stabilization of the composite material. As a result, positive ESPs are mainly distributed around Ag and Pyrrd-Phen and negative ESPs are mainly distributed around NBPhen, as illustrated in FIG. 6C. It is also found that the ESPs around the N1 and the N10 of NBPhen are negative whereas the ESPs around Ag are positive. Furthermore, the N1 and the N10 of NBPhen each have a negative Mulliken partial charge of −0.52 e in atomic units, whereas Ag has a positive Mulliken partial charge of 0.39 e in atomic units. These results reveal that the charge of the Ag atom is distributed around the N1 and the N10 of NBPhen.

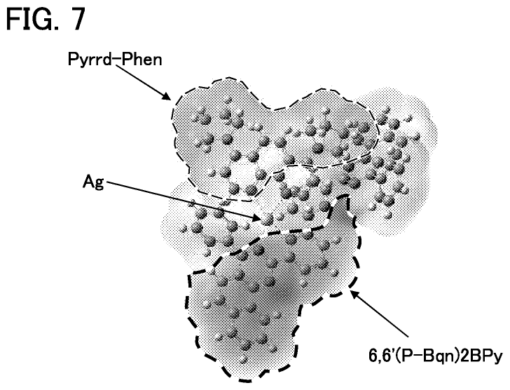

Next, FIG. 7 illustrates a result of analyzing the electrostatic potential map of the composite material of the first organic compound 161_1, the second organic compound 161_2, and the metal material in the case where Ag is used as the metal material 161_M, Pyrrd-Phen is used as the first organic compound 161_1, and 6,6′(P-Bqn)2BPy is used as the second organic compound 161_2. In the diagram, spheres represent atoms included in the compounds, and clouds around some of the atoms represent ESPs in electron density distribution at the time when the density threshold value (isovalue) is 0.0004 [electrons/au³]. To show a region with a negative ESP and a region with a positive ESP in FIG. 7, a deep red portion (i.e., the region with a negative ESP) is surrounded by a thick dotted line, and a deep blue portion (i.e., the region with a positive ESP) is surrounded by a thin dashed-dotted line.

In the composite material of the first organic compound (Pyrrd-Phen), the second organic compound (6,6′(P-Bqn)2BPy), and the metal material (Ag) in the doublet ground state, the first organic compound (Pyrrd-Phen), the second organic compound (6,6′(P-Bqn)2BPy), and the metal material (Ag) interact with one another, and the metal material (Ag) is coordinated to the N1 and the N10 of the first organic compound (Pyrrd-Phen) and nitrogen atoms having unshared electron pairs in a pyridine ring and benzo[h]quinazoline ring of the second organic compound (6,6′(P-Bqn)2BPy), which leads to stabilization of the composite material. As a result, positive ESPs are mainly distributed around Ag and Pyrrd-Phen, and negative ESPs are mainly distributed around 6,6′(P-Bqn)2BPy, as illustrated in FIG. 7. It is also shown that ESPs of the nitrogen atoms having unshared electron pairs in the pyridine ring and the benzo[h]quinazoline ring of 6,6′(P-Bqn)2BPy are negative whereas ESPs of Ag are positive. The Ag atom has a Mulliken partial charge of +0.372 e in atomic units.

In view of the above, it is found that the first organic compound 161_1 and the metal material 161_M interact with each other to form an electron donor and function as an electron donor in combination with respect to the second organic compound 161_2 having an electron-transport property. In one embodiment of the present invention, the composite material of the above combination is used for at least one of the intermediate layer and the electron-injection layer, whereby at least one of the intermediate layer and the electron-injection layer can have a favorable electron-injection property and resistance to oxygen and water in the air and water and a chemical solution used during the lithography process; thus, the light-emitting device can have a reduced driving voltage and high emission efficiency.

### <<Estimation of SOMO Level and Stabilization Energy>>

Next, quantum chemistry calculation is performed for estimation of the stabilization energy at the time when the metal material 161_M, the first organic compound 161_1, and the second organic compound 161_2 interact with one another and the SOMO level or the HOMO level formed at the time of the interaction. In the calculation, silver (Ag), aluminum (Al), copper (Cu), or indium (In) is used as the metal material 161_M, Pyrrd-Phen is used as the first organic compound 161_1, and 2,2′-(1,3-phenylene)bis(9-phenyl-1,10-phenanthroline) (abbreviation: mPPhen2P), NBPhen, 6,6′(P-Bqn)2BPy, 4′,4″″-(1,4-phenylene)bis(2,2′:6′,2″-terpyridine) (abbreviation: tPy2P), or 2,4,6-tris(2-pyridyl)-1,3,5-triazine (abbreviation: 2Py3Tzn) is used as the second organic compound 161_2.

The following are structural formulae of Pyrrd-Phen, mPPhen2P, NBPhen, 6,6′(P-Bqn)2BPy, tPy2P, and 2Py3Tzn. Note that 6,6′(P-Bqn)2BPy, tPy2P, and 2Py3Tzn are each an organic compound having two or more heteroaromatic rings that are bonded or condensed to each other and include three or more heteroatoms in total. Meanwhile, NBPhen is an organic compound having two or more heteroaromatic rings that are bonded or condensed to each other and include less than three heteroatoms in total.

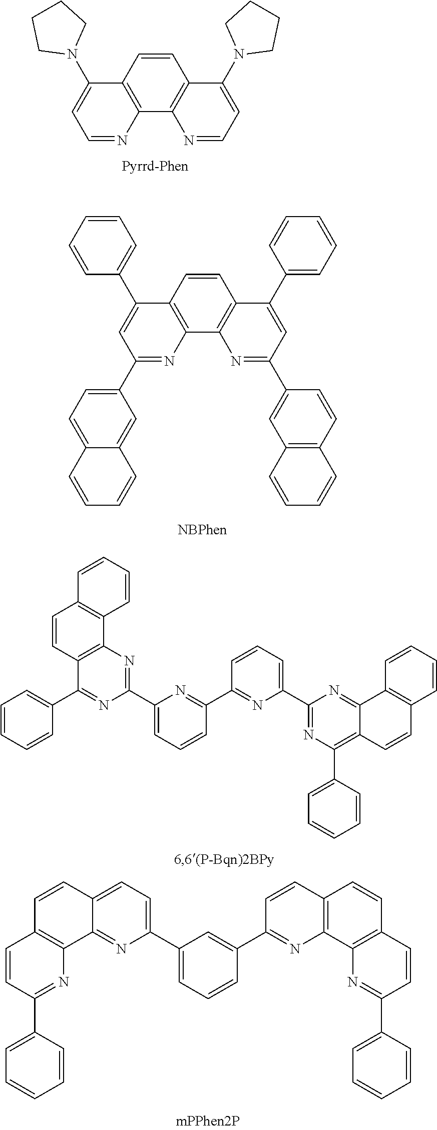 [SMILES: c1cc(N2CCCC2)c2ccc3c(N4CCCC4)ccnc3c2n1 ; c1ccc(-c2cc(-c3ccc4ccccc4c3)nc3c2ccc2c(-c4ccccc4)cc(-c4ccc5ccccc5c4)nc23)cc1 ; c1ccc(-c2nc(-c3cccc(-c4cccc(-c5nc(-c6ccccc6)c6ccc7ccccc7c6n5)n4)n3)nc3c2ccc2ccccc23)cc1 ; c1ccc(-c2ccc3ccc4ccc(-c5cccc(-c6ccc7ccc8ccc(-c9ccccc9)nc8c7n6)c5)nc4c3n2)cc1]

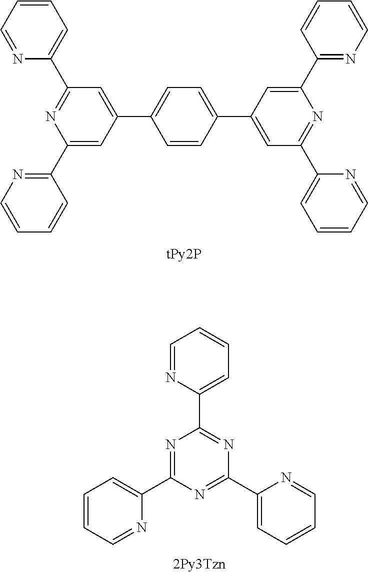 [SMILES: c1ccc(-c2cc(-c3ccc(-c4cc(-c5ccccn5)nc(-c5ccccn5)c4)cc3)cc(-c3ccccn3)n2)nc1 ; c1ccc(-c2nc(-c3ccccn3)nc(-c3ccccn3)n2)nc1]

As the quantum chemistry computational program, Gaussian 09 is used. The calculation is performed using SGI 8600 produced by HPE. First, DFT calculation of the most stable structure in the ground state is performed on the following materials: the first organic compound 161_1, the second organic compound 161_2, the metal material 161_M, the composite material of the first organic compound 161_1 and the metal material 161_M, the composite material of the second organic compound 161_2 and the metal material 161_M, and the composite material of the first organic compound 161_1, the second organic compound 161_2, and the metal material 161_M. As basis functions, 6-311G(d,p) and LanL2DZ are used, and as a functional, B3LYP is used. Next, the stabilization energy is calculated by subtracting the sum of the total energy of the organic compound(s) and the total energy of the metal element from the total energy of the composite material of the organic compound(s) and the metal element. That is, the following equation is satisfied: (stabilization energy)=(the total energy of the composite material of the organic compound(s) and the metal element)−(the total energy of the organic compound(s))−(the total energy of the metal element).

The following tables show the results of calculating the stabilization energy of the composite materials of the first organic compound 161_1, the second organic compound 161_2, and the metal material 161_M.

Table 1 shows the calculation results of the composite material using Pyrrd-Phen as the first organic compound 161_1, mPPhen2P as the second organic compound 161_2, and Ag as the metal material 161_M. Table 1 also shows the stabilization energy of the composite material of Ag and Pyrrd-Phen and the stabilization energy of the composite material of mPPhen2P and Ag.

TABLE 1

| | Stabilization |
|---|---|
| | energy (eV) |
| Pyrrd-Phen + mPPhen2P + Ag | −1.18 |
| Pyrrd-Phen + Ag | −0.41 |
| mPPhen2P + Ag | −0.14 |

In Table 1, the stabilization energy of the composite material of Pyrrd-Phen and Ag and the stabilization energy of the composite material of mPPhen2P and Ag are negative, revealing that the state where Ag and either Pyrrd-Phen or mPPhen2P interact with each other is energetically more stable than the state where Ag and either Pyrrd-Phen or mPPhen2P do not interact with each other. It is found that the absolute value of the stabilization energy is small and the interaction between Ag and either Pyrrd-Phen or mPPhen2P is weak.

Table 1 also shows that the composite material of Pyrrd-Phen, mPPhen2P, and Ag has lower stabilization energy than the composite material of Pyrrd-Phen and Ag and the composite material of mPPhen2P and Ag, and is energetically stable. The stabilization energy of the composite material of the metal material 161_M, the first organic compound 161_1, and the second organic compound 161_2 is preferably lower than or equal to −0.50 eV, further preferably lower than or equal to −1.0 eV, lower than or equal to −2.0 eV, lower than or equal to −3.0 eV, lower than or equal to −4.0 eV.

Next, Table 2 shows calculation results of composite materials including Pyrrd-Phen as the first organic compound 161_1, mPPhen2P as the second organic compound 161_2, and a metal belonging to an odd-numbered group (Group 3, Group 5, Group 7, Group 9, Group 11, or Group 13), specifically Al, Ag, Cu, or In, as the metal material 161_M.

TABLE 2

| | Stabilization | SOMO |
|---|---|---|
| | energy (eV) | level (eV) |
| Pyrrd-Phen + mPPhen2P + Al | −4.11 | −2.82 |
| Pyrrd-Phen + mPPhen2P + Ag | −1.18 | −2.35 |
| Pyrrd-Phen + mPPhen2P + Cu | −3.97 | −2.39 |
| Pyrrd-Phen + mPPhen2P + In | −1.10 | −2.83 |

Table 2 shows that the stabilization energy of the composite material of Pyrrd-Phen, mPPhen2P, and Al is lower than or equal to −4.0 eV, the stabilization energy of the composite material of Pyrrd-Phen, mPPhen2P, and Cu is lower than or equal to −3.0 eV, the stabilization energy of the composite material of Pyrrd-Phen, mPPhen2P, and Ag and the stabilization energy of the composite material of Pyrrd-Phen, mPPhen2P, and In are each lower than or equal to −1.0 eV. Thus, the metal element belonging to an odd-numbered group is preferably used, in which case the composite material of the first organic compound 161_1, the second organic compound 161_2, and the metal material 161_M can have a stabilization energy lower than or equal to −1.0 eV, lower than or equal to −3.0 eV, or lower than or equal to −4.0 eV and is energetically more stable. The calculated SOMO levels of these composite materials are higher than the calculated HOMO level (−5.65 eV) of Pyrrd-Phen and the calculated HOMO level of mPPhen2P (−5.88 eV). The SOMO level is preferably high, in which case the intermediate layer and the electron-injection layer using the composite material can have a higher electron-injection property.

Next, calculation is performed on composite materials including Pyrrd-Phen as the first organic compound 161_1, 6,6′(P-Bqn)2BPy, tPy2P, 2Py3Tzn, or NBPhen as the second organic compound 161_2, and a metal belonging to Group 11 or 13, specifically Ag, Al, or In, as the metal material 161_M.

Table 3 shows the calculation results for the case where Pyrrd-Phen is used as the first organic compound 161_1, 6,6′(P-Bqn)2BPy or NBPhen is used as the second organic compound 161_2, and Ag is used as the metal material 161_M. Note that Table 3 also lists calculation results of a composite material of Pyrrd-Phen and Ag, a composite material of 6,6′(P-Bqn)2BPy and Ag, and a composite material of NBPhen and Ag.

TABLE 3

| | Stabilization | SOMO |
|---|---|---|
| | energy (eV) | level (eV) |
| Pyrrd-Phen + 6,6′(P-Bqn)2BPy + Ag | −1.29 | −2.35 |
| Pyrrd-Phen + NBPhen + Ag | −1.26 | −2.50 |
| Pyrrd-Phen + Ag | −0.41 | −2.87 |
| 6,6′(P-Bqn)2BPy + Ag | −0.73 | −2.86 |
| NBPhen + Ag | −0.23 | −3.26 |

Table 4 shows the LUMO and HOMO levels of Pyrrd-Phen, 6,6′(P-Bqn)2BPy, tPy2P, 2Py3 Tzn, and NBPhen. Note that the values of the energy levels of the HOMO and LUMO levels in the table are calculated and might have absolute values different from those of measured values.

TABLE 4

| | LUMO | HOMO |
|---|---|---|
| | level (eV) | level (eV) |
| Pyrrd-Phen | −1.35 | −5.65 |
| 6,6′(P-Bqn)2BPy | −2.07 | −5.99 |
| tPy2P | −1.65 | −6.37 |
| 2Py3Tzn | −2.20 | −6.89 |
| NBPhen | −2.04 | −5.74 |

According to Table 3, the stabilization energy of the composite material of Pyrrd-Phen, 6,6′(P-Bqn)2Bpy, and Ag is negative, and the absolute value thereof is large. This indicates that the state where Pyrrd-Phen, 6,6′(P-Bqn)2BPy, and Ag interact with one another is energetically more stable than the case where Pyrrd-Phen, 6,6′(P-Bqn)2BPy, and Ag do not interact with one another. According to Table 3 and Table 4, the SOMO level of the composite material is higher than the HOMO level of each of Pyrrd-Phen and 6,6′(P-Bqn)2BPy and has a small difference from the LUMO level of each of Pyrrd-Phen and 6,6′(P-Bqn)2BPy, in which case the intermediate layer or the electron-injection layer using the composite material can have an excellent electron-injection property.

In Table 3, the stabilization energy of a composite material of Pyrrd-Phen, NBPhen, and Ag is also negative, revealing that the state where Pyrrd-Phen, NBPhen, and Ag interact with one another is energetically more stable than the state where Pyrrd-Phen, NBPhen, and Ag do not interact with one another.

Moreover, the composite material of 6,6′(P-Bqn)2Bpy and Ag has a low SOMO level of −2.86 eV. The composite material of 6,6′(P-Bqn)2BPy, Pyrrd-Phen, and Ag has a SOMO level of −2.35 eV, which is higher than that of the composite material of 6,6′(P-Bqn)2Bpy and Ag, and has an excellent electron-injection property. The composite material of 6,6′(P-Bqn)2Bpy and Ag has a stabilization energy of −0.73 eV, while the composite material of 6,6′(P-Bqn)2BPy, Pyrrd-Phen, and Ag has a stabilization energy of −1.29 eV and is more stable.

Furthermore, the composite material of Ag and NBPhen has a low SOMO level of −3.26 eV. On the other hand, the composite material of Ag, NBPhen, and Pyrrd-Phen has as high a SOMO level as −2.50 eV and thus has an excellent electron-injection property. The composite material of Ag and NBPhen has a stabilization energy of −0.23 eV, while the composite material of Ag, NBPhen, and Pyrrd-Phen has a stabilization energy of −1.26 eV and is more stable.

Table 5 shows the calculation results for the case where Pyrrd-Phen is used as the first organic compound 161_1, 6,6′(P-Bqn)2BPy, tPy2P, 2Py3Tzn, or NBPhen is used as the second organic compound 161_2, and In or Al is used as the metal material 161_M.

TABLE 5

| | Stabilization | SOMO |
|---|---|---|
| | energy (eV) | level (eV) |
| Pyrrd-Phen + tPy2P + In | −2.15 | −3.03 |
| Pyrrd-Phen + NBPhen + In | −1.25 | −3.02 |
| Pyrrd-Phen + 2Py3Tzn + Al | −5.76 | −3.21 |
| Pyrrd-Phen + NBPhen + Al | −4.28 | −3.10 |

According to Table 5, the stabilization energy of a composite material of In or Al, Pyrrd-Phen, and tPy2P, 2Py3Tzn, or NBPhen is negative, and the absolute value thereof is large.

Thus, the stabilization energy of the composite material of the metal belonging to Group 11 or Group 13, the first organic compound 161_1, and the second organic compound 161_2 is stable and thus the composite material is preferable. The SOMO level formed at this time is high and the electron-injection property is excellent; thus, the composite material is preferable.

From the above calculation results, it can be said that the composite material using the first organic compound 161_1, the second organic compound 161_2, and the metal material 161_M is stable and has an excellent electron-injection property and thus is suitable for an intermediate layer or an electron-injection layer.

In a general manufacturing process of a light-emitting device, an organic compound layer, particularly an intermediate layer, of the light-emitting device is formed by a vacuum evaporation method in many cases. Thus, it is preferable to use a material that can be easily deposited by vacuum evaporation, i.e., a material with a low melting point. The metals belonging to Group 11 and Group 13 have low melting points and thus can be suitably used for vacuum evaporation. The metals belonging to Group 11 and Group 13 are preferable because they are stable with respect to oxygen and water in the air. A vacuum evaporation method is preferably used, in which case a metal atom and an organic compound can be easily mixed.

Furthermore, each of Ag, Al, and In can be used also as a cathode material. The intermediate layer and the cathode are preferably formed using the same material, in which case the light-emitting device can be manufactured easily. In addition, the manufacturing cost of the light-emitting device can be reduced.

### <<Analysis of Composite Material of Metal and Organic Compounds>>

At least one of the intermediate layer and the electron-injection layer to which the layer 200 is applied in the light-emitting device of one embodiment of the present invention can be measured as a composite material in which the first organic compound 161_1, the second organic compound 161_2, and the metal material 161_M interact with each other.

Specifically, a film formed at a mixture ratio similar to that of the intermediate layer used in the light-emitting device is prepared, and the film is measured by, for example, mass spectrometry such as time-of-flight secondary ion mass spectrometry (ToF-SIMS), laser desorption/ionization mass spectrometry (LDI-MS), or matrix assisted laser desorption/ionization mass spectrometry (MALDI-MS).

As a result of the mass analysis, in the case where the mass number of the first organic compound 161_1 is M1, the mass number of the second organic compound 161_2 is M2, and the mass number of the metal material 161_M is M3, positive ions with a mass-to-charge ratio, m/z, of M1+M2+M3 or M1+M2+M3+1 can be detected. In the case where positive ions are measured by the aforementioned mass spectrometry, detected ions are derived from a compound included in the film, a substituent desorbed from the compound, a compound from which a substituent has been desorbed, and association thereof. Thus, for example, in the case where the mass number of the metal desorbed from the metal compound is 31, positive ions with m/z of M1+M2+31 or M1+M2+31+1 can be detected.

Next, substances that can be used for the metal material 161_M, the first organic compound 161_1, and the second organic compound 161_2 are described in detail.

### <Metal Material 161_M>

As described above, the metal material 161_M is at least one of a metal and a metal compound. At least one of the metal and the metal compound preferably includes at least one selected from metal elements belonging to Group 3 to Group 14 of the periodic table.

As the metal elements belonging to Group 3 to Group 11 in the periodic table (i.e., the transition elements), there are a Group 3 element including lanthanoids such as yttrium (Y), europium (Eu), or ytterbium (Yb), a Group 4 element such as titanium (Ti), a Group 5 element such as vanadium (V), a Group 5 element such as chromium (Cr), a Group 7 element such as manganese (Mn), a Group 8 element such as iron (Fe), a Group 9 element such as cobalt (Co), a Group 10 element such as nickel (Ni) or platinum (Pt), and a Group 11 element such as copper (Cu), silver (Ag), or gold (Au). The transition element is preferable because of having low reactivity with components of the air such as water and oxygen.

As the metal elements belonging to Group 12 to Group 14, there are a Group 12 element such as zinc (Zn), an earth metal (Group 13 element) such as aluminum (Al) or indium (In), and a Group 14 element such as tin (Sn).

Among the above-described elements, metal elements belonging to odd-numbered groups (Group 3, Group 5, Group 7, Group 9, Group 11, and Group 13) in the periodic table are further preferable. A metal material that includes a metal element having one electron (an unpaired electron) in the orbital of the outermost shell out of those metal elements is particularly preferably used because of being likely to form SOMO with the first organic compound 161_1.

A metal material including a metal element that has a low melting point and can be deposited by a vacuum evaporation method among the above-described metal elements is preferably used because of being able to easily form a mixed layer with an organic compound. Specifically, for example, the metals belonging to Group 11 and Group 13 have low melting points and thus can be suitably used for vacuum evaporation. The metals belonging to Group 11 and Group 13 are preferable because they are stable with respect to oxygen and water in the air.

In the case where the metal material 161_M is the metal compound, specific examples of the metal compound include a metal oxide and a metal nitride containing at least one selected from the above-described metal elements.

Note that even when a metal is used as a raw material in forming the layer 200, the metal might be oxidized in a step such as deposition or exposure to the air to become a metal oxide. In such a case, the layer 200 may contain both a metal and a metal compound.

The content of the metal material 161_M in the layer 200 is preferably greater than or equal to 0.1% and less than or equal to 5%, further preferably greater than or equal to 1% and less than or equal to 5% by volume. In the case where the layer 200 is formed by a vacuum evaporation method, the layer 200 having such a content is preferable because it can be a uniform film and improve the characteristics of the light-emitting device.

The content of an element included in a film can be analyzed by secondary ion mass spectrometry (SIMS) or X-ray photoelectron spectroscopy (XPS), for example. When the content percentage of a target element is high (e.g., higher than or equal to 0.5 atomic %, or higher than or equal to 1 atomic %), XPS is suitable. By contrast, SIMS is suitable when the content percentage of a target element is low (e.g., lower than or equal to 0.5 atomic %, or lower than or equal to 1 atomic %). To compare the contents of elements, analysis with a combination of SIMS and XPS is preferably used.

### <First Organic Compound 161_1>

As the first organic compound 161_1, an organic compound having an electron-transport property is preferably used. Examples of the organic compound having an electron-transport property include an organic compound having a heteroaromatic ring. Among organic compounds having a heteroaromatic ring, an organic compound having a π-electron deficient heteroaromatic ring that has particularly high electrochemical stability and a particularly high electron-transport property is further preferably used. In order that the first organic compound 161_1 and the metal material 161_M may interact with each other to function as an electron donor with respect to the second organic compound 161_2, the π-electron deficient heteroaromatic ring preferably includes an unshared electron pair, and the unshared electron pair preferably has an electron-donating property. In other words, the first organic compound 161_1 preferably includes a basic π-electron deficient heteroaromatic ring. Moreover, nitrogen has high electronegativity and thus easily interacts with a metal. Here, since nitrogen can form a conjugated bond in an organic compound, nitrogen enables the organic compound to have a high carrier-transport property when used in the molecule, particularly in a heteroaromatic ring. Accordingly, the first organic compound 161_1 preferably includes a heteroaromatic ring including nitrogen. It is further preferable that the heteroaromatic ring be an even-numbered ring such as a six-membered ring or an eight-membered ring. Since the unshared electron pair of nitrogen does not contribute to the conjugation in this structure, nitrogen is likely to interact with the metal material 161_M. To inject and transport electrons smoothly from the intermediate layer to the electron-transport layer, the first organic compound 161_1 preferably has an electron-transport property. Specifically, for example, the first organic compound 161_1 preferably includes a pyridine ring.

It is preferable that the first organic compound 161_1 include two or more π-electron deficient heteroaromatic rings and that the two or more π-electron deficient heteroaromatic rings be bonded or condensed to each other. This can stabilize the intermediate layer when the metal material 161_M interacts with the first organic compound 161_1 and the second organic compound 161_2 each serving as a bidentate or multidentate ligand; thus, the intermediate layer that is less likely to deteriorate even through a lithography process involving exposure to the air can be formed. Thus, electrons generated in the intermediate layer can be smoothly injected and transported to an adjacent electron-transport layer even through a lithography process involving exposure of the EL layer to the air, so that a tandem light-emitting device in which an increase in driving voltage can be inhibited and which has high emission efficiency and high reliability can be manufactured through a lithography process. Specifically, for example, the first organic compound 161_1 preferably includes a heteroaromatic ring having two or more pyridine rings. In particular, an organic compound having a bipyridine skeleton is preferable because its nitrogen atoms are likely to coordinate with a metal and thus the organic compound easily interacts with the metal material 161_M.

Furthermore, a phenanthroline ring is preferable because of its rigidity and high stability. Among organic compounds having a phenanthroline ring, an organic compound having a 1,10-phenanthroline ring, the two nitrogen atoms of which can be coordinated to a metal, is particularly preferably used to facilitate interaction with the metal material 161_M.

The first organic compound 161_1 may have a structure where a plurality of phenanthroline rings are bonded to each other via a single bond or a divalent group. Specific examples of the divalent group include an alkylene group and an arylene group.

The alkylene group refers to a divalent group obtained by eliminating two hydrogen atoms from an alkane. Specific examples of an alkylene group include a divalent group having a structure obtained by eliminating one hydrogen atom from any of the above specific examples of an alkyl group.

The arylene group refers to a divalent group obtained by eliminating two hydrogen atoms from an aromatic hydrocarbon. Specific examples of an arylene group include a divalent group having a structure obtained by eliminating one hydrogen atom from any of the above specific examples of an aryl group. Note that the arylene group may further have a substituent, and specific examples of the substituent include an alkyl group, an alkoxy group, and a phenyl group.

The first organic compound 161_1 preferably includes an electron-donating substituent. Accordingly, the first organic compound 161_1 can have a high HOMO level and a high LUMO level; thus, the difference between the LUMO level of the first organic compound 161_1 and the LUMO level of the second organic compound 161_2 can be increased, in which case the composite material formed by the interaction between the metal material 161_M, the first organic compound 161_1, and the second organic compound 161_2 can be stabilized and the intermediate layer that is less likely to deteriorate even through a lithography process involving exposure to the air can be formed. Thus, electrons generated in the intermediate layer can be smoothly injected and transported to an adjacent electron-transport layer even through a lithography process involving exposure of the EL layer to the air, so that a tandem light-emitting device in which an increase in driving voltage can be inhibited and which has high emission efficiency and high reliability can be manufactured through a lithography process.

Among organic compounds having a phenanthroline ring, an organic compound having a 1,10-phenanthroline ring, the two nitrogen atoms of which can be coordinated to a metal, is particularly preferably used to facilitate interaction with the metal material 161_M.

As the first organic compound 161_1, an organic compound having a phenanthroline ring with an electron-donating group is further preferably used. Specifically, introducing an electron-donating group to a 1,10-phenanthroline ring can increase the electron density of the phenanthroline ring, thereby increasing the efficiency of the interaction with the metal material 161_M. Furthermore, an electron-donating group is preferably bonded to at least one of the 4- and 7-positions of the 1,10-phenanthroline ring. Introducing electron-donating groups to the 4- and 7-positions can increase the electron density of the nitrogen atoms at the 1- and 10-positions, which are the para-positions with respect to the 4- and 7-positions. In addition, steric congestion around the nitrogen atoms at the 1- and 10-positions can be inhibited, and the electron density around the nitrogen atoms can be increased. This structure facilitates the interaction with the metal material 161_M and is thus preferable.

When the first organic compound 161_1 has strong basicity, the first organic compound 161_1 can easily interact with holes. This can significantly reduce the hole-transport property in the first layer 161a using the first organic compound 161_1. Thus, hole transport from the first layer 161a to the second layer 162a can be prevented, enabling a highly efficient light-emitting device, which is preferable. Specifically, the acid dissociation constant pKₐ of the first organic compound 161_1 is preferably greater than or equal to 8, further preferably greater than or equal to 10, still further preferably greater than or equal to 12.

Specific examples of the electron-donating group include an alkyl group, an alkoxy group, an aryloxy group, an alkylamino group, an arylamino group, and a heterocyclic amino group. Note that examples of the electron-donating group that is preferably introduced to the phenanthroline ring are not limited to the above examples. The electron-donating group may be any group that can increase the electron density of the phenanthroline ring by being introduced to the phenanthroline ring. The electron-donating group may be introduced to the phenanthroline ring via an arylene group such as a phenylene group, and the arylene group is preferably a p-phenylene group.

The alkyl group refers to a monovalent group obtained by eliminating one hydrogen atom from an alkane (CₙH₂ₙ₊₂). Specific examples of the alkyl group include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

The alkoxy group refers to a monovalent group with a structure where an alkyl group is bonded to an oxygen atom. Specific examples of the alkoxy group include a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neopentyloxy group, an n-hexyloxy group, an isohexyloxy group, a sec-hexyloxy group, a tert-hexyloxy group, and a neohexyloxy group.

The aryloxy group refers to a monovalent group with a structure where an aryl group is bonded to an oxygen atom. The aryl group refers to a monovalent group obtained by eliminating one hydrogen atom from one of carbon atoms forming the ring(s) of a monocyclic or polycyclic aromatic compound. Specific examples of the aryloxy group include a phenoxy group, an o-tolyloxy group, an m-tolyloxy group, a p-tolyloxy group, a mesityloxy group, an o-biphenyloxy group, an m-biphenyloxy group, ap-biphenyoxyl group, a 1-naphthyloxy group, a 2-naphthyloxy group, and a 2-fluorenyloxy group. Note that the aryloxy group may further have a substituent, and specific examples of the substituent include an alkyl group, an alkoxy group, and a phenyl group.

The alkylamino group refers to a monovalent group obtained by eliminating one hydrogen atom from the nitrogen atom of a primary amine in which one alkyl group is bonded to the nitrogen atom, or from the nitrogen atom of a secondary amine in which two alkyl groups are bonded to the nitrogen atom. Specific examples of the alkylamino group include a dimethylamino group and a diethylamino group.

The arylamino group refers to a monovalent group obtained by eliminating one hydrogen atom from the nitrogen atom of a primary amine in which one aryl group is bonded to the nitrogen atom, or from the nitrogen atom of a secondary amine in which two aryl groups are bonded to the nitrogen atom. Specific examples of the arylamino group include a diphenylamino group, a bis(a-naphthyl)amino group, and a bis(m-tolyl)amino group. Note that the arylamino group may further have a substituent, and specific examples of the substituent include an alkyl group, an alkoxy group, and a phenyl group.

Note that an amino group having a structure where both an alkyl group and an aryl group are bonded to the nitrogen atom can be regarded as an alkylamino group or an arylamino group. Specific examples of such an amino group include an N-methyl-N-phenylamino group.

A heterocyclic amino group refers to a monovalent group obtained by eliminating one hydrogen atom from one of the nitrogen atoms forming a ring of a heterocyclic amine. Here, the heterocyclic amine refers to a monocyclic or polycyclic heterocyclic compound in which at least one of the atoms forming the ring(s) is a nitrogen atom bonded to a hydrogen atom. Specific examples of the heterocyclic amino group include groups represented by Structural Formulae (R-1) to (R-27) below. Note that the heterocyclic amino group may further have a substituent, and specific examples of the substituent include an alkyl group, an alkoxy group, and a phenyl group.

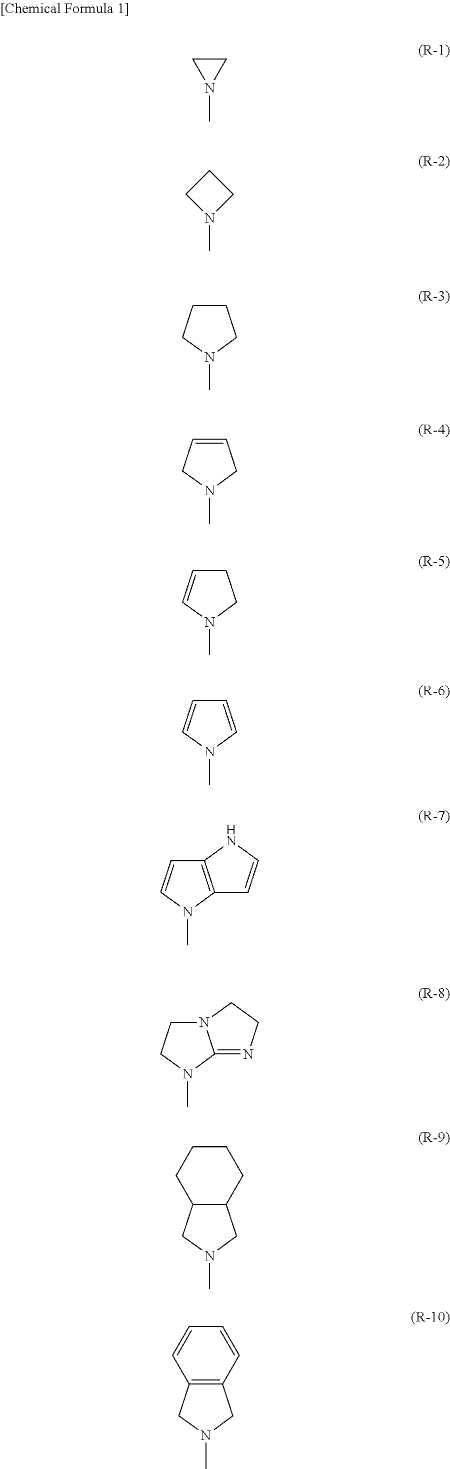

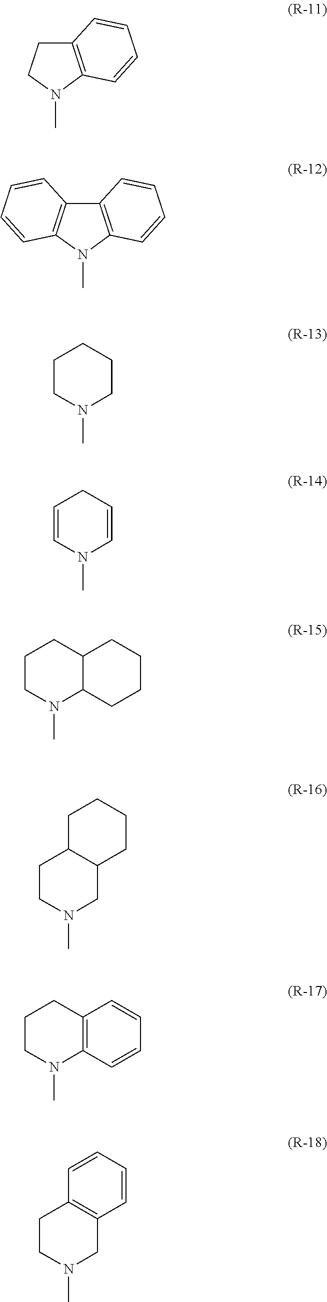

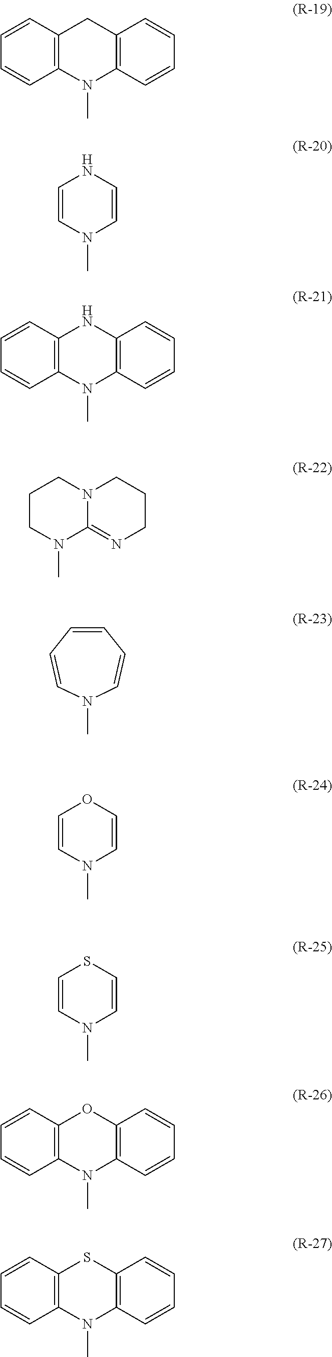

In some cases, the property of donating electrons to the phenanthroline ring is lower in a heterocyclic amino group which has aromaticity and in which an unshared electron pair of the nitrogen atom contributes to the aromaticity than in a heterocyclic amino group which has aromaticity and in which an unshared electron pair of the nitrogen atom does not contribute to the aromaticity. Thus, among the above heterocyclic amino groups, a heterocyclic amino group which has aromaticity and in which an unshared electron pair of the nitrogen atom does not contribute to the aromaticity is further preferable. Specifically, the group represented by Structural Formula (R-1), (R-2), (R-3), (R-4), (R-5), (R-8), (R-9), (R-10), (R-12), (R-14), (R-15), (R-16), (R-17), (R-18), or (R-22) is further preferably used as the electron-donating group. Among these groups, the group represented by Structural Formula (R-3), (R-4), (R-8), or (R-22) is preferably used because the group has a high electron-donating property and can further increase the electron density of the phenanthroline ring.

Specific examples of the electron-donating group include groups represented by Structural Formulae (R-28) and (R-29) below.

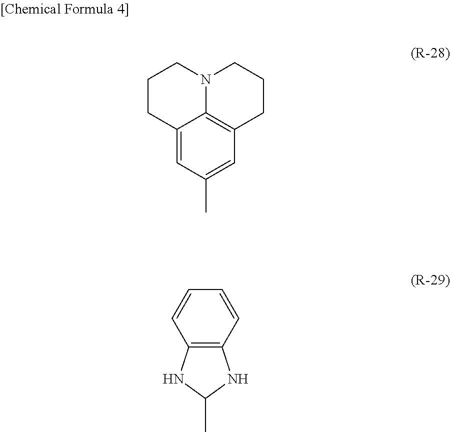

Note that an organic compound having a phenanthroline ring that can be used as the first organic compound 161_1 may have both the above-described electron-donating group and another substituent. Note that introduction of an electron-withdrawing group (e.g., a cyano group or a fluoro group) to the phenanthroline ring is not preferable because the introduction reduces the electron density of the phenanthroline ring and inhibits the interaction with the metal material 161_M in some cases. Specific examples of the substituent that can be introduced to the phenanthroline ring together with the above electron-donating group include an aryl group. Specific examples of the aryl group include a phenyl group, an o-tolyl group, an m-tolyl group, a p-tolyl group, a mesityl group, an o-biphenyl group, an m-biphenyl group, a p-biphenyl group, a 1-naphthyl group, a 2-naphthyl group, and a 2-fluorenyl group. Note that the aryl group may further have a substituent, and specific examples of the substituent include an alkyl group, an alkoxy group, and a phenyl group.

The first organic compound 161_1 may have a structure where a plurality of phenanthroline rings are bonded to each other via a single bond or a divalent group. Specific examples of the divalent group include an alkylene group and an arylene group.

The alkylene group refers to a divalent group obtained by eliminating two hydrogen atoms from an alkane. Specific examples of an alkylene group include a divalent group having a structure obtained by eliminating one hydrogen atom from any of the above specific examples of an alkyl group.

The arylene group refers to a divalent group obtained by eliminating two hydrogen atoms from an aromatic hydrocarbon. Specific examples of an arylene group include a divalent group having a structure obtained by eliminating one hydrogen atom from any of the above specific examples of an aryl group. Note that the arylene group may further have a substituent, and specific examples of the substituent include an alkyl group, an alkoxy group, and a phenyl group.

Specific examples of an organic compound that can be used as the first organic compound 161_1 are represented by Structural Formulae (100) to (112). Note that the organic compound that can be used as the first organic compound 161_1 is not limited to those examples.

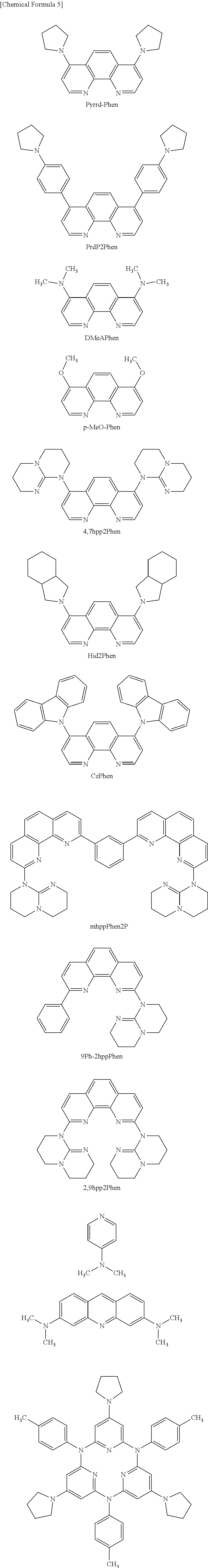

Note that Structural Formulae (100), (101), (104), (105), (107), (108), and (109) are respectively Pyrrd-Phen, 4,7-bis[4-(1-pyrrolidinyl)phenyl]-1,10-phenanthroline (abbreviation: PrdP2Phen), 4,7-bis(1,3,4,6,7,8-hexahydro-2H-pyrimido[1,2-a]pyrimidin-1-yl)-1,10-phenanthroline (abbreviation: 4,7hpp2Phen), 4,7-di(2,3,3a,4,5,6,7,7a-octahydro-1H-isoindol-2-yl)-1,10-phenanthroline (abbreviation: Hid2Phen), 2,2′-(1,3-phenylene)bis[9-(1,3,4,6,7,8-hexahydro-2H-pyrimido[1,2-a]pyrimidin-1-yl)-1,10-phenanthroline](abbreviation: mhppPhen2P), 2-(1,3,4,6,7,8-hexahydro-2H-pyrimido[1,2-a]pyrimidin-1-yl)-9-phenyl-1,10-phenanthroline (abbreviation: 9Ph-2hppPhen), and 2,9-bis(1,3,4,6,7,8-hexahydro-2H-pyrimido[1,2-a]pyrimidin-1-yl)-1,10-phenanthroline (abbreviation: 2,9hpp2Phen).

The minimum value of an ESP of the first organic compound 161_1 is preferably small (i.e., the minimum value is preferably negative and has a large absolute value), in which case the efficiency of the interaction with the metal material 161_M is high. In an organic compound having a phenanthroline ring, ESPs around the nitrogen atoms of the phenanthroline ring, which is likely to be negative, can be further lowered (i.e., the absolute value of the negative value can be increased) by introduction of an electron-donating group to the phenanthroline ring. Note that an ESP is the energy of interaction between positive point charge with unit quantity of electricity and electron distribution of a molecule. The value of an ESP also depends on the threshold value of electron density. To increase the efficiency of the interaction with the metal material 161_M, the minimum value of the ESP of the first organic compound 161_1 is preferably smaller (negatively larger) than the minimum value of an ESP of a phenanthroline ring having no substituent. Specifically, when the threshold value of electron density distribution in atomic units is 0.0004 e/a₀³, the minimum value of the ESP is preferably smaller than or equal to −0.085 Eₕ (Eₕ is the Hartree energy (1 Eₕ=27.211 eV)), further preferably smaller than or equal to −0.090 Eₕ. When the threshold value of electron density distribution is 0.003 e/a₀³, the minimum value of the ESP is preferably smaller than or equal to −0.12 Eₕ, further preferably smaller than or equal to −0.13 Eh.

### <<Estimation of Characteristics by Quantum Chemistry Calculation>>

The minimum values of ESPs of the organic compounds represented by Structural Formulae (100) to (109) are estimated by quantum chemistry calculation. For comparison, the minimum values of ESPs of BPhen, mPPhen2P, NBPhen, and Phen are also estimated. The following are structural formulae of BPhen, mPPhen2P, NBPhen, and Phen.

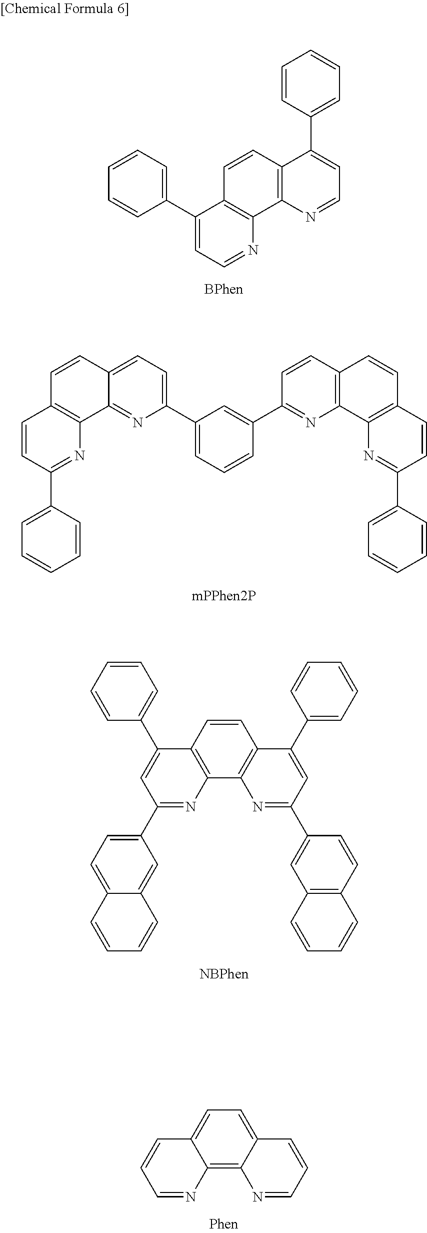 [SMILES: c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc4ccccc4c3)nc3c2ccc2c(-c4ccccc4)cc(-c4ccc5ccccc5c4)nc23)cc1 ; c1cnc2c(c1)ccc1cccnc12]

As the quantum chemistry computational program, Gaussian 09 is used. The calculation is performed using SGI 8600 produced by HPE. The most stable structure of the first organic compound 161_1 in the ground state is calculated by DFT. As a basis function, 6-311G(d,p) is used, and as a functional, B3LYP is used.

Table 6 shows the estimation results of the minimum values of ESPs of the first organic compound 161_1 in the ground state. Note that an ESP is the energy of interaction between positive point charge with unit quantity of electricity and electron distribution of a molecule. The value of an ESP also depends on the threshold value of electron density. Table 6 shows ESPs in electron density distribution at the time when the density value in atomic units is 0.0004 e/a₀³ or 0.003 e/a₀³.

TABLE 6

| | Minimum value | Minimum value |
|---|---|---|
| | of ESP (Eₕ) | of ESP (Eₕ) |
| | (Density threshold | (Density threshold |
| | value = 0.0004 | value = 0.003 |
| | e/a₀³) | e/a₀³) |
| Pyrrd-Phen (100) | −0.091 | −0.12 |
| PrdP2Phen (101) | −0.094 | −0.13 |
| DMeAPhen (102) | −0.089 | −0.12 |
| p-MeO-Phen (103) | −0.089 | −0.12 |
| 4,7hpp2Phen (104) | −0.096 | −0.13 |
| Hid2Phen (105) | −0.094 | −0.13 |
| CzPhen (106) | −0.072 | −0.10 |
| mhppPhen2P (107) | −0.057 | −0.096 |
| 9Ph-2hppPhen (108) | −0.057 | −0.096 |
| 2,9hpp2Phen (109) | −0.061 | −0.097 |
| BPhen | −0.083 | −0.11 |
| mPPhen2P | −0.057 | −0.094 |
| NBPhen | −0.053 | −0.093 |
| Phen | −0.081 | −0.11 |

From Table 6, it is found that the minimum values of ESPs of the organic compounds represented by Structural Formulae (100) to (105) are each smaller than or equal to −0.085 Eₕwhen the threshold value of electron density distribution is 0.0004 e/a₀³ and that using any of these organic compounds as the first organic compound 161_1 is the most preferable. In contrast, the minimum values of ESPs of the organic compounds represented by Structural Formulae (106) to (109) are each larger than −0.085 Eh.

The organic compounds represented by Structural Formulae (100) to (105) have the most preferable values because of having an electron-donating group at each of the 4- and 7-positions of the 1,10-phenanthroline ring.

The organic compound represented by Structural Formula (106) has N-carbazolyl groups as electron-donating groups at the 4- and 7-positions of the 1,10-phenanthroline ring. In the N-carbazolyl group, in which an unshared electron pair of the nitrogen atom contributes to aromaticity, the property of donating electrons to the phenanthroline ring is lower than that in a group in which an unshared electron pair of a nitrogen atom does not contribute to aromaticity, inhibiting a reduction in the minimum value of ESP of the organic compound represented by Structural Formula (106).

The organic compounds represented by Structural Formulae (107) to (109) each have electron-donating groups at the 2- and 9-positions of the 1,10-phenanthroline ring. In the case where the electron-donating groups are introduced to the 2- and 9-positions of the 1,10-phenanthroline ring, the property of donating electrons to the nitrogen atoms at the 1- and 10-positions of the 1,10-phenanthroline ring is low as compared with the case where the electron-donating groups are introduced to the 4- and 7-positions of the 1,10-phenanthroline ring. It is thus further preferable that substitution sites of electron-donating groups be the 4- and 7-positions of a 1,10-phenanthroline ring.

When the first organic compound 161_1 has strong basicity, the first organic compound 161_1 can easily interact with holes. This can significantly reduce the hole-transport property in the first layer 161a using the first organic compound 161_1. Thus, hole transport from the first layer 161a to the second layer 162a can be prevented, enabling a highly efficient light-emitting device, which is preferable. Specifically, the acid dissociation constant pKₐ of the first organic compound 161_1 is preferably greater than or equal to 8, further preferably greater than or equal to 10, still further preferably greater than or equal to 12.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant may be obtained by calculation. For example, the acid dissociation constant pKₐ can be obtained by the following calculation method.

The initial structure of a molecule serving as a calculation model is the most stable structure (the singlet ground state) obtained by first-principles calculation.

For the first-principles calculation, Jaguar, which is the quantum chemical computational software produced by Schrödinger, Inc., is used, and the most stable structure in the singlet ground state is calculated by the density functional theory (DFT). As a basis function, 6-31G** is used, and as a functional, B3LYP-D3 is used. The structure subjected to quantum chemistry calculation is sampled by conformational analysis in mixed torsional/low-mode sampling with Maestro GUI produced by Schrödinger, Inc.

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of the obtained values is used as a pKₐ value. The following are the obtained pKₐ values.

The acid dissociation constant pKₐ of 2,9hpp2Phen is 13.35, that of 4,7hpp2Phen is 13.42, that of Pyrrd-Phen is 11.23, that of mPPhen2P is 5.16, that of NBPhen is 5.59, and that of BPhen is 5.62.

### <Second Organic Compound 161_2>

As the second organic compound 161_2, an organic compound having an electron-transport property is preferably used. The organic compound having an electron-transport property is preferably a substance having an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property.

An organic compound including a π-electron deficient heteroaromatic ring is preferable as the organic compound having an electron-transport property. As the π-electron deficient heteroaromatic ring, a heteroaromatic ring having an azole skeleton (an imidazole ring, a pyrazole ring, an oxazole ring, a thiazole ring, a triazole ring, an oxadiazole ring, or a thiadiazole ring), a heteroaromatic ring having a pyridine skeleton, a heteroaromatic ring having a diazine skeleton, a heteroaromatic ring having a triazine skeleton, or the like is preferable, and a diazine ring (a pyrazine ring, a pyrimidine ring, or a pyridazine ring) and a triazine ring are particularly preferable because they are electrochemically stable and have a high electron-transport property.

Examples of the organic compound that can be used as the second organic compound 161_2 include an organic compound represented by General Formula (G1-1) below.

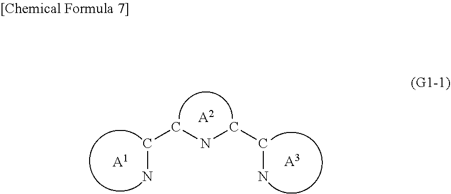

In General Formula (G1-1) above, A¹, A², and A³ each independently represent a substituted or unsubstituted heteroaromatic ring having 1 to 30 carbon atoms, and A¹, A², and A³ may form a condensed ring with each other.

The organic compound represented by General Formula (G1-1) includes a conjugated double bond in which N in the heteroaromatic rings are arranged in the order of N—C—C—N, and has a function of interacting with a metal as a tri- or higher dentate ligand. An organic compound having such a structure is likely to interact with a metal and thus can be suitably used for the second organic compound 161_2.

In General Formula (G1-1), examples of the substituted or unsubstituted heteroaromatic rings having 1 to 30 carbon atoms, which are represented by A¹, A², and A³, include a heteroaromatic ring having a pyridine skeleton (a pyridine ring, a quinoline ring, an isoquinoline ring, a naphthyridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹, A², and A³ are not limited to these. A¹, A², and A³ may form a condensed ring with each other. For example, A¹ and A² may be bonded to each other to form a phenanthroline ring.

Examples of the organic compound that can be used as the second organic compound 161_2 include an organic compound represented by General Formula (G2-1) below.

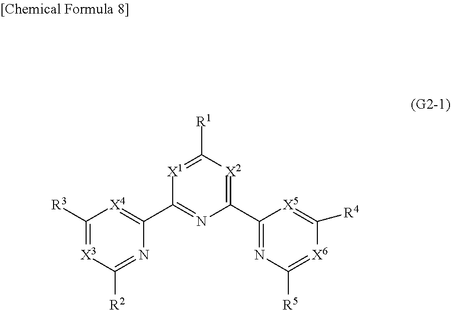

In General Formula (G2-1), X¹ to X⁶ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁴ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms. Alternatively, in General Formula (G2-1), X¹ to X⁶ may be directly bonded to each other or bonded to each other via a divalent group to form a condensed ring. Specific examples of the divalent group include an alkylene group and an arylene group.

As in the organic compound represented by General Formula (G2-1), it is further preferable that the organic compound having a function of interacting with the metal as a tri- or higher dentate ligand include at least one of a heteroaromatic ring having a pyridine skeleton, a heteroaromatic ring having a diazine skeleton, and a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

Examples of the organic compound that can be used as the second organic compound 161_2 include an organic compound represented by General Formula (G3-1) below.

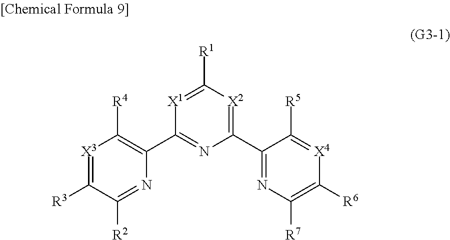

In General Formula (G3-1), X¹ to X⁴ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

Examples of the organic compound that can be used as the second organic compound 161_2 include an organic compound represented by General Formula (G4-1) below.

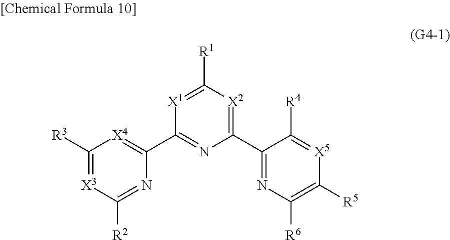

In General Formula (G4-1), X¹ to X⁵ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

An organic compound having a pyridine skeleton is preferable because it has a high LUMO level. For example, when X¹ and X² in each of General Formulae (G2-1), (G3-1), and (G4-1) represent carbon, the organic compound represented by each of General Formulae (G2-1), (G3-1), and (G4-1) has a pyridine skeleton and thus has a high LUMO level, thereby being capable of forming a composite material having a high SOMO level when interacting with a metal. That is, when such an organic compound having a pyridine ring and a function of interacting with a metal as a tri- or higher dentate ligand interacts with a metal, an intermediate layer having a high electron-injection property can be formed.

An organic compound having a diazine skeleton or a triazine skeleton is preferable because it is electrochemically stable and has a high electron-transport property. For example, when at least one of X¹ and X² in each of General Formulae (G2-1), (G3-1), and (G4-1) represents nitrogen, the organic compound represented by each of General Formulae (G2-1), (G3-1), and (G4-1) has a diazine skeleton or a triazine skeleton and thus is electrochemically stable and has a high electron-transport property, thereby being capable of forming a stable composite material having a high electron-transport property when interacting with a metal. That is, when such an organic compound having a diazine ring or a triazine ring and a function of interacting with a metal as a tri- or higher dentate ligand interacts with a metal, an intermediate layer having high reliability can be formed.

Examples of the organic compound that can be used as the second organic compound 161_2 include an organic compound represented by General Formula (G1-2) below.

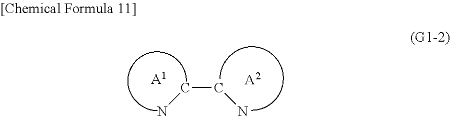

In General Formula (G1-2) above, A¹ and A² independently represent a substituted or unsubstituted heteroaromatic ring having 1 to 30 carbon atoms, A¹ and A² may form a condensed ring with each other, and A¹ includes two or more nitrogen atoms.

The organic compound represented by General Formula (G1-2) includes a conjugated double bond in which N in the heteroaromatic ring are arranged in the order of N—C—C—N and has a function of interacting with a metal as a bi- or higher dentate ligand. An organic compound having such a structure is likely to interact with a metal and thus can be suitably used for an intermediate layer.

In General Formula (G1-2), examples of the substituted or unsubstituted heteroaromatic ring having 1 to 30 carbon atoms, which is represented by A¹, include a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Examples of the substituted or unsubstituted heteroaromatic ring having 1 to 30 carbon atoms, which is represented by A², include a heteroaromatic ring having a pyridine skeleton (a pyridine ring, a quinoline ring, an isoquinoline ring, a naphthridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹ and A² are not limited to these. A¹ and A² may form a condensed ring with each other. For example, A¹ and A² may be bonded to each other to form a pyrazinoquinoxaline ring.

Examples of the organic compound that can be used as the second organic compound 161_2 include an organic compound represented by General Formula (G2-2) below.

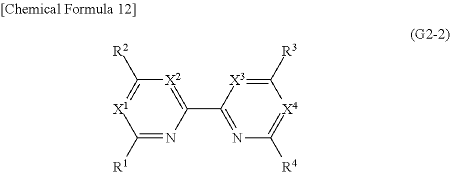

In General Formula (G2-2), at least one of X¹ to X⁴ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁴ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms. Alternatively, in General Formula (G2-2), X¹ to X⁴ may be directly bonded to each other or bonded via a divalent group to form a condensed ring. Specific examples of the divalent group include an alkylene group and an arylene group.

As in the organic compound represented by General Formula (G2-2), it is further preferable that the organic compound having a function of interacting with the metal as a bi- or higher dentate ligand include a heteroaromatic ring having a diazine skeleton or a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

Examples of the organic compound that can be used as the second organic compound 161_2 include an organic compound represented by General Formula (G3-2) below.

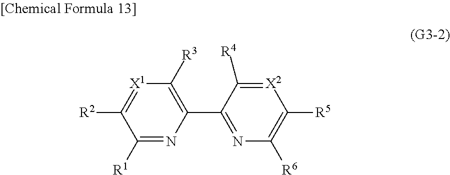

In General Formula (G3-2), one of X¹ and X² represents nitrogen (N); the other represents carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

Examples of the organic compound that can be used as the second organic compound 161_2 include an organic compound represented by General Formula (G4-2) below.

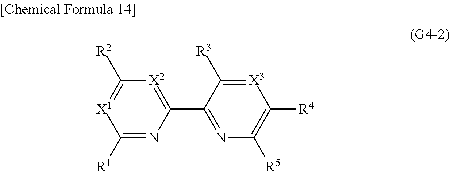

In General Formula (G4-2), at least one of X¹ to X³ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁵ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

An organic compound having a pyridine skeleton is preferable because it has a high LUMO level. For example, when X¹ and X² in each of General Formulae (G2-2) and (G4-2) and X¹ in General Formula (G3-2) represent carbon, the organic compound represented by each of General Formulae (G2-2), (G3-2), and (G4-2) has a pyridine skeleton and thus has a high LUMO level, thereby being capable of forming a composite material having a high SOMO level when interacting with a metal. That is, when such an organic compound having a pyridine ring and a function of interacting with a metal as a bi- or higher dentate ligand interacts with a metal, an intermediate layer having a high electron-injection property can be formed.

An organic compound having a diazine skeleton or a triazine skeleton is preferable because it is electrochemically stable and has a high electron-transport property. For example, when at least one of X¹ and X² in each of General Formulae (G2-2) and (G4-2) and X¹ in General Formula (G3-2) represent nitrogen, the organic compound represented by each of General Formulae (G2-2), (G3-2), and (G4-2) has a diazine skeleton or a triazine skeleton and thus is electrochemically stable and has a high electron-transport property, thereby being capable of forming a stable composite material having a high electron-transport property when interacting with a metal. That is, when such an organic compound having a diazine ring or a triazine ring and a function of interacting with a metal as a bi- or higher dentate ligand interacts with a metal, an intermediate layer having high reliability can be formed.

More specific examples of the organic compound that can be used as the second organic compound 161_2 and the organic compounds that are represented by General Formulae (G1-1) to (G4-2) above are represented by General Formulae (250) to (268) below.

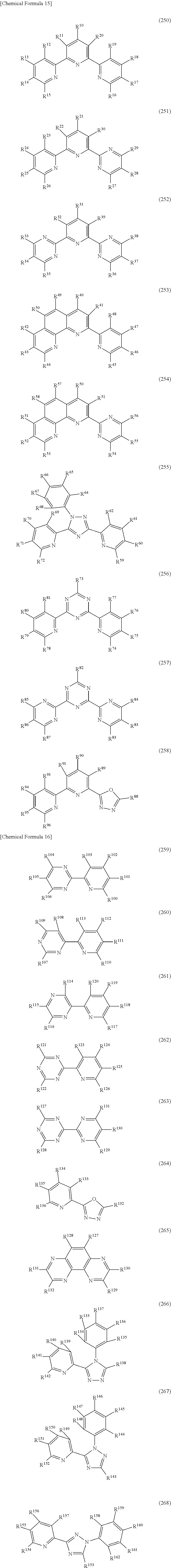

In General Formulae (250) to (268), R¹¹ to R¹⁶² each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

Examples of substituents that can be used in General Formulae (G1-1) to (G4-2) and (250) to (268) above include an alkyl group having 1 to 10 carbon atoms, a cycloalkyl group having 3 to 10 carbon atoms, an aryl group having 6 to 30 carbon atoms, an arylene group having 6 to 30 carbon atoms, and a heteroaryl group having 1 to 30 carbon atoms. Note that some or all of hydrogen atoms may be deuterium atoms. The groups that can be used in the above general formulae are not limited to the following specific examples.

Specific examples of the alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, a 2,3-dimethylbutyl group, and a 1-ethylhexyl group.

Specific examples of a cycloalkyl group having 3 to 10 carbon atoms include a cyclopropyl group, a cyclobutyl group, a methylcyclobutyl group, a cyclopentyl group, a methylcyclopentyl group, an isopropylcyclopentyl group, a tert-butylcyclopropyl group, a cyclohexyl group, a methylcyclohexyl group, an isopropylcyclohexyl group, a tert-butylcyclohexyl group, a cycloheptyl group, a methylcycloheptyl group, an isopropylcycloheptyl group, a cyclooctyl group, a methylcyclooctyl group, an isopropylcyclohexyl group, a cyclononyl group, a methylcyclononyl group, a cyclodecyl group, and an adamantyl group.

Specific examples of the aryl group having 6 to 30 carbon atoms include a phenyl group, an o-tolyl group, an m-tolyl group, a p-tolyl group, a mesityl group, an o-biphenyl group, an m-biphenyl group, ap-biphenyl group, a 1-naphthyl group, a 2-naphthyl group, a fluorenyl group, a 9,9-dimethylfluorenyl group, a spirobifluorenyl group, a phenanthryl group, an anthryl group, and a fluoranthenyl group. In the case where the aryl group having 6 to 30 carbon atoms includes a substituent, examples of the substituent include an alkyl group having 1 to 10 carbon atoms, a cycloalkyl group having 3 to 10 carbon atoms, and a phenyl group.

Specific examples of the arylene group having 6 to 30 carbon atoms include a phenylene group, a biphenyl-diyl group, a naphthalene-diyl group, a fluorene-diyl group, an acenaphthene-diyl group, an anthracene-diyl group, a phenanthrene-diyl group, a terphenyl-diyl group, a triphenylene-diyl group, a phenanthrene-diyl group, a tetracene-yl group, a benzanthracene-diyl group, a pyrene-diyl group, and a spirobi[9H-fluorene]-diyl group. In the case where the arylene group having 6 to 30 carbon atoms includes a substituent, examples of the substituent include an alkyl group having 1 to 10 carbon atoms, a cycloalkyl group having 3 to 10 carbon atoms, and a phenyl group.

The heteroaryl group having 1 to 30 carbon atoms refers to a monovalent group obtained by eliminating one hydrogen atom from one of carbon atoms forming the ring(s) of a monocyclic or polycyclic heterocyclic aromatic compound having 1 to 30 carbon atoms. Specific examples of the heteroaryl group having 1 to 30 carbon atoms include a 1,3,5-triazin-2-yl group, a 1,2,4-triazin-3-yl group, a pyrimidin-4-yl group, a pyrazin-2-yl group, a 2-pyridyl group, a 3-pyridyl group, a 4-pyridyl group, a carbazolyl group, a dibenzofuranyl group, a dibenzothiophenyl group, a benzonaphthofuranyl group, a benzonaphthothiophenyl group, an indolocarbazolyl group, a benzofurocarbazolyl group, a benzothienocarbazolyl group, an indenocarbazolyl group, and a dibenzocarbazolyl group. In the case where the heteroaryl group has a substituent, examples of the substituent include an alkyl group having 1 to 10 carbon atoms, a cycloalkyl group having 3 to 10 carbon atoms, and a phenyl group.

The following are specific examples of the organic compounds that can be used for the second organic compound 161_2 and the organic compounds represented by General Formulae (G1-1) to (G4-2) above.

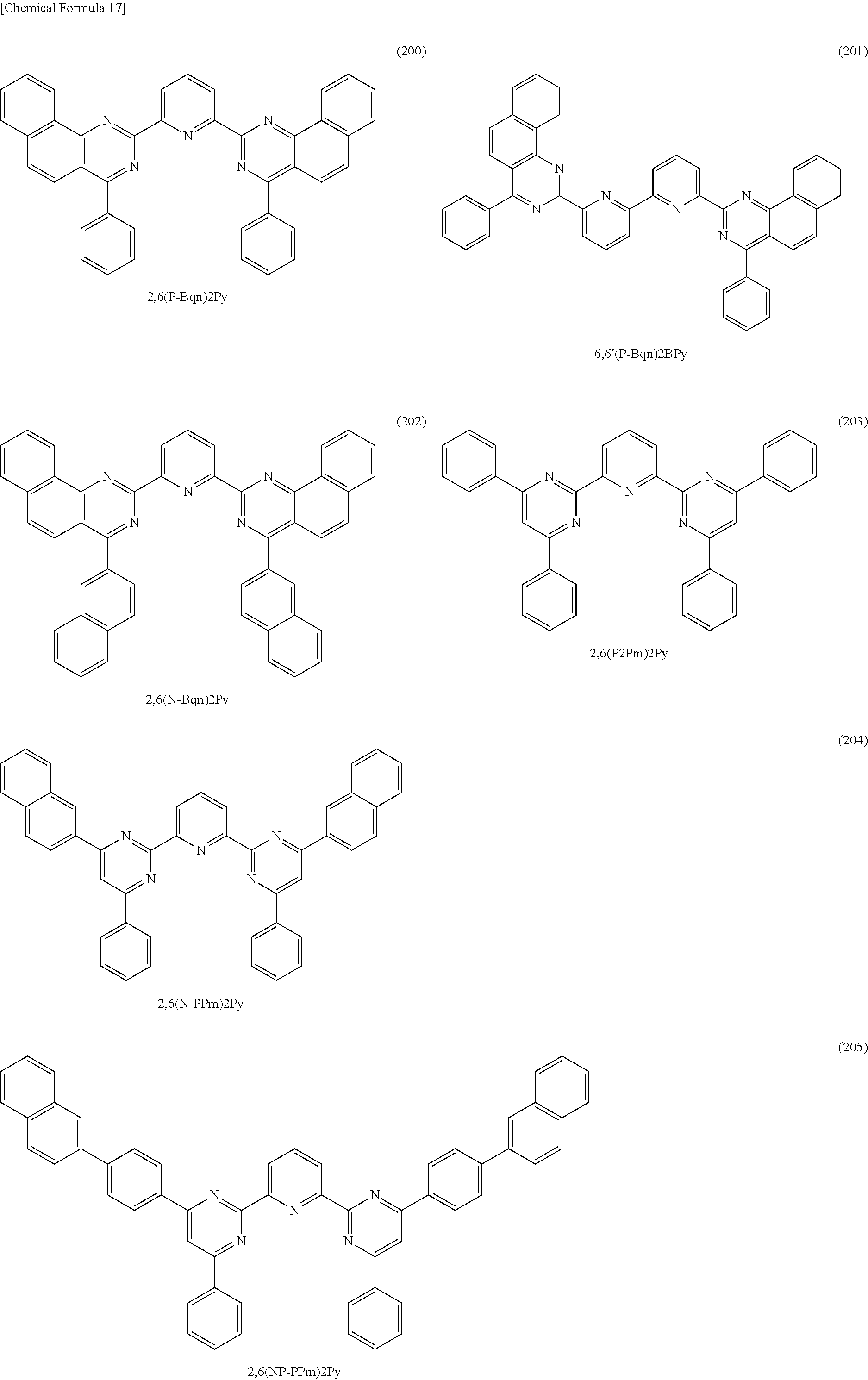

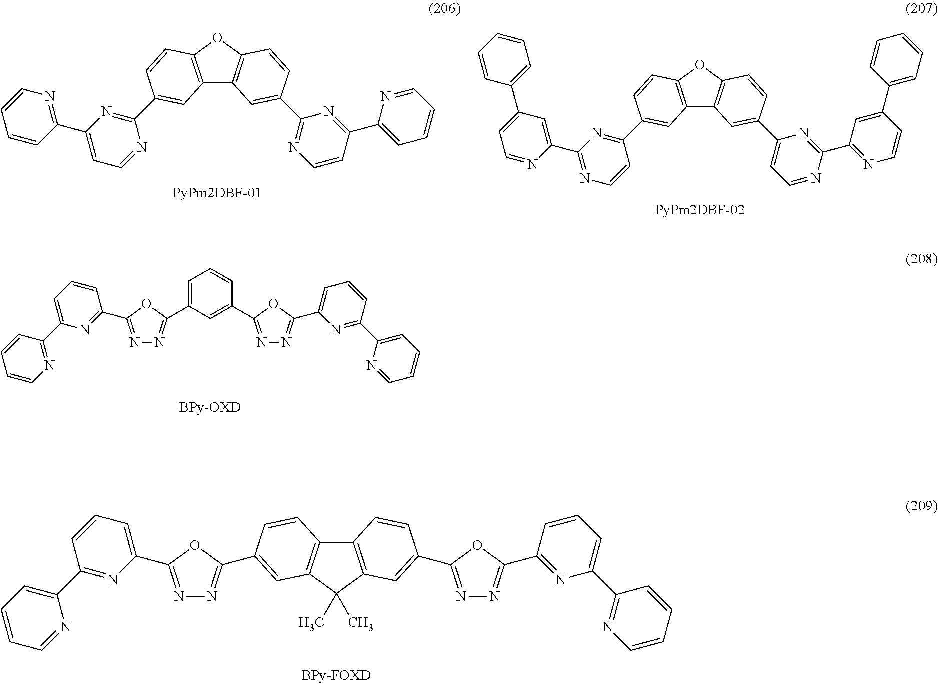

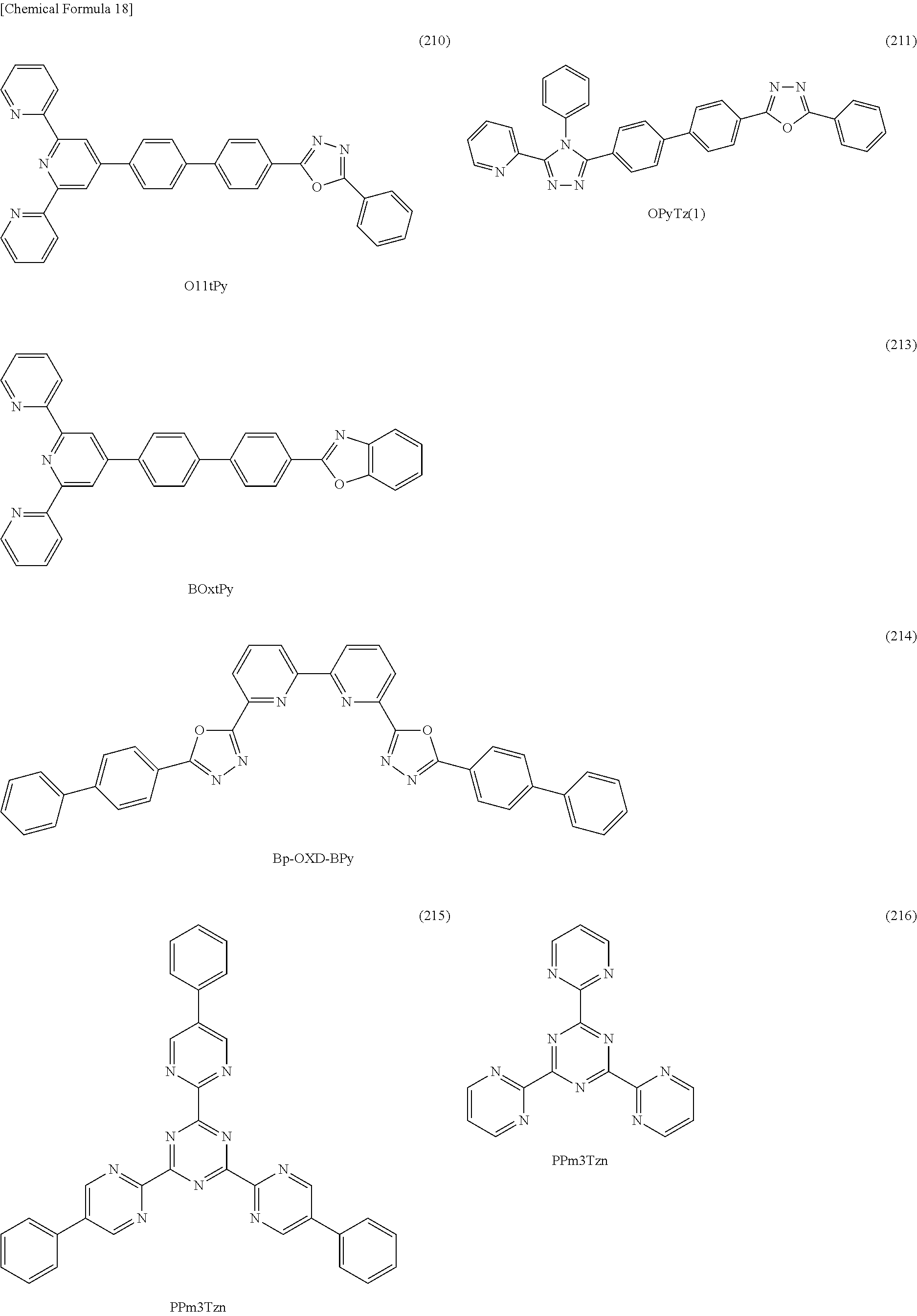

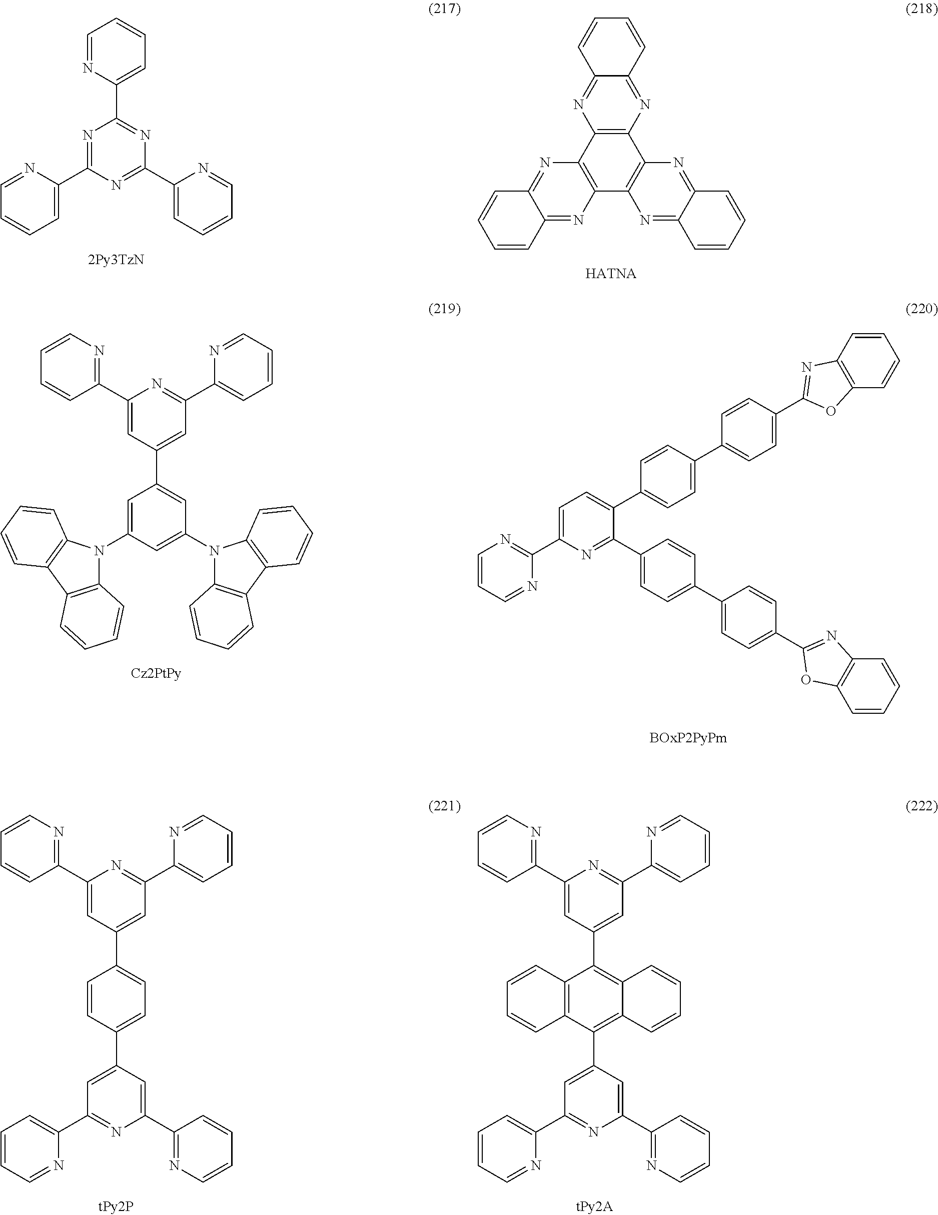

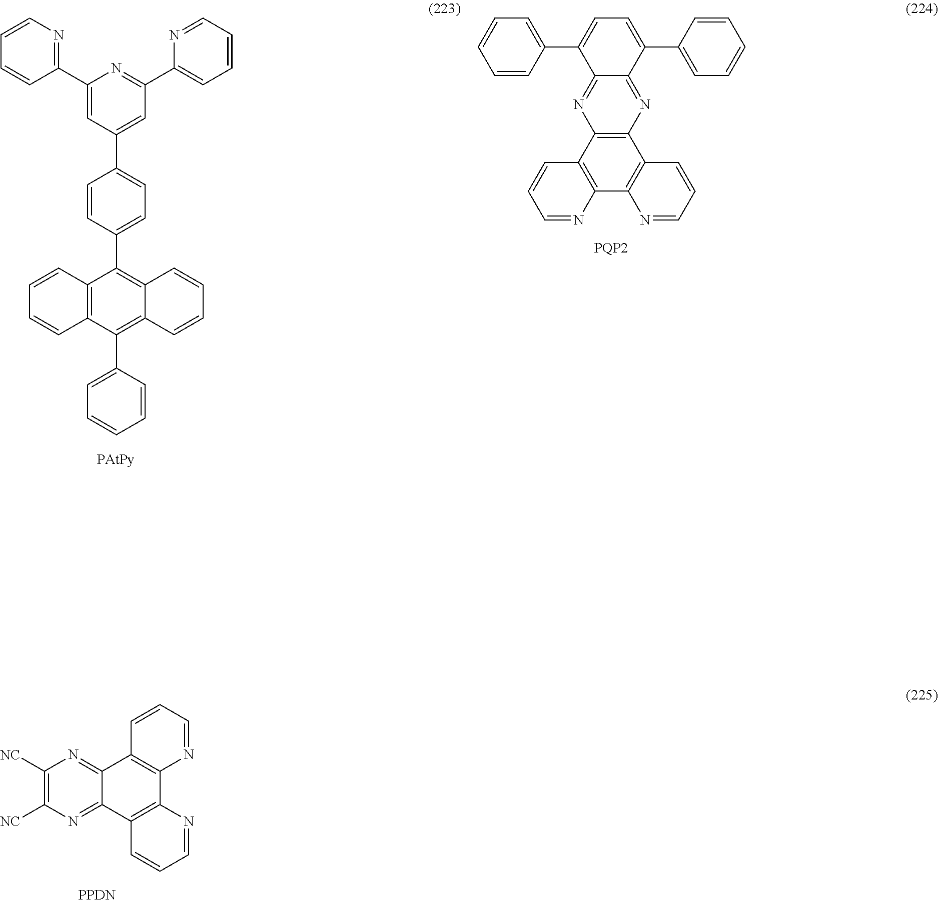

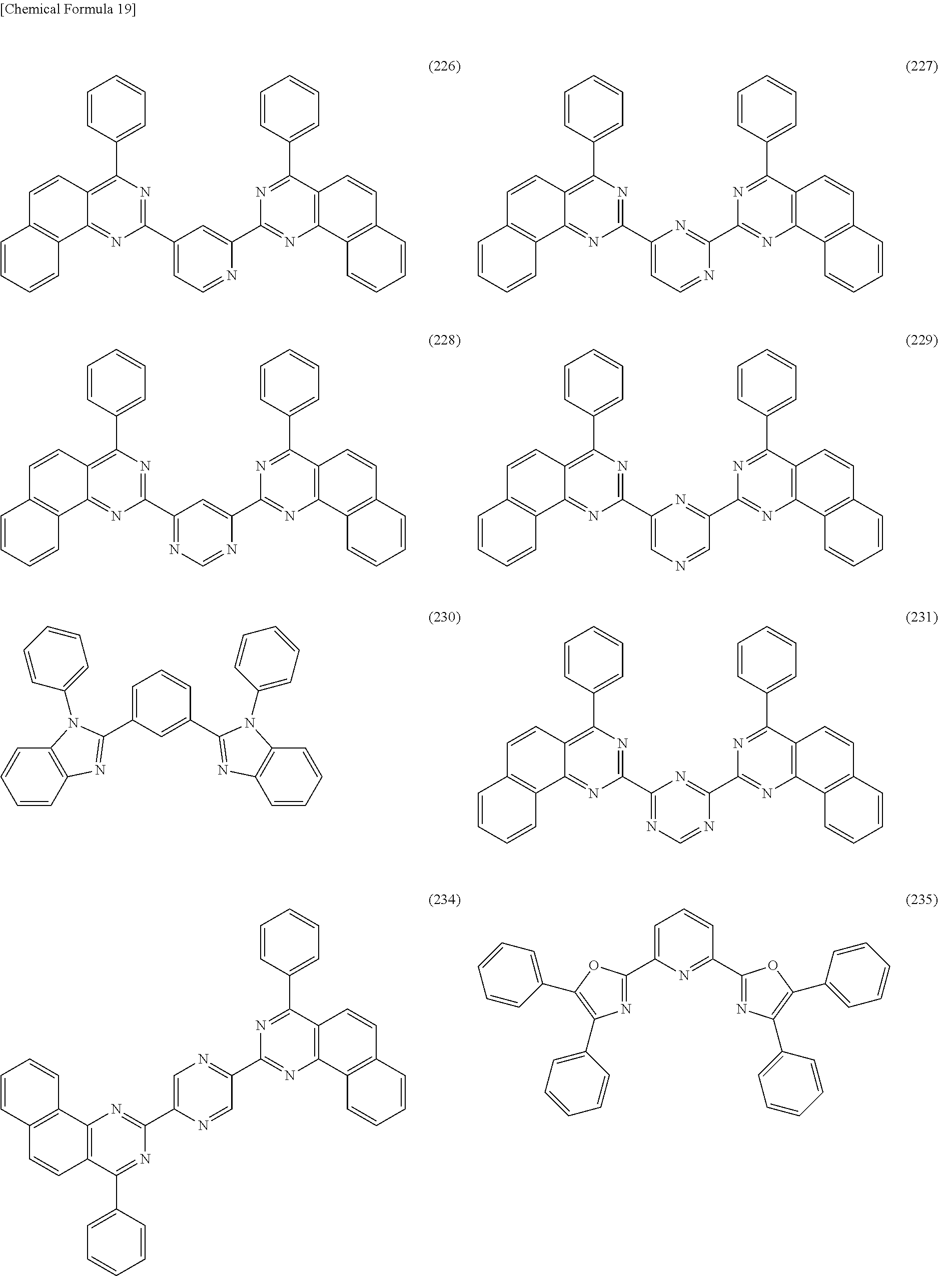

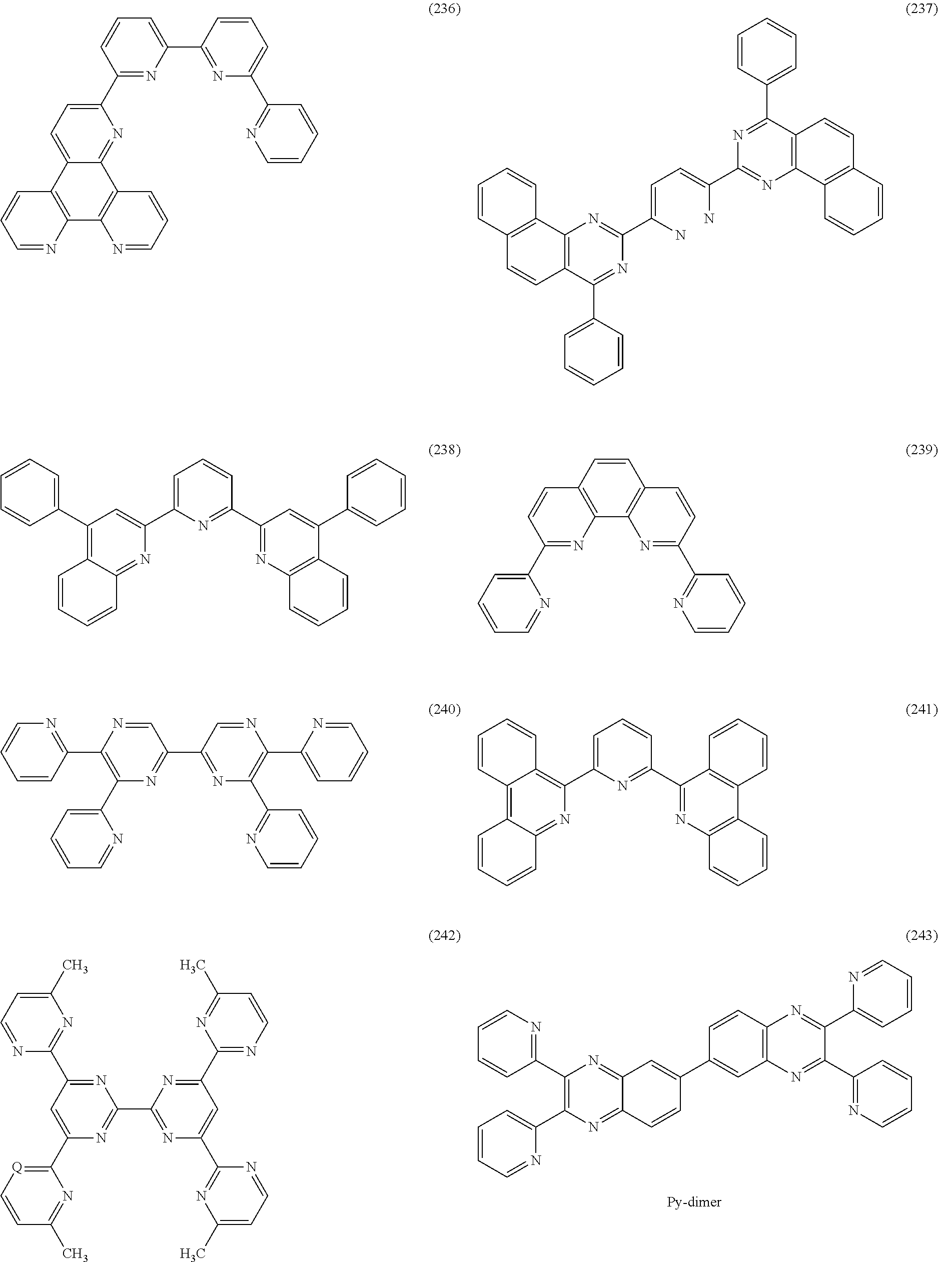

The organic compound that can be used as the second organic compound 161_2 is not limited to the above examples, and an organic compound that has an electron-transport property and forms an exciplex with the first organic compound 161_1 can be used as the second organic compound 161_2.

Specific examples of the organic compound having an electron-transport property include the following compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs); organic compounds having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), NBPhen, mPPhen2P, and 4,7-diphenyl-2,9-bis(4-(1-phenyl-1H-benzo[d]imidazol-2-yl)phenyl)-1,10-phenanthroline (abbreviation: DBimiBphen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-{3-[3-(N-phenyl-9H-carbazol-3-yl)-9H-carbazol-9-yl]phenyl}dibenzo[f,h]quinoxaline (abbreviation: 2mPCCzPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), 8-([1,1′:4′,1″-terphenyl-2,4,5,6,2′,3′,5′,6′,2″,3″,4″,5″,6″-d₁₃]-3-yl)-4-{3-[(dibenzothiophene-1,2,3,6,7,8,9-d₇)-4-yl]phenyl-2,4,6-d₃}-[1]benzofuro[3,2-d]pyrimidine (abbreviation: 8mpTP-4mDBtPBfpm-d₂₃), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-([2,2′-binaphthalen]-6-yl)-4-[3-(dibenzothiophen-4-yl)phenyl]-[1]benzofuro[3,2-d]pyrimidine (abbreviation: 8(βN2)-4mDBtPBfpm), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), and 7-[4-(9-phenyl-9H-carbazol-2-yl)quinazolin-2-yl]-7H-dibenzo[c,g]carbazole (abbreviation: PC-cgDBCzQz); and organic compounds having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), and 2-(biphenyl-3-yl)-4-phenyl-6-[8-([1,1′:4′,1″-terphenyl]-4-yl)-1-dibenzofuranyl]-1,3,5-triazine (abbreviation: mBP-TPDBfTzn).

Among the above organic compounds, the organic compound having a phenanthroline ring, particularly a 1,10-phenanthroline ring, such as BPhen, BCP, NBPhen, or mPPhen2P, is further preferable because two nitrogen atoms included therein can be coordinated to the metal to facilitate the interaction with the metal. An organic compound having a phenanthroline ring dimer structure, such as mPPhen2P, is further preferable because of its high stability.

The organic compound used as the second organic compound 161_2 preferably has 25 to 100 carbon atoms. When having 25 to 100 carbon atoms, the second organic compound 161_2 can have excellent sublimability, and thus, thermal decomposition of the organic compound during vacuum evaporation can be inhibited and the efficiency of use of the material can be high. An organic compound having a glass transition temperature (T_{g}) higher than or equal to 100 °C can also be used. In that case, the intermediate layer is not easily crystallized. Accordingly, the intermediate layer is not easily crystallized even when being affected by oxygen or water in the air and a chemical solution or water during processing by a lithography method for forming part of the organic compound layer. An increase in driving voltage or a reduction in current efficiency of the light-emitting device due to crystallization of the intermediate layer can be accordingly prevented. Thus, when the organic compound having T_{g} higher than or equal to 100 °C is used as the second organic compound 161_2, the second organic compound 161_2 can be suitably used for the intermediate layer of the light-emitting device in which part of the organic compound layer is processed by a lithography method.

Examples of an organic compound having a phenanthroline ring and T_{g} higher than or equal to 100 °C include NBPhen (T_{g}: 165 °C), mPPhen2P (T_{g}: 135 °C), 2,2′-(biphenyl-4,4′-diyl)bis(9-phenyl-1,10-phenanthroline) (abbreviation: PPhen2BP) (T_{g}: 166 °C), 2,2′-biphenyl-3,3′-diylbis(9-phenyl-1,10-phenanthroline) (abbreviation: mPPhen2BP) (T_{g}: 144 °C), 2,8-bis(phenanthrolin-5-yl)dibenzofuran (abbreviation: 2,8Phen2DBf) (T_{g}: 210 °C), and 5,5′,5″-(benzene-1,3,5-triyl)tri-1,10-phenanthroline (abbreviation: Phen3P) (T_{g}: 257 °C). Note that T_{g}can be measured with a differential scanning calorimeter (DSC8500 produced by PerkinElmer Japan Co., Ltd.) in a state where a powder sample is put on an aluminum cell and the temperature is increased at a rate of 40 °C/min.

As the second organic compound 161_2, an organic compound with an acid dissociation constant pKₐ greater than or equal to 4 and less than 8 can be used. The second organic compound 161_2 preferably has such an acid dissociation constant to have a poor hole-transport property, in which case the hole-transport property in the first layer 161a of the intermediate layer 160a can be reduced and hole transport from the first layer 161a to the second layer 162a can be prevented, enabling the light-emitting device to have high efficiency. An excessively large acid dissociation constant pKₐ leads to high solubility in water and thus reduces the resistance to water and a chemical solution used during the lithography process. Thus, the acid dissociation constant pKₐ of the second organic compound 161_2 is preferably greater than or equal to 4 and less than 8.

In the layer including the combination of the metal material 161_M, the first organic compound 161_1, and the second organic compound 161_2, interaction between the materials occurs more efficiently than in a layer including only two of the materials (e.g., a layer including the metal material 161_M and the first organic compound 161_1 or a layer including the metal material 161_M and the second organic compound 161_2). This can be confirmed when the spin densities of the films that include some or all of the materials with a metal belonging to an odd-numbered group as the metal material 161_M are measured by an electron spin resonance (ESR) method.

For example, the spin density measured by ESR of a film that includes the metal, the first organic compound 161_1, and the second organic compound 161_2 is preferably higher than the spin density measured by ESR of a film that includes the metal and the first organic compound 161_1 or a film that includes the metal and the second organic compound 161_2. In such a case, it can be confirmed that the interaction between the materials has occurred more efficiently in the film that includes the combination of the metal, the first organic compound 161_1, and the second organic compound 161_2 than in the film that includes only two of the materials. Note that spin density measurement by an electron spin resonance method is preferably performed at room temperature.

Specifically, in the case where the densities of spins attributed to a signal observed at a g-factor of approximately 2.00 measured by an electron spin resonance method of a mixed film that includes the metal and the first organic compound 161_1, a mixed film that includes the metal and the second organic compound 161_2, and a mixed film that includes the first organic compound 161_1 and the second organic compound 161_2 are each, for example, lower than or equal to 2×10¹⁶ spins/cm³ and the density of spins attributed to a signal observed at a g-factor of approximately 2.00 measured by an electron spin resonance method of a mixed film that includes the metal, the first organic compound 161_1, and the second organic compound 161_2 is, for example, higher than or equal to 5×10¹⁶ spins/cm³, preferably higher than or equal to 1×10¹⁷ spins/cm³, it can be confirmed that the interaction between the materials has occurred more efficiently in the mixed film that includes the combination of the metal, the first organic compound 161_1, and the second organic compound 161_2 than in the mixed film that includes only two of the materials.

The molar ratio of the metal to the sum of the first organic compound 161_1 and the second organic compound 161_2 is preferably greater than or equal to 0.1 and less than or equal to 10, further preferably greater than or equal to 0.2 and less than or equal to 5, still further preferably greater than or equal to 0.5 and less than or equal to 2. Alternatively, the volume ratio of the metal to the sum of the first organic compound 161_1 and the second organic compound 161_2 is preferably greater than or equal to 0.005 and less than or equal to 0.3, further preferably greater than or equal to 0.01 and less than or equal to 0.1, still further preferably greater than or equal to 0.01 and less than or equal to 0.05. Mixing the metal, the first organic compound 161_1, and the second organic compound 161_2 in such a ratio enables providing the intermediate layer having a favorable electron-injection property. The volume ratio of the first organic compound 161_1 to the second organic compound 161_2 is preferably greater than or equal to 0.1 and less than or equal to 10, further preferably greater than or equal to 0.2 and less than or equal to 5, still further preferably greater than or equal to 0.5 and less than or equal to 2. Mixing the first organic compound 161_1 and the second organic compound 161_2 in such a ratio enables providing the intermediate layer having a favorable electron-transport property.

The thickness of the first layer 161a, which is located on the anode side in the intermediate layer 160a, is preferably greater than or equal to 3 nm and less than or equal to 20 nm, further preferably greater than or equal to 5 nm and less than or equal to 10 nm. In that case, the composite material in which the metal, the first organic compound 161_1, and the second organic compound 161_2 are mixed can favorably function, enabling high emission efficiency of the light-emitting device.

Next, descriptions are given of structures of the second layer and the third layer which are preferable in the case where the layer 200 is used as the first layer of the intermediate layer.

### [Second Layer]

As the second layer of the intermediate layer, a layer including a third organic compound and a fourth organic compound is preferably used to favorably inject holes into an upper light-emitting layer.

### <Third Organic Compound>

As the third organic compound, an organic compound having a hole-transport property is preferably used. As the organic compound having a hole-transport property, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property preferably has a hole mobility higher than or equal to 1×10⁻⁶ cm²/Vs. The organic compound having a hole-transport property is preferably a compound having a fused aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has at least any one of a carbazole skeleton, a dibenzofuran skeleton, a dibenzothiophene skeleton, and an anthracene skeleton. In particular, an aromatic amine including a substituent having a dibenzofuran ring or a dibenzothiophene ring, an aromatic monoamine having a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable manufacturing a light-emitting device having a long life.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-([2,1′-binaphthyl]-6-yl)triphenylamine (abbreviation: BBAαNβNB), 4,4′-diphenyl-4″-([2,1′-binaphthyl]-7-yl)triphenylamine (abbreviation: BBAPβNB-03), 4,4′-diphenyl-4″-(7-phenyl)naphthyl-2-yltriphenylamine (abbreviation: BBAPβNB-03), 4,4′-diphenyl-4″-([2,2′-binaphthyl]-6-yl)triphenylamine (abbreviation: BBA(βN2)B), 4,4′-diphenyl-4″-([2,2′-binaphthyl]-7-yl)triphenylamine (abbreviation: BBA(βN2)B-03), 4,4′-diphenyl-4″-([1,2′-binaphthyl]-4-yl)triphenylamine (abbreviation: BBAβNαNB), 4,4′-diphenyl-4″-([1,2′-binaphthyl]-5-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, and 9′-[3-(triphenylsilyl)phenyl]-9′H-9,3′:6′,9″-tercarbazole (abbreviation: PSiCzGI).

As the material having a hole-transport property, any of the following aromatic amine compounds can also be used: N,N-di(p-tolyl)-NN-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

### <Fourth Organic Compound>

As the fourth organic compound, a material having an acceptor property with respect to the third organic compound is preferably used. As the substance having an acceptor property, it is preferable to use an organic compound having an electron-withdrawing group (e.g., a halogen group or a cyano group), and it is further preferable to use an organic compound having four or more halogen groups, four or more cyano groups, or a combination of a halogen group and a cyano group the number of which is four or more. Specific examples include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F₆-TCNNQ), and 2-(7-dicyanomethylene-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

A signal is preferably observed by electron spin resonance in the second layer. For example, the density of spins attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³. In that case, the second layer can function as a charge-generation layer. Furthermore, the light-emitting device can have a low driving voltage and high efficiency.

### [Third Layer]

Between the first layer and the second layer of the intermediate layer, the third layer for enabling smooth electron transfer between the two layers may be provided.

The third layer includes a substance having an electron-transport property and has a function of preventing interaction between the first layer and the second layer and transferring electrons smoothly. The LUMO level of the substance having an electron-transport property included in the third layer 163 is preferably between the LUMO level of the acceptor substance in the second layer 162 and the LUMO level of the organic compound included in a layer which is included in the light-emitting unit on the first electrode 101 side and is in contact with the intermediate layer 160. A specific LUMO level of the substance having an electron-transport property in the third layer 163 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, so as to facilitate injection of electrons generated in the second layer into the first layer and thus inhibit an increase in the driving voltage of the light-emitting device. Note that as the substance having an electron-transport property in the third layer 163, a phthalocyanine-based material or a metal complex having a metal-oxygen bond and an aromatic ligand is preferably used.

Specifically, it is possible to use a perylenetetracarboxylic acid derivative such as diquinoxalino[2,3-α:2′,3′-c]phenazine (abbreviation: HATNA), 2,3,8,9,14,15-hexafluorodiquinoxalino[2,3-α:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C₆₀-Iₕ)[5,6]fullerene (abbreviation: C₆₀), (C₇₀-D₅ₕ)[5,6]fullerene (abbreviation: C₇₀), or phthalocyanine (abbreviation: H₂Pc). Alternatively, it is possible to use a metal phthalocyanine including copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-α:2′,3′-c]phenazine.

The thickness of the third layer 163 is greater than or equal to 1 nm and less than or equal to 10 nm, preferably greater than or equal to 2 nm and less than or equal to 5 nm.

The structures described in this embodiment can be used in appropriate combination with any of the structures described in the other embodiments.

### Embodiment 2

In this embodiment, other structures of a light-emitting device of one embodiment of the present invention are described.

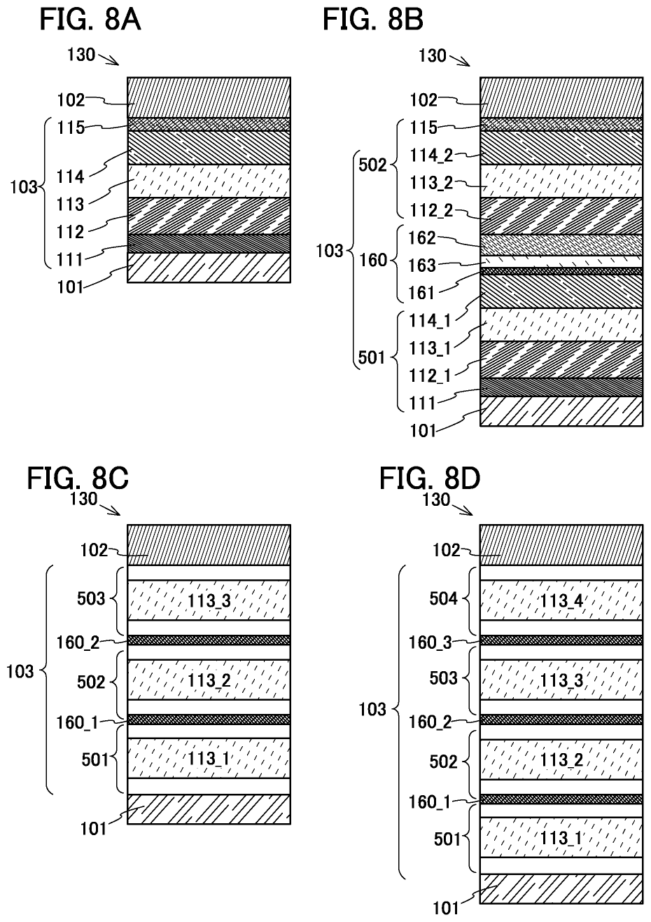

FIG. 8A illustrates a light-emitting device 130, which is an example of the light-emitting device of one embodiment of the present invention. The light-emitting device 130 includes an organic compound layer 103 that includes a light-emitting layer 113, between a first electrode 101 that includes an anode and the second electrode 102 that includes a cathode.

FIG. 8B illustrates the light-emitting device 130 that is another example of the light-emitting device of one embodiment of the present invention. The light-emitting device 130 is a tandem light-emitting device. The light-emitting device 130 includes a first light-emitting unit 501 including a first light-emitting layer 1131, a second light-emitting unit 502 including a second light-emitting layer 1132, and an intermediate layer 160, as the organic compound layer 103. The intermediate layer 160 includes a first layer 161, a second layer 162, and a third layer 163 between the first layer 161 and the second layer 162.

Although a light-emitting device that includes one intermediate layer 160 and two light-emitting units is described as an example in this embodiment, the light-emitting device may include n intermediate layer(s) (n is an integer greater than or equal to 1) and n+1 light-emitting units.

For example, the light-emitting device 130 illustrated in FIG. 8C is an example of a tandem light-emitting device in which n is 2 and which includes the first light-emitting unit 501, the first intermediate layer 160_1, the second light-emitting unit 502, the second intermediate layer 160_2, and a third light-emitting unit 503 including a third light-emitting layer 1133, as the organic compound layer 103. The color gamut of light emitted by a light-emitting layer of one light-emitting unit may be the same as or different from that of light emitted by a light-emitting layer of another light-emitting unit. In addition, the light-emitting layers may each have a single-layer structure or a stacked-layer structure. For example, the first light-emitting unit and the third light-emitting unit emit light in a blue region and stacked light-emitting layers of the second light-emitting unit emit light in a red region and light in a green region, so that white emission can be obtained.

The light-emitting device 130 illustrated in FIG. 8D is an example of a tandem light-emitting device in which n is 3 and which includes the first light-emitting unit 501, the first intermediate layer 1601, the second light-emitting unit 502, the second intermediate layer 1602, the third light-emitting unit 503, a third intermediate layer 1603, and a fourth light-emitting unit 504 including a fourth light-emitting layer 1134, as the organic compound layer 103. The color gamut of light emitted by a light-emitting layer of one light-emitting unit may be the same as or different from that of light emitted by a light-emitting layer of another light-emitting unit. In addition, the light-emitting layers may each have a single-layer structure or a stacked-layer structure. For example, any three of the four light-emitting units can be units for blue (B) light emission, and the other one can be a unit for green (G) light emission; any two of the four light-emitting units can be units for blue (B) light emission, and the other two can be units for yellow (Y) light emission; alternatively, any one of the four light-emitting units can be a unit for red (R) light emission, another one can be a unit for green (G) light emission, the other two can be units for blue (B) light emission.

The light-emitting device 130 may be manufactured using a lithography method, for example. In the case of the light-emitting device manufactured using a lithography method, at least the light-emitting layer 113 or the second light-emitting layer 113_2 and the layer(s) in the organic compound layer that is/are closer to the first electrode 101 than the light-emitting layer or the second light-emitting layer are formed by processing at the same time; consequently, their end portions are substantially aligned in the perpendicular direction.

The organic compound layer 103 may include another functional layer in addition to the light-emitting layer. FIG. 8A illustrates a structure where, in addition to the light-emitting layer 113, a hole-injection layer 111, a hole-transport layer 112, an electron-transport layer 114, and the electron-injection layer 115 are provided in the organic compound layer 103. Furthermore, the first light-emitting unit 501 and the second light-emitting unit 502 may each include another functional layer in addition to the light-emitting layer. FIG. 8B illustrates a structure where the hole-injection layer 111, a first hole-transport layer 112_1, and the first electron-transport layer 114_1, in addition to the first light-emitting layer 1131, are provided in the first light-emitting unit 501 and a second hole-transport layer 1122, a second electron-transport layer 1142, and the electron-injection layer 115, in addition to the second light-emitting layer 1132, are provided in the second light-emitting unit 502. The structure of the organic compound layer 103 in the present invention is not limited to these structures; any of the layers may be absent or another layer may be added. A carrier-blocking layer (a hole-blocking layer or an electron-blocking layer), an exciton-blocking layer, or the like may be typically added.

Then, components of the above light-emitting device 130, other than the intermediate layer 160, are described.

### <<Structure of First Electrode>>

The first electrode 101 includes an anode. The first electrode 101 may have a stacked-layer structure where the layer in contact with the organic compound layer 103 functions as the anode. The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide including silicon or silicon oxide, indium oxide-zinc oxide, and indium oxide including tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide including tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the second layer 162 in the above intermediate layer 160 is used for the layer (typically the hole-injection layer) in contact with the anode.

### <<Structure of Hole-Injection Layer>>

The hole-injection layer 111 is provided in contact with the anode and has a function of facilitating injection of holes into the organic compound layer 103 (the first light-emitting unit 501). The hole-injection layer 111 can be formed using a phthalocyanine-based compound such as H₂Pc or CuPc, an aromatic amine compound such as DPAB or DNTPD, a high molecular compound such as poly(3,4-ethylenedioxythiophene)/(polystyrenesulfonic acid) (abbreviation: PEDOT/PSS), or the like.

The hole-injection layer 111 may be formed using a substance with an electron-accepting property. As the substance with an acceptor property, any of the substances described as the substance with an acceptor property used for the second layer 162 of the above intermediate layer 160 can be used similarly.

The hole-injection layer 111 may be formed using the material with a hole-transport property that is used for the second layer 162 of the above intermediate layer 160.

Further preferably, in the hole-injection layer 111, the organic compound with a hole-transport property that is used in the composite material has a relatively low HOMO level higher than or equal to −5.7 eV and lower than or equal to −5.4 eV. When the organic compound having a hole-transport property that is used in the composite material has a relatively low HOMO level, holes can be easily injected into the hole-transport layer and a light-emitting device having a long life can be easily obtained. In addition, when the organic compound having a hole-transport property that is used in the composite material has a relatively low HOMO level, induction of holes can be inhibited properly, so that the light-emitting device can have a longer life.

The formation of the hole-injection layer 111 can improve the hole-injection property, which allows the light-emitting device to be driven at a low voltage.

Among substances with an acceptor property, an organic compound with an acceptor property is easy to use because the organic compound is easily deposited by evaporation as a film.

The second light-emitting unit 502 includes no hole-injection layer because the second layer 162 of the intermediate layer 160 functions as a hole-injection layer; however, the second light-emitting unit 502 may include a hole-injection layer.

### <<Structure of Hole-Transport Layer>>

The hole-transport layer (the first hole-transport layer 112_1 or the second hole-transport layer 112_2) includes an organic compound with a hole-transport property. The organic compound with a hole-transport property preferably has a hole mobility higher than or equal to 1×10⁻⁶ cm²/Vs.

Examples of the aforementioned organic compound with a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), BPAFLP, mBPAFLP, PCBA1BP, PCBBi1BP, PCBANB, PCBNBB, 9,9-dimethyl-N-phenyl-N-[4-(9-phenyl-9H-carbazol-3-yl)phenyl]fluoren-2-amine (abbreviation: PCBAF), and PCBASF; compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property that is used for the composite material in the hole-injection layer 111 can also be suitably used as the material included in the hole-transport layer. Further preferably, an organic compound having an amine skeleton and a fluorene skeleton is used. The organic compound having an amine skeleton and a fluorene skeleton is preferable because the organic compound has high reliability and a high hole-transport property and thus can reduce the power consumption of the light-emitting device.

### <<Structure of Light-Emitting Layer>>

The light-emitting layer (the light-emitting layer 113, the first light-emitting layer 1131, or the second light-emitting layer 1132) preferably includes a light-emitting substance and a host material. The light-emitting layer may additionally include another material. Alternatively, the light-emitting layer may have a stacked-layer structure of two layers with different compositions.

The light-emitting substance may be a fluorescent substance, a phosphorescent substance, a substance exhibiting thermally activated delayed fluorescence (TADF), or any other light-emitting substance.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), 9,10-bis(2-biphenyl)-2-(N,N,N-triphenyl-1,4-phenylenediamin-N-yl)anthracene (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N′-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N-diphenyl-N,N-bis(9-phenyl-9H-carbazol-2-yl)naphtho[2,3-b; 6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b; 6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A condensed heteroaromatic compound including nitrogen and boron, especially a compound having a diaza-boranaphtho-anthracene skeleton, emits high color purity blue light with a narrow emission spectrum and can thus be suitably used. Examples of the compound include 5,9-diphenyl-5H,9H-[1,4]benzazaborino[2,3,4-kl]phenazaborine (abbreviation: DABNA-1), 9-(biphenyl-3-yl)-N,N,5,11-tetraphenyl-5H,9H-[1,4]benzazaborino[2,3,4-k]phenazaborin-3-amine (abbreviation: DABNA-2), 2,12-di(tert-butyl)-5,9-di(4-tert-butylphenyl)-N,N-diphenyl-5H,9H-[1,4]benzazaborino[2,3,4-k/]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-k/]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, a compound having an indole skeleton, such as 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex including a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), or tris[4-(3-biphenyl)-5-isopropyl-3-phenyl-4H-1,2,4-triazolato]iridium(III) (abbreviation: [Ir(iPrptz-3b)₃]); an organometallic iridium complex including a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex including an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or tris(2-{1-[2,6-bis(1-methylethyl)phenyl]-1H-imidazol-2-yl-κN³}-4-cyanophenyl-κC)iridium(III) (abbreviation: CNImIr); an organometallic complex including a benzimidazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); an organometallic iridium complex in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIr(acac)); and a platinum complex such as (2-{3-[3-(3,5-di-tert-butylphenyl)benzimidazol-1-yl-2-ylidene-kC²]phenoxy-kC²}-9-(4-tert-butyl-2-pyridinyl-kN)carbazole-2,1-diyl-kC¹)platinum(II) (abbreviation: PtON-TBBI). These compounds emit blue phosphorescent light and have an emission peak in the wavelength range from 450 nm to 520 nm. Alternatively, a compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: [Ir(5mtpy-d₆)₂(mbfpypy-iPr-d₄)]), [2-(methyl-d₃)-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and tris{2-[5-(methyl-d₃)-4-phenyl-2-pyridinyl-κN]phenyl-κC}iridium(III) (abbreviation: [Ir(5m4dppy-d₃)₃]); rare earth metal complexes such as tris(acetylacetonato)(monophenanthroline)terbium(III) (abbreviation: [Tb(acac)₃(Phen)]); and organometallic platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: [Pt(tBudppymmtBubiz-tBubp)]) and [2-(4-(3,5-di-tert-butylphenyl)-6-{3-[4-(5′-tert-butyl[1,1′:3′,1″-terphenyl]-2′-yl)-2-pyridinyl-κN]phenyl-C²}-2-pyridinyl-κN)phenolato-κO]platinum(II) (abbreviation: [Pt(4tButpppypyp-mmtBup)]). These are mainly compounds that emit green phosphorescent light and have an emission peak in the wavelength range from 500 nm to 600 nm. Note that organometallic iridium complexes including a pyrimidine skeleton have remarkably high reliability or emission efficiency and thus are particularly preferable. Alternatively, a compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Jr(tppr)₂(dpm)]), and (acetylacetonato)bis[2,3-bis(4-fluorophenyl)quinoxalinato]iridium(III) (abbreviation: [Jr(Fdpq)₂(acac)]); organometallic iridium complexes having a pyridine skeleton, such as tris(1-phenylisoquinolinato-N,C^{2′})iridium(III) (abbreviation: [Jr(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-N]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)3(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity. Alternatively, a compound obtained by substituting deuterium for part of hydrogen in any of these compounds can also be used.

Besides the above phosphorescent compounds, known phosphorescent compounds may be selected and used.

Examples of the TADF material include a fullerene, a derivative thereof, an acridine, a derivative thereof, and an eosin derivative. Other examples include a metal-including porphyrin, such as a porphyrin including magnesium (Mg), zinc (Zn), cadmium (Cd), tin (Sn), platinum (Pt), indium (In), or palladium (Pd). Examples of the metal-including porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

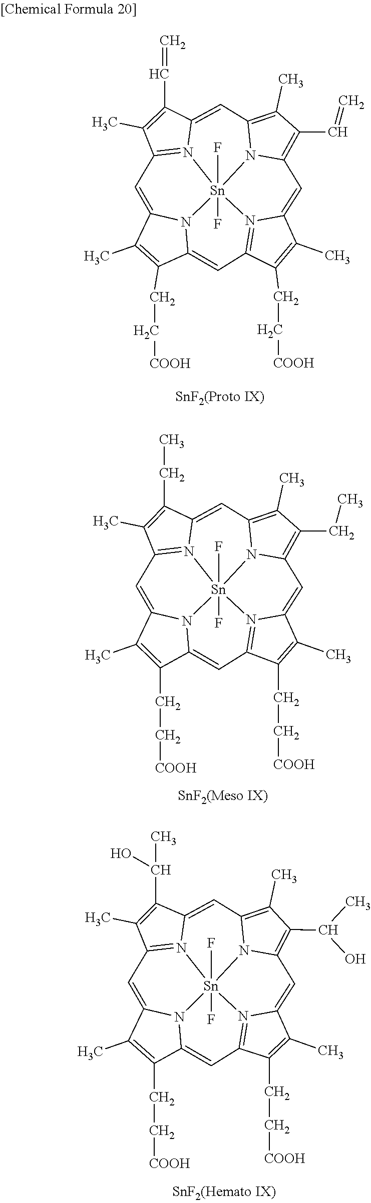

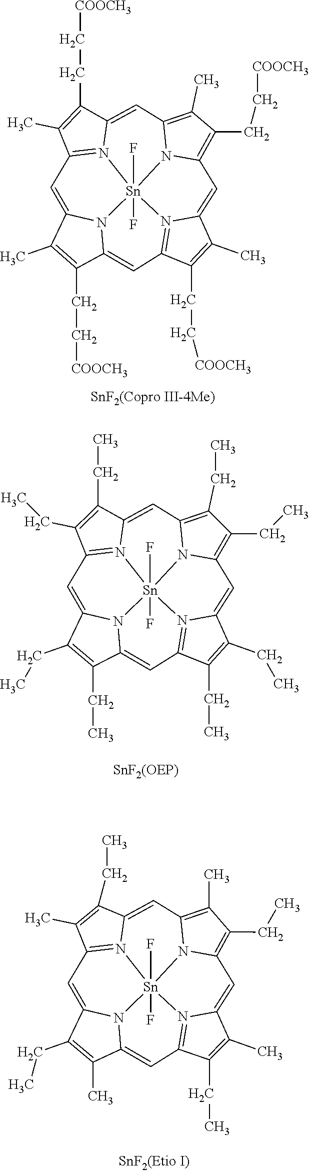

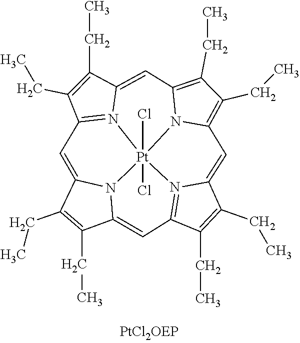

Alternatively, any of heterocyclic compounds each having one or both of a π-electron rich heteroaromatic ring and a π-electron deficient heteroaromatic ring and represented by the following structure formulae can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having a π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring is directly bonded to a π-electron deficient heteroaromatic ring is particularly preferable because the electron-donating property of the π-electron rich heteroaromatic ring and the electron-accepting property of the π-electron deficient heteroaromatic ring are both improved, the energy difference between the Si level and the Ti level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

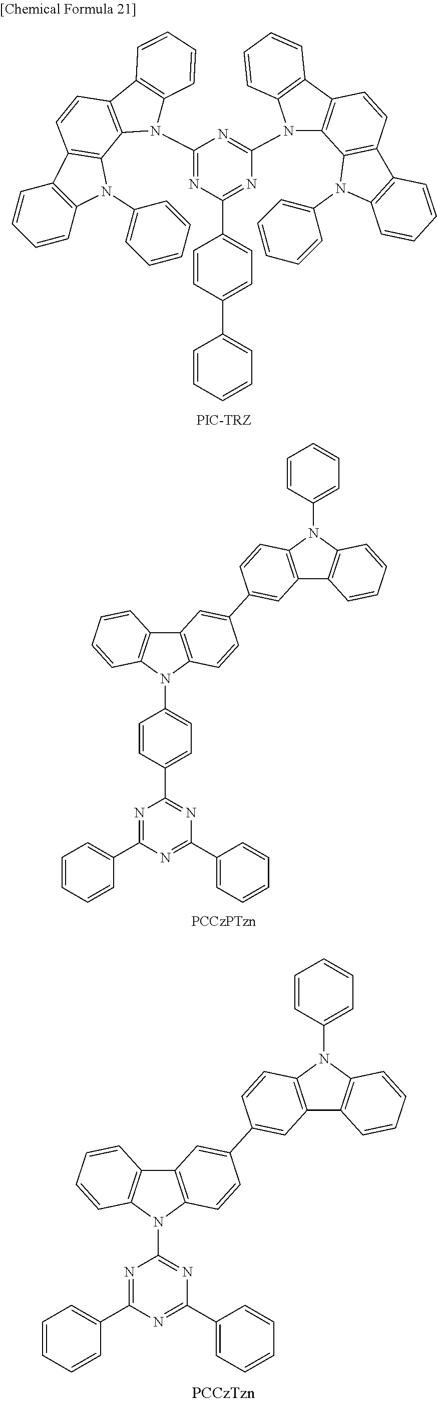 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

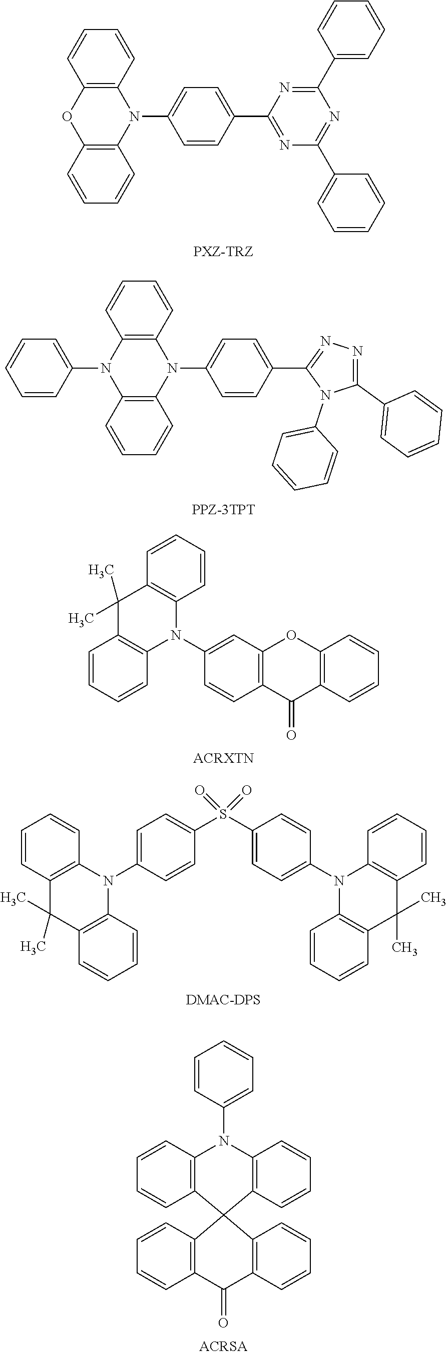 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Alternatively, a TADF material whose singlet excited state and triplet excited state are in a thermal equilibrium state may be used. Since such a TADF material enables a short emission lifetime (excitation lifetime), the efficiency of a light-emitting device in a high-luminance region can be less likely to decrease. Specifically, a material having the following molecular structure can be used.

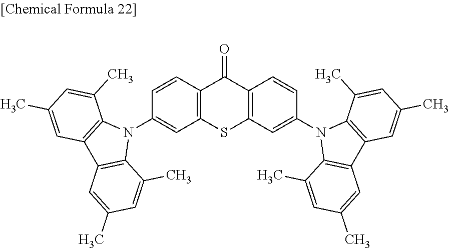

Note that a TADF material is a material having a small energy difference between the Si level and the Ti level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small energy difference between the S₁ level and the T₁ level and functions as a TADF material capable of converting triplet excitation energy into singlet excitation energy.

A phosphorescence spectrum observed at a low temperature (e.g., 77 K to 10 K) can be used for an index of the T₁ level. When the level of energy with a wavelength of the line obtained by extrapolating a tangent to the fluorescence spectrum at a tail on the short wavelength side is the S1 level and the level of energy with a wavelength of the line obtained by extrapolating a tangent to the phosphorescence spectrum at a tail on the short wavelength side is the T1 level, the energy difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

The host material in the light-emitting layer can be selected from various carrier-transport materials such as materials with an electron-transport property and/or materials with a hole-transport property, and the TADF materials.

As the material with a hole-transport property, any of the aforementioned materials given as the material with a hole-transport property can be used similarly.

As the material with an electron-transport property, any of the aforementioned materials given as the material with an electron-transport property can be used similarly.

As the TADF material that can be used as the host material, any of the above materials mentioned as the TADF material can be used similarly. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of the lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carriers are preferably recombined in the TADF material. It is also preferable that the triplet excitation energy generated in the TADF material not be transferred to the triplet excitation energy of the fluorescent substance. For that purpose, the fluorescent substance preferably has a protective group around a luminophore (a skeleton that causes light emission) of the fluorescent substance. As the protective group, a substituent having no π bond is preferably used, and a saturated hydrocarbon is preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transport or carrier recombination. Here, the luminophore refers to an atomic group (skeleton) that causes light emission in a fluorescent substance. The luminophore is preferably a skeleton having a π bond, preferably includes an aromatic ring, or preferably includes a condensed aromatic ring or a condensed heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to form a light-emitting layer with high emission efficiency and high durability. Among the substances having an anthracene skeleton, a substance having a diphenylanthracene skeleton, especially, a substance having a 9,10-diphenylanthracene skeleton, is chemically stable and thus is preferably used as the host material. The host material preferably has a carbazole skeleton because the hole-injection and hole-transport properties are improved; and the host material further preferably has a benzocarbazole skeleton in which a benzene ring is further fused to the carbazole skeleton because the HOMO level thereof is higher than that of a host material having a carbazole skeleton by approximately 0.1 eV and thus holes enter the host material easily. In particular, the host material preferably has a dibenzocarbazole skeleton because the HOMO level thereof is higher than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: uaN-PNPAnth), 9-(1-naphthyl)-10-(2-naphthyl)anthracene (abbreviation: α,β-ADN), 2-(10-phenylanthracen-9-yl)dibenzofuran, 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthryl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material with an electron-transport property and a material with a hole-transport property. By mixing the material with an electron-transport property and the material with a hole-transport property, the transport property of the light-emitting layer 113 can be easily adjusted and a recombination region can be easily controlled. The weight ratio of the content of the material with a hole-transport property to the content of the material with an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength of the lowest-energy-side absorption band of the light-emitting substance, in which case energy can be transferred smoothly and light emission can be obtained efficiently. Such a structure is preferably used to reduce the driving voltage.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be calculated from the electrochemical characteristics (the reduction potentials and the oxidation potentials) of the materials that are measured by cyclic voltammetry (CV).

The formation of an exciplex can be confirmed, for example, in the following manners: when the emission spectrum of the material having a hole-transport property, the emission spectrum of the material having an electron-transport property, and the emission spectrum of a mixed film of these materials are compared, it is observed that the emission spectrum of the mixed film is shifted to the long wavelength side than the emission spectrum of each of the material having a hole-transport property and the material having an electron-transport property (or has another peak on the long wavelength side). Alternatively, when the transient photoluminescence (PL) of the material having a hole-transport property, the transient PL of the material having an electron-transport property, and the transient PL of the mixed film of these materials are compared, a difference in transient response is observed, for example, the transient PL lifetime of the mixed film has a longer lifetime component or has a larger portion of a delayed component than that of each of the material having a hole-transport property and the material having an electron-transport property. The transient PL can be rephrased as transient electroluminescence (EL). That is, the formation of an exciplex can also be confirmed by comparing the transient EL of the material having a hole-transport property, the transient EL of the material having an electron-transport property, and the transient EL of the mixed film of these materials and observing a difference in transient response.

### <<Structure of Electron-Transport Layer>>

The electron-transport layer (the electron-transport layer 114, the first electron-transport layer 114_1, or the second electron-transport layer 1142) includes a substance with an electron-transport property. The material having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound having a π-electron deficient heteroaromatic ring is preferably one or more of an organic compound having a heteroaromatic ring with an azole skeleton, an organic compound having a heteroaromatic ring with a pyridine skeleton, an organic compound having a heteroaromatic ring with a diazine skeleton, and an organic compound having a heteroaromatic ring with a triazine skeleton.

As the organic compound with an electron-transport property that can be used for the electron-transport layer, any of the above organic compounds that can be used as the organic compound having an electron-transport property in the first layer of the intermediate layer 160 can be used similarly. Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage.

The electron mobility of the electron-transport layer is preferably higher than or equal to 1×10⁻⁷ cm²/Vs and lower than or equal to 5×10⁻⁵ cm²/Vs, when the square root of the electric field strength [V/cm] is 600. The amount of electrons injected into the light-emitting layer can be controlled by reducing the electron-transport property of the electron-transport layer, whereby the light-emitting layer can be prevented from having excess electrons. It is particularly preferable to employ this structure when the hole-injection layer is formed using a composite material that includes a material having a hole-transport property with a relatively low HOMO level higher than or equal to −5.7 eV and lower than or equal to −5.4 eV, in which case a long lifetime can be achieved. In this case, the material with an electron-transport property preferably has a HOMO level higher than or equal to −6.0 eV.

For example, as the electron-transport material that can be used for the electron-transport layer, a heteroaromatic compound can be used. The term heteroaromatic compound refers to a cyclic compound including at least two different kinds of elements in a ring. Examples of cyclic structures include a three-membered ring, a four-membered ring, a five-membered ring, a six-membered ring, and the like, and in particular, a five-membered ring and a six-membered ring are preferable. The elements included in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used. The compounds in Embodiment 1 have an electron-transport property and thus can be used as an electron-transport material.

Note that the electron-transport material can be different from the materials used in the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the energy level (the lowest singlet excitation energy level or the lowest triplet excitation energy level) of a material used for the layer in contact with the light-emitting layer or the layer in the vicinity of the light-emitting layer is preferably higher than that of a material used for the light-emitting layer. Thus, when a material different from the material of the light-emitting layer is used as the electron-transport material, an element having high efficiency can be obtained.

The heteroaromatic compound is an organic compound including at least one heteroaromatic ring.

The heteroaromatic ring includes any one of a pyridine ring, a diazine ring, a triazine ring, an azole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having an azole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound including carbon and one or more of nitrogen, oxygen, and sulfur, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of the heteroaromatic compound having a six-membered ring structure, which is a heteroaromatic compound including carbon and one or more of nitrogen, oxygen, sulfur, and the like, include a heteroaromatic compound having a heteroaromatic ring, such as a pyridine ring, a diazine ring (a pyrimidine ring, a pyrazine ring, a pyridazine ring, or the like), a triazine ring, or an azole ring. Other examples include a heteroaromatic compound having a bipyridine structure, a heteroaromatic compound having a terpyridine structure, and the like, which are included in examples of a heteroaromatic compound in which pyridine rings are connected.

Examples of the heteroaromatic compound having a fused ring structure partly including the above six-membered ring structure include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to a furan ring of a furodiazine ring), or a benzimidazole ring.

As specific examples of the heteroaromatic compound having a five-membered ring structure and specific examples of the heteroaromatic compound having a six-membered ring structure, the electron-transport materials described in Embodiment 1 can be given.

For the electron-transport layer, any of the metal complexes given below as well as the heteroaromatic compounds given above can be used. Examples of the metal complexes include a metal complex having a quinoline ring or a benzoquinoline ring, such as tris(8-quinolinolato)aluminum(III) (abbreviation: Alq₃), Almq₃, 8-quinolinolato-lithium (abbreviation: Liq), BeBq₂, bis(2-methyl-8-quinolinolato)(4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

A high-molecular compound such as poly(2,5-pyridinediyl) (abbreviation: PPy), poly[(9,9-dihexylfluorene-2,7-diyl)-co-(pyridine-3,5-diyl)](abbreviation: PF-Py), or poly[(9,9-dioctylfluorene-2,7-diyl)-co-(2,2′-bipyridine-6,6′-diyl)](abbreviation: PF-BPy) can be used as the electron-transport material.

The electron-transport layer is not limited to a single layer and may have a stacked-layer structure of two or more layers each including any of the above substances.

### <<Structure of Electron-Injection Layer>>

As the electron-injection layer 115, a layer that includes an alkali metal, an alkaline earth metal, or a rare earth metal or a compound or a complex thereof, such as lithium fluoride (LiF), cesium fluoride (CsF), calcium fluoride (CaF₂), 8-quinolinolato-lithium (abbreviation: Liq), or ytterbium (Yb), may be provided. An electride or a layer that is formed using a substance having an electron-transport property and includes an alkali metal, an alkaline earth metal, or a compound thereof can be used as the electron-injection layer 115. Examples of the electride include a substance in which electrons are added at high concentration to calcium oxide-aluminum oxide.

Note that as the electron-injection layer 115, it is possible to use a layer including a substance having an electron-transport property (preferably an organic compound having a bipyridine skeleton) that includes a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device including the layer can have favorable external quantum efficiency.

The layer 200 described in Embodiment 1 can also be used as the electron-injection layer 115.

### <<Structure of Second Electrode>>

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Group 1 and Group 2 of the periodic table, such as alkali metals (e.g., lithium (Li) or cesium (Cs)), magnesium (Mg), calcium (Ca), and strontium (Sr), alloys including any of these elements (e.g., MgAg and AlLi), rare earth metals such as europium (Eu) and ytterbium (Yb), and alloys including any of these rare earth metals. However, when the electron-injection layer is provided between the second electrode 102 and the electron-transport layer, any of a variety of conductive materials such as Al, Ag, ITO, or indium oxide-tin oxide including silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an inkjet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an inkjet method, a spin coating method, or the like may be employed.

Different film formation methods may be used to form the electrodes or the layers described above.

This embodiment can be combined as appropriate with any of the other embodiments or examples. In this specification, in the case where a plurality of structure examples are shown in one embodiment, the structure examples can be combined as appropriate.

### Embodiment 3

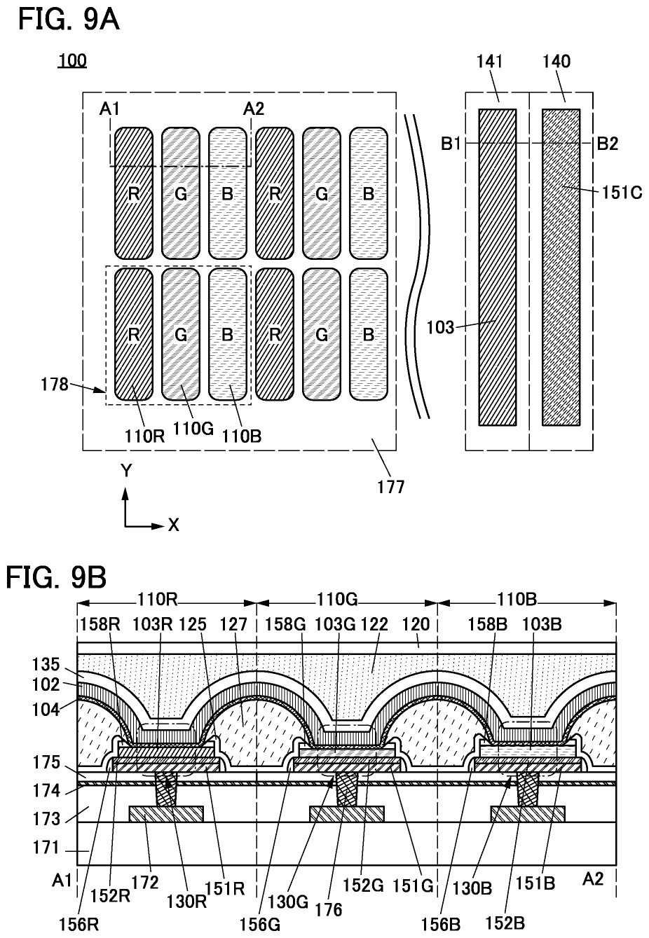

As illustrated in FIGS. 9A and 9B, a plurality of the light-emitting devices 130 are formed over the insulating layer 175 to constitute a display apparatus. In this embodiment, the display apparatus of one embodiment of the present invention will be described in detail.

A display apparatus 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and are perpendicular to each other, for example.

FIG. 9A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 9A illustrates an example where the region 141 and the connection portion 140 are positioned on the right side of the pixel portion 177, there is no particular limitation on the positions of the region 141 and the connection portion 140. The number of regions 141 and the number of connection portions 140 can each be one or two or more.

FIG. 9B is an example of a cross-sectional view along the dashed-dotted line A1-A2 in FIG. 9A. As illustrated in FIG. 9B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not shown). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 135 is provided to cover the light-emitting device 130. A substrate 120 is bonded to the protective layer 135 with a resin layer 122. An inorganic insulating layer 125 and an insulating layer 127 over the inorganic insulating layer 125 are preferably provided between adjacent light-emitting devices 130.

Although FIG. 9B illustrates cross sections of a plurality of the inorganic insulating layers 125 and a plurality of the insulating layers 127, the inorganic insulating layers 125 are preferably connected to each other and the insulating layers 127 are preferably connected to each other when the display apparatus 100 is seen from above. That is, the inorganic insulating layer 125 and the insulating layer 127 preferably include opening portions over first electrodes.

In FIG. 9B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission light-emitting apparatus where light is emitted in the direction opposite to a substrate over which light-emitting devices are formed. Note that the display apparatus of one embodiment of the present invention may be of a bottom-emission type.

Examples of a light-emitting substance included in the light-emitting device 130 include organic compounds or organometallic complexes such as a substance emitting fluorescent light (a fluorescent material), a substance emitting phosphorescent light (a phosphorescent material), and a substance exhibiting thermally activated delayed fluorescence (a thermally activated delayed fluorescent (TADF) material). Other examples include inorganic compounds (e.g., a quantum dot material).

The light-emitting device 130R has a structure as described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and the second electrode (common electrode) 102 over the common layer. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is not provided, the organic compound layer 103R corresponds to the organic compound layer 103 described in Embodiments 1 and 2. In the case where the common layer 104 is provided, a stack of the organic compound layer 103R and the common layer 104 corresponds to the organic compound layer 103 described in Embodiments 1 and 2.

The light-emitting device 130G has a structure as described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer. Although the common layer 104 is not necessarily provided, it is preferable to provide the common layer 104 to reduce damage to the organic compound layer 103G during processing. Furthermore, in the case where the common layer 104 is not provided, the organic compound layer 103G corresponds to the organic compound layer 103 described in Embodiments 1 and 2. In the case where the common layer 104 is provided, a stack of the organic compound layer 103G and the common layer 104 corresponds to the organic compound layer 103 described in Embodiments 1 and 2.

The light-emitting device 130B has a structure as described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer. Although the common layer 104 is not necessarily provided, it is preferable to provide the common layer 104 to reduce damage to the organic compound layer 103B during processing. Furthermore, in the case where the common layer 104 is not provided, the organic compound layer 103B corresponds to the organic compound layer 103 described in Embodiments 1 and 2. In the case where the common layer 104 is provided, a stack of the organic compound layer 103B and the common layer 104 corresponds to the organic compound layer 103 described in Embodiments 1 and 2.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layer 103R, the organic compound layer 103G, and the organic compound layer 103B are island-shaped layers and are isolated on a device basis or on an emission color basis. Providing the island-shaped organic compound layer 103 in each of the light-emitting devices 130 can suppress a leakage current between the adjacent light-emitting devices 130 even in a high-resolution display apparatus. This can prevent crosstalk, so that a display apparatus with extremely high contrast can be provided. Specifically, a display apparatus having high current efficiency at low luminance can be provided.

The island-shaped organic compound layer 103 is formed by forming an EL film and processing the EL film by a lithography method.

In the display apparatus of one embodiment of the present invention, the first electrode (pixel electrode) of the light-emitting device preferably has a stacked-layer structure. For example, in the example illustrated in FIG. 9B, the first electrode of the light-emitting device 130 is a stack of the conductive layer 151 (the conductive layers 151R, 151G, and 151B) and the conductive layer 152 (the conductive layers 152R, 152G, and 152B). In the case where the display apparatus 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display apparatus 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 having high visible light reflectance and the conductive layer 152 having a high work function, the light-emitting device 130 can have high light extraction efficiency and a low driving voltage. In this specification and the like, for example, description common to the conductive layers 151R, 151G, and 151B is sometimes made using the collective term “conductive layer 151”.

In the case where the conductive layer 151 has high visible light reflectance, the visible light reflectance of the conductive layer 151 is higher than or equal to 40% and lower than or equal to 100%, preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers might change in quality as a result of, for example, a reaction between the plurality of layers. For example, when a film formed after the formation of the pixel electrode is removed by a wet etching method, contact of a chemical solution with the pixel electrode might cause galvanic corrosion.

Thus, in the display apparatus 100 of this embodiment, an insulating layer 156 (insulating layers 156R, 156G, and 156B) is formed on the side surfaces of the conductive layers 151 and 152. This can inhibit a chemical solution from coming into contact with the conductive layer 151 even when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display apparatus 100 to be manufactured by a high-yield method and to be accordingly inexpensive. In addition, generation of a defect in the display apparatus 100 can be inhibited, which makes the display apparatus 100 highly reliable. In this specification and the like, description common to the conductive layers 156R, 156G, and 156B is sometimes made using the collective term “conductive layer 156”.

A metal material can be used for the conductive layer 151, for example. Specifically, it is possible to use a metal such as aluminum (Al), titanium (Tl), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy including an appropriate combination of any of these metals, for example.

For the conductive layer 152, an oxide including one or more selected from indium, tin, zinc, gallium, titanium, aluminum, and silicon can be used. For example, it is preferable to use a conductive oxide including one or more of indium oxide, indium tin oxide, indium zinc oxide, zinc oxide, zinc oxide including gallium, titanium oxide, indium zinc oxide including gallium, indium zinc oxide including aluminum, indium tin oxide including silicon, indium zinc oxide including silicon, and the like. In particular, indium tin oxide including silicon can be suitably used for the conductive layer 152 because of having a high work function, for example, a work function higher than or equal to 4.0 eV.

The conductive layer 151 and the conductive layer 152 may each be a stack of a plurality of layers that include different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

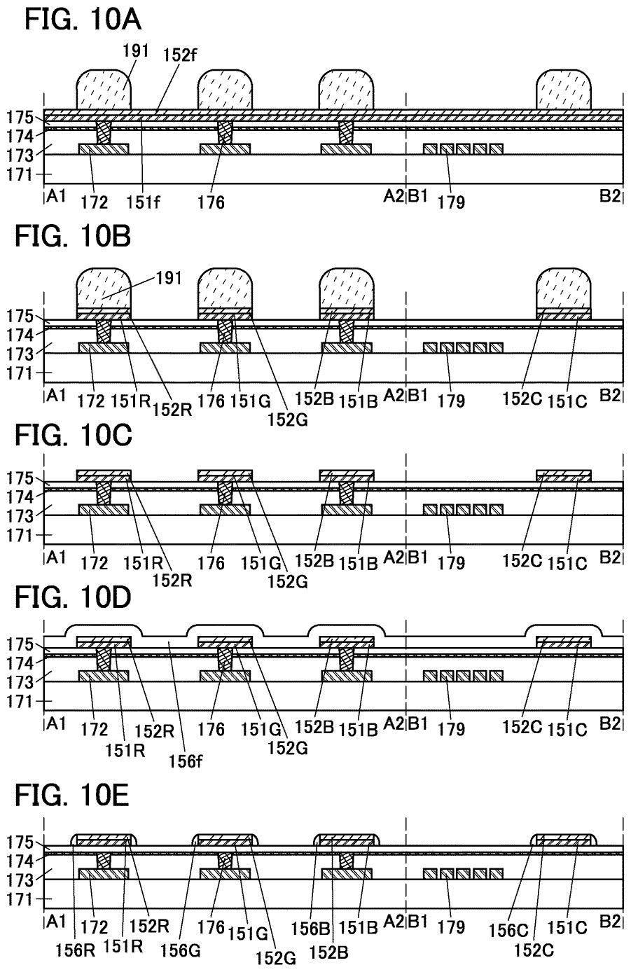

Next, an example of a method for manufacturing the display apparatus 100 having the structure illustrated in FIG. 9A is described with reference to FIGS. 10A to 10E, FIGS. 11A and 11B, FIGS. 12A to 12D, FIGS. 13A to 13C, FIGS. 14A to 14C, and FIGS. 15A to 15C. An organic layer of the light-emitting device included in the display apparatus 100 is formed by a manufacturing process including treatment using water. When the light-emitting device of one embodiment of the present invention is used as the light-emitting device included in the display apparatus of one embodiment of the present invention, the display apparatus including the light-emitting device having reduced driving voltage and high emission efficiency can be provided.

### Manufacturing Method Example

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like. Examples of a CVD method include a plasma-enhanced CVD (PECVD) method and a thermal CVD method. An example of a thermal CVD method is a metal organic CVD (MOCVD) method.

Thin films included in the display apparatus (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Specifically, for manufacture of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

Thin films included in the display apparatus can be processed by a lithography method, for example. Alternatively, a nanoimprinting method, a sandblasting method, a lift-off method, or the like may be used to process thin films. Alternatively, island-shaped thin films may be directly formed by a film formation method using a shielding mask such as a metal mask.

As a lithography method, for example, a photolithography method can be used. There are two typical examples of photolithography methods. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam to perform extremely minute processing. Note that when exposure is performed by scanning of a beam such as an electron beam, a photomask is not needed.

For etching of thin films, a dry etching method, a wet etching method, a sandblast method, or the like can be used.

In a manufacturing process of the light-emitting device, an organic compound that is excited by absorbing light is used. The excited organic compound is highly likely to react with oxygen or water in the air in some cases. In other words, when the organic compound is irradiated with light having a wavelength that is absorbed by the organic compound while oxygen exists, a deterioration product might be generated in the organic compound.

In view of the above, in the case where a substrate over which the organic compound is formed is exposed to the air when processed by a photolithography method, it is preferable to appropriately control lighting. The substrate over which the organic compound that is excited by absorbing light is formed is ideally processed under lighting with a wavelength that does not cause excitation of the organic compound; to ensure illuminance or color rendering properties with which work efficiency is not reduced, lighting with a wavelength of the shortest-wavelength emission edge among emission edges in the emission spectrum of a light source of less than or equal to 600 nm, preferably less than or equal to 580 nm is preferably used.

It is preferable to use yellow light (light of a fluorescent lamp or light of a light-emitting diode (LED)) which does not include light with a wavelength shorter than 500 nm for the lighting, for example. It is further preferable to use orange light (light of a fluorescent lamp or light of a light-emitting diode (LED)) which does not include light with a wavelength shorter than 530 nm. Light of a low-pressure sodium lamp can also be used. Light of an incandescent lamp, light of a fluorescent lamp, light of a light-emitting diode (LED), light of a halogen lamp, or sunlight can be used, for example, as long as an optical filter that can shield light with a short wavelength is used. As the optical filter that can shield light with a short wavelength, for example, a band-pass filter or a long-pass filter (short-wavelength cut filter) can be used. The above lighting can result in low illuminance.

First, as illustrated in FIG. 10A, the insulating layer 171 is formed over a substrate (not shown). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. When an insulating substrate is used as the substrate, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 10A, openings reaching the conductive layer 172 are formed in the insulating layers 175, 174, and 173. Then, the plugs 176 are formed to fill the openings.

Next, as illustrated in FIG. 10A, a conductive film 151f to be the conductive layers 151R, 151G, 151B, and 151C is formed over the plugs 176 and the insulating layer 175. The conductive film 151f can be formed by a sputtering method or a vacuum evaporation method, for example. A metal material can be used for the conductive film 151f, for example.

Next, as illustrated in FIG. 10A, a conductive film 152f to be the conductive layer 152R, the conductive layer 152G, the conductive layer 152B, and a conductive layer 152C is formed over the conductive film 151f. The conductive film 152f can be formed by a sputtering method or a vacuum evaporation method, for example. A conductive oxide can be used for the conductive film 152f, for example. The conductive film 152f can have a stacked-layer structure of a film formed using a metal material and a film formed using a conductive oxide thereover. For example, the conductive film 152f can have a stacked-layer structure of a film formed using titanium, silver, or an alloy including silver and a film formed using a conductive oxide thereover.

The conductive film 152f can be formed by an ALD method. In this case, for the conductive film 152f, an oxide including one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film including a plurality of kinds of metals (e.g., an indium tin oxide film) is formed as the conductive film 152f, the composition of the metals can be controlled by varying the number of cycles for different kinds of precursors.

For example, in the case where an indium tin oxide film is formed as the conductive film 152f, after a precursor including indium is introduced, the precursor is purged, and an oxidizer is introduced to form an In—O film, and then a precursor including tin is introduced, the precursor is purged, and an oxidizer is introduced to form a Sn—O film. Here, when the number of cycles of forming an In—O film is larger than the number of cycles of forming a Sn—O film, the number of In atoms included in the conductive film 152f can be larger than the number of Sn atoms included therein.

For example, to form a zinc oxide film as the conductive film 152f, a Zn—O film is formed in the above procedure. For another example, to form an aluminum zinc oxide film as the conductive film 152f, a Zn—O film and an Al—O film are formed in the above procedure. For another example, to form a titanium oxide film as the conductive film 152f, a Tl—O film is formed in the above procedure. For another example, to form an indium tin oxide film including silicon as the conductive film 152f, an In—O film, a Sn—O film, and a Si—O film are formed in the above procedure. For another example, to form a zinc oxide film including gallium, a Ga—O film and a Zn—O film are formed in the above procedure.

As a precursor including indium, it is possible to use, for example, triethylindium, trimethylindium, or [1,1,1-trimethyl-N-(trimethylsilyl)amide]-indium. As a precursor including tin, it is possible to use, for example, tin chloride or tetrakis(dimethylamido)tin. As a precursor including zinc, it is possible to use, for example, diethylzinc or dimethylzinc. As a precursor including gallium, it is possible to use, for example, triethylgallium. As a precursor including titanium, it is possible to use, for example, titanium chloride, tetrakis(dimethylamido)titanium, or tetraisopropyl titanate. As a precursor including aluminum, it is possible to use, for example, aluminum chloride or trimethylaluminum. As a precursor including silicon, it is possible to use, for example, trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Subsequently, a resist mask 191 is formed over the conductive films 151f and 152f as illustrated in FIG. 10A. The resist mask 191 can be formed by application of a photosensitive material (photoresist), light exposure, and development.

Subsequently, as illustrated in FIG. 10B, the conductive films 151f and 152f in a region not overlapping with the resist mask 191, for example, are removed by an etching method, specifically, a dry etching method, for instance, so that the pixel electrodes each including the conductive layers 151 and 152 are formed. Note that in the case where the conductive film 151f includes a layer formed using a conductive oxide such as indium tin oxide, for example, the layer may be removed by a wet etching method. In this manner, the conductive layers 151 and 152 are formed. In the case where part of the conductive film 151f is removed by a dry etching method, for example, a recessed portion may be formed in a region of the insulating layer 175 not overlapping with the conductive layer 151.

Note that the following process may be employed: the conductive film 152f is processed by a lithography method to form the conductive layers 152R, 152G, 152B, and 152C, and then, the conductive film 151f is processed using the conductive layers 152R, 152G, 152B, and 152C as masks. Specifically, after a resist mask is formed, part of the conductive film 152f is removed by an etching method, for example. The conductive film 152f can be removed by a wet etching method, for example. The conductive film 152f may be removed by a dry etching method. After that, the conductive film 151f is preferably removed by a wet etching method.

Next, hydrophobization treatment is preferably performed on the conductive layer 152. The hydrophobization treatment can change the hydrophilic properties of the subject surface into hydrophobic properties or increase the hydrophobic properties of the subject surface. The hydrophobization treatment on the conductive layer 152 can increase the adhesion between the conductive layer 152 and the organic compound layer 103 formed in a later step to reduce film peeling. Note that the hydrophobization treatment is not necessarily performed.

Next, the resist mask 191 is removed as illustrated in FIG. 10C. The resist mask 191 can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 191 may be removed by wet etching.

Then, as illustrated in FIG. 10D, an insulating film 156f to be an insulating layer 156R, an insulating layer 156G, an insulating layer 156B, and an insulating layer 156C is formed over the conductive layers 151R and 152R, the conductive layers 151G and 152G, the conductive layers 151B and 152B, the conductive layers 151C and 152C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film including silicon, a nitride insulating film including silicon, an oxynitride insulating film including silicon, a nitride oxide insulating film including silicon, or the like can be used as the insulating film 156f. For the insulating film 156f, silicon oxynitride can be used, for example.

Subsequently, as illustrated in FIG. 10E, the insulating film 156f is processed to form the insulating layers 156R, 156G, 156B, and 156C. The insulating layer 156 can be formed by performing etching substantially uniformly on the top surface of the insulating film 156f, for example. Such uniform etching for planarization is also referred to as etch back treatment. Note that the insulating layer 156 may be formed by a lithography method.

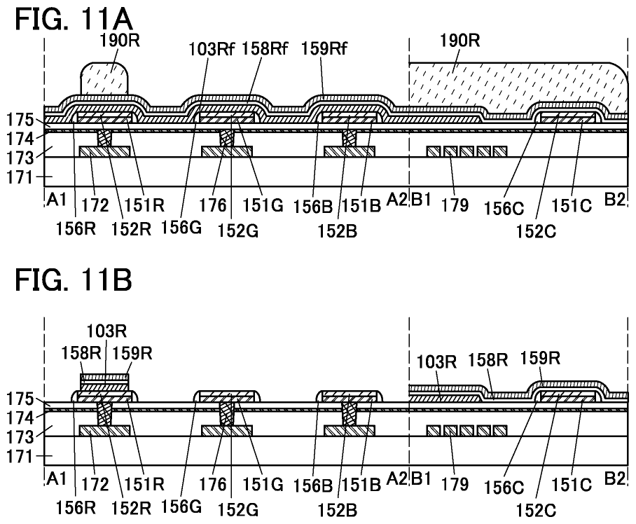

Next, as illustrated in FIG. 11A, an organic compound film 103Rf to be the organic compound layer 103R is formed over the conductive layers 152R, 152G, and 152B, the insulating layers 156R, 156G, and 156B, and the insulating layer 175.

As illustrated in FIG. 11A, the organic compound film 103Rf is not formed over the conductive layer 152C. For example, a mask for defining a film formation area (also referred to as an area mask, a rough metal mask, or the like to be distinguished from a fine metal mask) is used, so that the organic compound film 103Rf can be formed only in a desired region. Employing a film formation step using an area mask and a processing step using a resist mask enables a light-emitting device to be manufactured by a relatively easy process.

The organic compound film 103Rf can be formed by an evaporation method, specifically a vacuum evaporation method, for example. The organic compound film 103Rf may be formed by a transfer method, a printing method, an ink-jet method, a coating method, or the like.

Next, as illustrated in FIG. 11A, a sacrificial film 158Rf to be a sacrificial layer 158R and a mask film 159Rf to be a mask layer 159R are sequentially formed over the organic compound film 103Rf, the conductive layer 152C, and the insulating layer 175.

Although this embodiment shows an example where a mask film having a two-layer structure of the sacrificial film 158Rf and the mask film 159Rf is formed, a mask film may have a single-layer structure or a stacked-layer structure of three or more layers. In this specification and the like, a mask layer may be referred to as a sacrificial layer.

Providing the sacrificial layer over the organic compound film 103Rf can reduce damage to the organic compound film 103Rf in the manufacturing process of the display apparatus, resulting in an increase in reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200 °C, preferably lower than or equal to 150 °C, further preferably lower than or equal to 120 °C, still further preferably lower than or equal to 100 °C, yet still further preferably lower than or equal to 80 °C

The sacrificial film 158Rf and the mask film 159Rf are preferably films that can be removed by a wet etching method. The use of a wet etching method can reduce damage to the organic compound film 103Rf in processing of the sacrificial film 158Rf and the mask film 159Rf, as compared to the case of using a dry etching method.

The sacrificial film 158Rf and the mask film 159Rf can be formed by a sputtering method, an ALD method (including a thermal ALD method and a PEALD method), a CVD method, or a vacuum evaporation method, for example. Alternatively, the sacrificial film 158Rf and the mask film 159Rf may be formed by the above-described wet film formation method.

Note that the sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material including any of the metal materials, for example. It is particularly preferable to use a low-melting-point material such as aluminum or silver. A metal material that can block ultraviolet rays is preferably used for one or both of the sacrificial film 158Rf and the mask film 159Rf, in which case the organic compound film 103Rf can be inhibited from being irradiated with ultraviolet rays and deteriorating.

The sacrificial film 158Rf and the mask film 159Rf can each be formed using a metal oxide such as In—Ga—Zn oxide, indium oxide, In—Zn oxide, In—Sn oxide, indium titanium oxide (In—Tl oxide), indium tin zinc oxide (In—Sn—Zn oxide), indium titanium zinc oxide (In—Tl—Zn oxide), indium gallium tin zinc oxide (In—Ga—Sn—Zn oxide), or indium tin oxide including silicon.

In place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As each of the sacrificial film and the mask film, a film including a material having a light-blocking property, particularly with respect to ultraviolet rays, is preferably used. Although a variety of materials such as a metal, an insulator, a semiconductor, and a metalloid that have a property of blocking ultraviolet rays can be used as a light-blocking material, each of the sacrificial film and the mask film is preferably a film capable of being processed by etching and is particularly preferably a film having good processability because part or the whole of each of the sacrificial film and the mask film is removed in a later step.

The sacrificial film and the mask film are preferably formed using a semiconductor material such as silicon or germanium, for example, for excellent compatibility with a semiconductor manufacturing process. Alternatively, an oxide or a nitride of the semiconductor material can be used. A non-metallic material such as carbon or a compound thereof can be used. A metal such as titanium, tantalum, tungsten, chromium, or aluminum or an alloy including at least one of these metals can be used. Alternatively, an oxide including the above-described metal, such as titanium oxide or chromium oxide, or a nitride such as titanium nitride, chromium nitride, or tantalum nitride can be used.

When a film including a material having a property of blocking ultraviolet rays is used as each of the sacrificial film and the mask film, the organic compound layer can be inhibited from being irradiated with ultraviolet rays in a light exposure step, for example. The organic compound layer is inhibited from being damaged by ultraviolet rays, so that the reliability of the light-emitting device can be improved.

Note that the same effect is obtained when a film including a material having a property of blocking ultraviolet rays is used for an inorganic insulating film 125f described later.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf. As the sacrificial film 158Rf and the mask film 159Rf, aluminum oxide films can be formed by an ALD method, for example. An ALD method is preferably used, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

Note that the same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. For the sacrificial film 158Rf and the inorganic insulating layer 125, the same film formation conditions may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, since the sacrificial film 158Rf is a layer a large part or the whole of which is to be removed in a later step, it is preferable that the processing of the sacrificial film 158Rf be easy. Therefore, the sacrificial film 158Rf is preferably formed with a substrate temperature lower than that for formation of the inorganic insulating layer 125.

One or both of the sacrificial film 158Rf and the mask film 159Rf may be formed using an organic material. For example, as the organic material, a material that can be dissolved in a solvent chemically stable with respect to at least the uppermost film of the organic compound film 103Rf may be used. Specifically, a material that will be dissolved in water or an alcohol can be suitably used. In forming a film of such a material, it is preferable to apply the material dissolved in a solvent such as water or an alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the organic compound film 103Rf can be reduced accordingly.

The sacrificial film 158Rf and the mask film 159Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet film formation methods can be used as the sacrificial film 158Rf, and an inorganic film (e.g., a silicon nitride film) formed by a sputtering method can be used as the mask film 159Rf.

Subsequently, a resist mask 190R is formed over the mask film 159Rf as illustrated in FIG. 11A. The resist mask 190R can be formed by application of a photosensitive material (photoresist), light exposure, and development.

The resist mask 190R may be formed using either a positive resist material or a negative resist material.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display apparatus. Note that the resist mask 190R is not necessarily provided over the conductive layer 152C. The resist mask 190R is preferably provided to cover the area from an end portion of the organic compound film 103Rf to an end portion of the conductive layer 152C (the end portion closer to the organic compound film 103Rf), as illustrated in the cross-sectional view along the line B1-B2 in FIG. 11A.

Next, as illustrated in FIG. 111B, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

Each of the sacrificial film 158Rf and the mask film 159Rf can be processed by a wet etching method or a dry etching method. The sacrificial film 158Rf and the mask film 159Rf are preferably processed by isotropic etching.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution including a mixed solution of any of these acids, for example.

Since the organic compound film 103Rf is not exposed in the processing of the mask film 159Rf, the range of choice for a processing method for the mask film 159Rf is wider than that for the sacrificial film 158Rf Specifically, even in the case where a gas including oxygen is used as the etching gas in the processing of the mask film 159Rf, deterioration of the organic compound film 103Rf can be inhibited.

In the case of using a dry etching method to process the sacrificial film 158Rf, deterioration of the organic compound film 103Rf can be inhibited by not using a gas including oxygen as the etching gas. In the case of using a dry etching method, it is preferable to use a gas including CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using CHF₃ and He or a combination of CHF₃, He, and CH₄. In the case where an In—Ga—Zn oxide film formed by a sputtering method is used as the mask film 159Rf, part of the mask film 159Rf can be removed by a wet etching method using diluted phosphoric acid. Alternatively, part of the mask film 159Rf may be removed by a dry etching method using CH₄ and Ar. Alternatively, part of the mask film 159Rf can be removed by a wet etching method using diluted phosphoric acid. In the case where a tungsten film formed by a sputtering method is used as the mask film 159Rf, part of the mask film 159Rf can be removed by a dry etching method using a combination of SF₆, CF₄, and O₂ or a combination of CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. At this time, the sacrificial film 158Rf is located on the outermost surface, and the organic compound film 103Rf is not exposed; thus, the organic compound film 103Rf can be inhibited from being damaged in the step of removing the resist mask 190R. In addition, the range of choice for the method for removing the resist mask 190R can be widened.

Next, as illustrated in FIG. 11B, the organic compound film 103Rf is processed, so that the organic compound layer 103R is formed. For example, part of the organic compound film 103Rf is removed using the mask layer 159R and the sacrificial layer 158R as a hard mask to form the organic compound layer 103R.

Accordingly, as illustrated in FIG. 11B, the stacked-layer structure of the organic compound layer 103R, the sacrificial layer 158R, and the mask layer 159R remains over the conductive layer 152R. The conductive layers 152G and 152B are exposed.

In the example illustrated in FIG. 11B, an end portion of the organic compound layer 103R is located inward from an end portion of the conductive layer 152R. This structure allows miniaturization of pixels, enabling manufacture of a high-resolution display. Although not illustrated in FIG. 111B, by the above etching treatment, a recessed portion may be formed in the insulating layer 175 in a region not overlapping with the organic compound layer 103R.

As described above, the resist mask 190R is preferably provided to cover the area from the end portion of the organic compound layer 103R to the end portion of the conductive layer 152C (the end portion closer to the organic compound layer 103R) in the cross section along the dashed-dotted line B1-B2. In that case, as illustrated in FIG. 111B, the sacrificial layer 158R and the mask layer 159R are provided to cover the area from the end portion of the organic compound layer 103R to the end portion of the conductive layer 152C (the end portion closer to the organic compound layer 103R) in the cross section along the dashed-dotted line B1-B2. Hence, the insulating layer 175 can be inhibited from being exposed in the cross section along the dashed-dotted line B1-B2, for example. This can prevent the insulating layers 175, 174, and 173 from being partly removed by etching and thus prevent the conductive layer 179 from being exposed. Accordingly, the conductive layer 179 can be inhibited from being unintentionally electrically connected to another conductive layer. For example, a short circuit between the conductive layer 179 and the second electrode 102 formed in a later step can be inhibited.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas including oxygen as the etching gas.

A gas including oxygen may be used as the etching gas. When the etching gas includes oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas including at least one of H₂, CF₄, C_{4F}s, SF₆, CHF₃, Cl₂, H₂O, BCl₃, and a Group 18 element such as He or Ar as the etching gas, for example. Alternatively, a gas including oxygen and at least one of the above is preferably used as the etching gas. Alternatively, an oxygen gas may be used as the etching gas. Specifically, for example, a gas including H₂ and Ar or a gas including CF₄ and He can be used as the etching gas. For another example, a gas including CF₄, He, and oxygen can be used as the etching gas. For another example, a gas including H₂ and Ar and a gas including oxygen can be used as the etching gas.

As described above, in one embodiment of the present invention, the mask layer 159R is formed in the following manner: the resist mask 190R is formed over the mask film 159Rf and part of the mask film 159Rf is removed using the resist mask 190R. After that, part of the organic compound film 103Rf is removed using the mask layer 159R as a hard mask, so that the organic compound layer 103R is formed. In other words, the organic compound layer 103R is formed by processing the organic compound film 103Rf by a lithography method. Note that part of the organic compound film 103Rf may be removed using the resist mask 190R. Then, the resist mask 190R may be removed.

Next, hydrophobization treatment for the conductive layer 152G, for example, is preferably performed. At the time of processing the organic compound film 103Rf, the properties of a surface of the conductive layer 152G change to hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling. Note that the hydrophobization treatment is not necessarily performed.

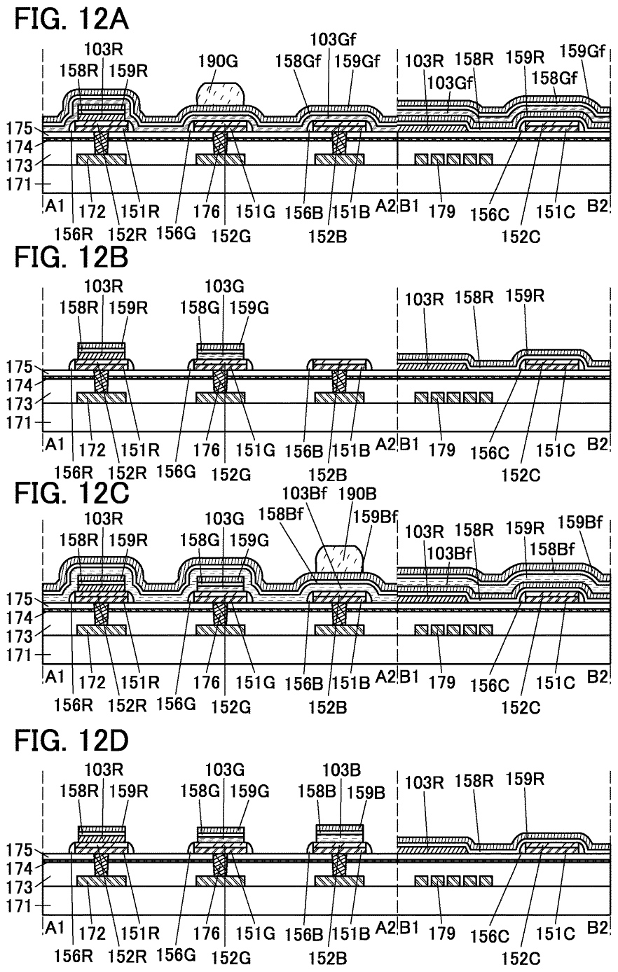

Next, as illustrated in FIG. 12A, an organic compound film 103Gf to be the organic compound layer 103G is formed over the conductive layers 152G and 152B, the insulating layers 156R, 156G, and 156B, the mask layer 159R, and the insulating layer 175.

The organic compound film 103Gf can be formed by a method similar to that for forming the organic compound film 103Rf. The organic compound film 103Gf can have a structure similar to that of the organic compound film 103Rf.

Then, as illustrated in FIG. 12A, a sacrificial film 158Gf to be a sacrificial layer 158G and a mask film 159Gf to be a mask layer 159G are sequentially formed over the organic compound film 103Gf and the mask layer 159R. After that, a resist mask 190G is formed. The materials and the formation methods of the sacrificial film 158Gf and the mask film 159Gf are similar to those of the sacrificial film 158Rf and the mask film 159Rf. The material and the formation method of the resist mask 190G are similar to those of the resist mask 190R.

The resist mask 190G is provided at a position overlapping with the conductive layer 152G.

Subsequently, as illustrated in FIG. 12B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the organic compound film 103Gf is processed, so that the organic compound layer 103G is formed. For example, part of the organic compound film 103Gf is removed using the mask layer 159G and the sacrificial layer 158G as a hard mask to form the organic compound layer 103G.

Accordingly, as illustrated in FIG. 12B, the stacked-layer structure of the organic compound layer 103G, the sacrificial layer 158G, and the mask layer 159G remains over the conductive layer 152G. The mask layer 159R and the conductive layer 152B are exposed.

Next, hydrophobization treatment for the conductive layer 152B, for example, is preferably performed. At the time of processing the organic compound film 103Gf, the properties of a surface of the conductive layer 152B change to hydrophilic properties in some cases, for example. The hydrophobization treatment for the conductive layer 152B, for example, can increase the adhesion between the conductive layer 152B and a layer to be formed in a later step (which is the organic compound layer 103B here) and inhibit film peeling. Note that the hydrophobization treatment is not necessarily performed.

Next, as illustrated in FIG. 12C, an organic compound film 103Bf to be the organic compound layer 103B is formed over the conductive layer 152B, the insulating layers 156R, 156G, and 156B, the mask layers 159R and 159G, and the insulating layer 175.

The organic compound film 103Bf can be formed by a method similar to that for forming the organic compound film 103Rf. The organic compound film 103Bf can have a structure similar to that of the organic compound film 103Rf.

Then, as illustrated in FIG. 12C, a sacrificial film 158Bf to be a sacrificial layer 158B and a mask film 159Bf to be a mask layer 159B are sequentially formed over the organic compound film 103Bf and the mask layer 159R. After that, a resist mask 190B is formed. The materials and the formation methods of the sacrificial film 158Bf and the mask film 159Bf are similar to those of the sacrificial film 158Rf and the mask film 159Rf. The material and the formation method of the resist mask 190B are similar to those of the resist mask 190R.

The resist mask 190B is provided at a position overlapping with the conductive layer 152B.

Subsequently, as illustrated in FIG. 12D, part of the mask film 159Bf is removed using the resist mask 190B, so that the mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, as illustrated in FIG. 12D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 600 and less than or equal to 90°.

The distance between two adjacent layers among the organic compound layers 103R, 103G, and 103B, which are formed by a lithography method as described above, can be shortened to less than or equal to 8 μm, less than or equal to 5 μm, less than or equal to 3 μm, less than or equal to 2 μm, or less than or equal to 1 μm. Here, the distance can be specified, for example, by the distance between opposite end portions of two adjacent layers among the organic compound layers 103R, 103G, and 103B. Shortening the distance between the island-shaped organic compound layers can provide a display apparatus having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

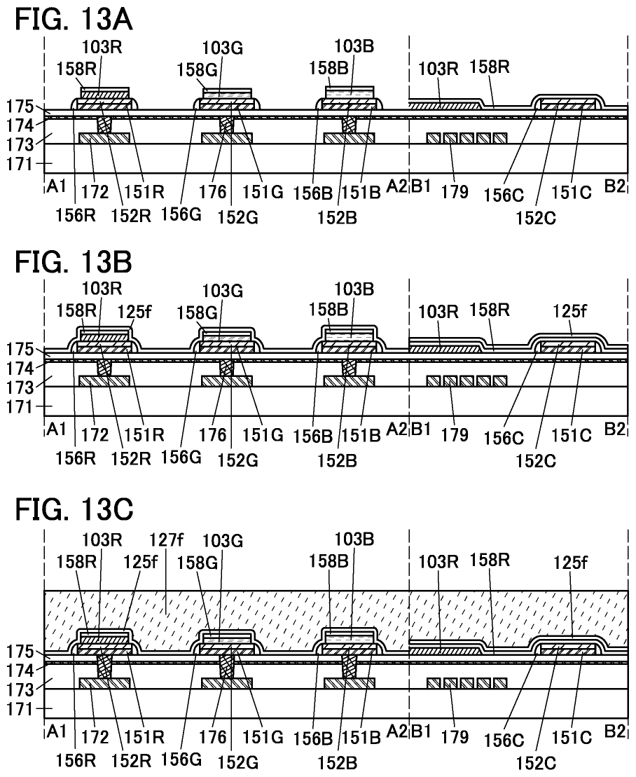

Next, as illustrated in FIG. 13A, the mask layers 159R, 159G, and 159B are preferably removed. The sacrificial layers 158R, 158G, and 158B and the mask layers 159R, 159G, and 159B remain in the display apparatus in some cases depending on the subsequent steps. Removing the mask layers 159R, 159G, and 159B at this stage can inhibit the mask layers 159R, 159G, and 159B from being left in the display apparatus. For example, in the case where a conductive material is used for the mask layers 159R, 159G, and 159B, removing the mask layers 159R, 159G, and 159B in advance can inhibit generation of a leakage current, formation of a capacitor, and the like due to the remaining mask layers 159R, 159G, and 159B.

This embodiment describes an example where the mask layers 159R, 159G, and 159B are removed; however, the mask layers 159R, 159G, and 159B are not necessarily removed. For example, in the case where the mask layers 159R, 159G, and 159B include the above-described material having a property of blocking ultraviolet rays, the procedure preferably proceeds to the next step without removing the mask layers 159R, 159G, and 159B, in which case the organic compound layers can be protected from ultraviolet rays.

The step of removing the mask layers can be performed by a method similar to that for the step of processing the mask films. Specifically, by using a wet etching method, damage applied to the organic compound layers 103R, 103G, and 103B at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layers 103R, 103G, and 103B and water adsorbed onto the surfaces of the organic compound layers 103R, 103G, and 103B. For example, heat treatment in an inert gas atmosphere or a reduced-pressure atmosphere can be performed. The heat treatment can be performed at a substrate temperature higher than or equal to 50 °C and lower than or equal to 200 °C, preferably higher than or equal to 60 °C and lower than or equal to 150°C., further preferably higher than or equal to 70 °C and lower than or equal to 120 °C The heat treatment is preferably performed in a reduced-pressure atmosphere, in which case drying at a lower temperature is possible.

Next, as illustrated in FIG. 13B, the inorganic insulating film 125f to be the inorganic insulating layer 125 is formed to cover the organic compound layers 103R, 103G, and 103B and the sacrificial layers 158R, 158G, and 158B.

As described later, an insulating film to be the insulating layer 127 is formed in contact with the top surface of the inorganic insulating film 125f. Therefore, the top surface of the inorganic insulating film 125f preferably has a high affinity for the material used for the insulating film (e.g., a photosensitive resin composition including an acrylic resin). To improve the affinity, surface treatment is preferably performed so that the top surface of the inorganic insulating film 125f is made hydrophobic or its hydrophobic properties are improved. For example, it is preferable to perform the treatment using a silylation agent such as hexamethyldisilazane (INMDS). By making the top surface of the inorganic insulating film 125f hydrophobic in such a manner, an insulating film 127f can be formed with favorable adhesion. Note that the above-described hydrophobization treatment may be performed as the surface treatment.

Then, as illustrated in FIG. 13C, the insulating film 127f to be the insulating layer 127 is formed over the inorganic insulating film 125f.

The inorganic insulating film 125f and the insulating film 127f are preferably formed by a formation method that causes less damage to the organic compound layers 103R, 103G, and 103B. The inorganic insulating film 125f, which is formed in contact with the side surfaces of the organic compound layers 103R, 103G, and 103B, is particularly preferably formed by a formation method that causes less damage to the organic compound layers 103R, 103G, and 103B than the formation method of the insulating film 127f.

Each of the inorganic insulating film 125f and the insulating film 127f is formed at a temperature lower than the upper temperature limits of the organic compound layers 103R, 103G, and 103B. When the inorganic insulating film 125f is formed at a high substrate temperature, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60 °C, higher than or equal to 80 °C, higher than or equal to 100 °C, or higher than or equal to 120 °C and lower than or equal to 200°C., lower than or equal to 180 °C, lower than or equal to 160 °C, lower than or equal to 150 °C, or lower than or equal to 140 °C

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage caused by deposition is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable display apparatus can be manufactured with high productivity.

The insulating film 127f is preferably formed by the aforementioned wet process. The insulating film 127f is preferably formed by spin coating using a photosensitive material, for example, and preferably formed using specifically a photosensitive resin composition including an acrylic resin.

The insulating film 127f is preferably formed using a resin composition including a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limits of the organic compound layers 103R, 103G, and 103B. The substrate temperature in the heat treatment is preferably higher than or equal to 50 °C and lower than or equal to 200 °C, further preferably higher than or equal to 60 °C and lower than or equal to 150°C., still further preferably higher than or equal to 70 °C and lower than or equal to 120 °C Accordingly, the solvent included in the insulating film 127f can be removed.

Then, part of the insulating film 127f is exposed to visible light or ultraviolet rays. Here, when a positive photosensitive resin composition including an acrylic resin is used for the insulating film 127f, a region where the insulating layer 127 is not formed in a later step is irradiated with visible light or ultraviolet rays. The insulating layer 127 is formed in regions that are sandwiched between any two of the conductive layers 152R, 152G, and 152B and around the conductive layer 152C. Thus, the top surfaces of the conductive layers 152R, 152G, 152B, and 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 that is to be formed later can be controlled in accordance with the exposed region of the insulating film 127f. In this embodiment, processing is performed such that the insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

Here, when a barrier insulating layer against oxygen (e.g., an aluminum oxide film) is provided as one or both of the sacrificial layer 158 (the sacrificial layers 158R, 158G, and 158B) and the inorganic insulating film 125f, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere including oxygen, oxygen might be bonded to the organic compound included in the organic compound layer. By providing the sacrificial layer 158 and the inorganic insulating film 125f over the island-shaped organic compound layer, bonding of oxygen in the atmosphere to the organic compound included in the organic compound layer can be inhibited.

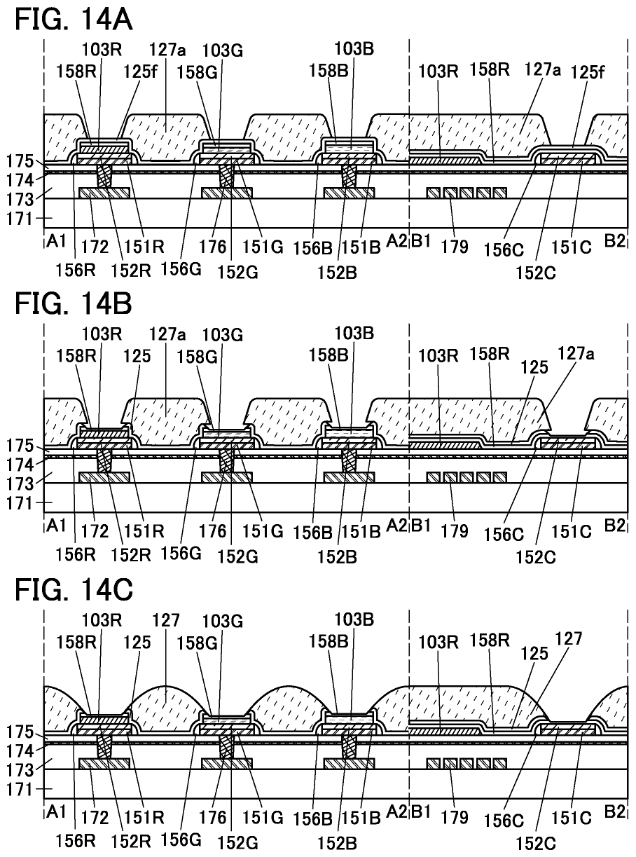

Next, as illustrated in FIG. 14A, development is performed to remove the exposed region of the insulating film 127f, so that an insulating layer 127a is formed. The insulating layer 127a is formed in regions that are sandwiched between any two of the conductive layers 152R, 152G, and 152B and a region surrounding the conductive layer 152C. Here, when an acrylic resin is used for the insulating film 127f, an alkaline solution, such as TMAH, can be used as a developer.

Then, a residue (scum) due to the development may be removed. For example, the residue can be removed by ashing using oxygen plasma.

Etching may be performed to adjust the surface level of the insulating layer 127a. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 14B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed collectively.

By etching using the insulating layer 127a with a tapered side surface as a mask, the side surface of the inorganic insulating layer 125 and upper end portions of the side surfaces of the sacrificial layers 158R, 158G, and 158B can be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, the capacitively coupled plasma etching apparatus may have a structure where different high-frequency voltages are applied to one of the parallel-plate electrodes. Alternatively, the capacitively coupled plasma etching apparatus may have a structure where high-frequency voltages with the same frequency are applied to the parallel-plate electrodes. Alternatively, the capacitively coupled plasma etching apparatus may have a structure where high-frequency voltages with different frequencies are applied to the parallel-plate electrodes.

In the case of performing dry etching, a by-product or the like generated by the dry etching might be deposited on the top surface and the side surface of the insulating layer 127a, for example. Accordingly, a component of the etching gas, a component of the inorganic insulating film 125f, a component of the sacrificial layers 158R, 158G, and 158B, and the like might be included in the insulating layer 127 in the completed display apparatus.

The first etching treatment is preferably performed by wet etching. The use of a wet etching method can reduce damage to the organic compound layers 103R, 103G, and 103B, as compared to the case of using a dry etching method. For example, the wet etching can be performed using an alkaline solution. For instance, TMAH, which is an alkaline solution, can be used for the wet etching of an aluminum oxide film. In this case, puddle wet etching can be performed. Note that the inorganic insulating film 125f is preferably formed using a material similar to that of the sacrificial layers 158R, 158G, and 158B, in which case the above etching treatment can be performed collectively.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, the insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Here, when a barrier insulating layer against oxygen (e.g., an aluminum oxide film) is present as each of the sacrificial layers 158R, 158G, and 158B, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere including oxygen, oxygen might be bonded to the organic compound included in the organic compound layer. By providing the sacrificial layers 158R, 158G, and 158B over the island-shaped organic compound layers, bonding of oxygen in the atmosphere to the organic compounds included in the organic compound layers can be inhibited.

Then, heat treatment (also referred to as post-baking) is performed. The heat treatment can change the insulating layer 127a into the insulating layer 127 having a tapered side surface (FIG. 14C). The heat treatment is performed at a temperature lower than the upper temperature limits of the organic compound layers. The heat treatment can be performed at a substrate temperature higher than or equal to 50 °C and lower than or equal to 200 °C, preferably higher than or equal to 60 °C and lower than or equal to 150 °C, further preferably higher than or equal to 70 °C and lower than or equal to 130 °C The heating atmosphere may be an air atmosphere or an inert gas atmosphere. Moreover, the heating atmosphere may be an atmospheric-pressure atmosphere or a reduced-pressure atmosphere. The substrate temperature in the heat treatment of this step is preferably higher than that in the heat treatment (prebaking) after the formation of the insulating film 127f. In that case, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

Note that the side surface of the insulating layer 127 may have a concave shape depending on the material of the insulating layer 127 and the temperature, time, and atmosphere of the post-baking. For example, when the temperature of the post-baking is higher or the duration of the post-baking is longer, the insulating layer 127 is more likely to change in shape and thus the concave shape may be more likely to be formed.

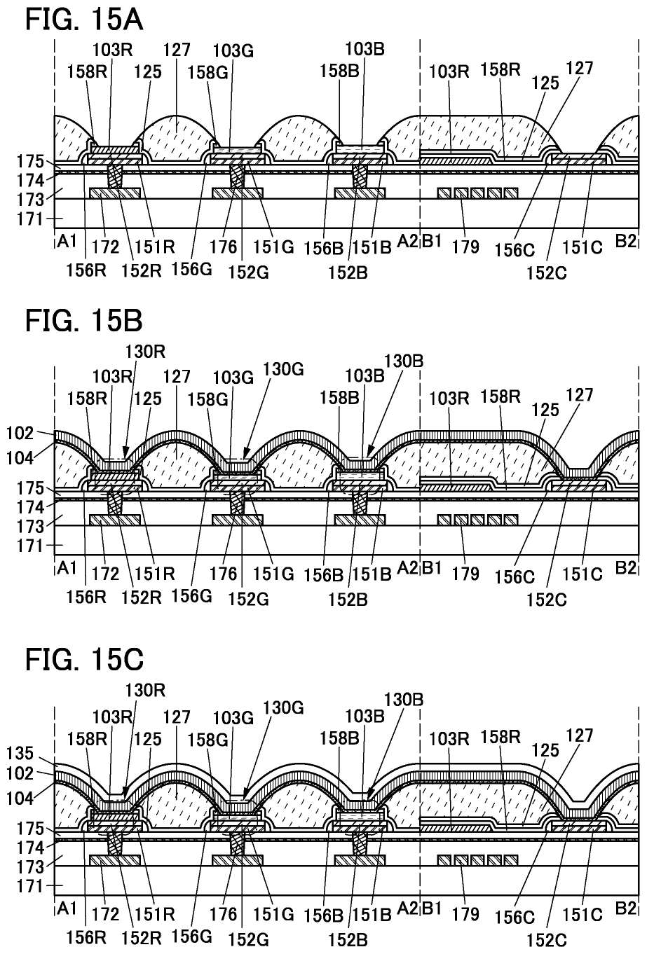

Next, as illustrated in FIG. 15A, etching treatment is performed using the insulating layer 127 as a mask to partly remove the sacrificial layers 158R, 158G, and 158B. Note that part of the inorganic insulating layer 125 is also removed in some cases. Thus, openings are formed in the sacrificial layers 158R, 158G, and 158B, and the top surfaces of the organic compound layers 103R, 103G, and 103B and the conductive layer 152C are exposed. Note that the etching treatment using the insulating layer 127 as a mask may be hereinafter referred to as second etching treatment.

An end portion of the inorganic insulating layer 125 is covered with the insulating layer 127. FIG. 15A illustrates an example where part of an end portion of the sacrificial layer 158G (specifically a tapered portion formed by the first etching treatment) is covered with the insulating layer 127 and a tapered portion formed by the second etching treatment is exposed.

If the first etching treatment is not performed and the inorganic insulating layer 125 and the mask layer are collectively etched after the post-baking, the inorganic insulating layer 125 and the mask layer under an end portion of the insulating layer 127 may disappear because of side etching and a void may be formed. The void causes unevenness on the formation surface of the second electrode 102, so that step disconnection is more likely to be caused in the second electrode 102. Even when avoid is formed owing to side etching of the inorganic insulating layer 125 and the mask layer by the first etching treatment, the post-baking performed subsequently can make the insulating layer 127 fill the void. After that, the thinned mask layer is etched by the second etching treatment; thus, the amount of side etching decreases, a void is less likely to be formed, and even if a void is formed, it can be extremely small. Consequently, the formation surface of the second electrode 102 can be made flatter.

Note that the insulating layer 127 may cover the entire end portion of the sacrificial layer 158G. For example, the end portion of the insulating layer 127 may droop to cover the end portion of the sacrificial layer 158G. For another example, the end portion of the insulating layer 127 may be in contact with the top surface of at least one of the organic compound layers 103R, 103G, and 103B. As described above, when light exposure is not performed on the insulating layer 127a after the development, the shape of the insulating layer 127 may be likely to change.

The second etching treatment is performed by wet etching. The use of a wet etching method can reduce damage to the organic compound layers 103R, 103G, and 103B, as compared to the case of using a dry etching method. The wet etching can be performed using an alkaline solution such as TMAH, for example.

Meanwhile, in the case where the second etching treatment is performed by a wet etching method and gaps due to, for example, poor adhesion between the organic compound layer 103 and another layer exist at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layers 151 and 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. As a result, the yield of the display apparatus decreases in some cases. Moreover, the reliability of the display apparatus decreases in some cases.

When the insulating layer 156 is formed to have a region overlapping with the side surface of the conductive layer 151 and the insulating layer 156 is formed to cover the conductive layers 151 and 152 as described above, step disconnection in the inorganic insulating layer 125 can be prevented, whereby the chemical solution can be prevented from coming into contact with a lower-layer structure such as the conductive layer 151 in the second etching treatment, for example. Thus, corrosion of the pixel electrode can be prevented.

As described above, by providing the insulating layer 127, the inorganic insulating layer 125, and the sacrificial layers 158R, 158G, and 158B, poor connection due to a disconnected portion and an increase in electrical resistance due to a locally thinned portion can be inhibited from occurring in the second electrode 102 between the light-emitting devices. Thus, the display apparatus of one embodiment of the present invention can have improved display quality.

Heat treatment is performed after the organic compound layers 103R, 103G, and 103B are partly exposed. By the heat treatment, water included in the organic compound layers and water adsorbed onto the surfaces of the organic compound layers, for example, can be removed. The shape of the insulating layer 127 may be changed by the heat treatment. Specifically, the insulating layer 127 may be widened to cover at least one of the end portion of the inorganic insulating layer 125, the end portions of the sacrificial layers 158R, 158G, and 158B, and the top surfaces of the organic compound layers 103R, 103G, and 103B.

If the temperature of the heat treatment is too low, water included in the organic compound layers and water adsorbed onto the surfaces of the organic compound layers, for example, cannot be sufficiently removed. If the temperature of the heat treatment is too high, the organic compound layer 103 might deteriorate and the insulating layer 127 might change in shape excessively. Therefore, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the upper surface of the organic compound layer 103. Specifically, the substrate temperature is preferably higher than or equal to 80 °C and lower than or equal to 130 °C, further preferably higher than or equal to 90 °C and lower than or equal to 120 °C, still further preferably higher than or equal to 100 °C and lower than or equal to 120 °C, yet still further preferably higher than or equal to 100 °C and lower than or equal to 110 °C The heating atmosphere may be an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water included in the organic compound layers and water adsorbed onto the surfaces of the organic compound layers, for example, can be sufficiently removed without deterioration of the organic compound layers 103R, 103G, and 103B and an excessive change in the shape of the insulating layer 127. Thus, degradation of the characteristics of the light-emitting devices can be prevented.

Next, as illustrated in FIG. 15B, the common layer 104 and the second electrode 102 are formed over the organic compound layers 103R, 103G, and 103B, the conductive layer 152C, and the insulating layer 127. The common layer 104 and the second electrode 102 can be formed by a sputtering method, a vacuum evaporation method, or the like. The common layer 104 may be formed by an evaporation method while the second electrode 102 may be formed by a sputtering method.

Next, as illustrated in FIG. 15C, the protective layer 135 is formed over the second electrode 102. The protective layer 135 can be formed by a vacuum evaporation method, a sputtering method, a CVD method, an ALD method, or the like. Note that the protective layer 135 may also function as a cap layer. For example, when a material with an ordinary refractive index (no) of greater than or equal to 1.90 at a wavelength of 450 nm, an ordinary refractive index (no) of greater than or equal to 1.80 at a wavelength of 520 nm, or an ordinary refractive index (no) of greater than or equal to 1.75 at a wavelength of 630 nm is used, the total reflection of light from the organic compound layer 103 by the cap layer can be inhibited, leading to an improvement in light extraction efficiency.

In order to prevent exposure to the air of the light-emitting device before being incorporated in the display apparatus or the light-emitting apparatus, a sealing film may be provided over the protective layer 135. The sealing film can be formed using a material that does not easily transmit an impurity such as oxygen or water. Specifically, an aluminum oxide film is preferably provided by an ALD method. Note that in order to prevent exposure of the light-emitting device to the air after the formation of the protective layer 135 but before the provision of the sealing film, the light-emitting device is preferably transferred into an ALD apparatus in a glove box including a nitrogen atmosphere after the protective layer 135 is formed. In that case, the oxygen concentration in the glove box is preferably lower than or equal to 100 ppm, further preferably lower than or equal to 10 ppm, still further preferably lower than or equal to 1 ppm.

Then, the substrate 120 is bonded to the protective layer 135 or the sealing film using the resin layer 122, so that the display apparatus can be manufactured. In the method for manufacturing the display apparatus of one embodiment of the present invention, the insulating layer 156 is provided on the side surfaces of the conductive layer 151 and the conductive layer 152 as described above. This can increase the yield of the display apparatus and inhibit generation of defects. Note that before the bonding of the substrate 120, a microlens array is provided over the protective layer 135 or the sealing film and then the substrate 120 is bonded, whereby a display apparatus including the microlens array can be manufactured.

As described above, in the method for manufacturing the display apparatus in one embodiment of the present invention, the island-shaped organic compound layers 103R, 103G, and 103B are formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display apparatus with extremely high contrast can be provided. Moreover, even a display apparatus that includes tandem light-emitting devices formed by a lithography method can have favorable characteristics.

The structure described in this embodiment can be used in combination with any of the structures described in other embodiments as appropriate.

### Embodiment 4

In this embodiment, a light-emitting apparatus of one embodiment of the present invention will be described.

The light-emitting apparatus in this embodiment can be a high-resolution light-emitting apparatus. Thus, the light-emitting apparatus in this embodiment can be used for display portions of information terminals (wearable devices) such as watch-type and bracelet-type information terminals and display portions of wearable devices capable of being worn on a head, such as a virtual reality (VR) device like a head mounted display (HMD) and a glasses-type augmented reality (AR) device.

The light-emitting apparatus in this embodiment can be a high-definition light-emitting apparatus or a large-sized light-emitting apparatus. Accordingly, the light-emitting apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

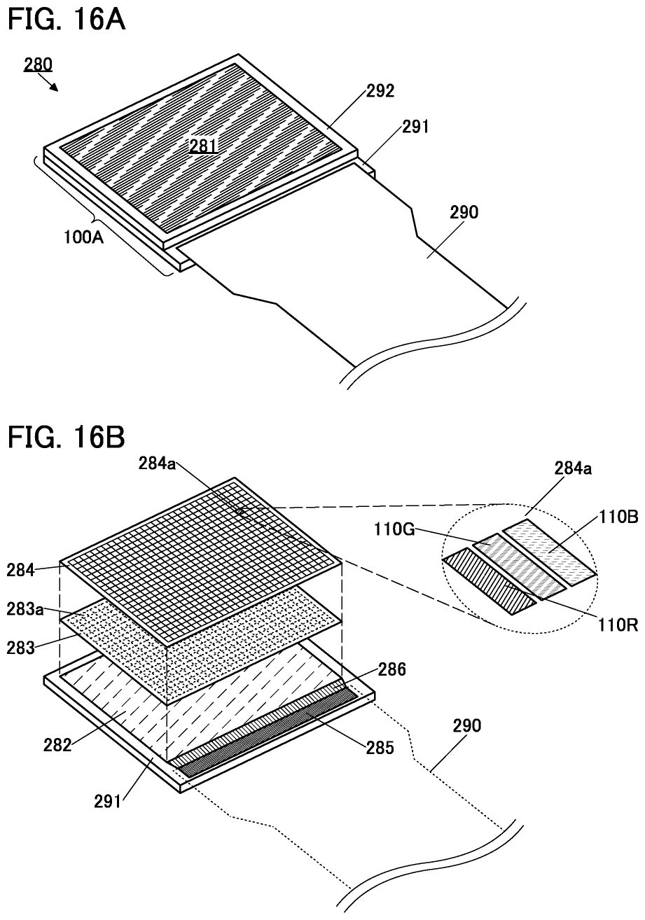

FIG. 16A is a perspective view of a display module 280. The display module 280 includes a display apparatus 100A and an FPC 290. Note that the light-emitting apparatus included in the display module 280 is not limited to the display apparatus 100A and may be a display apparatus 100B described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 16B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 16B. The pixels 284a can employ any of the structures described in the above embodiments. FIG. 16B illustrates an example where the pixel 284a has a structure similar to that of the pixel 178 illustrated in FIGS. 9A and 9B.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor per light-emitting device. A gate signal is input to a gate of the selection transistor, and a video signal is input to a source or a drain of the selection transistor. With such a structure, an active-matrix light-emitting apparatus is obtained.

The circuit portion 282 includes a circuit for driving the pixel circuits 283a in the pixel circuit portion 283. For example, the circuit portion 282 preferably includes one or both ofa gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high resolution. For example, the pixels 284a are preferably arranged in the display portion 281 with a resolution higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion. For example, the display module 280 can be favorably used in a display portion of a wearable electronic appliance, such as a wrist watch.

### [Display Apparatus 100A]

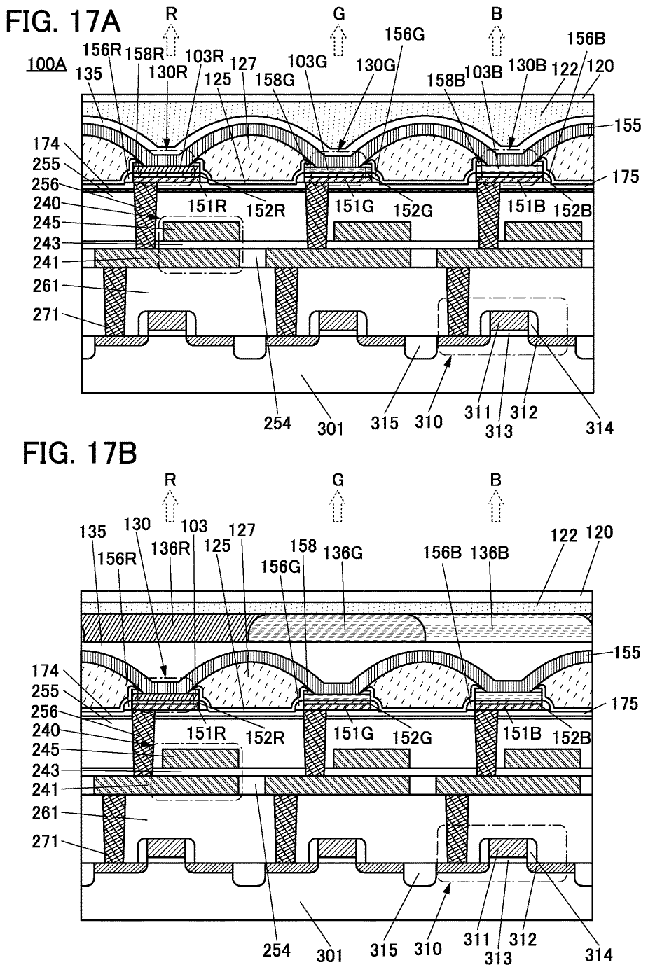

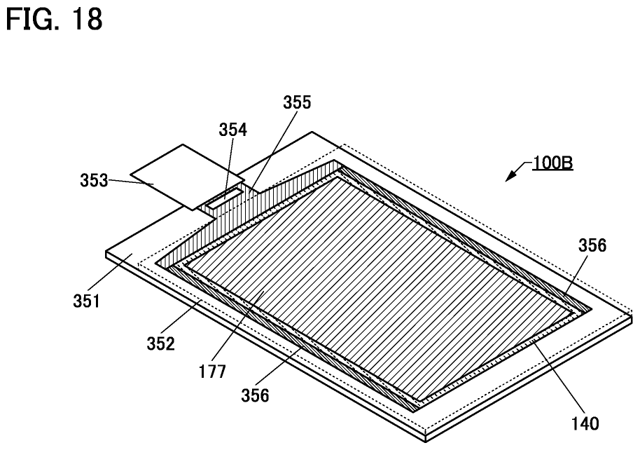

The display apparatus 100A illustrated in FIG. 17A includes a substrate 301, the light-emitting devices 130R, 130G, and 130B, a capacitor 240, and a transistor 310.

The substrate 301 corresponds to the substrate 291 in FIGS. 16A and 16B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. FIG. 17A illustrates an example in which the light-emitting devices 130R, 130G, and 130B each have the stacked-layer structure illustrated in FIG. 1A. An insulator is provided in regions between adjacent light-emitting devices. For example, in FIG. 17A, the inorganic insulating layer 125 and the insulating layer 127 over the inorganic insulating layer 125 are provided in those regions.

The insulating layer 156R is provided to include a region overlapping with the side surface of the conductive layer 151R of the light-emitting device 130R. The insulating layer 156G is provided to include a region overlapping with the side surface of the conductive layer 151G of the light-emitting device 130G. The insulating layer 156B is provided to include a region overlapping with the side surface of the conductive layer 151B of the light-emitting device 130B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R of the light-emitting device 130R. The sacrificial layer 158G is positioned over the organic compound layer 103G of the light-emitting device 130G. The sacrificial layer 158B is positioned over the organic compound layer 103B of the light-emitting device 130B.

The conductive layers 151R, 151G, and 151B is electrically connected to the sources or the drains of the corresponding transistors 310 through plugs 256 embedded in the insulating layers 243, 255, 174, and 175, the conductive layers 241 embedded in the insulating layer 254, and the plugs 271 embedded in the insulating layer 261. The top surface of the insulating layer 175 and the top surface of the plug 256 are level with or substantially level with each other. Any of a variety of conductive materials can be used for the plugs.

The protective layer 135 is provided over the light-emitting devices 130R, 130G, and 130B. The substrate 120 is bonded to the protective layer 135 with the resin layer 122. Embodiment 3 can be referred to for the details of the light-emitting device 130 and the components thereover up to the substrate 120. The substrate 120 corresponds to the substrate 292 in FIG. 16A.

FIG. 17B illustrates a modification example of the display apparatus 100A illustrated in FIG. 17A. The light-emitting apparatus illustrated in FIG. 17B includes the coloring layers 136R, 136G, and 136B, and each of the light-emitting devices 130 includes a region overlapping with one of the coloring layers 136R, 136G, and 136B. In the light-emitting apparatus illustrated in FIG. 17B, the light-emitting device 130 can emit white light, for example. For example, the coloring layer 136R, the coloring layer 136G, and the coloring layer 136B can transmit red light, green light, and blue light, respectively.

### [Display Apparatus 100B]

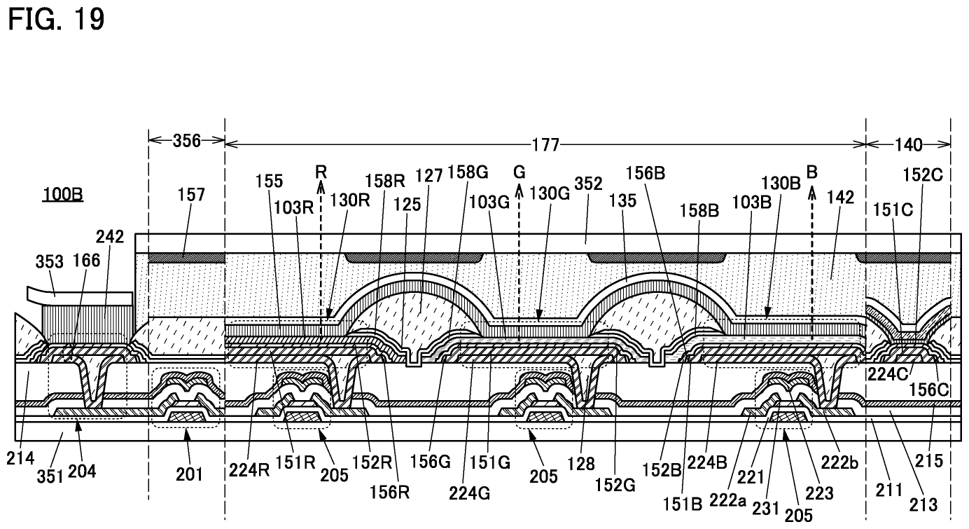

FIG. 18 is a perspective view of the display apparatus 100B, and FIG. 19 is a cross-sectional view of the display apparatus 100B.

In the display apparatus 100B, a substrate 352 and a substrate 351 are bonded to each other. In FIG. 18, the substrate 352 is denoted by a dashed line.

The display apparatus 100B includes the pixel portion 177, the connection portion 140, a circuit 356, a wiring 355, and the like. FIG. 18 illustrates an example in which an integrated circuit (IC) 354 and an FPC 353 are mounted on the display apparatus 100B. Thus, the structure illustrated in FIG. 18 can be regarded as a display module including the display apparatus 100B, the IC, and the FPC. Here, a light-emitting apparatus in which a substrate is equipped with a connector such as an FPC or mounted with an IC is referred to as a display module.

The connection portion 140 is provided outside the pixel portion 177. The connection portion 140 can be provided along one side or a plurality of sides of the pixel portion 177. The number of connection portions 140 may be one or more. FIG. 18 illustrates an example in which the connection portion 140 is provided to surround the four sides of the pixel portion 177. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 18 illustrates an example in which the IC 354 is provided for the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 19 illustrates an example of cross sections of part of a region including the FPC 353, part of the circuit 356, part of the pixel portion 177, part of the connection portion 140, and part of a region including an edge portion of the display apparatus 100B.

The display apparatus 100B illustrated in FIG. 19 includes a transistor 201, a transistor 205, the light-emitting device 130R that emits red light, the light-emitting device 130G that emits green light, the light-emitting device 130B that emits blue light, and the like between the substrate 351 and the substrate 352.

The stacked-layer structure of each of the light-emitting devices 130R, 130G, and 130B is the same as that illustrated in FIG. 1A except for the structure of the pixel electrode. The above embodiments can be referred to for the details of the light-emitting devices.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B. Here, the conductive layers 224R, 151R, and 152R can be collectively referred to as the pixel electrode of the light-emitting device 130R; the conductive layers 151R and 152R excluding the conductive layer 224R can also be referred to as the pixel electrode of the light-emitting device 130R. Similarly, the conductive layers 224G, 151G, and 152G can be collectively referred to as the pixel electrode of the light-emitting device 130G; the conductive layers 151G and 152G excluding the conductive layer 224G can also be referred to as the pixel electrode of the light-emitting device 130G. The conductive layers 224B, 151B, and 152B can be collectively referred to as the pixel electrode of the light-emitting device 130n; the conductive layers 151B and 152B excluding the conductive layer 224B can also be referred to as the pixel electrode of the light-emitting device 130B.

The conductive layer 224R is connected to a conductive layer 222b included in the transistor 205 through the opening provided in an insulating layer 214. The edge portion of the conductive layer 151R is positioned outward from an edge portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151i, and 152B and the insulating layer 156B in the light-emitting device 130B.

The conductive layers 224R, 224G, and 224B each have a depression portion covering an opening provided in the insulating layer 214. A layer 128 is embedded in the depression portion.

The layer 128 has a function of filling the depression portions of the conductive layers 224R, 224G, and 224B to enable planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 135 is provided over the light-emitting devices 130R, 130G, and 130B. The protective layer 135 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 19, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided in a frame shape not to overlap with the light-emitting device. Furthermore, the space may be filled with a resin other than the frame-shaped adhesive layer 142.

FIG. 19 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 19, the insulating layer 156C is provided to include a region overlapping with the side surface of the conductive layer 151C.

The display apparatus 100B has a top-emission structure. Light from the light-emitting device is emitted toward the substrate 352. For the substrate 352, a material having a high visible-light-transmitting property is preferably used. The pixel electrode includes a material that reflects visible light, and the counter electrode (the common electrode 155) includes a material that transmits visible light.

The transistor 201 and the transistor 205 are formed over the substrate 351. These transistors can be manufactured using the same materials in the same steps.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively reduce diffusion of impurities to the transistors from the outside and increase the reliability of the light-emitting apparatus.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

An organic insulating layer is suitable for the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. This can inhibit formation of a recessed portion in the insulating layer 214 at the time of processing of the conductive layer 224R, 151R, or 152R or the like. Alternatively, a recessed portion may be provided in the insulating layer 214 at the time of processing of the conductive layer 224R, 151R, or 152R or the like.

Each of the transistors 201 and 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are illustrated with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the light-emitting apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of transistor characteristics can be suppressed.

The semiconductor layer of the transistor preferably includes a metal oxide. That is, a transistor including a metal oxide in its channel formation region (hereinafter, also referred to as an OS transistor) is preferably used in the light-emitting apparatus of this embodiment.

Examples of an oxide semiconductor having crystallinity include a c-axis-aligned crystalline oxide semiconductor (CAAC-OS) and a nanocrystalline oxide semiconductor (nc-OS).

Alternatively, a transistor including silicon in its channel formation region (a Si transistor) may be used. Examples of silicon include single crystal silicon, polycrystalline silicon, and amorphous silicon. In particular, a transistor including low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows for simplification of an external circuit mounted on the light-emitting apparatus and a reduction in costs of parts and mounting costs.

An OS transistor has much higher field-effect mobility than a transistor including amorphous silicon. In addition, the OS transistor has an extremely low leakage current between a source and a drain in an off state (hereinafter also referred to as an off-state current), and electric charge accumulated in a capacitor that is connected in series to the transistor can be held for a long period. Furthermore, the light-emitting apparatus can consume less power by including the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, a high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, by using OS transistors as the driving transistors included in the pixel circuits, it is possible to suppress black-level degradation, increase the luminance, increase the number of gray levels, and suppress variations in light-emitting devices, for example.

The semiconductor layer preferably includes indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide including indium (In), gallium (Ga), and zinc (Zn) (also referred to as IGZO) be used for the semiconductor layer. It is preferable to use an oxide including indium, tin, and zinc. It is preferable to use an oxide including indium, gallium, tin, and zinc. It is preferable to use an oxide including indium (In), aluminum (Al), and zinc (Zn) (also referred to as IAZO). It is preferable to use an oxide including indium (In), aluminum (Al), gallium (Ga), and zinc (Zn) (also referred to as IAGZO).

When the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide are In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and a composition in the neighborhood of any of the above atomic ratios. Note that the neighborhood of the atomic ratio includes ±30% of an intended atomic ratio.

For example, in the case of describing an atomic ratio of In:Ga:Zn=4:2:3 or a composition in the neighborhood thereof, the case is included in which with the atomic proportion of In being 4, the atomic proportion of Ga is greater than or equal to 1 and less than or equal to 3 and the atomic proportion of Zn is greater than or equal to 2 and less than or equal to 4. In the case of describing an atomic ratio of In:Ga:Zn=5:1:6 or a composition in the neighborhood thereof, the case is included in which with the atomic proportion of In being 5, the atomic proportion of Ga is greater than 0.1 and less than or equal to 2 and the atomic proportion of Zn is greater than or equal to 5 and less than or equal to 7. In the case of describing an atomic ratio of In:Ga:Zn=1:1:1 or a composition in the neighborhood thereof, the case is included in which with the atomic proportion of In being 1, the atomic proportion of Ga is greater than 0.1 and less than or equal to 2 and the atomic proportion of Zn is greater than 0.1 and less than or equal to 2.

The transistors included in the circuit 356 and the transistors included in the pixel portion 177 may have the same structure or different structures. One structure or two or more kinds of structures may be employed for a plurality of transistors included in the circuit 356. Similarly, one structure or two or more kinds of structures may be employed for a plurality of transistors included in the pixel portion 177.

All transistors included in the pixel portion 177 may be OS transistors, or all transistors included in the pixel portion 177 may be Si transistors. Alternatively, some of the transistors included in the pixel portion 177 may be OS transistors and the others may be Si transistors.

For example, when both an LTPS transistor and an OS transistor are used in the pixel portion 177, the light-emitting apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling a current.

For example, one transistor included in the pixel portion 177 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the pixel portion 177 functions as a switch for controlling selection or non-selection of a pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the light-emitting apparatus of one embodiment of the present invention can have all of a high aperture ratio, high resolution, high display quality, and low power consumption.

Note that the light-emitting apparatus of one embodiment of the present invention has a structure including the OS transistor and the light-emitting device having a metal maskless (MML) structure. This structure can significantly reduce a leakage current that would flow through a transistor and a leakage current that would flow between adjacent light-emitting devices (sometimes referred to as a horizontal leakage current or a lateral leakage current). Displaying images on the light-emitting apparatus having this structure can bring one or more of image crispness, image sharpness, high color saturation, and a high contrast ratio to the viewer. When a leakage current that would flow through the transistor and a lateral leakage current that would flow between the light-emitting devices are extremely low, leakage of light at the time of black display (black-level degradation) or the like can be minimized.

In particular, in the case where a light-emitting device having an MML structure employs a side-by-side (SBS) structure, which is the above-described structure for separately forming or coloring light-emitting layers, a layer provided between light-emitting devices (for example, also referred to as an organic layer or a common layer which is shared by the light-emitting devices) is disconnected; accordingly, side leakage can be prevented or be made extremely low.

A connection portion 204 is provided in a region that is of the substrate 351 and does not overlap with the substrate 352. In the connection portion 204, the wiring 355 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

This embodiment can be combined as appropriate with any of the other embodiments or examples. In this specification, in the case where a plurality of structure examples are shown in one embodiment, the structure examples can be combined as appropriate.

### Embodiment 5

In this embodiment, an electronic appliance of one embodiment of the present invention will be described.

The electronic appliance of this embodiment includes the light-emitting apparatus of one embodiment of the present invention in its display portions. The light-emitting apparatus of one embodiment of the present invention is highly reliable and can be easily increased in resolution and definition. Thus, the light-emitting apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the light-emitting apparatus of one embodiment of the present invention can have high resolution, and thus can be suitably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The definition of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, 4K, 8K, or higher definition is preferable. The pixel density (resolution) of the light-emitting apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With such a light-emitting apparatus having one or both of high definition and high resolution, the electronic appliance can provide higher realistic sensation, sense of depth, and the like in personal use such as portable use or home use. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

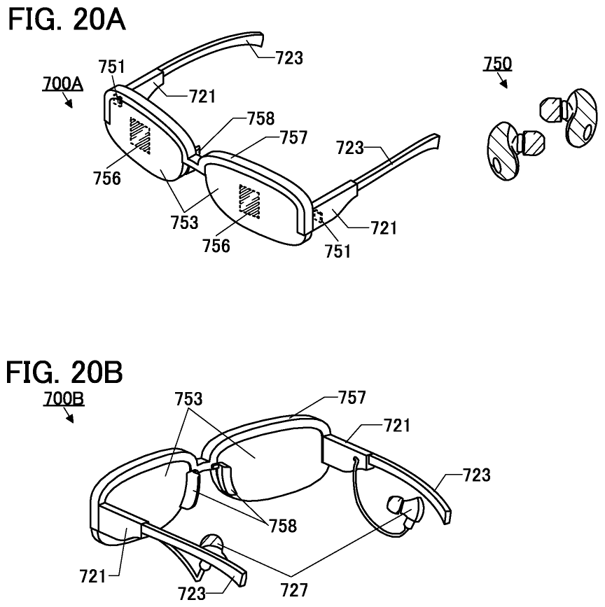

Examples of head-mounted wearable devices are described with reference to FIGS. 20A and 20B. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 20A and an electronic appliance 700B illustrated in FIG. 20B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The light-emitting apparatus of one embodiment of the present invention can be used for the display panels 751. Thus, a highly reliable electronic appliance can be obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Various types of processing can be executed by detecting a tap operation, a slide operation, or the like by the user with the touch sensor module. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

The electronic appliance of one embodiment of the present invention may have a function of performing wireless communication with earphones 750. The earphones 750 include a communication portion (not shown) and have a wireless communication function. The earphones 750 can receive information (e.g., audio data) from the electronic appliance with the wireless communication function. For example, the electronic appliance 700A in FIG. 20A has a function of transmitting information to the earphones 750 with the wireless communication function.

The electronic appliance may include an earphone portion. The electronic appliance 700B in FIG. 20B includes earphone portions 727. For example, the earphone portion 727 can be connected to the control portion by a wiring. Part of the wiring that connects the earphone portion 727 and the control portion may be positioned inside the housing 721 or the wearing portion 723.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

Note that the electronic appliance of one embodiment of the present invention is not limited to being of a glasses-type (e.g., the electronic appliance 700A and the electronic appliance 700B) and can also suitably employ a goggles-type.

The electronic appliance of one embodiment of the present invention can transmit information to earphones by wire or wirelessly.

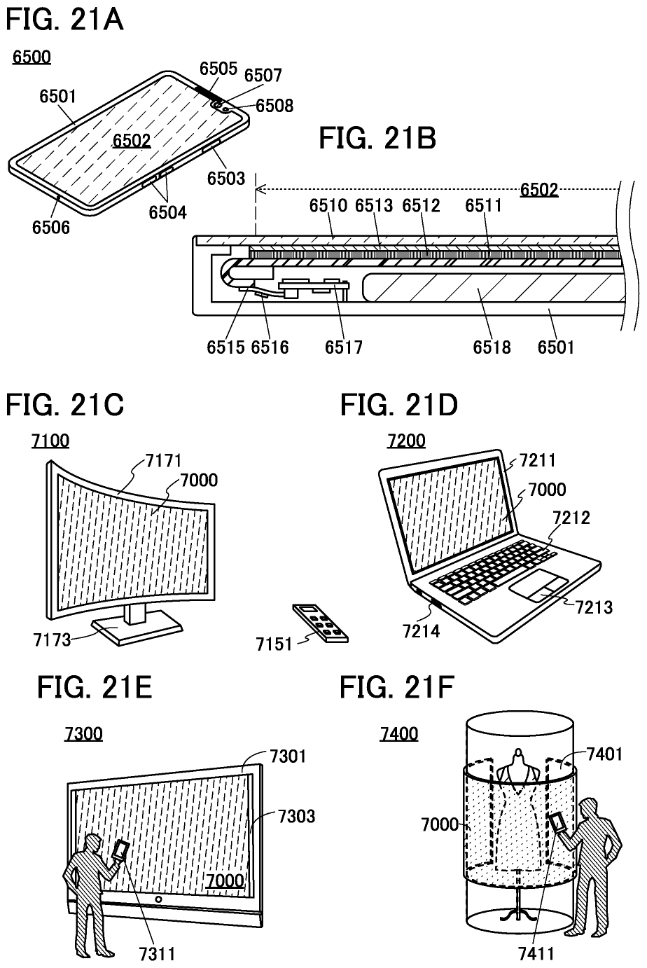

An electronic appliance 6500 illustrated in FIG. 21A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The light-emitting apparatus of one embodiment of the present invention can be used in the display portion 6502. Thus, a highly reliable electronic appliance can be obtained.

FIG. 21B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The light-emitting apparatus of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be provided when part of the display panel 6511 is folded back and the portion connected to the FPC 6515 is provided on the back side of a pixel portion.

FIG. 21C illustrates an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic appliance is obtained.

Operation of the television device 7100 illustrated in FIG. 21C can be performed with an operation switch provided in the housing 7171 and a separate remote controller 7151. Alternatively, the display portion 7000 may include a touch sensor, and the television device 7100 may be operated by touch on the display portion 7000 with a finger or the like. The remote controller 7151 may be provided with a display portion for displaying information output from the remote controller 7151. With operation keys or a touch panel of the remote controller 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 21D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used in the display portion 7000. Thus, a highly reliable electronic appliance can be obtained.

FIGS. 21E and 21F illustrate examples of digital signage that can be used for a store window, a showcase, or the like.

Digital signage 7300 illustrated in FIG. 21E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 21F illustrates digital signage 7400 attached to a cylindrical pillar 7401. The digital signage 7400 includes the display portion 7000 provided along a curved surface of the pillar 7401.

In FIGS. 21E and 21F, the light-emitting apparatus of one embodiment of the present invention can be used in the display portion 7000. Thus, a highly reliable electronic appliance can be obtained.

A larger area of the display portion 7000 can increase the amount of information that can be provided at a time. The display portion 7000 having a larger area attracts more attentions, so that the effectiveness of the advertisement can be increased, for example.

Specifically, in the case where the display apparatus of one embodiment of the present invention is used for the digital signage 7400 illustrated in FIG. 21F that displays advertisements and the like, the display apparatus being a light-transmitting panel can increase the flexibility of representation. The display apparatus having a light-transmitting property can be manufactured, for example, by using a wiring and a support member that include a conductive film transmitting visible light and adjusting the distance between pixel electrodes.

The use of the tandem light-emitting device of one embodiment of the present invention in addition to the wiring and the support member each of which is formed of the conductive film that transmits visible light can increase the luminance per pixel. That is, favorable display can be performed even when the display apparatus has a low aperture ratio, so that the light-transmitting property of the display portion of the display apparatus can be increased. Thus, such a structure is suitably used in the light-transmitting display apparatus of one embodiment of the present invention.

As illustrated in FIGS. 21E and 21F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

This embodiment can be combined as appropriate with any of the other embodiments or examples. In this specification, in the case where a plurality of structure examples are shown in one embodiment, the structure examples can be combined as appropriate.

### Example 1

In this example, description is made on results of several analyses on 4,7-di(2,3,3a,4,5,6,7,7a-octahydro-1H-isoindol-2-yl)-1,10-phenanthroline (abbreviation: Hid2Phen), 2,2′-([2,2′-bipyridine]-6,6′-diyl)bis(4-phenylbenzo[h]quinazoline) (abbreviation: 6,6′(P-Bqn)2BPy), and 2,2′-(1,3-phenylene)bis(9-phenyl-1,10-phenanthroline) (abbreviation: mPPhen2P), which are organic compounds that can be used for the layer 200 of the light-emitting device of one embodiment of the present invention. The following are structural formulae of the organic compounds used in this example.

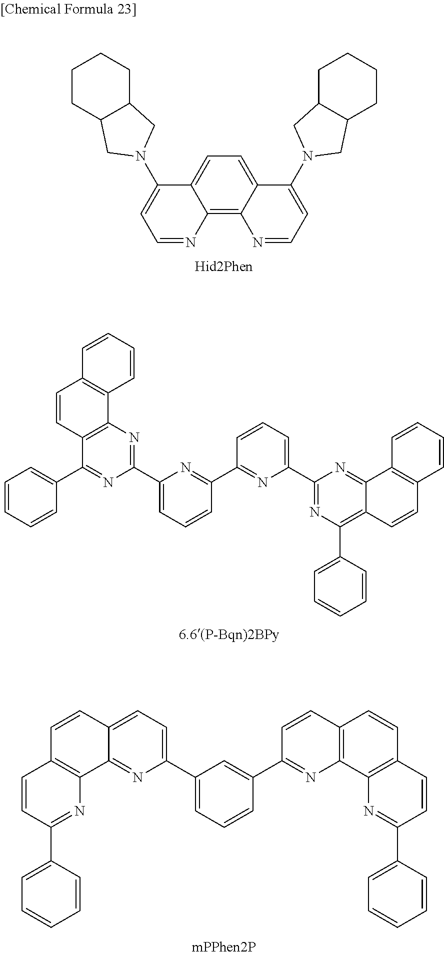 [SMILES: c1cc(N2CC3CCCCC3C2)c2ccc3c(N4CC5CCCCC5C4)ccnc3c2n1 ; c1ccc(-c2nc(-c3cccc(-c4cccc(-c5nc(-c6ccccc6)c6ccc7ccccc7c6n5)n4)n3)nc3c2ccc2ccccc23)cc1 ; c1ccc(-c2ccc3ccc4ccc(-c5cccc(-c6ccc7ccc8ccc(-c9ccccc9)nc8c7n6)c5)nc4c3n2)cc1]

### <<Absorption Spectrum Measurement>>

First, results of measuring absorption spectra of single films and mixed films of Hid2Phen, 6,6′(P-Bqn)2BPy, mPPhen2P, In, and Li are described. Methods for forming single films 1 to 5 and mixed films 1 to 10 used for the absorption spectrum measurement are described below.

### <Single Film 1>

Over a quartz substrate, Hid2Phen was deposited by evaporation to a thickness of 50 nm.

### <Single Film 2>

Over a quartz substrate, 6,6′(P-Bqn)2BPy was deposited by evaporation to a thickness of 50 nm.

### <Single Film 3>

Over a quartz substrate, In was deposited by evaporation to a thickness of 1 nm.

### <Single Film 4>

Over a quartz substrate, Li was deposited by evaporation to a thickness of 1 nm.

### <Single Film 5>

Over a quartz substrate, mPPhen2P was deposited by evaporation to a thickness of 50 nm.

### <Mixed Film 1>

Over a quartz substrate, Hid2Phen, 6,6′(P-Bqn)2BPy, and In were deposited by co-evaporation to a thickness of 50 nm at a volume ratio of 0.5:0.5:0.02 (=Hid2Phen: 6,6′(P-Bqn)2BPy: In).

### <Mixed Film 2>

Over a quartz substrate, Hid2Phen and In were deposited by co-evaporation to a thickness of 50 nm at a volume ratio of 1:0.02 (=Hid2Phen: In).

### <Mixed Film 3>

Over a quartz substrate, 6,6′(P-Bqn)2BPy and In were deposited by co-evaporation to a thickness of 50 nm at a volume ratio of 1:0.02 (=6,6′(P-Bqn)2BPy: In).

### <Mixed Film 4>

Over a quartz substrate, Hid2Phen and 6,6′(P-Bqn)2BPy were deposited by co-evaporation to a thickness of 50 nm at a volume ratio of 0.5:0.5 (=Hid2Phen: 6,6′(P-Bqn)2BPy).

### <Mixed Film 5>

Over a quartz substrate, Hid2Phen, 6,6′(P-Bqn)2BPy, and Li were deposited by co-evaporation to a thickness of 50 nm at a volume ratio of 0.5:0.5:0.02 (=Hid2Phen: 6,6′(P-Bqn)2BPy: Li). Note that the mixed film 5 is a sample for comparison.

### <Mixed Film 6>

Over a quartz substrate, Hid2Phen and Li were deposited by co-evaporation to a thickness of 50 nm at a volume ratio of 1:0.02 (=Hid2Phen: Li). Note that the mixed film 6 is a sample for comparison.

### <Mixed Film 7>

Over a quartz substrate, 6,6′(P-Bqn)2BPy and Li were deposited by co-evaporation to a thickness of 50 nm at a volume ratio of 1:0.02 (=6,6′(P-Bqn)2BPy: Li). Note that the mixed a film 7 is a sample for comparison.

### <Mixed Film 8>

Over a quartz substrate, Hid2Phen, mPPhen2P, and In were deposited by co-evaporation to a thickness of 50 nm at a volume ratio of 0.5:0.5:0.02 (=Hid2Phen: mPPhen2P: In).

### <Mixed Film 9>

Over a quartz substrate, mPPhen2P and In were deposited by co-evaporation to a thickness of 50 nm at a volume ratio of 1:0.02 (=mPPhen2P: In).

### <Mixed Film 10>

Over a quartz substrate, Hid2Phen and mPPhen2P were deposited by co-evaporation to a thickness of 50 nm at a volume ratio of 0.5:0.5 (=Hid2Phen: mPPhen2P).

The vapor deposition was performed at the settings made to previously measure the thickness of an evaporated film of Hid2Phen and mPPhen2P with the evaporation rate and the thickness monitored with a quartz oscillator, with a spectroscopic ellipsometer (M-2000U manufactured by J. A. Woollam Japan Corp.). By this method, a film having a difference in thickness of less than or equal to 5% from the target thickness can be formed. Thus, the difference in thickness between the thin films deposited by co-evaporation to a thickness of 50 nm can be less than or equal to 10%.

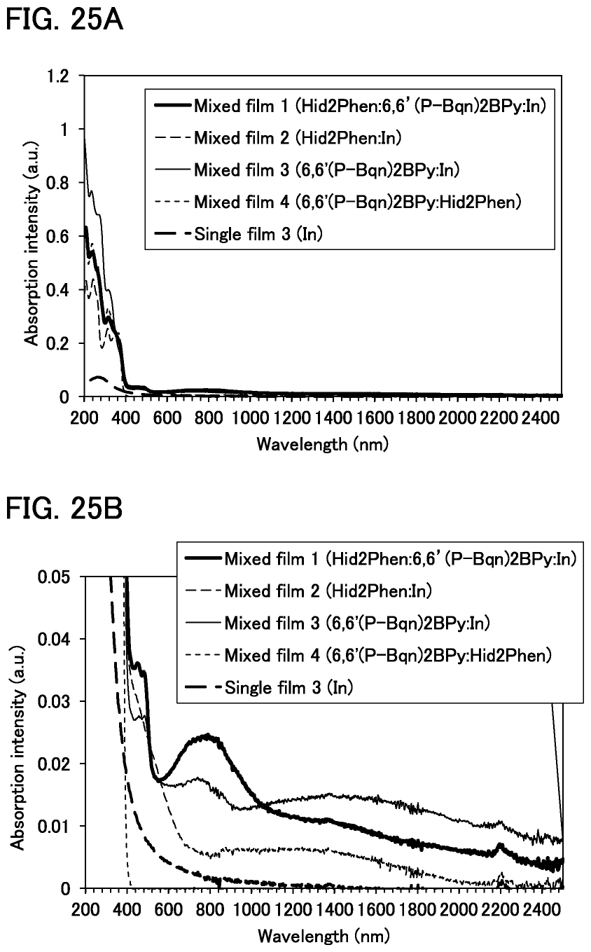

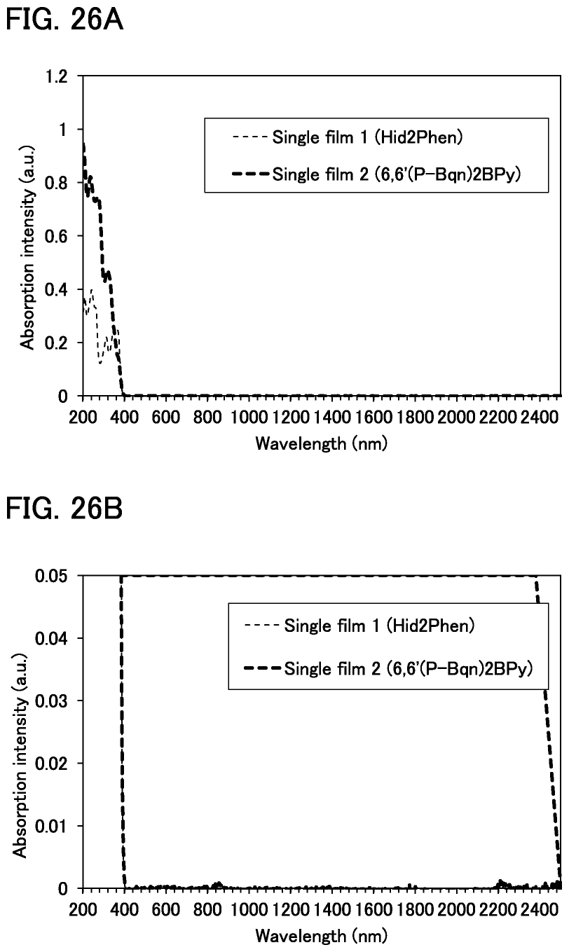

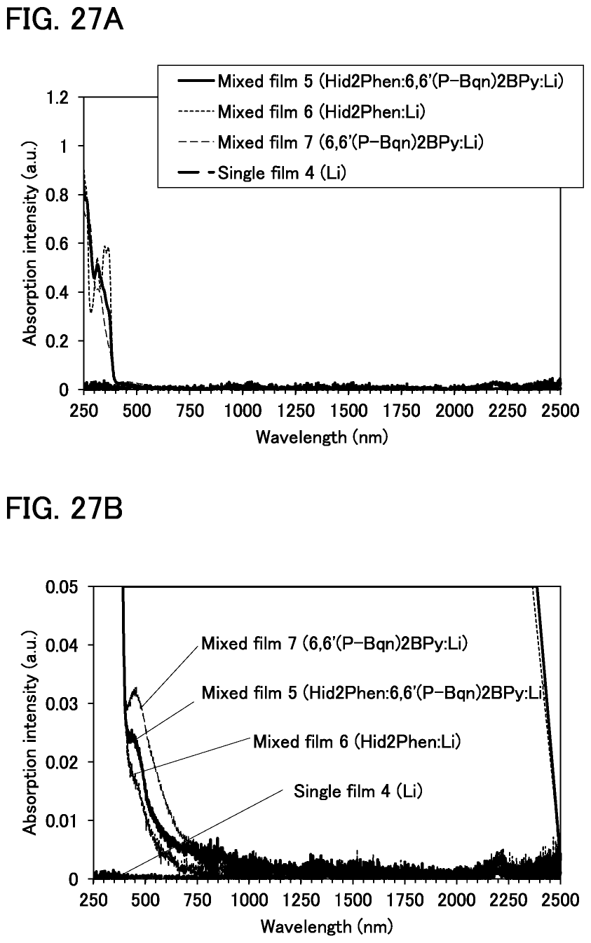

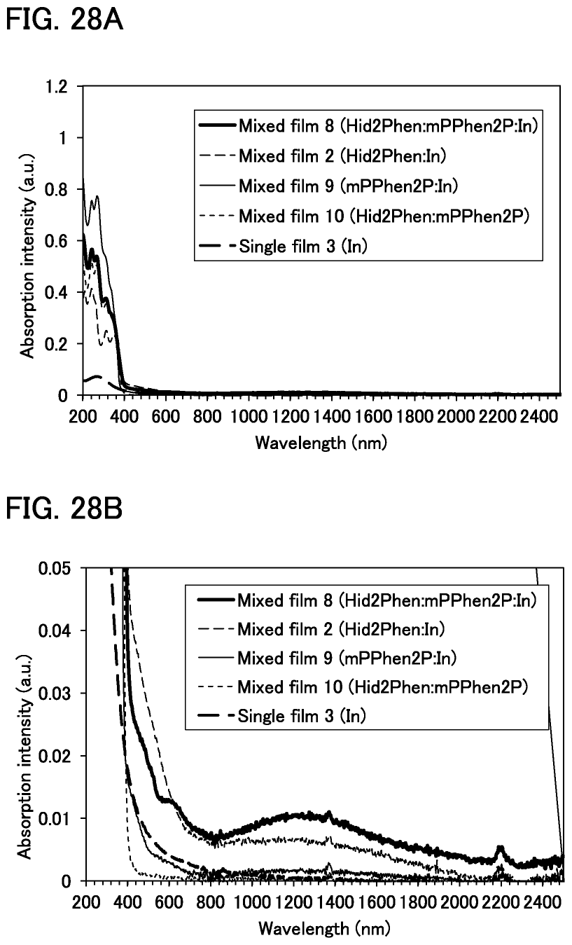

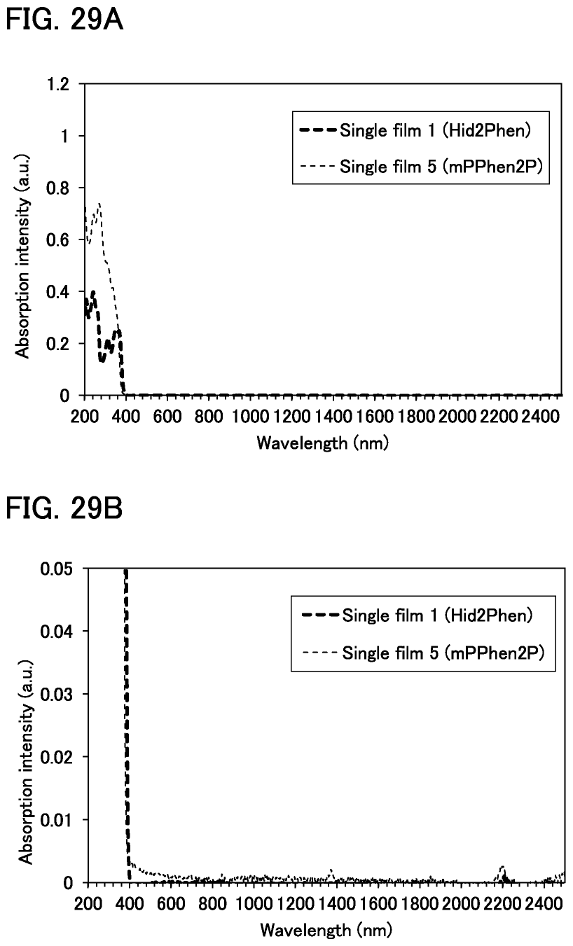

The absorption spectra of the samples were measured at room temperature. A UV-visible spectrophotometer (U-4100 produced by Hitachi High-Technologies Corporation) was used for the measurement. FIG. 25A illustrates absorption spectra of the mixed films 1 to 4 and the single film 3, and FIG. 25B is an enlarged view of the absorption spectra illustrated in FIG. 25A. FIG. 26A illustrates absorption spectra of the single films 1 and 2, and FIG. 26B is an enlarged view of the absorption spectra illustrated in FIG. 26A. FIG. 27A illustrates absorption spectra of the mixed films 5 to 7 and the single film 4, and FIG. 27B is an enlarged view of the absorption spectra illustrated in FIG. 27A. FIG. 28A illustrates absorption spectra of the mixed films 8, 2, 9, and 10 and the single film 3, and FIG. 28B is an enlarged view of the absorption spectra illustrated in FIG. 28A. FIG. 29A illustrates absorption spectra of the single films 1 and 5, and FIG. 29B is an enlarged view of the absorption spectra illustrated in FIG. 29A.

As illustrated in FIGS. 25A and 26A, in the wavelength region of 400 nm to 2500 nm, the absorption spectrum of the mixed film 1 including Hid2Phen, 6,6′(P-Bqn)2BPy, and In has an absorption intensity peak that is not observed in the single film 1 (Hid2Phen), the single film 2 (6,6′(P-Bqn)2BPy), the single film 3 (In), or the mixed film 4 (Hid2Phen and 6,6′(P-Bqn)2BPy).

As illustrated in FIG. 25B, in the wavelength region of 600 nm to 1000 nm, the absorption spectrum of the mixed film 1 has a higher absorption intensity than the absorption spectrum of the mixed film 2 including Hid2Phen and In. The wavelength region is a region at longer wavelengths than a wavelength (388 nm) of an absorption edge on the long wavelength side of the absorption spectrum of the single film 1 including Hid2Phen, which can be read from FIG. 26A. In the wavelength region of 600 nm to 1000 nm, the absorption spectrum of the mixed film 1 has a higher absorption intensity than the absorption spectrum of the mixed film 3 including 6,6′(P-Bqn)2BPy and In. The wavelength region is a region at longer wavelengths than a wavelength (392 nm) of an absorption edge on the long wavelength side of the absorption spectrum of the single film 2 including 6,6′(P-Bqn)2BPy, which can be read from FIG. 26A.

Note that the absorption edge on the long wavelength side of each sample was determined as the intersection between a tangent and the horizontal axis (wavelength) or the baseline. The tangent is drawn at a point at which the slope on the long wavelength side of the longest-wavelength peak (or the longest-wavelength shoulder peak) of the absorption spectrum has the maximum absolute value.

In FIG. 27A, in the wavelength region of 400 nm to 2500 nm, the absorption spectrum of the mixed film 5 including Hid2Phen, 6,6′(P-Bqn)2BPy, and Li has an absorption intensity peak that is not observed in the single film 1 (Hid2Phen), the single film 2 (6,6′(P-Bqn)2BPy), or the single film 4 (Li).

However, as can be seen from FIG. 27B, in a region at longer wavelengths than a wavelength (392 nm) of an absorption edge on the long wavelength side of the absorption spectrum of the single film 2 including 6,6′(P-Bqn)2BPy in the wavelength region of approximately 400 nm to approximately 800 nm, the absorption spectrum of the mixed film 5 does not include a wavelength region having a higher absorption intensity than the absorption spectrum of the mixed film 7 including 6,6′(P-Bqn)2BPy and Li.

These results show that the combination of Hid2Phen, 6,6′(P-Bqn)2BPy, and In more easily forms a charge-transfer complex than the combination of Hid2Phen, 6,6′(P-Bqn)2BPy, and Li.

As illustrated in FIG. 28B, in the wavelength region of 400 nm to 2500 nm, the absorption spectrum of the mixed film 8 including Hid2Phen, mPPhen2P, and In has an absorption intensity peak that is not observed in the single film 1 (Hid2Phen), the single film 3 (In), the single film 5 (mPPhen2P), or the mixed film 10 (Hid2Phen and mPPhen2P). In the wavelength region of 800 nm to 2000 nm, the absorption spectrum of the mixed film 8 has a higher absorption intensity than the absorption spectrum of the mixed film 2 including Hid2Phen and In. The wavelength region is a region at longer wavelengths than the wavelength (388 nm) of the absorption edge on the long wavelength side of the absorption spectrum of the single film 1 including Hid2Phen, which can be read from FIG. 29A. In the wavelength region of 800 nm to 2000 nm, the absorption spectrum of the mixed film 8 has a higher absorption intensity than the absorption spectrum of the mixed film 9 including mPPhen2P and In. The wavelength region is a region at longer wavelengths than a wavelength (376 nm) of an absorption edge on the long wavelength side of the absorption spectrum of the single film 5 including mPPhen2P, which can be read from FIG. 29A.

This indicates that the combination of Hid2Phen, mPPhen2P, and In can form a charge-transfer complex.

### 30<<LDI-MS Analysis>>

Next, results of laser desorption/ionization mass spectrometry (LDI-MS) analysis on the mixed film including the combination of Hid2Phen, 6,6′(P-Bqn)2BPy, and In are described.

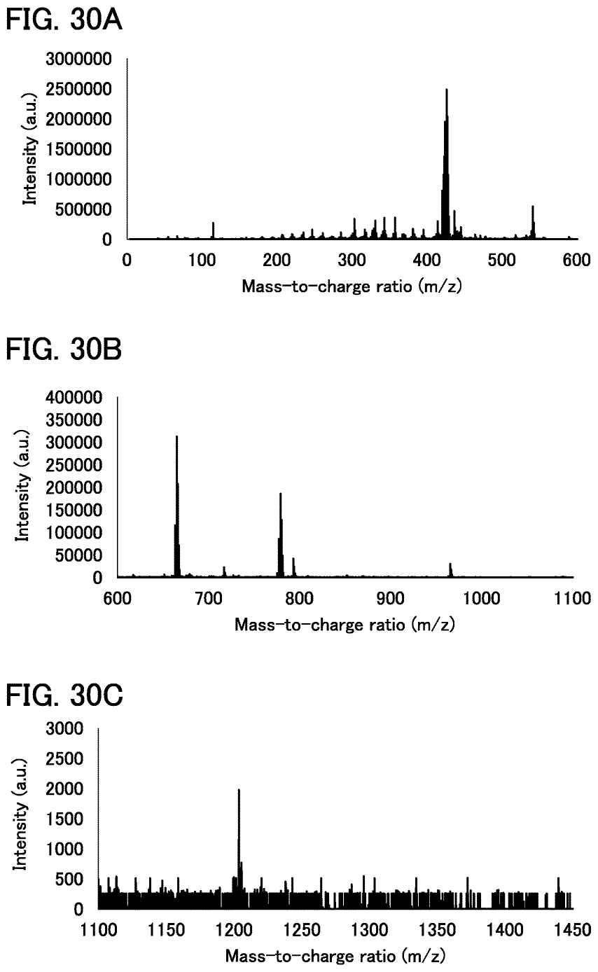

A sample for the LDI-MS analysis was formed by depositing Hid2Phen, 6,6′(P-Bqn)2BPy, and In by co-evaporation to a thickness of 20 nm at a volume ratio of 0.5:0.5:0.02 (=Hid2Phen: 6,6′(P-Bqn)2BPy: In) over a silicon substrate. In the measurement, LDI-MS spectra of the sample surface was measured with MALDI-TOF-MS_JMS-S3000 manufactured by JEOL Ltd. in a spiral POS mode at 65% of laser intensity, 70 ns of delay time, 70% of detector, 0.5 ns of sampling interval, and 250 Hz of laser frequency. FIGS. 30A to 30C show the measurement results. FIG. 30A illustrates an LDI-MS spectrum in a mass-to-charge ratio range of 0 to 600, FIG. 30B illustrates an LDI-MS spectrum in a mass-to-charge ratio range of 600 to 1100, and FIG. 30C illustrates an LDI-MS spectrum in a mass-to-charge ratio range of 1100 to 1450.

In FIG. 30C, the LDI-MS spectrum has a peak at a mass-to-charge ratio of 1205, which corresponds to the sum of the mass numbers of Hid2Phen, 6,6′(P-Bqn)2BPy, and In (M1+M2+M3). This indicates that these three materials interact with each other in the film and exist as a composite material.

### <<HOMO Level and LUMO Level>>

The HOMO level and the LUMO level of Hid2Phen obtained by cyclic voltammetry (CV) measurement were −5.5 eV and −2.5 eV, respectively. The LUMO level of 6,6′(P-Bqn)2BPy was −2.92 eV, and the LUMO level of mPPhen2P was −2.71 eV. Since the oxidation potentials of 6,6′(P-Bqn)2BPy and mPPhen2P were high and the peak potentials thereof were not observed, the HOMO levels of 6,6′(P-Bqn)2BPy and PPhen2P were found to be lower than −6.0 eV. Thus, the HOMO level of Hid2Phen is higher than the HOMO level of 6,6′(P-Bqn)2BPy, and the LUMO level of Hid2Phen is higher than the LUMO level of 6,6′(P-Bqn)2BPy. Furthermore, the HOMO level of Hid2Phen is higher than the HOMO level of mPPhen2P, and the LUMO level of Hid2Phen is higher than the LUMO level of mPPhen2P.

Note that the HOMO level and the LUMO level were obtained through cyclic voltammetry (CV) measurement. In the cyclic voltammetry (CV) measurement, the values (E) of the HOMO and LUMO levels were calculated on the basis of an oxidation peak potential (Eₚₐ) and a reduction peak potential (E_{pc}), which were obtained by changing the potential of a working electrode with respect to a reference electrode. In the measurement, a HOMO level and a LUMO level were obtained by potential scanning in the positive direction and potential scanning in the negative direction, respectively. The scanning speed in the measurement was 0.1 V/s. Specifically, a standard oxidation-reduction potential (Eₒ) (=(Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Ex) of the reference electrode with respect to a vacuum level, whereby each of the values (E) (=Eₓ−Eₒ) of HOMO and LUMO levels was obtained. Note that the reversible oxidation-reduction wave is obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

The above results show that the combination of Hid2Phen, 6,6′(P-Bqn)2BPy and In and the combination of Hid2Phen, mPPhen2P, and In are combinations that can be preferably used for the layer 200.

### Example 2

In this example, results of several analyses on fabricated analysis samples that imitate a light-emitting device of one embodiment of the present invention are described. The following are structural formulae of organic compounds used in this example.

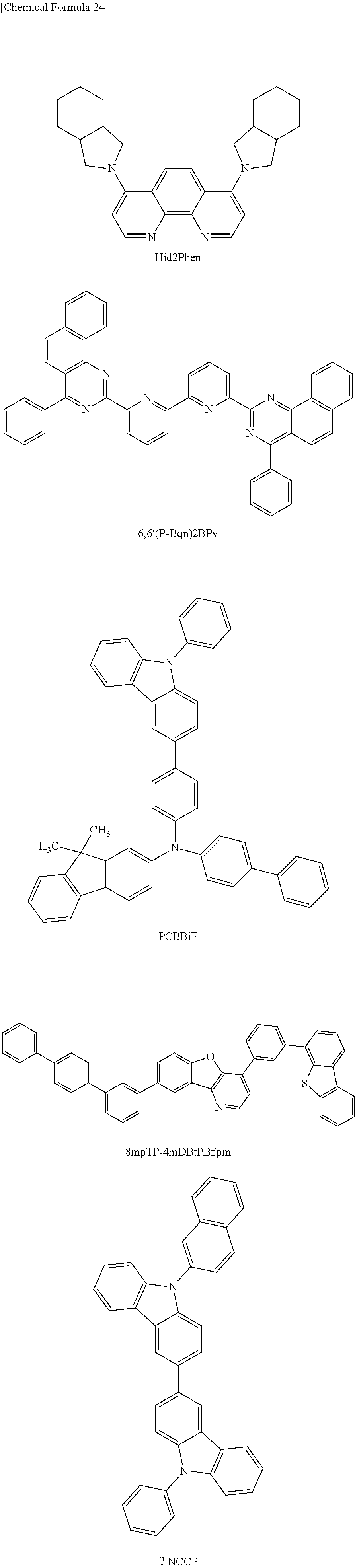

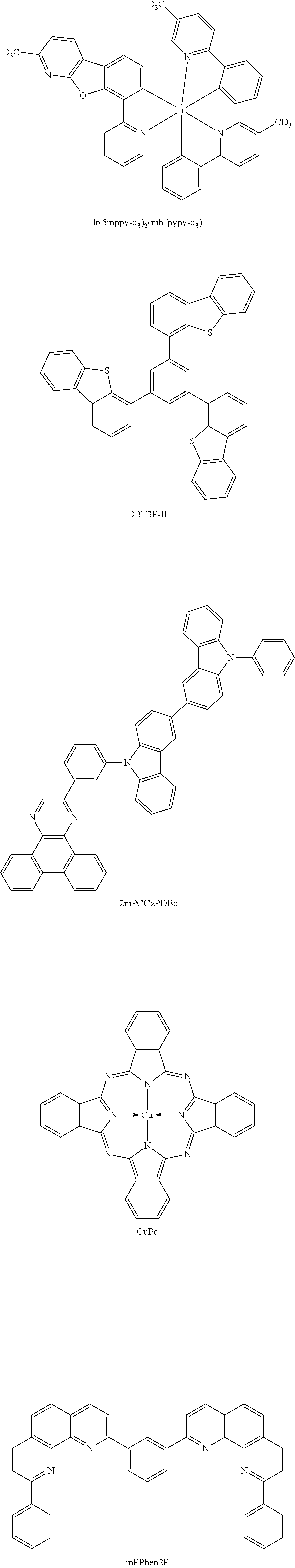

### <<Plane SEM Analysis>>

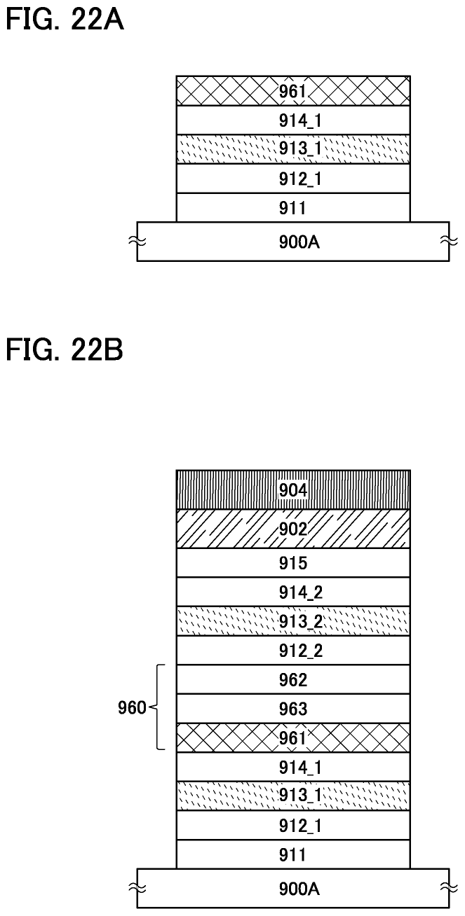

First, an analysis sample 1 and an analysis sample 2 for comparison which have a stacked-layer structure equivalent to the structure of the hole-injection layer, the first hole-transport layer, the first light-emitting layer, the first electron-transport layer, and the first layer of the intermediate layer of the light-emitting device of one embodiment of the present invention were fabricated, and the film plane was analyzed with a scanning electron microscope (SEM). As illustrated in FIG. 22A, the analysis sample 1 and the analysis sample 2 each have a structure in which a hole-injection layer 911, a first hole-transport layer 912_1, a first light-emitting layer 913_1, a first electron-transport layer 914_1, and a first layer 961 are stacked in this order over a quartz substrate 900A. Methods for fabricating the analysis samples 1 and 2 are described below.

### <Analysis Sample 1>

The quartz substrate 900A was fixed to a substrate holder provided in a vacuum evaporation apparatus, and N-(biphenyl-4-yl)-N-[4-(9-phenyl-9H-carbazol-3-yl)phenyl]-9,9-dimethyl-9H-fluoren-2-amine (abbreviation: PCBBiF) and an electron-acceptor material with a molecular weight of 672 and four or more fluorine atoms (OCHD-003) were deposited by co-evaporation to a thickness of 10 nm at a weight ratio of 1:0.03 (=PCBBiF: OCHD-003), whereby the hole-injection layer 911 was formed.

Next, PCBBiF was deposited by evaporation to a thickness of 30 nm over the hole-injection layer 911, whereby the first hole-transport layer 912_1 was formed.

Then, over the first hole-transport layer 9121, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-3,3′-bi-9H-carbazole (abbreviation: βNCCP), and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) were deposited by co-evaporation to a thickness of 40 nm at a weight ratio of 0.5:0.5:0.1 (=8mpTP-4mDBtPBfpm: βNCCP: Ir(5mppy-d₃)₂(mbfpypy-d₃)), whereby the first light-emitting layer 913_1 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, whereby the first electron-transport layer 914_1 was formed.

After the formation of the first electron-transport layer 9141, Hid2Phen, 6,6′(P-Bqn)2BPy, and In were deposited by co-evaporation to a thickness of 5 nm at a volume ratio of 0.5:0.5:0.02 (=Hid2Phen: 6,6′(P-Bqn)2BPy: In), whereby the first layer 961 was formed. In this manner, the analysis sample 1 was fabricated.

### <Analysis Sample 2>

The analysis sample 2 is a sample for comparison fabricated by forming the first layer 961 by depositing Hid2Phen and 6,6′(P-Bqn)2BPy by co-evaporation to a thickness of 5 nm at a volume ratio of 0.5:0.5 (=Hid2Phen: 6,6′(P-Bqn)2BPy) after the formation of the first electron-transport layer 914_1 in the method for fabricating the analysis sample 1.

Table 7 shows the stacked-layer structures of the analysis samples 1 and 2.

TABLE 7

| | Thickness | | Analysis sample 1 | Analysis sample 2 |
|---|---|---|---|---|
| First layer | 5 | nm | Hid2Phen:6,6′(P-Bqn)2BPy:In | Hid2Phen:6,6′(P-Bqn)2BPy |
| | | | (0.5:0.5:0.02) | (0.5:0.5) |
| First electron-transport | 10 | nm | 2mPCCzPDBq | |
| layer | | | | |

| | | | |
|---|---|---|---|
| First light-emitting layer | 40 | nm | 8mpTP-4mDBtPBfpm:βNCCP:Ir(5mppy-d₃)₂(mbfpypy-d₃) |
| | | | (0.5:0.5:0.1) |
| First hole-transport layer | 30 | nm | PCBBiF |
| Hole-injection layer | 10 | nm | PCBBiF:OCHD-003 (1:0.03) |
| Substrate | 0.7 | mm | Quartz |

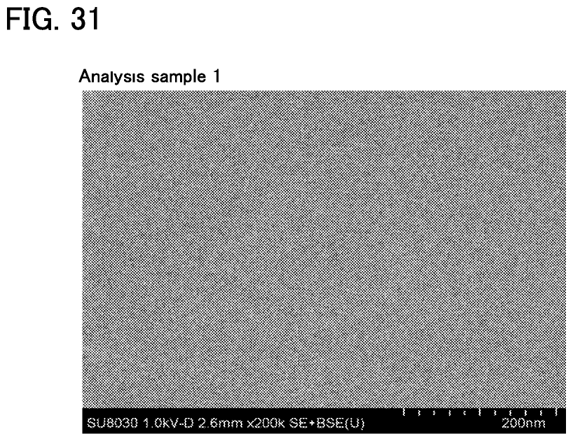

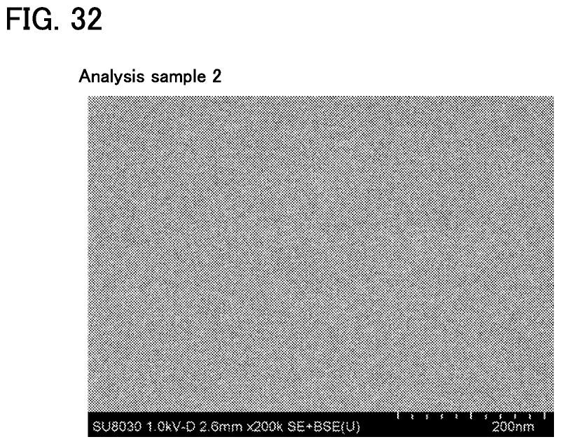

FIG. 31 and FIG. 32 illustrate plane SEM images of the analysis samples 1 and 2, respectively. An SU8030 scanning electron microscope produced by Hitachi High-Tech Corporation was used for the plane SEM analysis. The accelerating voltage was 1 kV. FIG. 31 and FIG. 32 show no significant difference between plane SEM images of the analysis samples 1 and 2, indicating that In exists uniformly in the first layer 961 of the analysis sample 1. In other words, it was found that a composite material can be formed by uniformly mixing In with the organic compounds in the first layer of the intermediate layer of the light-emitting device of one embodiment of the present invention.

### <<Cross-Sectional STEM Analysis>>

Next, an analysis sample 3 having a stacked-layer structure equivalent to that of the hole-injection layer, the first hole-transport layer, the first light-emitting layer, the first electron-transport layer, the intermediate layer (the first layer, the third layer, and the second layer), the second hole-transport layer, the second light-emitting layer, the second electron-transport layer, the second electrode, and the cap layer of the light-emitting device of one embodiment of the present invention was fabricated, and cross sections of films processed with a focused ion beam (FIB) were analyzed by scanning transmission electron microscopy (STEM). Note that an atomic resolution analytical electron microscope JEM-ARM200F manufactured by JEOL Ltd. was used for the analysis. The accelerating voltage was 80 kV and the magnification accuracy was ±3%. As illustrated in FIG. 22B, the analysis sample 3 has a structure in which the hole-injection layer 911, the first hole-transport layer 912_1, the first light-emitting layer 913_1, the first electron-transport layer 914_1, an intermediate layer 960 (the first layer 961, a third layer 963, and a second layer 962), a second hole-transport layer 9122, a second light-emitting layer 9132, a second electron-transport layer 914_2, and a cap layer 904 are stacked in this order over the quartz substrate 900A. A method for fabricating the analysis sample 3 is described below.

### <Analysis Sample 3>

First, in a manner similar to that for the analysis sample 1, the hole-injection layer 911, the first hole-transport layer 912_1, the first light-emitting layer 913_1, the first electron-transport layer 914_1, and the first layer 961 were formed over the quartz substrate 900A.

Then, copper phthalocyanine (abbreviation: CuPc) was deposited to a thickness of 2 nm, whereby the third layer 963 was formed.

Furthermore, PCBBiF and OCHD-003 were deposited by co-evaporation to a thickness of 10 nm at a weight ratio of 1:0.15 (PCBBiF: OCHD-003), whereby the second layer 962 was formed.

Next, PCBBiF was deposited by evaporation to a thickness of 50 nm over the second layer 962, whereby the second hole-transport layer 912_2 was formed.

Over the second hole-transport layer 912_2, 8mpTP-4mDBtPBfpm, βNCCP, and Ir(5mppy-d3)2(mbfpypy-d3) were deposited by co-evaporation to a thickness of 40 nm at a weight ratio of 0.5:0.5:0.1 (=8mpTP-4mDBtPBfpm: βNCCP: Ir(5mppy-d₃)₂(mbfpypy-d₃)), whereby the second light-emitting layer 913_2 was formed.

Then, 2mPCCzPDBq was deposited by evaporation to a thickness of 20 nm, and mPPhen2P was further deposited by evaporation to a thickness of 20 nm, whereby the second electron-transport layer 914_2 was formed.

Next, over the second electron-transport layer 9142, lithium fluoride (LiF) and ytterbium (Yb) were deposited by co-evaporation to a thickness of 1.5 nm at a volume ratio of 2:1 (═LiF: Yb) to form an electron-injection layer, and lastly silver (Ag) and magnesium (Mg) were deposited by co-evaporation to a thickness of 15 nm at a volume ratio of 1:0.1 (═Ag: Mg), whereby a second electrode 902 was formed.

Then, as the cap layer 904, 4,4,4″-(benzene-1,3,5-triyl)tri(dibenzothiophene) (abbreviation: DBT3P-II) was deposited by evaporation to a thickness of 70 nm over the second electrode 902.

Table 8 shows the stacked-layer structure of the analysis sample 3.

TABLE 8

| | | Thickness | | Analysis sample 3 |
|---|---|---|---|---|
| Cap layer | | 70 | nm | DBT3P-II |
| Second electrode | | 15 | nm | Ag:Mg (1:0.1) |
| Electron-injection layer | | 1.5 | nm | LiF:Yb (2:1) |
| Second electron- | 2 | 20 | nm | mPPhen2P |
| transport layer | 1 | 20 | nm | 2mPCCzPDBq |

| | | | |
|---|---|---|---|
| Second light-emitting layer | 40 | nm | 8mpTP-4mDBtPBfpm:βNCCP:Ir(5mppy-d₃)₂(mbfpypy-d₃) (0.5:0.5:0.1) |
| Second hole-transport layer | 50 | nm | PCBBiF |
| Second layer | 10 | nm | PCBBiF:OCHD-003 (1:0.15) |
| Third layer | 2 | nm | CuPc |
| First layer | 5 | nm | Hid2Phen:6,6′(P-Bqn)2BPy:In(0.5:0.5:0.02) |
| First electron-transport layer | 10 | nm | 2mPCCzPDBq |
| First light-emitting layer | 40 | nm | 8mpTP-4mDBtPBfpm:βNCCP:Ir(5mppy-d₃)₂(mbfpypy-d₃) (0.5:0.5:0.1) |
| First hole-transport layer | 30 | nm | PCBBiF |
| Hole-injection layer | 10 | nm | PCBBiF:OCHD-003 (1:0.03) |
| Substrate | 0.7 | mm | Quartz |

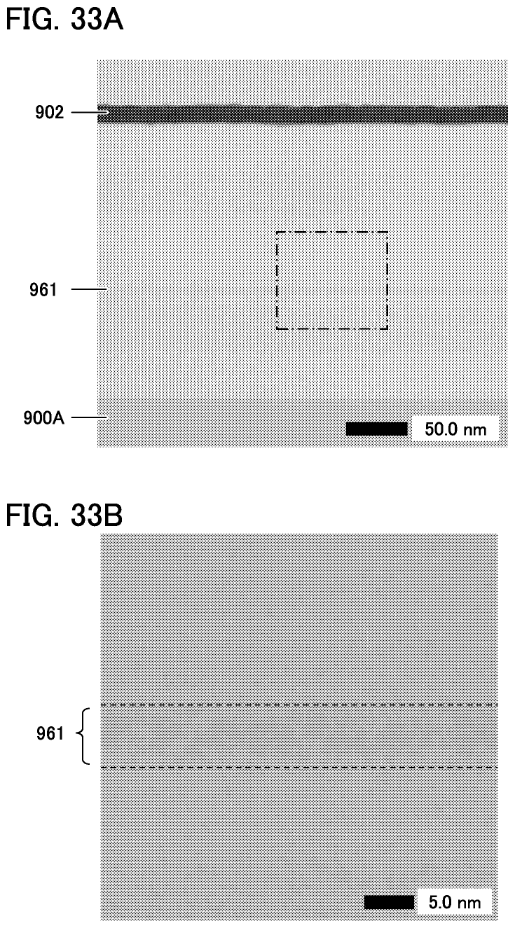

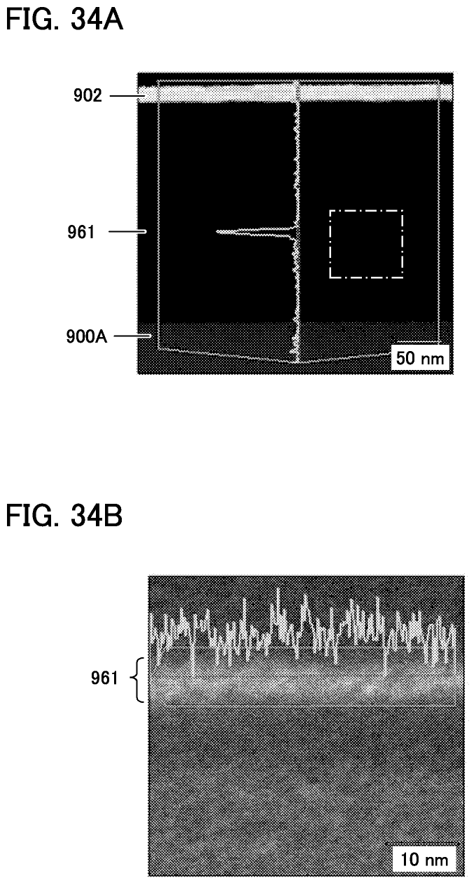

FIG. 33A illustrates a cross-sectional STEM image of the analysis sample 3 processed by an FIB, and FIG. 34A illustrates results of energy dispersive X-ray spectroscopy (EDX). For the cross-sectional STEM observation and the EDX measurement, JEM-ARM200F manufactured by JEOL Ltd. was used, the acceleration voltage was 80 kV, and the magnification accuracy was ±3%. In the EDX measurement, an energy dispersive X-ray spectrometer AnalysisStation JED-2300T manufactured by JEOL Ltd. was used as an element analysis apparatus, and the area of an X-ray detection element was 158 mm²×2. For the measurement conditions, dell time was 50 s and the number of frames was 300 (FIG. 34A) and 155 (FIG. 34B3). FIG. 33B is an enlarged view of a portion surrounded by a dashed-dotted line in FIG. 33A, and FIG. 34B is an enlarged view of a portion surrounded by a dashed-dotted line in FIG. 34A. In FIGS. 34A and 34B3, the results of the cross-sectional STEM-EDX line analysis for In are superimposed on the cross-sectional STEM image. In FIGS. 33A and 33B and FIGS. 34A and 34B3, the areas corresponding to the quartz substrate 900A, the first layer 961, and the second electrode 902 are denoted by reference numerals.

FIGS. 33A and 33B and FIGS. 34A and 34B show no characteristic tendency in In distribution in the first layer 961, indicating that In exists uniformly in the first layer 961 of the analysis sample 3. In other words, it was found also from these results that a composite material can be formed by uniformly mixing In with the organic compounds in the first layer of the light-emitting device of one embodiment of the present invention.

### Example 3

In this example, analysis samples and analysis devices using In and analysis samples and analysis devices using Li were fabricated and subjected to several analyses to carry out an analysis of a metal that has high resistance to acid treatment and is preferably used as the metal material 161_M. The analysis results are described. The following are structural formulae of the organic compounds used in this example.

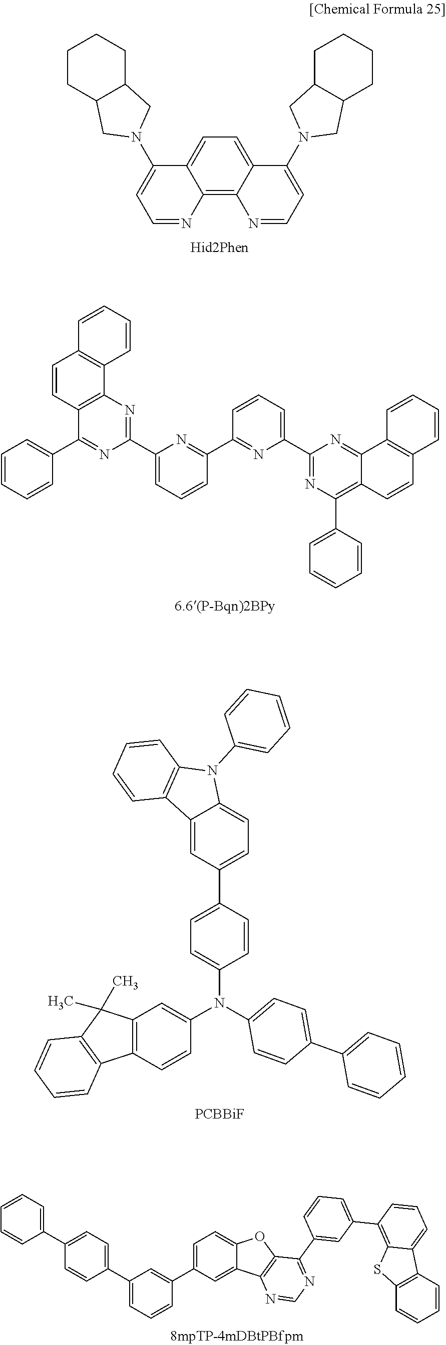

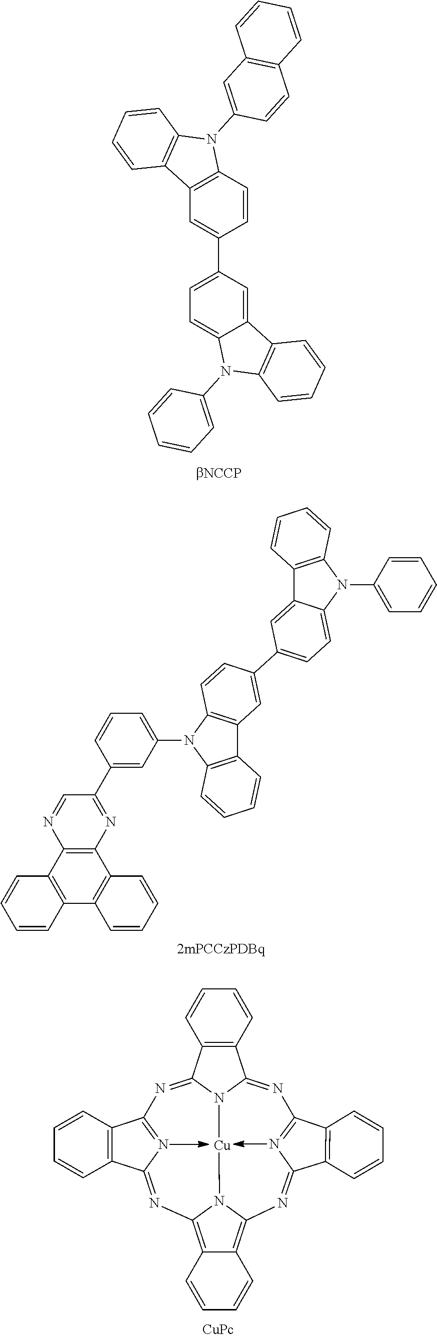

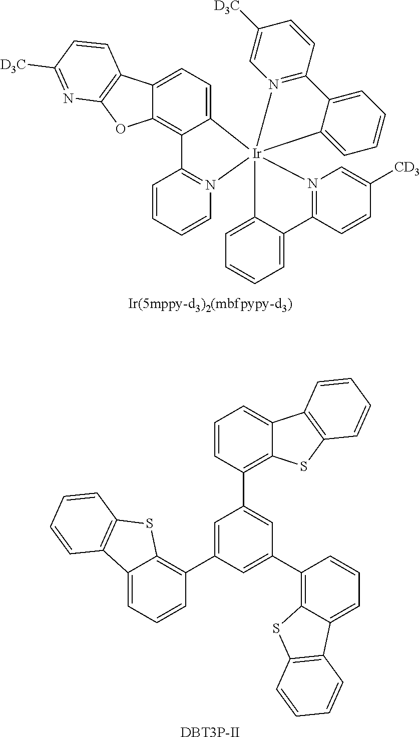

### <<Cross-Sectional STEM Analysis and SIMS Analysis>>

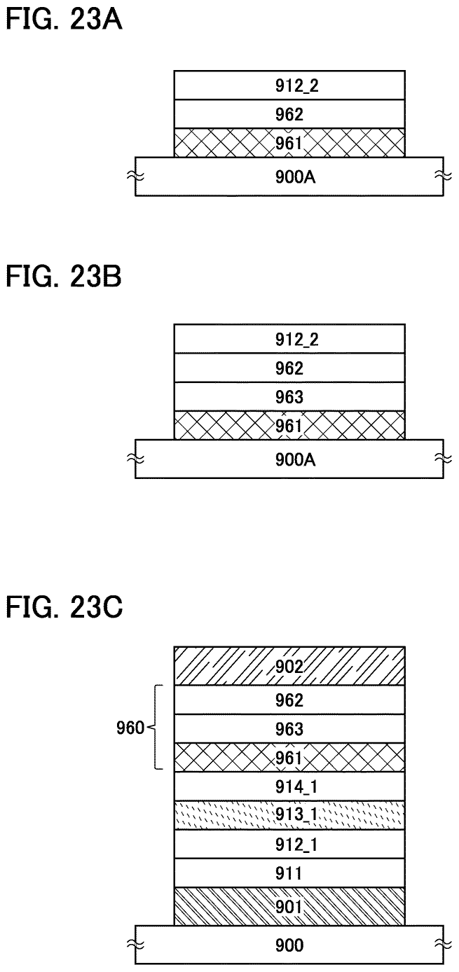

First, analysis samples 4a and 4b having a stacked-layer structure that imitates the intermediate layer and the second hole-transport layer of a light-emitting device of one embodiment of the present invention and analysis samples 5a and 5b for comparison were fabricated, and cross-sectional STEM analysis was performed. As illustrated in FIG. 23A, the analysis samples 4 and the analysis samples 5 each have a structure in which the first layer 961, the second layer 962, and the second hole-transport layer 912_2 are stacked in this order over the quartz substrate 900A. Methods for fabricating the analysis samples 4 and 5 are described below.

<Analysis Sample 4a>

The quartz substrate 900A was fixed to a substrate holder provided in a vacuum evaporation apparatus, and Hid2Phen, 6,6′(P-Bqn)2BPy, and In were deposited by co-evaporation to a thickness of 10 nm at a volume ratio of 0.5:0.5:0.02 (=Hid2Phen: 6,6′(P-Bqn)2BPy: In), whereby the first layer 961 was formed.

Next, PCBBiF and OCHD-003 were deposited by co-evaporation to a thickness of 10 nm at a weight ratio of 1:0.15 (═PCBBiF: OCHD-003), whereby the second layer 962 was formed.

Then, PCBBiF was deposited by evaporation to a thickness of 10 nm over the second layer 962, whereby the second hole-transport layer 912_2 was formed. In this manner, the analysis sample 4a was fabricated.

<Analysis Sample 4b>

The analysis sample 4b is different from the analysis sample 4a by being fabricated through acid treatment after the formation of the first layer 961 and before the formation of the second layer 962 and the second hole-transport layer 912_2 in the method for fabricating the analysis sample 4a. Except for this, the analysis sample 4b was fabricated in a manner similar to that of the analysis sample 4a.

Specifically, the acid treatment was performed in such a manner that the substrate was immersed in a mixed aqueous solution of hydrogen fluoride (0.010 vol %) and a phosphoric acid (0.081 vol %) for 156 seconds, the substrate was washed with water for 60 seconds, and then moisture was removed with a spin coater. Then, the substrate was transferred into a vacuum evaporation apparatus where the pressure was reduced to approximately 1×10⁻⁴ Pa, and heat treatment was performed at 100 °C for 1 hour in a heating chamber of the vacuum evaporation apparatus.

<Analysis Sample 5a>

The analysis sample 5a is different from the analysis sample 4a in that the first layer 961 in the method for fabricating the analysis sample 4a was formed by depositing Hid2Phen, 6,6′(P-Bqn)2BPy, and Li₂O (lithium oxide) by co-evaporation to a thickness of 10 nm at a volume ratio of 0.5:0.5:0.02 (=Hid2Phen: 6,6′(P-Bqn)2BPy: Li₂O). Except for this, the analysis sample 5a was fabricated in a manner similar to that of the analysis sample 4a.

<Analysis Sample 5b>

The analysis sample 5b is different from the analysis sample 5a in being fabricated through acid treatment as in the method for fabricating the analysis sample 4b after the formation of the first layer 961 and before the formation of the second layer of the intermediate layer and the second hole-transport layer in the method for fabricating the analysis sample 5a. Except for this, the analysis sample 5b was fabricated in a manner similar to that of the analysis sample 5a.

Table 9 shows the stacked-layer structures of the analysis samples 4a, 4b, 5a, and 5b.

TABLE 9

| | | | | |
|---|---|---|---|---|
| | Analysis | Analysis | Analysis | Analysis |
| Thickness | sample 4a | sample 4b | sample 5a | sample 5b |

| | | | |
|---|---|---|---|
| Second hole-transport | 10 | nm | PCBBiF |

layer

| | | | |
|---|---|---|---|
| Second layer | 10 | nm | PCBBiF:OCHD-003 (1:0.15) |

| | | | | |
|---|---|---|---|---|
| Acid treatment | x | ∘ | x | ∘ |

| | | | | |
|---|---|---|---|---|
| First layer | 10 | nm | Hid2Phen:6,6′(P-Bqn)2BPy:In | Hid2Phen:6,6′(P-Bqn)2BPy:Li₂O |

| | |
|---|---|
| (0.5:0.5:0.02) | (0.5:0.5:0.02) |

| | | | |
|---|---|---|---|
| Substrate | 0.7 | mm | Quartz |

x: Acid treatment not performed
∘: Acid treatment performed

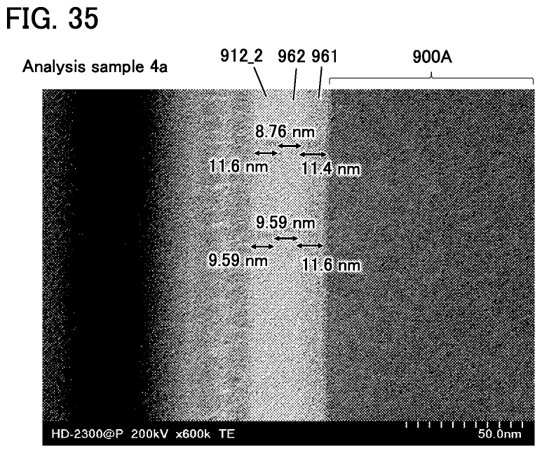

FIGS. 35, 36, 37, and 38 illustrate cross-sectional STEM images obtained by processing the analysis samples 4a, 4b, 5a, and 5b, respectively, with an FIB. The analysis was performed with a scanning transmission electron microscope HD-2300 manufactured by Hitachi High-Tech Corporation at an acceleration voltage of 200 kV and a beam diameter of approximately 0.5 nmφ. In FIGS. 35, 36, 37, and 38, the positions corresponding to the quartz substrate 900A, the first layer 961, the second layer 962, and the second hole-transport layer 912_2 are denoted by reference numerals.

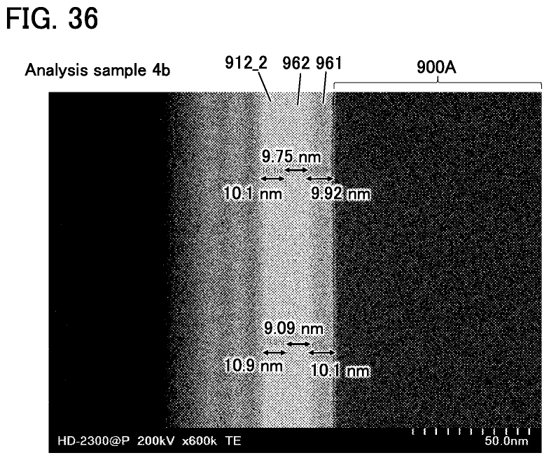

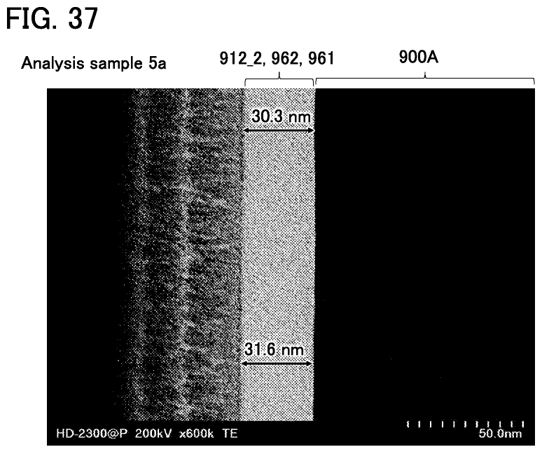

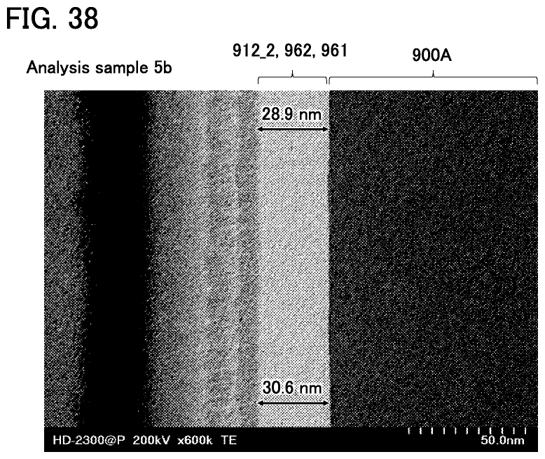

As illustrated in FIGS. 35 and 36, there was no difference in the thickness of the first layer 961 between the analysis samples 4a and 4b. Moreover, as illustrated in FIGS. 37 and 38, there was no difference in the total thickness of the first layer 961, the second layer 962, and the second hole-transport layer 912_2 between the analysis samples 5a and 5b. That is, in the case of using In or Li as the metal element, no change was observed in the thickness of the organic compound layer depending on whether the acid treatment was performed.

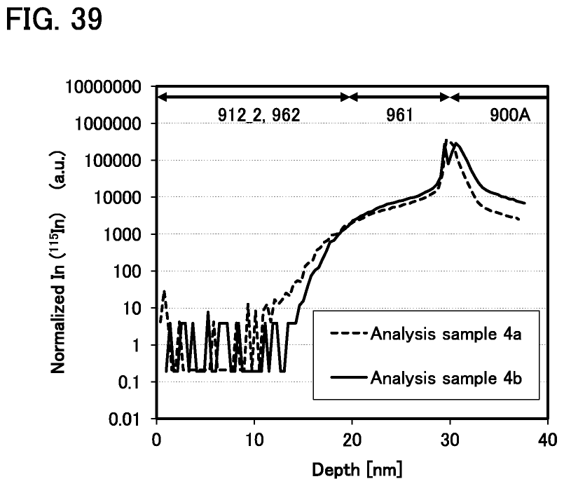

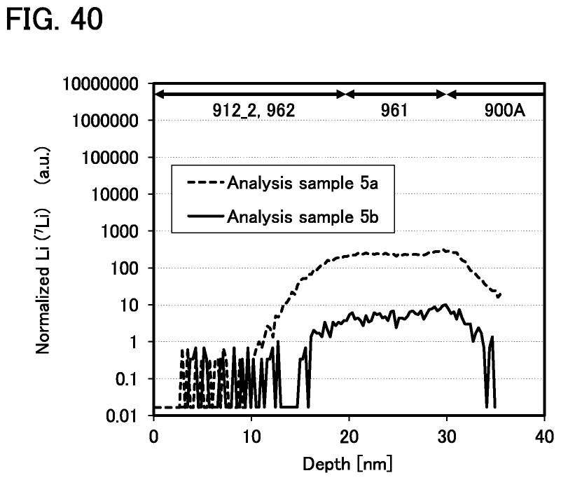

Secondary ion mass spectrometry (SIMS) was performed on the analysis samples 4a, 4b, 5a, and 5b. The SIMS analysis was performed with a PHI-ADEPT1010 quadrupole SIMS instrument produced by ULVAC-PHI, Inc. FIG. 39 illustrates ¹¹⁵In profiles of the analysis samples 4a and 4b measured by SIMS analysis, and FIG. 40 illustrates ⁷Li profiles of the analysis samples 5a and 5b measured by SIMS analysis. Note that oxygen primary ions (O₂⁺) were used as primary ion species in FIG. 39, and cesium primary ions (Cs⁺) were used as primary ion species in FIG. 40.

It was found from FIG. 39 that a difference in detection intensity was small between the analysis samples 4a and 4b. That is, in the case of using In as the metal element, the detection intensity for ¹¹⁵In did not change depending on whether the acid treatment was performed. In contrast, according to FIG. 40, the detection intensity for Li in the analysis sample 5b was lower than that in the analysis sample 5a. That is, in the case where Li was used as the metal element, the detection intensity for ⁷Li was decreased owing to the acid treatment.

The above results show that in the case of using In as the metal element, the acid treatment did not change the thickness of the first layer 961 or the amount of In in the first layer 961 and did not cause a leakage of In from the first layer 961. Meanwhile, in the case of using Li as the metal element, the acid treatment did not change the thickness of the first layer 961 but decreased the amount of Li in the first layer 961, which suggests that Li leaked from the first layer 961.

### <<Examination of Characteristics of Light-Emitting Device>>

Next, analysis devices 1a, 1b, 2a, and 2b that are light-emitting devices for analysis each having a stacked-layer structure imitating the first electrode, the hole-injection layer, the first hole-transport layer, the first light-emitting layer, and the intermediate layer of the light-emitting device of one embodiment of the present invention were fabricated and subjected to several measurements. The measurement results are described. As illustrated in FIG. 23C, the analysis devices 1a, 1b, 2a, and 2b each have a structure in which a first electrode 901, the hole-injection layer 911, the first hole-transport layer 912_1, the first light-emitting layer 913_1, the first electron-transport layer 914_1, the intermediate layer 960 (the first layer 961, the third layer 963, and the second layer 962), and the second electrode 902 are stacked in this order over a glass substrate 900. Methods for fabricating the analysis devices 1a, 1b, 2a, and 2b are described below.

### (Method for Fabricating Analysis Device 1a)

Indium tin oxide containing silicon oxide (ITSO) was deposited by a sputtering method to a thickness of 70 nm over the glass substrate 900, whereby the first electrode 901 being a transparent electrode was formed. The electrode area was set to 4 mm² (2 mm×2 mm).

Next, in pretreatment for forming the light-emitting device over the substrate, the substrate surface was washed with water and baking was performed at 200 °C for 1 hour. Then, the substrate was transferred into a vacuum evaporation apparatus where the pressure was reduced to approximately 1×10⁻⁴ Pa, and was subjected to heat treatment at 170 °C for 30 minutes in a heating chamber of the vacuum evaporation apparatus, and then the substrate was cooled down for approximately 30 minutes.

Next, the substrate was fixed to a substrate holder provided in a vacuum evaporation apparatus such that the surface on which the first electrode 901 was formed faced downward. Over the first electrode 901, PCBBiF and OCHD-003 were deposited by co-evaporation to a thickness of 10 nm at a weight ratio of 1:0.03 (═PCBBiF: OCHD-003), whereby the hole-injection layer 911 was formed.

Over the hole-injection layer 911, PCBBiF was deposited by evaporation to a thickness of 50 nm, whereby the first hole-transport layer 912_1 was formed.

Then, over the first hole-transport layer 912_1, 8mpTP-4mDBtPBfpm, βNCCP, and Ir(5mppy-d3)2(mbfpypy-d3) were deposited by co-evaporation to a thickness of 40 nm at a weight ratio of 0.5:0.5:0.1 (=8mpTP-4mDBtPBfpm: βNCCP: Ir(5mppy-d₃)₂(mbfpypy-d₃)), whereby the first light-emitting layer 913_1 was formed.

Next, 2mPCCzPDBq was deposited by evaporation to a thickness of 10 nm, whereby the first electron-transport layer 914_1 was formed.

After the formation of the first electron-transport layer 9141, Hid2Phen, 6,6′(P-Bqn)2BPy, and In were deposited by co-evaporation to a thickness of 5 nm at a volume ratio of 0.5:0.5:0.02 (=Hid2Phen: 6,6′(P-Bqn)2BPy: In), whereby the first layer 961 was formed.

Next, copper phthalocyanine (abbreviation: CuPc) was deposited to a thickness of 2 nm, whereby the third layer 963 was formed.

Furthermore, PCBBiF and OCHD-003 were deposited by co-evaporation to a thickness of 50 nm at a weight ratio of 1:0.15 (PCBBiF: OCHD-003), whereby the second layer 962 was formed.

Over the second layer 962, Al was deposited by evaporation to a thickness of 200 nm, whereby the second electrode 902 was formed. In this manner, the analysis device 1a was fabricated.

### (Method for Fabricating Analysis Device 1b)

The analysis device 1b is different from the analysis device 1a in being fabricated through acid treatment after the formation of the first layer 961 and before the formation of the third layer 963, the second layer 962, and the second electrode 902 in the method for fabricating the analysis device 1a. Except for this, the analysis device 1b was fabricated in a manner similar to that of the analysis device 1a.

Specifically, the acid treatment was performed in such a manner that the substrate was immersed in a mixed aqueous solution of hydrogen fluoride (0.010 vol %) and a phosphoric acid (0.081 vol %) for 156 seconds, the substrate was washed with water for 60 seconds, and then moisture was removed with a spin coater. Then, the substrate was transferred into a vacuum evaporation apparatus where the pressure was reduced to approximately 1×10⁻⁴ Pa, and heat treatment was performed at 100 °C for 1 hour in a heating chamber of the vacuum evaporation apparatus.

<Analysis Device 2a>

The analysis device 2a is different from the analysis device 1a in that the first layer 961 in the method for fabricating the analysis device 1a was formed by depositing Hid2Phen, 6,6′(P-Bqn)2BPy, and Li₂O by co-evaporation to a thickness of 5 nm at a volume ratio of 0.5:0.5:0.02 (=Hid2Phen: 6,6′(P-Bqn)2BPy: Li₂O). Except for this, the analysis device 2a was fabricated in a manner similar to that of the analysis device 1a.

<Analysis Device 2b>

The analysis device 2b is different from the analysis device 2a in being fabricated through acid treatment in a manner similar to that of the method for fabricating the analysis device 1b after the formation of the first layer 961 and before the formation of the third layer 963, the second layer 962, and the second electrode 902 in the method for fabricating the analysis device 2a. Except for this, the analysis device 2b was fabricated in a manner similar to that of the analysis device 2a.

Table 10 shows the device structures of the analysis devices 1a, 1b, 2a, and 2b.

TABLE 10

| | | | Analysis | Analysis | Analysis | Analysis |
|---|---|---|---|---|---|---|
| | Thickness | | device 1a | device 1b | device 2a | device 2b |
| Second electrode | 200 | nm | Al | | | |
| Second layer | 50 | nm | PCBBiF:OCHD-003 (1:0.15) | | | |
| Third layer | 2 | nm | CuPc | | | |
| Acid treatment | | | x | ∘ | x | ∘ |
| First layer | 5 | nm | Hid2Phen:6,6′(P-Bqn)2BPy:In | | Hid2Phen:6,6′(P-Bqn)2BPy:Li₂O | |
| | | | (0.5:0.5:0.02) | | (0.5:0.5:0.02) | |
| First electron-transport | 10 | nm | 2mPCCzPDBq | | | |
| layer | | | | | | |

| | | | |
|---|---|---|---|
| First light-emitting layer | 40 | nm | 8mpTP-4mDBtPBfpm:βNCCP:Ir(5mppy-d₃)₂(mbfpypy-d₃) |
| | | | (0.5:0.5:0.1) |
| First hole-transport layer | 50 | nm | PCBBiF |
| Hole-injection layer | 10 | nm | PCBBiF:OCHD-003 (1:0.03) |
| First electrode | 70 | nm | ITSO |

| | | |
|---|---|---|
| Substrate | — | Glass |

x: Acid treatment not performed
∘: Acid treatment performed

Each of the fabricated light-emitting devices was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80 °C under an atmospheric pressure for 1 hour. Then, the initial characteristics of the light-emitting devices were measured.

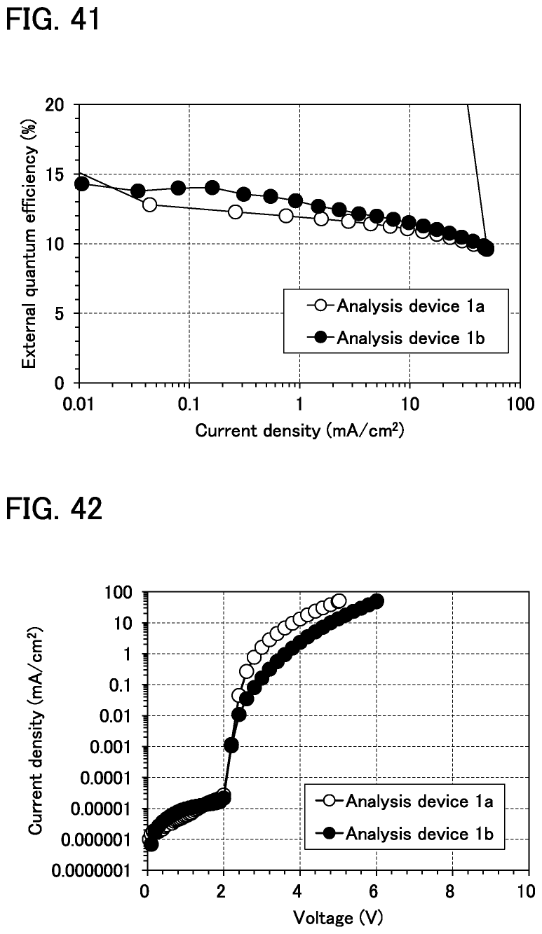

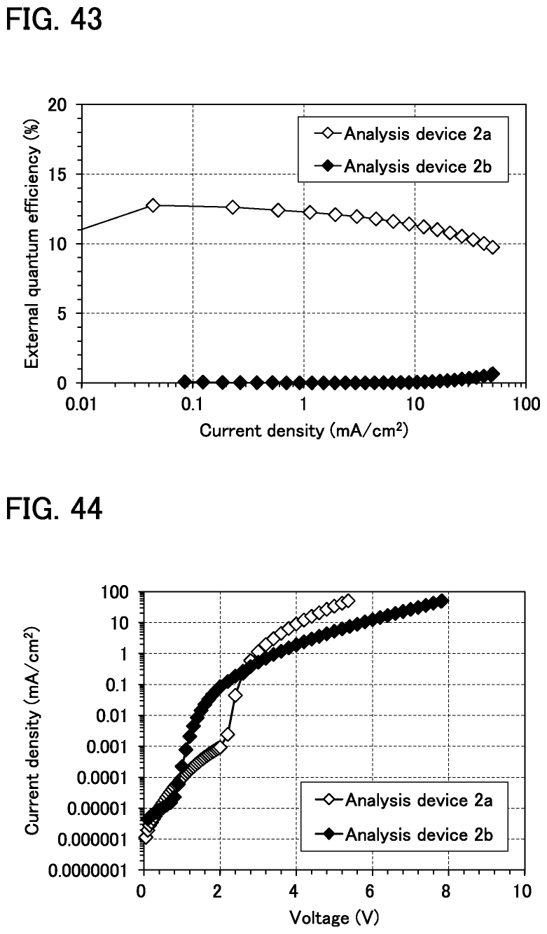

FIGS. 41 and 42 respectively illustrate external quantum efficiency-current density characteristics and current density-voltage characteristics of the analysis devices 1a and 1b, and FIGS. 43 and 44 respectively illustrate external quantum efficiency-current density characteristics and current density-voltage characteristics of the analysis devices 2a and 2b.

FIGS. 41 and 42 show that the analysis devices 1a and 1b have equivalent external quantum efficiencies. That is, in the case of using In as the metal element, the characteristics of the light-emitting device were not changed depending on whether the acid treatment was performed. Meanwhile, according to FIGS. 43 and 44, the external quantum efficiency of the analysis device 2b was significantly lower than that of the analysis device 2a. That is, in the case of using Li as the metal element, the acid treatment significantly decreased the external quantum efficiency of the light-emitting device.

The above results show that In has higher resistance to acid treatment than Li and is a metal that is preferable for the light-emitting device of one embodiment of the present invention.

### Example 4

In this example, results of several measurements on a device 1 are described. The device 1 is a light-emitting device of one embodiment of the present invention in which a layer having the same structure as the mixed film 1 whose absorption spectrum has been measured in Example 1 is used as the first layer of the intermediate layer. The following are structural formulae of organic compounds used in this example.

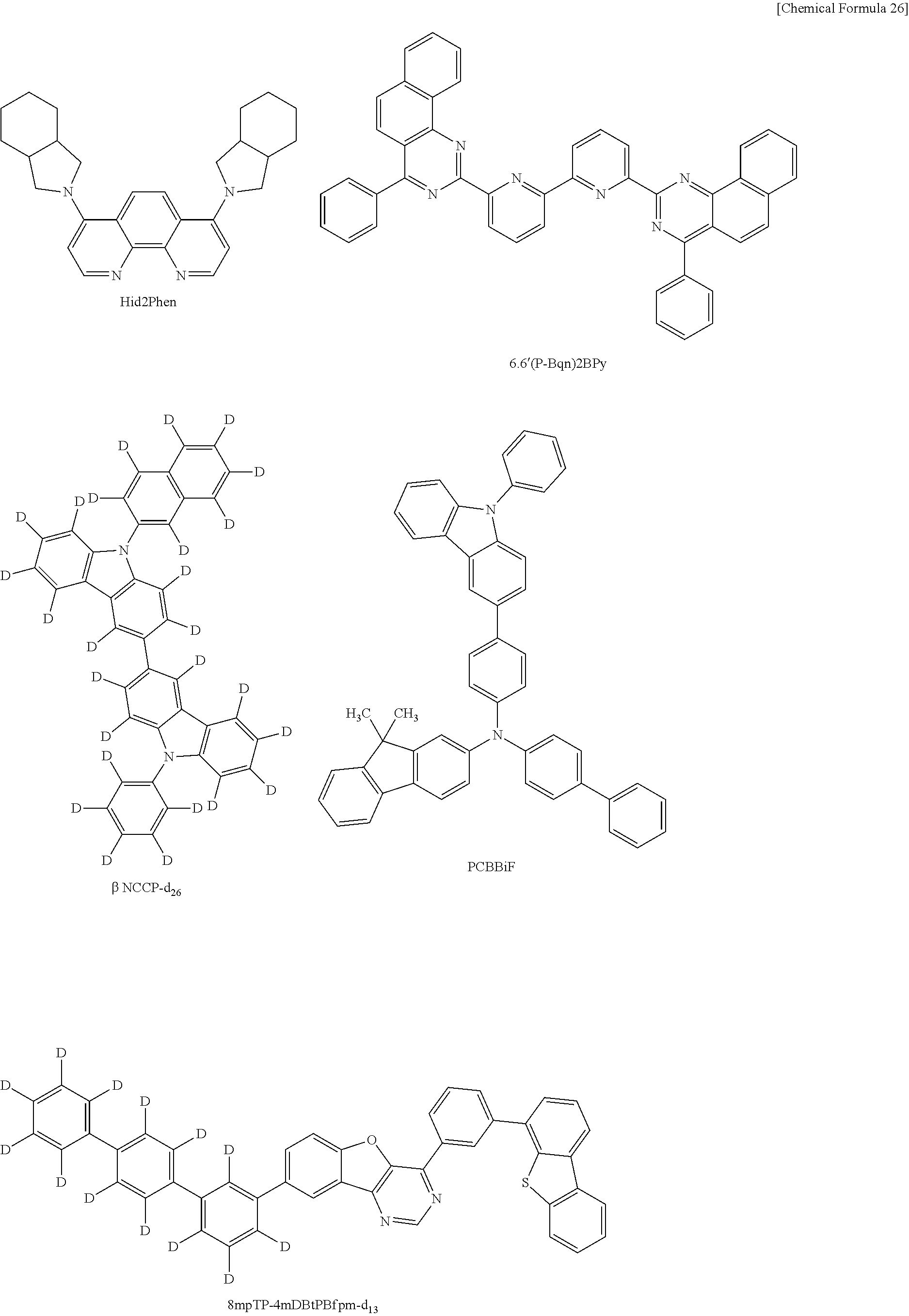

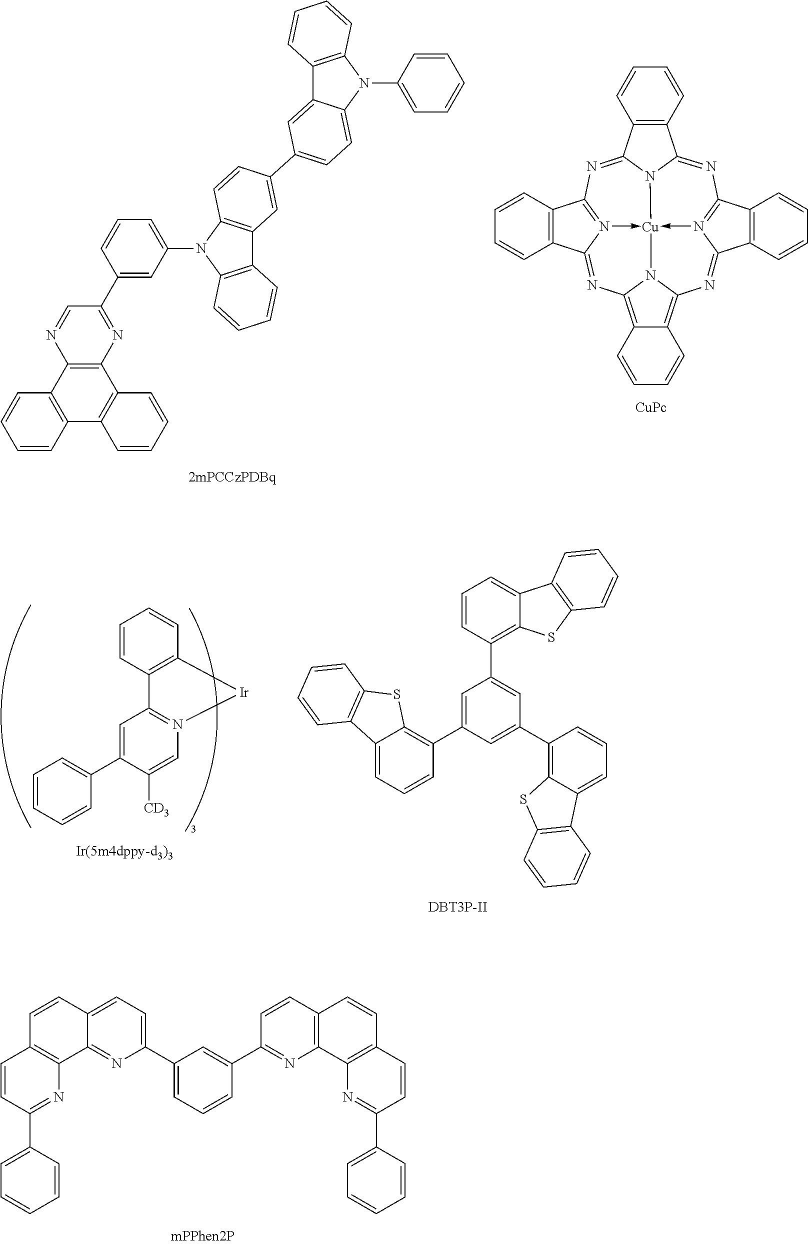

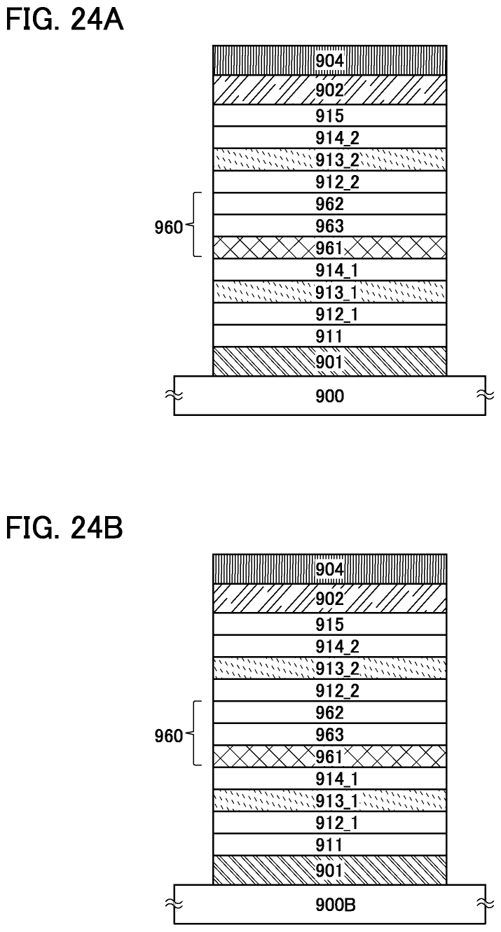

As illustrated in FIG. 24A, a device 1, a comparative device 2, and a comparative device 3 each have a structure in which the first electrode 901, the hole-injection layer 911, the first hole-transport layer 912_1, the first light-emitting layer 9131, the first electron-transport layer 9141, the intermediate layer 960 (the first layer 961, the third layer 963, and the second layer 962), the second hole-transport layer 912_2, the second light-emitting layer 9132, the second electron-transport layer 9142, an electron-injection layer 915, the second electrode 902, and the cap layer 904 are stacked in this order over the glass substrate 900. Methods for fabricating the device 1, the comparative device 2, and the comparative device 3 are described below.

### (Method for Fabricating Device 1)

An alloy containing silver (Ag), palladium (Pd), and copper (Cu) (abbreviation: APC) was deposited by a sputtering method to a thickness of 100 nm as a reflective electrode over the glass substrate 900, and then indium tin oxide containing silicon oxide (ITSO) was deposited by a sputtering method to a thickness of 50 nm as a transparent electrode, whereby the first electrode 901 was formed. Note that the transparent electrode functions as the anode, and the transparent electrode and the reflective electrode can be collectively regarded as the first electrode 901. The electrode area was set to 4 mm² (2 mm×2 mm).

Next, in pretreatment for forming the light-emitting device over the substrate, the substrate surface was washed with water and baking was performed at 200 °C for 1 hour. Then, the substrate was transferred into a vacuum evaporation apparatus where the pressure was reduced to approximately 1×10⁻⁴ Pa, and was subjected to heat treatment at 170 °C for 30 minutes in a heating chamber of the vacuum evaporation apparatus, and then the substrate was cooled down for approximately 30 minutes.

Next, the substrate was fixed to a substrate holder provided in a vacuum evaporation apparatus such that the surface on which the first electrode 901 was formed faced downward. Over the first electrode 901, PCBBiF and OCHD-003 were deposited by co-evaporation to a thickness of 10 nm at a weight ratio of 1:0.03 (PCBBiF: OCHD-003), whereby the hole-injection layer 911 was formed.

Over the hole-injection layer 911, PCBBiF was deposited by evaporation to a thickness of 125 nm, whereby the first hole-transport layer 9121 was formed.

Then, over the first hole-transport layer 912_1, 8-([1,1′:4′,1″-terphenyl-2,4,5,6,2′,3′,5′,6′,2″,3″,4″,5″,6″-d₁₃]-3-yl)-4-[3-(dibenzothiophen-4-yl)phenyl]-[1]benzofuro[3,2-d]pyrimidine (abbreviation: 8mpTP-4mDBtPBfpm-di₃), 9-(2-naphthyl-1,3,4,5,6,7,8-d₇)-9′-(phenyl-2,3,4,5,6-d₅)-3,3′-bi-9H-carbazole-1,1′,2,2′,4,4′,5,5′,6,6′,7,7′,8,8′-di₄ (abbreviation: βNCCP-d₂₆), and tris{2-[5-(methyl-d₃)-4-phenyl-2-pyridinyl-κN]phenyl-κC}iridium(III) (abbreviation: Ir(5m4dppy-d₃)₃) were deposited by co-evaporation to a thickness of 40 nm at a weight ratio of 0.5:0.5:0.1 (=8mpTP-4mDBtPBfpm-di₃: βNCCP-d₂₆: Ir(5m4dppy-d₃)₃), whereby the first light-emitting layer 913_1 was formed.

Next, 2mPCCzPDBq was deposited by evaporation to a thickness of 20 nm, whereby the first electron-transport layer 914_1 was formed.

After the formation of the first electron-transport layer 9141, Hid2Phen, 6,6′(P-Bqn)2BPy, and In were deposited by co-evaporation to a thickness of 5 nm at a volume ratio of 0.5:0.5:0.02 (=Hid2Phen: 6,6′(P-Bqn)2BPy: In), whereby the first layer 961 was formed.

Then, CuPc was deposited to a thickness of 2 nm, whereby the third layer 963 was formed.

Furthermore, PCBBiF and OCHD-003 were deposited by co-evaporation to a thickness of 10 nm at a weight ratio of 1:0.15 (PCBBiF: OCHD-003), whereby the second layer 962 was formed.

Next, PCBBiF was deposited by evaporation to a thickness of 50 nm over the second layer 962, whereby the second hole-transport layer 912_2 was formed.

Over the second hole-transport layer 912_2, 8mpTP-4mDBtPBfpm-d₁₃, βNCCP-d₂₆, and Ir(5m4dppy-d₃)₃ were deposited by co-evaporation to a thickness of 40 nm at a weight ratio of 0.5:0.5:0.1 (=8mpTP-4mDBtPBfpm-di₃: βNCCP-d₂₆: Ir(5m4dppy-d₃)₃), whereby the second light-emitting layer 913_2 was formed.

Then, 2mPCCzPDBq was deposited by evaporation to a thickness of 20 nm, and mPPhen2P was further deposited by evaporation to a thickness of 20 nm, whereby the second electron-transport layer 914_2 was formed.

After the second electron-transport layer 914_2 was formed, the substrate was taken out from the vacuum evaporation apparatus and exposed to the air. Then, as a first sacrificial layer, a film of aluminum oxide was deposited to a thickness of 30 nm by an ALD method using trimethylaluminum (abbreviation: TMA) as a precursor and water vapor as an oxidizer.

Next, molybdenum was deposited to a thickness of 50 nm over the first sacrificial layer by a sputtering method to form a second sacrificial layer.

Next, a resist was formed using a photoresist over the second sacrificial layer, and the organic compound layer was processed by a photolithography method such that an end portion of the organic compound layer was located outward from an end surface of the first electrode. Specifically, processing was performed such that a slit with a width of 3 μm was formed at a position 3.5 μm away from an end portion of the first electrode.

Specifically, the second sacrificial layer was processed using an etching gas containing sulfur hexafluoride (SF₆) and oxygen (O₂) at a SF₆: O₂ flow rate ratio of 10:4 and an etching gas containing oxygen (O₂) with the use of the resist as a mask and then, the first sacrificial layer was processed using an etching gas containing fluoroform (CHF₃) and helium (He) at a CHF₃: He flow rate ratio of 1:49. Then, the organic compound layer (the second electron-transport layer 914_2, the second light-emitting layer 913_2, the second hole-transport layer 912_2, the intermediate layer 960, the first electron-transport layer 914_1, the first light-emitting layer 913_1, the first hole-transport layer 9121, and the hole-injection layer 911) were processed using an etching gas containing oxygen (O₂).

After the organic compound layer was processed by a photolithography method, the second sacrificial layer was removed using an etching gas containing SF₆ and O₂, and then the first sacrificial layer was removed using an aqueous solution containing a hydrofluoric acid and a phosphoric acid, so that the top surface of the second electron-transport layer 914_2 was exposed. Then, the substrate was transferred into a vacuum evaporation apparatus where the pressure was reduced to approximately 1×10⁻⁴ Pa, and heat treatment was performed at 100 °C for 1 hour in a heating chamber of the vacuum evaporation apparatus.

Next, over the exposed second electron-transport layer 914_2, lithium fluoride (LiF) and ytterbium (Yb) were deposited by co-evaporation to a thickness of 1.5 nm at a volume ratio of 2:1 (═LiF: Yb) to form the electron-injection layer, and silver (Ag) and magnesium (Mg) were deposited by co-evaporation to a thickness of 15 nm at a volume ratio of 1:0.1 (═Ag: Mg) to form the second electrode 902.

The second electrode 902 is a semi-transmissive and semi-reflective electrode having a function of reflecting light and a function of transmitting light; thus, the light-emitting device of this example is a top-emission tandem device from which light is extracted through the second electrode. Over the second electrode, DBT3P-II was deposited by evaporation to a thickness of 70 nm as the cap layer 904 to improve light extraction efficiency.

### (Method for Fabricating Comparative Device 2)

The comparative device 2 is different from the device 1 in that the first layer 961 was formed by depositing Hid2Phen and In by co-evaporation to a thickness of 5 nm at a volume ratio of 1:0.02 (=Hid2Phen: In) after the formation of the first electron-transport layer 914_1. Except for this, the comparative device 2 was fabricated in a manner similar to that of the device 1.

### (Method for Fabricating Comparative Device 3)

The comparative device 3 is different from the device 1 in that the first layer 961 was formed by depositing 6,6′(P-Bqn)2BPy and In by co-evaporation to a thickness of 5 nm at a volume ratio of 1:0.02 (=6,6′(P-Bqn)2BPy: In) after the formation of the first electron-transport layer 914_1. Except for this, the comparative device 3 was fabricated in a manner similar to that of the device 1.

Table 11 shows the device structures of the device 1 and the comparative devices 2 and 3.

TABLE 11

| | | | |
|---|---|---|---|
| Thickness | Device 1 | Comparative device 2 | Comparative device 3 |

| | | | |
|---|---|---|---|
| Cap layer | 70 | nm | DBT3P-II |
| Second electrode | 15 | nm | Ag:Mg (1:0.1) |
| Electron-injection layer | 1.5 | nm | LiF:Yb (2:1) |

Processed by photolithography method

| | | | | |
|---|---|---|---|---|
| Second electron- | 2 | 20 | nm | mPPhen2P |
| transport layer | 1 | 20 | nm | 2mPCCzPDBq |

| Second light-emitting | 40 | nm | 8mpTP-4mDBtPBfpm-d₁₃:βNCCP-d₂₆:Ir(5m4dppy-d₃)₃ | | |
|---|---|---|---|---|---|
| layer | | | (0.5:0.5:0.1) | | |
| Second hole-transport | 50 | nm | PCBBiF | | |
| layer | | | | | |
| Second layer | 10 | nm | PCBBiF:OCHD-003 (1:0.15) | | |
| Third layer | 2 | nm | CuPc | | |
| First layer | 5 | nm | Hid2Phen:6,6′(P-Bqn)2BPy:In | Hid2Phen:In | 6,6′(P-Bqn)2BPy:In |
| | | | (0.5:0.5:0.02) | (1:0.02) | (1:0.02) |
| First electron-transport | 20 | nm | 2mPCCzPDBq | | |
| layer | | | | | |

| First light-emitting layer | | 40 | nm | 8mpTP-4mDBtPBfpm-d₁₃:βNCCP-d₂₆:Ir(5m4dppy-d₃)₃ |
|---|---|---|---|---|
| | | | | (0.5:0.5:0.1) |
| First hole-transport layer | | 125 | nm | PCBBiF |
| Hole-injection layer | | 10 | nm | PCBBiF:OCHD-003 (1:0.03) |
| First electrode | 2 | 50 | nm | ITSO |
| | 1 | 100 | nm | APC |

| | | |
|---|---|---|
| Substrate | — | Glass |

Each of the fabricated light-emitting devices was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80 °C under an atmospheric pressure for 1 hour. Then, the initial characteristics of the light-emitting devices were measured.

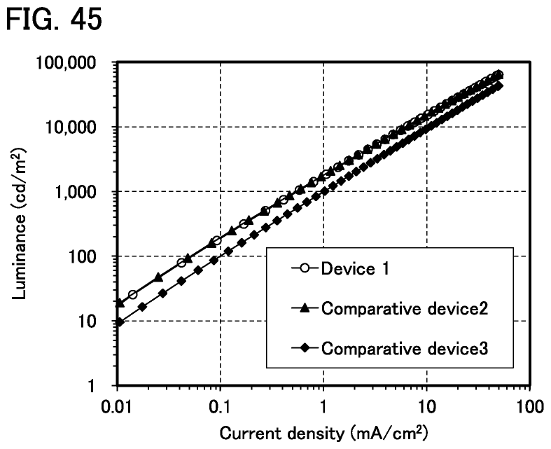

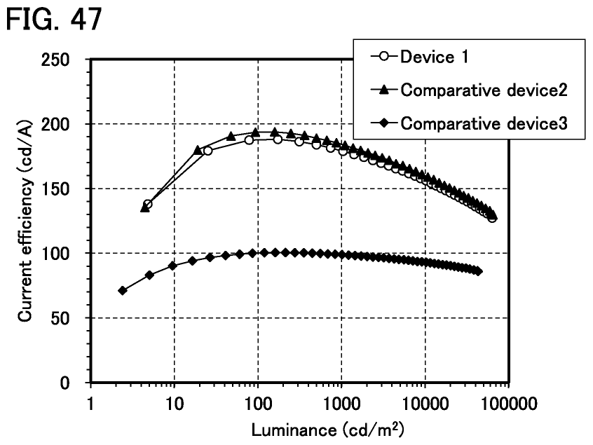

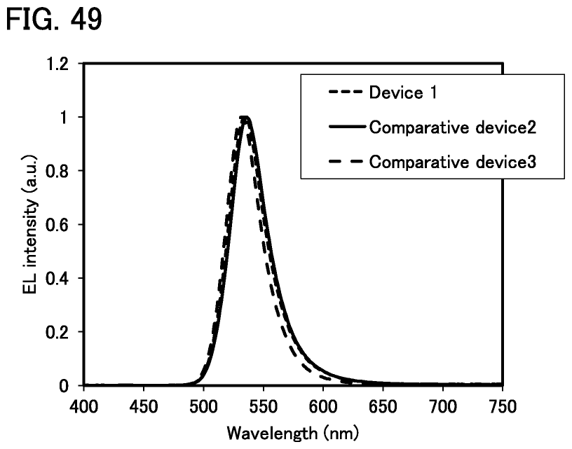

FIGS. 45, 46, 47, 48, and 49 respectively illustrate luminance-current density characteristics, luminance-voltage characteristics, current efficiency-luminance characteristics, current density-voltage characteristics, and the electroluminescence spectra of the device 1 and the comparative devices 2 and 3.

Table 12 shows the main characteristics of the device 1 and the comparative devices 2 and 3 at a luminance of approximately 1000 cd/m². The luminance, CIE chromaticity, and electroluminescence spectra were measured at normal temperature with a spectroradiometer (SR-UL1R produced by TOPCON TECHNOHOUSE CORPORATION).

TABLE 12

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Device 1 | 5.80 | 0.0233 | 0.584 | 0.278 | 0.692 | 1043 | 179 |
| Comparative device 2 | 6.40 | 0.0240 | 0.601 | 0.285 | 0.688 | 1101 | 183 |
| Comparative device 3 | 8.80 | 0.0410 | 1.03 | 0.251 | 0.712 | 1012 | 98.7 |

FIGS. 45 to 49 and Table 12 have revealed that the device 1 is a tandem light-emitting device that exhibits green light emission derived from Ir(5m4dppy-d₃)₃ and has favorable emission characteristics.

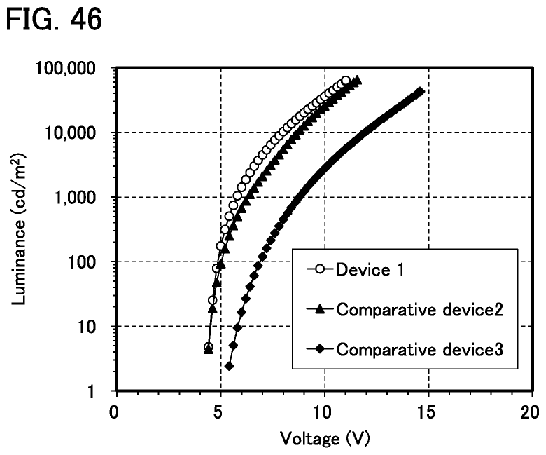

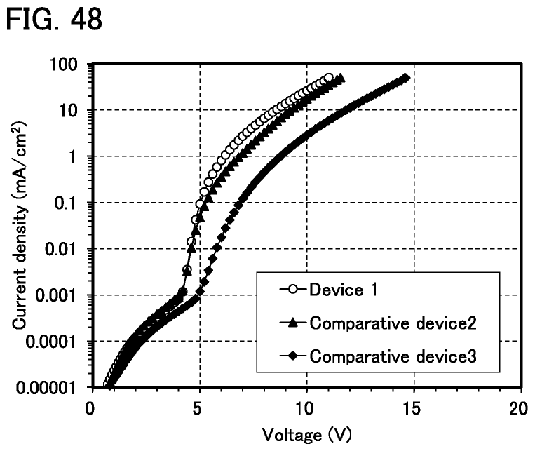

FIGS. 46 to 48 show that the device 1 has lower driving voltage and higher current efficiency than the comparative device 3. Furthermore, FIGS. 46 and 48 and Table 12 show that the device 1 is a light-emitting device having a lower driving voltage than the comparative device 2.

The above results show that the light-emitting device of one embodiment of the present invention has favorable characteristics.

### Example 5

In this example, results of several analyses on 4,7-di-1-pyrrolidinyl-1,10-phenanthroline (abbreviation: Pyrrd-Phen) and 4,7-diphenyl-2,9-bis(4-(1-phenyl-1H-benzo[d]imidazol-2-yl)phenyl)-1,10-phenanthroline (abbreviation: DBimiBphen), which are organic compounds that can be used for the layer 200 of the light-emitting device of one embodiment of the present invention, are described. Note that the vapor deposition method, the method for measuring the absorption spectrum, the method for calculating the absorption edge on the long wavelength side of the absorption spectrum, the method for calculating the HOMO and LUMO levels, and the like are similar to those described in Example 1. The following are structural formulae of the organic compounds used in this example.

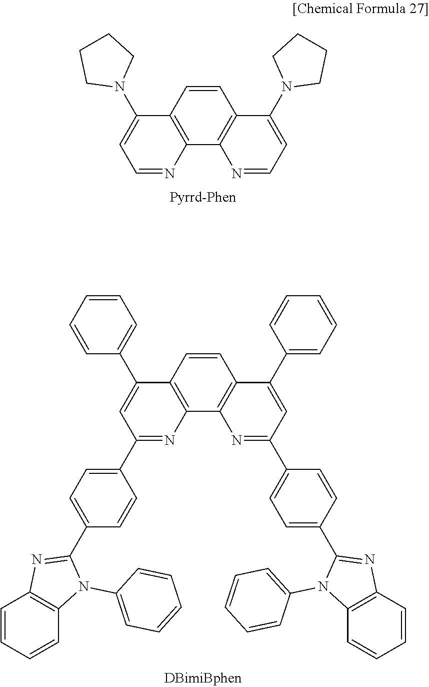 [SMILES: c1cc(N2CCCC2)c2ccc3c(N4CCCC4)ccnc3c2n1 ; c1ccc(-c2cc(-c3ccc(-c4nc5ccccc5n4-c4ccccc4)cc3)nc3c2ccc2c(-c4ccccc4)cc(-c4ccc(-c5nc6ccccc6n5-c5ccccc5)cc4)nc23)cc1]

### <<Absorption Spectrum Measurement>>

First, results of measuring absorption spectra of single films and mixed films of Pyrrd-Phen, DBimiBphen, and In are described. Materials used for single films 6 to 8 and mixed films 11 to 14 used for the absorption spectrum measurement are described below.

### <Single Film 6>

Over a quartz substrate, Pyrrd-Phen was deposited by evaporation to a thickness of 50 nm.

### <Single Film 7>

Over a quartz substrate, DBimiBphen was deposited by evaporation to a thickness of 50 nm.

### <Single Film 8>

Over a quartz substrate, In was deposited by evaporation to a thickness of 1 nm.

### <Mixed Film 11>

Over a quartz substrate, Pyrrd-Phen, DBimiBphen, and In were deposited by co-evaporation to a thickness of 50 nm at a volume ratio of 0.5:0.5:0.02 (=Pyrrd-Phen: DBimiBphen: In).

### <Mixed Film 12>

Over a quartz substrate, Pyrrd-Phen and In were deposited by co-evaporation to a thickness of 50 nm at a volume ratio of 1:0.02 (=Pyrrd-Phen: In).

### <Mixed Film 13>

Over a quartz substrate, DBimiBphen and In were deposited by co-evaporation to a thickness of 50 nm at a volume ratio of 1:0.02 (=DBimiBphen: In).

### <Mixed Film 14>

Over a quartz substrate, Pyrrd-Phen and DBimiBphen were deposited by co-evaporation to a thickness of 50 nm at a volume ratio of 0.5:0.5 (=Pyrrd-Phen: DBimiBphen).

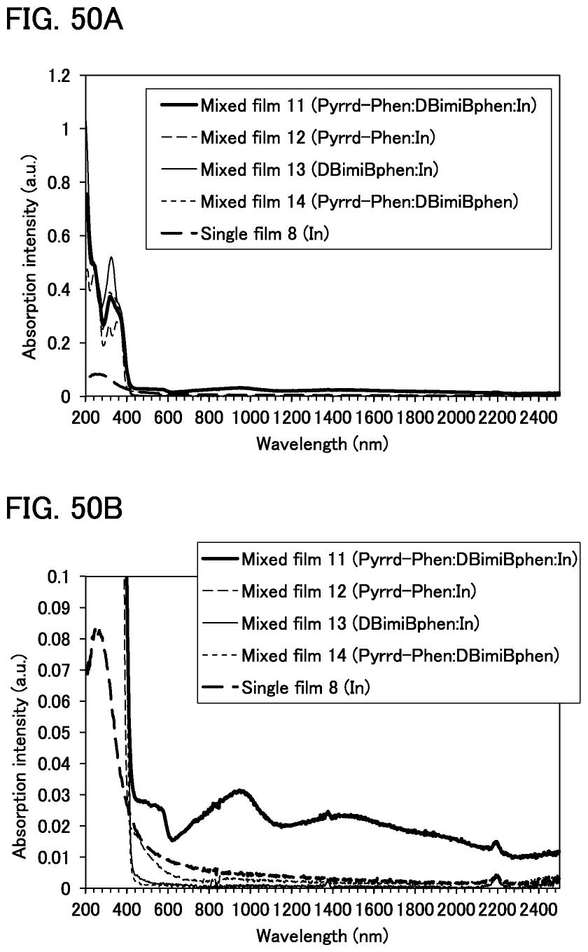

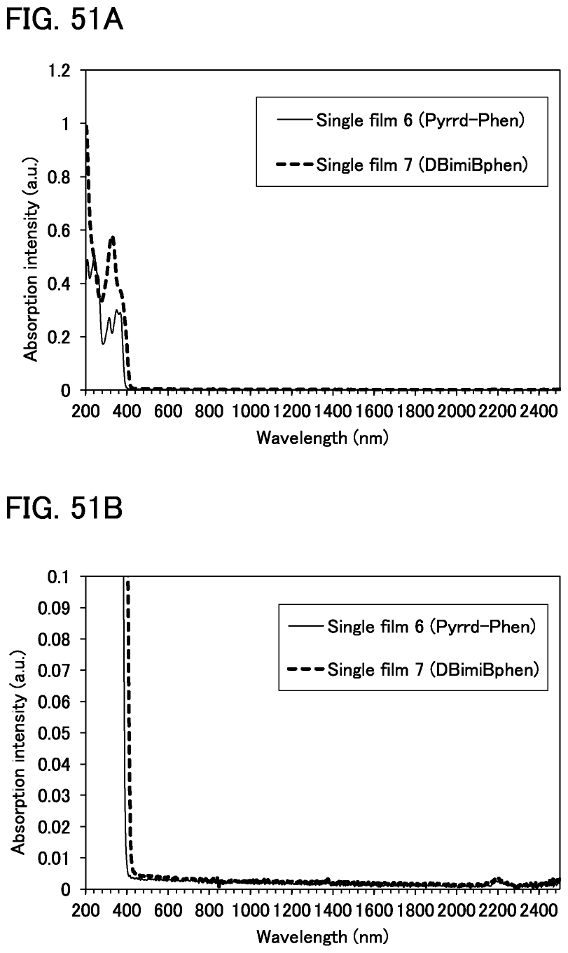

FIG. 50A illustrates absorption spectra of the mixed films 11 to 14 and the single film 8, and FIG. 50B is an enlarged view of the absorption spectra illustrated in FIG. 50A. FIG. 51A illustrates absorption spectra of the single films 6 and 7, and FIG. 51B is an enlarged view of the absorption spectra illustrated in FIG. 51A.

As illustrated in FIGS. 50A and 51A, in the wavelength region of 400 nm to 2500 nm, the absorption spectrum of the mixed film 11 including Pyrrd-Phen, DBimiBphen, and In has an absorption intensity peak that is not observed in the single film 6, the single film 7, the single film 8, the mixed film 12, or the mixed film 13.

As illustrated in FIG. 50B, in the wavelength region of 450 nm to 2500 nm, the absorption spectrum of the mixed film 11 has a higher absorption intensity than the absorption spectrum of the mixed film 12 including Pyrrd-Phen and In. The wavelength region is a region at longer wavelengths than a wavelength (390 nm) of an absorption edge on the long wavelength side of the absorption spectrum of the single film 6 including Pyrrd-Phen, which can be read from FIG. 51A. In the wavelength region of 450 nm to 2500 nm, the absorption spectrum of the mixed film 11 has a higher absorption intensity than the absorption spectrum of the mixed film 13 including DBimiBphen and In. The wavelength region is a region at longer wavelengths than a wavelength (414 nm) of an absorption edge on the long wavelength side of the absorption spectrum of the single film 7 including DBimiBphen, which can be read from FIG. 51A.

This indicates that the combination of Pyrrd-Phen, DBimiBphen, and In can form a charge-transfer complex.

### <<PL Spectrum Measurement>>

PL spectra of the single film 6 (Pyrrd-Phen), the single film 7 (DBimiBphen), and the mixed film 14 (Pyrrd-Phen and DBimiBphen) were measured. The measurement was performed at room temperature with a fluorescence spectrophotometer (FP-8600 manufactured by JASCO Corporation).

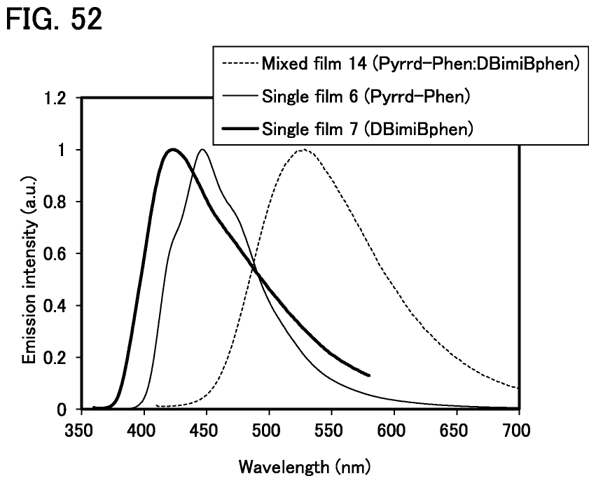

FIG. 52 illustrates the PL spectra of the single film 6, the single film 7, and the mixed film 14. As illustrated in FIG. 52, the PL spectrum of the mixed film 14 is positioned on the long wavelength side of the PL spectra of the single films 6 and 7; thus, the combination of Pyrrd-Phen and DBimiBphen was found to form an exciplex.

More specifically, the peak wavelength (530 nm) of the PL spectrum of the mixed film 14 is longer than the peak wavelength (424 nm) of the PL spectrum of the single film 6 (Pyrrd-Phen) and the peak wavelength (447 nm) of the PL spectrum of the single film 7 (DBimiBphen) at room temperature. Furthermore, a wavelength of the emission edge (459 nm) on the short wavelength side of the PL spectrum of the mixed film 14 is longer than a wavelength of the emission edge (380 nm) on the short wavelength side of the PL spectrum of the single film 6 and a wavelength of the emission edge (402 nm) on the short wavelength side of the PL spectrum of the single film 7 at room temperature. This also indicates that Pyrrd-Phen and DBimiBphen form an exciplex in combination.

### <<HOMO Level and LUMO Level>>

The HOMO level and the LUMO level of Pyrrd-Phen obtained by cyclic voltammetry (CV) measurement were −5.8 eV and −2.55 eV, respectively. The LUMO level of DBimiBphen was −2.92 eV. Since the oxidation potential of DBimiBphen was high and the peak potential thereof was not observed, the HOMO level of DBimiBphen was found to be lower than −6.0 eV. Thus, the HOMO level of Pyrrd-Phen is higher than the HOMO level of DBimiBphen, and the LUMO level of Pyrrd-Phen is higher than the LUMO level of DBimiBphen.

The above results show that Pyrrd-Phen, DBimiBphen, and In are a combination that can be preferably used for the layer 200.

### Example 6

In this example, analysis samples and analysis devices using In were fabricated and subjected to several analyses to carry out an analysis of a metal that has high resistance to acid treatment and is preferably used as the metal material 161_M. The analysis results are described. Note that the analysis methods are similar to those in Example 3. The following are structural formulae of the organic compounds used in this example.

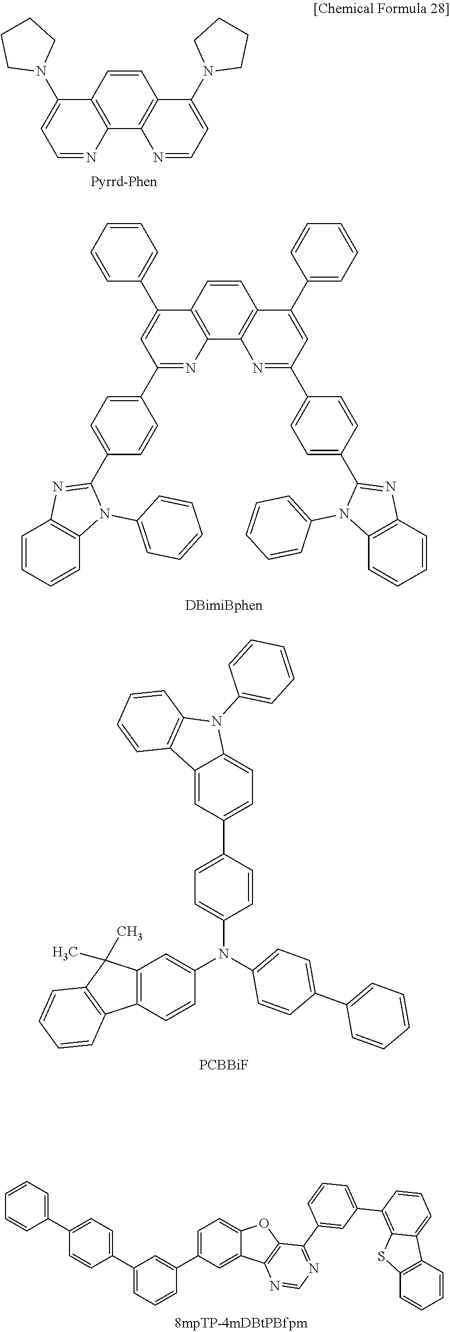

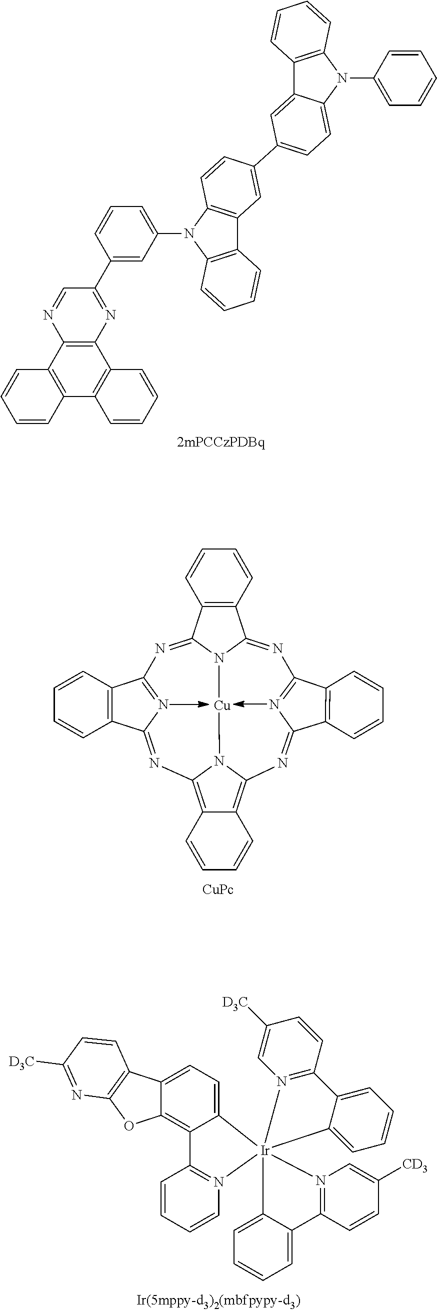

### <<Cross-Sectional STEM Analysis and SIMS Analysis>>

First, analysis samples 6a, 6b, 6c, and 6d each having a stacked-layer structure that imitates the intermediate layer and the second hole-transport layer of the light-emitting device of one embodiment of the present invention were fabricated, and cross-sectional STEM analysis and SIMS analysis were performed. As illustrated in FIG. 23B, the analysis samples 6a and 6b each have a structure in which the first layer 961, the third layer 963, the second layer 962, and the second hole-transport layer 912_2 are stacked in this order over the quartz substrate 900A. As illustrated in FIG. 23A, the analysis samples 6c and 6d each have a structure in which the first layer 961, the second layer 962, and the second hole-transport layer 912_2 are stacked in this order over the quartz substrate 900A. Methods for fabricating the analysis samples 6 are described below.

<Analysis Sample 6a>

The analysis sample 6a is different from the analysis sample 4a in that, in the method for fabricating the analysis sample 4a described in Example 3, the first layer 961 was formed by depositing Pyrrd-Phen, DBimiBphen, and In by co-evaporation to a thickness of 11 nm at a volume ratio of 0.2:0.8:0.02 (=Pyrrd-Phen: DBimiBphen: In), the third layer 963 was formed by depositing CuPc to a thickness of 5 nm, and the second layer 962 and the second hole-transport layer 912_2 were respectively formed by depositing PCBBiF and OCHD-003 by co-evaporation at a weight ratio of 1:0.15 (═PCBBiF: OCHD-003) and depositing PCBBiF by evaporation so that the total thickness of the second layer 962 and the second hole-transport layer 9122 could be 22 nm. Except for these, the analysis sample 6a was fabricated in a manner similar to that of the analysis sample 4a.

<Analysis Sample 6b>

The analysis sample 6b is different from the analysis sample 6a in being fabricated through acid treatment after the formation of the first layer 961 and before the formation of the third layer 963, the second layer 962, and the second hole-transport layer 912_2 in the method for fabricating the analysis sample 6a. Except for this, the analysis sample 6b was fabricated in a manner similar to that of the analysis sample 6a. The acid treatment was performed in a manner similar to the method described in Example 3.

<Analysis Sample 6c>

The analysis sample 6c is different from the sample 4a in that, in the method for fabricating the analysis sample 4a described in Example 3, the first layer 961 was formed by depositing Pyrrd-Phen, DBimiBphen, and In by co-evaporation to a thickness of 11 nm at a volume ratio of 0.2:0.8:0.02 (=Pyrrd-Phen: DBimiBphen: In) and the second layer 962 and the second hole-transport layer 9122 were respectively formed by depositing PCBBiF and OCHD-003 by co-evaporation at a weight ratio of 1:0.15 (═PCBBiF: OCHD-003) and depositing PCBBiF by evaporation so that the total thickness of the second layer 962 and the second hole-transport layer 912_2 could be 22 nm. Except for these, the analysis sample 6c was fabricated in a manner similar to that of the analysis sample 4a.

<Analysis Sample 6d>

The analysis sample 6d is different from the analysis sample 6c in being fabricated through acid treatment after the formation of the first layer 961 and before the formation of the second layer 962 and the second hole-transport layer 912_2 in the method for fabricating the analysis sample 6c. Except for this, the analysis sample 6d was fabricated in a manner similar to that of the analysis sample 6c. The acid treatment was performed in a manner similar to the method described in Example 3.

Table 13 shows the stacked-layer structures of the analysis samples 6a to 6d.

TABLE 13

| | | | Analysis | Analysis | Analysis | Analysis |
|---|---|---|---|---|---|---|
| | Thickness | | sample 6a | sample 6b | sample 6c | sample 6d |
| Second hole-transport | 22 | nm | PCBBiF | | | |
| layer | | | | | | |

| Second layer | | | PCBBiF:OCHD-003 (1:0.15) | |
|---|---|---|---|---|
| Third layer | 5 | nm | CuPc | — |

| | | | | |
|---|---|---|---|---|
| Acid treatment | x | ∘ | x | ∘ |

| | | | |
|---|---|---|---|
| First layer | 11 | nm | Pyrrd-Phen:DBimiBphen:In(0.2:0.8:0.02) |
| Substrate | 0.7 | mm | Quartz |

x: Acid treatment not performed
∘: Acid treatment performed

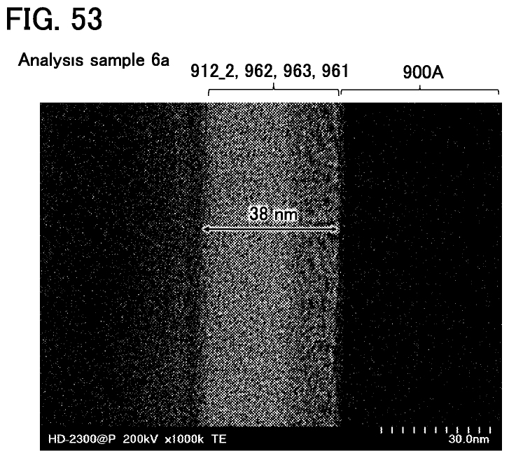

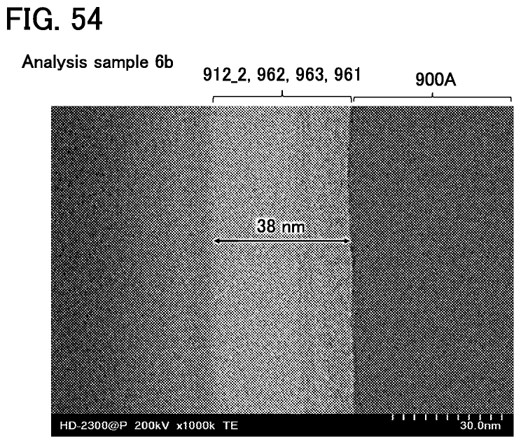

FIGS. 53 and 54 illustrate cross-sectional STEM images obtained by processing the analysis samples 6a and 6B, respectively, with an FIB. In FIGS. 53 and 54, the positions corresponding to the quartz substrate 900A, the first layer 961, the third layer 963, the second layer 962, and the second hole-transport layer 912_2 are denoted by reference numerals.

As illustrated in FIGS. 53 and 54, there was no difference in the thickness of the first layer 961 between the analysis samples 6a and 6b. That is, no change was observed in the thickness of the organic compound layer depending on whether the acid treatment was performed.

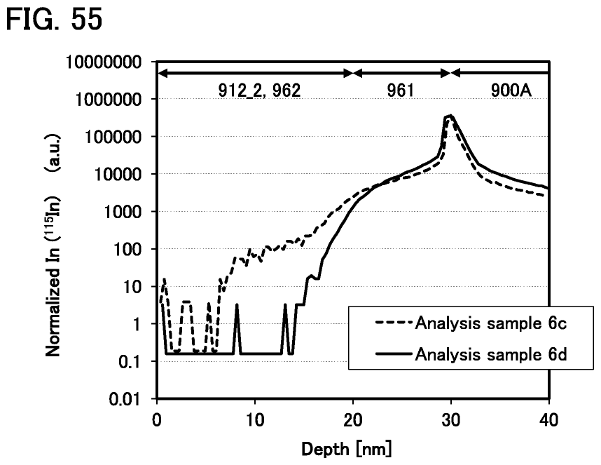

Moreover, SIMS analysis was performed on the analysis samples 6c and 6d. FIG. 55 illustrates ¹¹⁵In profiles of the analysis samples 6c and 6d measured by SIMS analysis. Note that oxygen primary ions (O₂⁺) were used as primary ion species in FIG. 55.

It was found from FIG. 55 that a difference in detection intensity was small between the analysis samples 6c and 6d. That is, the detection intensity for ¹¹⁵In did not change depending on whether the acid treatment was performed.

The above results show that the acid treatment did not change the thickness of the first layer 961 and caused no leakage of In.

### <<Examination of Characteristics of Light-Emitting Device>>

Next, an analysis device 3 that is a light-emitting device for analysis having a stacked-layer structure imitating the first electrode, the hole-injection layer, the first hole-transport layer, the first light-emitting layer, and the intermediate layer of the light-emitting device of one embodiment of the present invention was fabricated and subjected to several measurements. The measurement results are described. As illustrated in FIG. 23C, the analysis device 3 has a structure in which the first electrode 901, the hole-injection layer 911, the first hole-transport layer 912_1, the first light-emitting layer 913_1, the first electron-transport layer 914_1, the intermediate layer 960 (the first layer 961, the third layer 963, and the second layer 962), and the second electrode 902 are stacked in this order over the glass substrate 900. A method for fabricating the analysis device 3 is described below.

### (Analysis Device 3)

The analysis device 3 is different from the analysis device 1b in that the first layer 961 in the method for fabricating the analysis device 1b described in Example 3 was formed by depositing Pyrrd-Phen, DBimiBphen, and In by co-evaporation to a thickness of 5 nm at a volume ratio of 0.2:0.8:0.02 (=Pyrrd-Phen: DBimiBphen: In). Except for this, the analysis device 3 was fabricated in a manner similar to that of the analysis device 1b.

Table 14 shows the device structure of the analysis device 3.

TABLE 14

| | Thickness | | Analysis device 3 |
|---|---|---|---|
| Second electrode | 200 | nm | Al |
| Second layer | 50 | nm | PCBBiF:OCHD-003 (1:0.15) |
| Third layer | 2 | nm | CuPc |
| Acid treatment | | | ∘ |
| First layer | 5 | nm | Pyrrd-Phen:DBimiBphen:In(0.2:0.8:0.02) |
| First electron-transport | 10 | nm | 2mPCCzPDBq |
| layer | | | |
| First light-emitting layer | 40 | nm | 8mpTP-4mDBtPBfpm:βNCCP:Ir(5mppy-d₃)₂(mbfpypy-d₃) |
| | | | (0.5:0.5:0.1) |
| First hole-transport layer | 50 | nm | PCBBiF |
| Hole-injection layer | 10 | nm | PCBBiF:OCHD-003 (1:0.03) |
| First electrode | 70 | nm | ITSO |

| | | |
|---|---|---|
| Substrate | — | Glass |

O:Acid treatment performed

The fabricated analysis device 3 was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80 °C under an atmospheric pressure for 1 hour. Then, the initial characteristics of the analysis device 3 were measured.

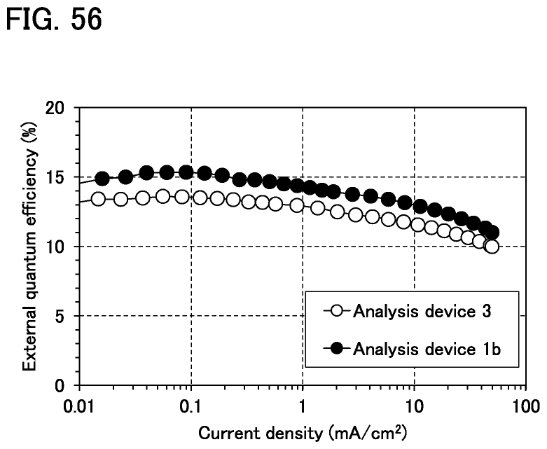

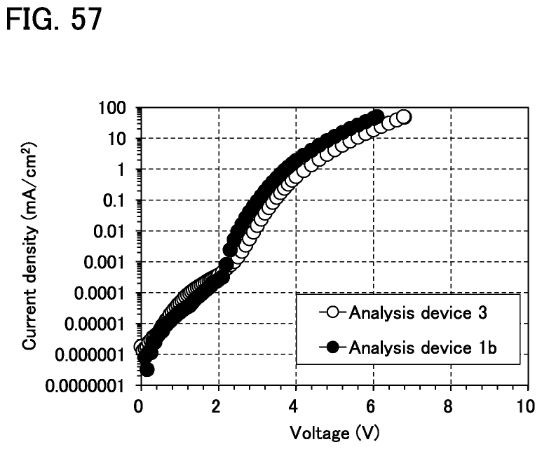

FIGS. 56 and 57 respectively illustrate external quantum efficiency-current density characteristics and current density-voltage characteristics of the analysis device 3. FIGS. 56 and 57 also illustrate the measured initial characteristics of the analysis device 1b. Note that the analysis device 1b used for the measurement of the initial characteristics illustrated in FIGS. 41 and 42 and the analysis device 1b used for the measurement of the initial characteristics illustrated in FIGS. 56 and 57 are different samples fabricated by the same method.

FIGS. 56 and 57 show that the analysis device 3 is a light-emitting device having high external quantum efficiency, low drive voltage, and favorable characteristics even though having been subjected to the acid treatment in a manner similar to that of the analysis sample 1b.

The above results show that the combination of Pyrrd-Phen, DBimiBphen, and In has high resistance to acid treatment and thus is preferable for the light-emitting device of one embodiment of the present invention.

### Example 7

In this example, a light-emitting device (a device 4) of one embodiment of the present invention in which a layer including Hid2Phen, 6,6′(P-Bqn)2BPy, and In whose absorption spectrum was measured in Example 1 was used as the first layer of the intermediate layer and a light-emitting device (a device 5) of one embodiment of the present invention in which a layer including Pyrrd-Phen, DBimiBphen, and In whose absorption spectrum was measured in Example 5 was used as the first layer of the intermediate layer were fabricated and subjected to several measurements. The measurement results are described. The following are structural formulae of organic compounds used in this example.

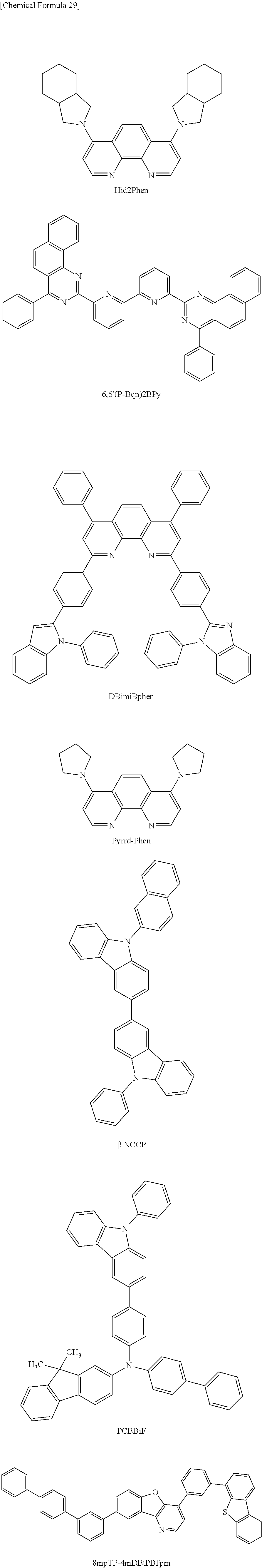

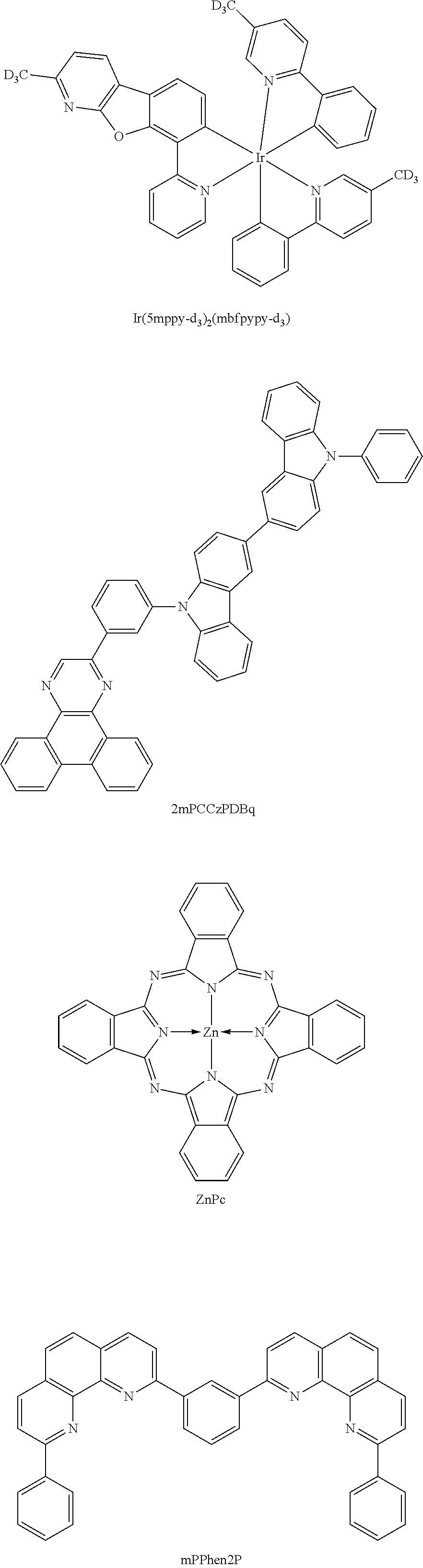

As illustrated in FIG. 24B, the devices 4 and 5 each have a structure in which the first electrode 901, the hole-injection layer 911, the first hole-transport layer 912_1, the first light-emitting layer 913_1, the first electron-transport layer 914_1, the intermediate layer 960 (the first layer 961, the third layer 963, and the second layer 962), the second hole-transport layer 9122, the second light-emitting layer 9132, the second electron-transport layer 9142, the electron-injection layer 915, the second electrode 902, and the cap layer 904 are stacked in this order over a silicon substrate 900B. Methods for fabricating the devices 4 and 5 are described below.

<METHOD for fabricating device 4>

First, over the silicon substrate 900B provided with wirings, titanium nitride (TiN), titanium (Ti), aluminum (Al), and Ti were stacked in this order by a sputtering method to have thicknesses of 1 nm, 49 nm, 70 nm, and 2 nm, respectively, and then indium tin oxide containing silicon oxide (ITSO) was stacked by a sputtering method to have a thickness of 10 nm. Then, these layers were processed to have a resolution of 5009 ppi by a lithography method, whereby the first electrode 901 was formed.

Next, in pretreatment for forming the light-emitting device over the substrate, the substrate was subjected to heat treatment at 120 °C for 120 seconds, and then 1,1,1,3,3,3-hexamethyldisilazane (abbreviation: HMDS) was vaporized and sprayed for 120 seconds to the substrate heated to 60 °C This can make it difficult for the stacked-layer film formed over the first electrode 901 to be separated from the first electrode 901 in the fabrication process.

Then, the substrate was transferred into a vacuum evaporation apparatus where the pressure was reduced to approximately 1×10⁻⁴ Pa, and was subjected to vacuum baking at 170°C. for 30 minutes in a heating chamber of the vacuum evaporation apparatus, and then the substrate was cooled down for approximately 30 minutes.

Next, the substrate was fixed to a substrate holder provided in a vacuum evaporation apparatus such that the surface on which the first electrode 901 was formed faced downward. Over the first electrode 901, PCBBiF and OCHD-003 were deposited by co-evaporation to a thickness of 10 nm at a weight ratio of 1:0.03 (═PCBBiF: OCHD-003), whereby the hole-injection layer 911 was formed.

Over the hole-injection layer 911, PCBBiF was deposited by evaporation to a thickness of 30 nm, whereby the first hole-transport layer 912_1 was formed.

Then, over the first hole-transport layer 912_1, 8mpTP-4mDBtPBfpm, βNCCP, and Ir(5mppy-d₃)₂(mbfpypy-d₃) were deposited by co-evaporation to a thickness of 40 nm at a weight ratio of 0.5:0.5:0.1 (=8mpTP-4mDBtPBfpm: βNCCP: Ir(5mppy-d₃)₂(mbfpypy-d₃)), whereby the first light-emitting layer 913_1 was formed.

Next, 2mPCCzPDBq was deposited by evaporation to a thickness of 10 nm, whereby the first electron-transport layer 914_1 was formed.

After the formation of the first electron-transport layer 9141, Hid2Phen, 6,6′(P-Bqn)2BPy, and In were deposited by co-evaporation to a thickness of 5 nm at a volume ratio of 0.5:0.5:0.02 (=Hid2Phen: 6,6′(P-Bqn)2BPy: In), whereby the first layer 961 was formed.

Next, zinc phthalocyanine (abbreviation: ZnPc) was deposited to a thickness of 2 nm, whereby the third layer 963 was formed.

Furthermore, PCBBiF and OCHD-003 were deposited by co-evaporation to a thickness of 10 nm at a weight ratio of 1:0.15 (PCBBiF: OCHD-003), whereby the second layer 962 was formed.

Next, PCBBiF was deposited by evaporation to a thickness of 50 nm over the second layer 962, whereby the second hole-transport layer 912_2 was formed.

Over the second hole-transport layer 912_2, 8mpTP-4mDBtPBfpm, βNCCP, and Ir(5mppy-d3)2(mbfpypy-d3) were deposited by co-evaporation to a thickness of 40 nm at a weight ratio of 0.5:0.5:0.1 (=8mpTP-4mDBtPBfpm: βNCCP: Ir(5mppy-d₃)₂(mbfpypy-d₃)), whereby the second light-emitting layer 913_2 was formed.

Then, 2mPCCzPDBq was deposited by evaporation to a thickness of 10 nm, and mPPhen2P was further deposited by evaporation to a thickness of 20 nm, whereby the second electron-transport layer 914_2 was formed.

After the second electron-transport layer 914_2 was formed, the substrate was taken out from the vacuum evaporation apparatus and exposed to the air. Then, as a first sacrificial layer, a film of aluminum oxide was deposited to a thickness of 30 nm by an ALD method using trimethylaluminum (abbreviation: TMA) as a precursor and water vapor as an oxidizer.

Next, tungsten (W) was deposited to a thickness of 54 nm over the first sacrificial layer by a sputtering method to form a second sacrificial layer.

A photoresist was applied onto the second sacrificial layer, light exposure and development were performed, and processing was performed such that an end portion of the second sacrificial layer was located inward from the end surface of the first electrode. In this way, the organic compound layer can be processed to have a shape in which an end portion of the organic compound layer is located inward from the end surface of the first electrode.

The second sacrificial layer was processed using an etching gas containing SF₆ with the use of the photoresist as a mask and then, the first sacrificial layer was processed using an etching gas containing fluoroform (CHF₃), helium (He), and methane (CH₄) at a CHF₃:He:CH₄ flow rate ratio of 16.5:118.5:15 with the use of the second sacrificial layer as a hard mask. Then, the organic compound layer (the second electron-transport layer 914_2, the second light-emitting layer 913_2, the second hole-transport layer 912_2, the intermediate layer 960, the first electron-transport layer 914_1, the first light-emitting layer 913_1, the first hole-transport layer 912_1, and the hole-injection layer 911) was processed using an etching gas containing oxygen (O₂).

After the organic compound layer was processed, the second sacrificial layer was removed using an etching gas containing SF₆, whereas the first sacrificial layer was left. Then, aluminum oxide was deposited to a thickness of 15 nm by an ALD method, whereby an insulating layer was formed.

Next, a photosensitive high molecular material was provided by a photolithography method between a plurality of organic compound layers to form an insulating layer, and then an unnecessary portion of the insulating layer was removed using a mixed acid aqueous solution containing hydrofluoric acid (HF). After heating was performed at 100 °C in an air atmosphere for 10 minutes, unnecessary portions of the first sacrificial layer were removed using a mixed acid aqueous solution containing hydrofluoric acid (HF), so that the top surface of the second electron-transport layer 914_2 was exposed. Then, the substrate was transferred into a vacuum evaporation apparatus where the pressure was reduced to approximately 1×10⁻⁴ Pa, and vacuum baking was performed at 100 °C for 90 minutes in a heating chamber of the vacuum evaporation apparatus.

Next, over the exposed second electron-transport layer 9142, lithium fluoride (LiF) and ytterbium (Yb) were deposited by co-evaporation to a thickness of 1.5 nm at a volume ratio of 2:1 (═LiF: Yb) to form the electron-injection layer 915, and silver (Ag) and magnesium (Mg) were deposited by co-evaporation to a thickness of 15 nm at a volume ratio of 1:0.1 (═Ag: Mg) to form the second electrode 902.

The second electrode 902 is a semi-transmissive and semi-reflective electrode having a function of reflecting light and a function of transmitting light; thus, the light-emitting device of this example is a top-emission tandem device from which light is extracted through the second electrode. Over the second electrode, ITO (indium oxide-tin oxide) was deposited by a sputtering method to a thickness of 70 nm to form the cap layer 904.

### <Method for Fabricating Device 5>

The device 5 is different from the device 4 in that the first layer 961 was formed by depositing Pyrrd-Phen, DBimiBphen, and In by co-evaporation to a thickness of 5 nm at a volume ratio of 0.2:0.8:0.02 (=Pyrrd-Phen: DBimiBphen: In) after the formation of the first electron-transport layer 914_1 in the method for fabricating the device 4. Except for this, the device 5 was fabricated in a manner similar to that of the device 4.

Table 15 shows the structures of the devices 4 and 5.

TABLE 15

| | | |
|---|---|---|
| Thickness | Device 4 | Device 5 |

| | | | |
|---|---|---|---|
| Cap layer | 70 | nm | ITO |
| Second electrode | 15 | nm | Ag:Mg (1:0.1) |
| Electron-injection layer | 1.5 | nm | LiF:Yb (2:1) |

Processed by photolithography method

| Second electron- | 2 | 20 | nm | mPPhen2P | |
|---|---|---|---|---|---|
| transport layer | 1 | 10 | nm | 2mPCCzPDBq | |
| Second light-emitting layer | | 40 | nm | 8mpTP-4mDBtPBfpm:βNCCP:Ir(5mppy-d₃)₂(mbfpypy-d₃) | |
| | | | | (0.5:0.5:0.1) | |
| Second hole-transport | | 50 | nm | PCBBiF | |
| layer | | | | | |
| Second layer | | 10 | nm | PCBBiF:OCHD-003 (1:0.15) | |
| Third layer | | 2 | nm | ZnPc | |
| First layer | | 5 | nm | Hid2Phen:6,6′(P-Bqn)2BPy:In | Pyrrd-Phen:DBimiBphen:In |
| | | | | (0.5:0.5:0.02) | (0.2:0.8:0.02) |
| First electron-transport | | 10 | nm | 2mPCCzPDBq | |
| layer | | | | | |

| | | | | |
|---|---|---|---|---|
| First light-emitting layer | | 40 | nm | 8mpTP-4mDBtPBfpm:βNCCP:Ir(5mppy-d₃)₂(mbfpypy-d₃) |
| | | | | (0.5:0.5:0.1) |
| First hole-transport layer | | 30 | nm | PCBBiF |
| Hole-injection layer | | 10 | nm | PCBBiF:OCHD-003 (1:0.03) |
| First electrode | 5 | 10 | nm | ITSO |
| | 4 | 2 | nm | Ti |
| | 3 | 70 | nm | Al |
| | 2 | 49 | nm | Ti |
| | 1 | 1 | nm | TiN |

| | | |
|---|---|---|
| Substrate | — | Silicon |

Each of the fabricated light-emitting devices was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80 °C under an atmospheric pressure for 1 hour. Then, the initial characteristics of the light-emitting devices were measured.

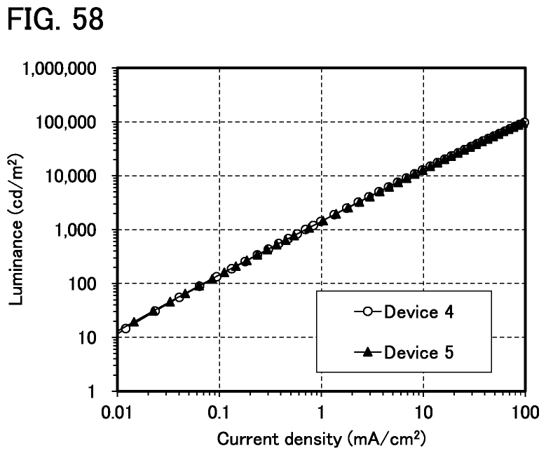

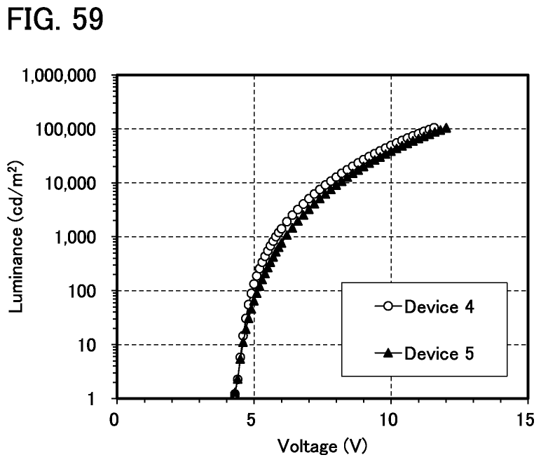

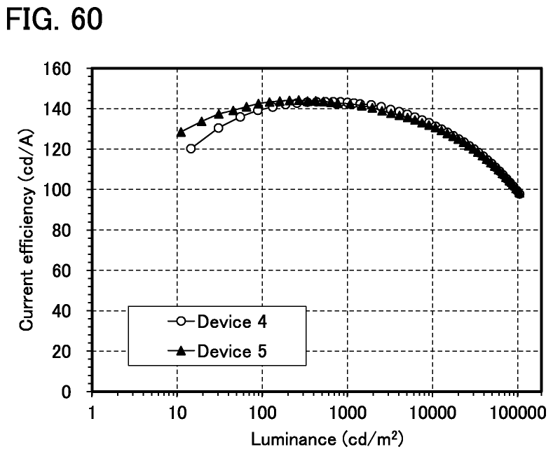

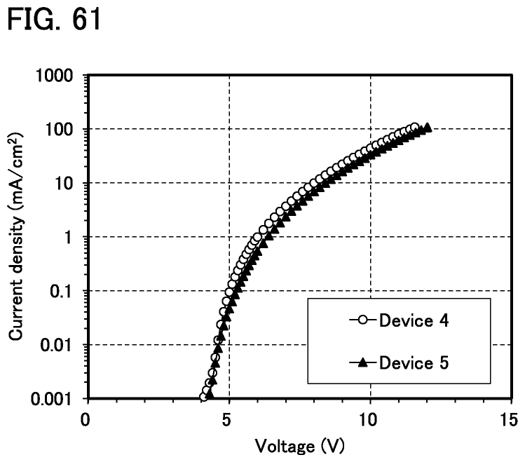

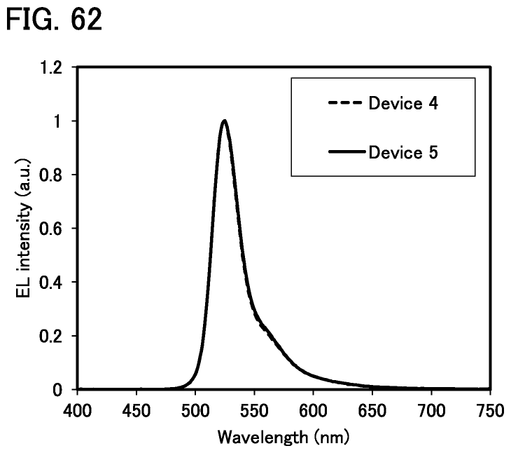

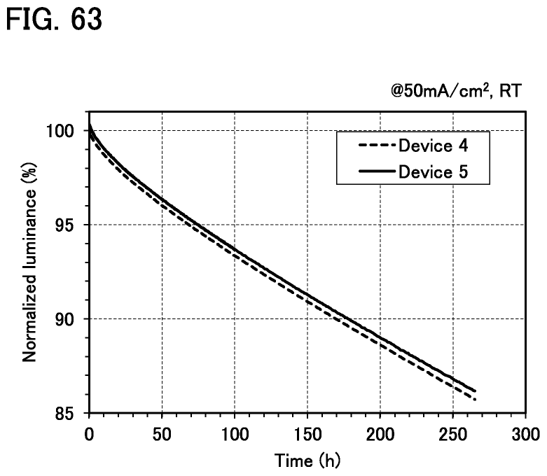

FIGS. 58, 59, 60, 61, and 62 respectively illustrate luminance-current density characteristics, luminance-voltage characteristics, current efficiency-luminance characteristics, current density-voltage characteristics, and the electroluminescence spectra of the devices 4 and 5. FIG. 63 illustrates luminance changes over driving time when the devices 4 and 5 are driven at a constant current of 0.242 mA (50 mA/cm²).

Table 16 shows the main characteristics of the devices 4 and 5 at a luminance of approximately 7500 cd/m². The luminance, CIE chromaticity, and electroluminescence spectra were measured at normal temperature with a spectroradiometer (SR-UL1R produced by TOPCON TECHNOHOUSE CORPORATION).

TABLE 16

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Device 4 | 7.40 | 0.0271 | 5.60 | 0.248 | 0.704 | 7531 | 134 |
| Device 5 | 7.80 | 0.0274 | 5.67 | 0.249 | 0.704 | 7544 | 133 |

FIGS. 58 to 63 and Table 16 have revealed that the devices 4 and 5 are each a tandem light-emitting device that exhibits green light emission derived from Ir(5mppy-d₃)₂(mbfpypy-d₃) and has favorable emission characteristics and a long life.

The above results show that the light-emitting device of one embodiment of the present invention has favorable characteristics.

### Example 8

In this example, a light-emitting device (a device 6) of one embodiment of the present invention in which a layer including Hid2Phen, 6,6′(P-Bqn)2BPy, and In whose absorption spectrum was measured in Example 1 was used as the first layer of the intermediate layer and a comparative light-emitting device (a comparative device 7) in which a layer including Hid2Phen, 6,6′(P-Bqn)2BPy, and Li₂O was used as the first layer of the intermediate layer were fabricated and subjected to several measurements. The measurement results are described. Since the organic compounds used in this example are the same as those used in the above example, the illustration of the structural formulae is omitted here.

As illustrated in FIG. 24B, the device 6 and the comparative device 7 each have a structure in which the first electrode 901, the hole-injection layer 911, the first hole-transport layer 912_1, the first light-emitting layer 913_1, the first electron-transport layer 914_1, the intermediate layer 960 (the first layer 961, the third layer 963, and the second layer 962), the second hole-transport layer 912_2, the second light-emitting layer 9132, the second electron-transport layer 9142, the electron-injection layer 915, the second electrode 902, and the cap layer 904 are stacked in this order over the silicon substrate 900B. Methods for fabricating the device 6 and the comparative device 7 are described below.

### <Method for Fabricating Device 6>

The device 6 is different from the device 4 in that the second electron-transport layer 914_2 was formed by depositing 2mPCCzPDBq by evaporation to a thickness of 20 nm and then depositing mPPhen2P by evaporation to a thickness of 20 nm after the formation of the second light-emitting layer 913_2 in the method for fabricating the device 4 described in Example 7. Except for this, the device 6 was fabricated in a manner similar to that of the device 4.

### <Method for Fabricating Comparative Device 7>

The comparative device 7 is different from the device 6 in that the first layer 961 of the intermediate layer 960 was formed by depositing Hid2Phen, 6,6′(P-Bqn)2BPy, and Li₂O by co-evaporation to a thickness of 5 nm at a volume ratio of 0.5:0.5:0.02 (=Hid2Phen: 6,6′(P-Bqn)2BPy: Li₂O). Except for this, the comparative device 7 was fabricated in a manner similar to that of the device 6.

Table 17 shows the structures of the device 6 and the comparative device 7.

TABLE 17

| | | |
|---|---|---|
| Thickness | Device 6 | Comparative device 7 |

| | | | |
|---|---|---|---|
| Cap layer | 70 | nm | ITO |
| Second electrode | 15 | nm | Ag:Mg (1:0.1) |
| Electron-injection layer | 1.5 | nm | LiF:Yb (2:1) |

Processed by photolithography method

| | | | | |
|---|---|---|---|---|
| Second electron- | 2 | 20 | nm | mPPhen2P |
| transport layer | 1 | 20 | nm | 2mPCCzPDBq |
| Second light-emitting layer | | 40 | nm | 8mpTP-4mDBtPBfpm:βNCCP:Ir(5mppy-d₃)₂(mbfpypy-d₃) |
| | | | | (0.5:0.5:0.1) |

| Second hole-transport | 50 | nm | PCBBiF | |
|---|---|---|---|---|
| layer | | | | |
| Second layer | 10 | nm | PCBBiF:OCHD-003 (1:0.15) | |
| Third layer | 2 | nm | ZnPc | |
| First layer | 5 | nm | Hid2Phen:6,6′(P-Bqn)2BPy:In | Hid2Phen:6,6′(P-Bqn)2BPy:Li₂O |
| | | | (0.5:0.5:0.02) | (0.5:0.5:0.02) |
| First electron-transport | 10 | nm | 2mPCCzPDBq | |
| layer | | | | |

| First light-emitting layer | | 40 | nm | 8mpTP-4mDBtPBfpm:βNCCP:Ir(5mppy-d3)2(mbfpypy-d₃) |
|---|---|---|---|---|
| | | | | (0.5:0.5:0.1) |
| First hole-transport layer | | 30 | nm | PCBBiF |
| Hole-injection layer | | 10 | nm | PCBBiF:OCHD-003 (1:0.03) |
| First electrode | 5 | 10 | nm | ITSO |
| | 4 | 2 | nm | Ti |
| | 3 | 70 | nm | Al |
| | 2 | 49 | nm | Ti |
| | 1 | 1 | nm | TiN |

| | | |
|---|---|---|
| Substrate | — | Silicon |

Each of the fabricated light-emitting devices was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80 °C under an atmospheric pressure for 1 hour. Then, the initial characteristics of the light-emitting devices were measured.

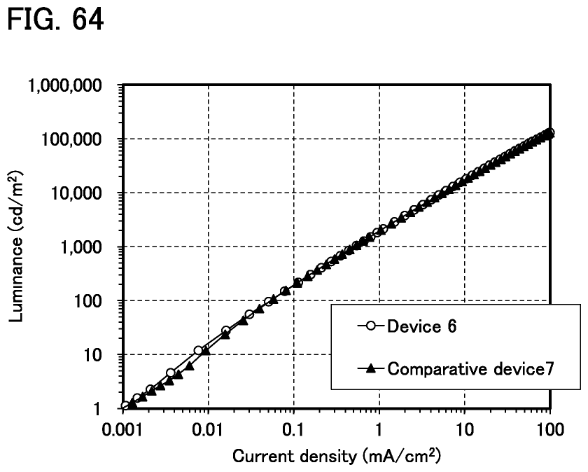

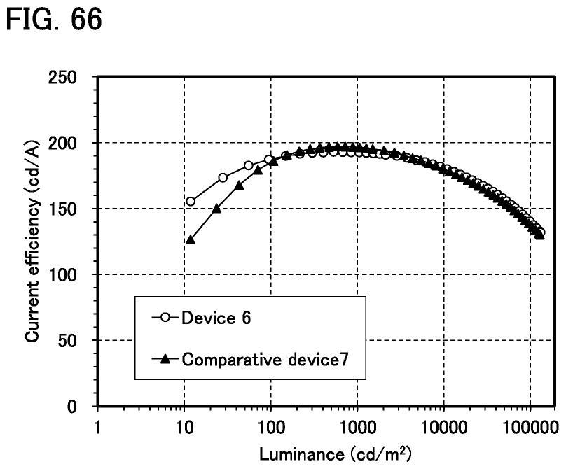

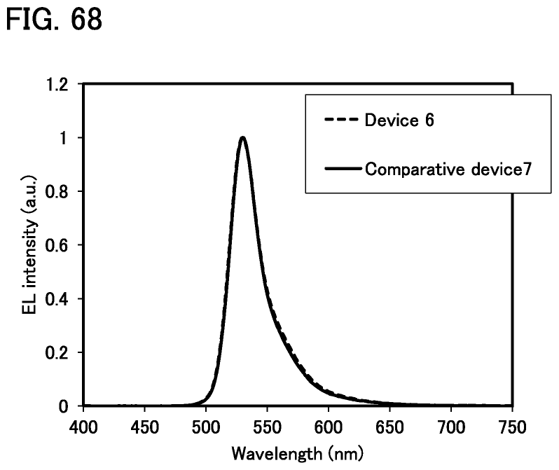

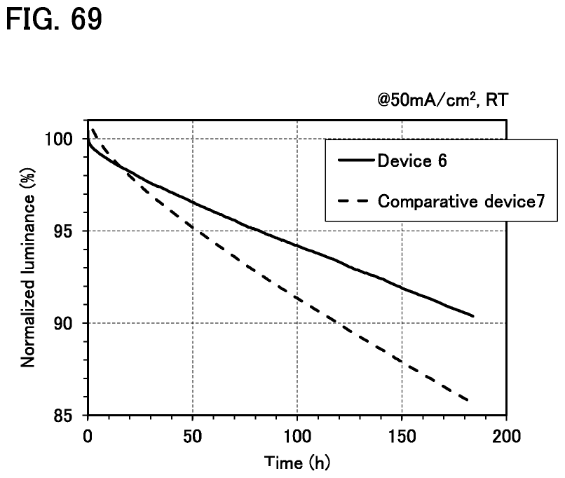

FIGS. 64, 65, 66, 67, and 68 respectively illustrate luminance-current density characteristics, luminance-voltage characteristics, current efficiency-luminance characteristics, current density-voltage characteristics, and the electroluminescence spectra of the device 6 and the comparative device 7. FIG. 69 illustrates luminance changes over driving time when the device 6 and the comparative device 7 are driven at a constant current of 0.242 mA (50 mA/cm²) in a room temperature (23 °C) environment.

Table 18 shows the main characteristics of the device 6 and the comparative device 7 at a luminance of approximately 7500 cd/m². The luminance, CIE chromaticity, and electroluminescence spectra were measured at normal temperature with a spectroradiometer (SR-UL1R produced by TOPCON TECHNOHOUSE CORPORATION).

TABLE 18

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Device 6 | 7.00 | 0.0212 | 4.05 | 0.273 | 0.695 | 7431 | 184 |
| Comparative device 7 | 7.40 | 0.0233 | 4.45 | 0.268 | 0.699 | 8122 | 182 |

FIGS. 64 to 69 and Table 18 have revealed that the device 6 is a tandem light-emitting device that exhibits green light emission derived from Ir(5mppy-d₃)₂(mbfpypy-d₃) and has favorable emission characteristics and a long life.

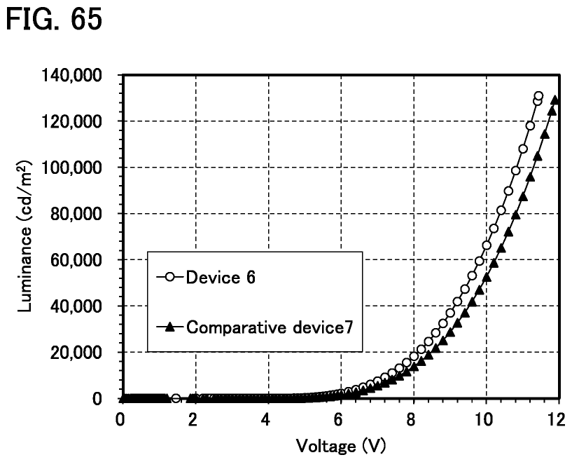

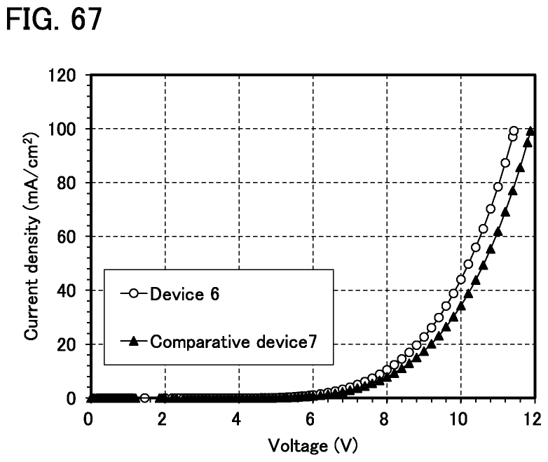

FIGS. 65 and 67 show that the device 6 is a light-emitting device having a lower driving voltage than the comparative device 7. Furthermore, FIG. 69 shows that the device 6 is a light-emitting device having a longer life than the comparative device 7.

This is because the organic compound layer in the device 6 in which In was used for the first layer 961 of the intermediate layer 960 did not easily deteriorate when being processed by a photolithography method, whereas the organic compound layer in the comparative device 7 in which Li₂O was used for the first layer 961 of the intermediate layer 960 easily deteriorated by being processed by a photolithography method owing to the influence of oxygen or water in the air or a chemical solution or water in the process, which caused an increase in driving voltage and a reduction in reliability.

The above results show that a layer including In has higher resistance to acid treatment than a layer including Li and that In is a metal that is preferable for the light-emitting device of one embodiment of the present invention.

The above results show that the light-emitting device of one embodiment of the present invention has favorable characteristics.

### Example 9

In this example, results of several analyses on a mixed film of Hid2Phen, 6,6′(P-Bqn)2BPy, and copper (Cu), which are organic compounds that can be used for the layer 200 of the light-emitting device of one embodiment of the present invention, are described. Note that the vapor deposition method, the method for measuring the absorption spectrum, and the like are similar to those described in Example 1.

### <<Absorption Spectrum Measurement>>

Results of measuring absorption spectra of a single film and mixed films of Hid2Phen, 6,6′(P-Bqn)2BPy, and Cu are described. Materials used for a single film 9 and mixed films 15 to 17 used for the absorption spectrum measurement are described below.

### <Single Film 9>

Over a quartz substrate, Cu was deposited by evaporation to a thickness of 1 nm.

### <Mixed Film 15>

Over a quartz substrate, Hid2Phen, 6,6′(P-Bqn)2BPy, and Cu were deposited by co-evaporation to a thickness of 50 nm at a volume ratio of 0.5:0.5:0.02 (=Hid2Phen: 6,6′(P-Bqn)2BPy: Cu).

### <Mixed Film 16>

Over a quartz substrate, Hid2Phen and Cu were deposited by co-evaporation to a thickness of 50 nm at a volume ratio of 1:0.02 (=Hid2Phen: Cu).

### <Mixed Film 17>

Over a quartz substrate, 6,6′(P-Bqn)2BPy and Cu were deposited by co-evaporation to a thickness of 50 nm at a volume ratio of 1:0.02 (=6,6′(P-Bqn)2BPy: Cu).

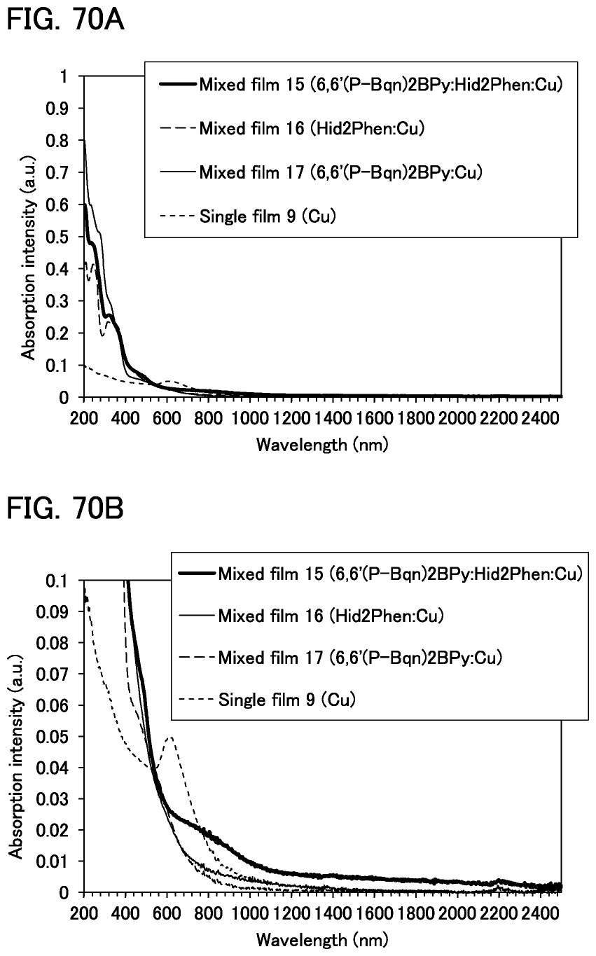

FIG. 70A illustrates absorption spectra of the mixed films 15 to 17 and the single film 9, and FIG. 70B is an enlarged view of the absorption spectra illustrated in FIG. 70A.

As illustrated in FIG. 70A, in the wavelength region of 400 nm to 2500 nm, the absorption spectrum of the mixed film 15 including Hid2Phen, 6,6′(P-Bqn)2BPy, and Cu has an absorption intensity peak that is not observed in the single film 9, the mixed film 16, or the mixed film 17.

As illustrated in FIG. 70B, in the wavelength region of 600 nm to 1000 nm, the absorption spectrum of the mixed film 15 has a broad peak with a higher absorption intensity than the absorption spectrum of the mixed film 16 including Hid2Phen and Cu. The wavelength region is a region at longer wavelengths than a wavelength (388 nm) of an absorption edge on the long wavelength side of the absorption spectrum of the single film 1 including Hid2Phen, which can be read from FIG. 26A. In the wavelength region of 400 nm to 1000 nm, the absorption spectrum of the mixed film 15 has broad peaks with wavelength regions having higher absorption intensities than the absorption spectrum of the mixed film 17 including 6,6′(P-Bqn)2BPy and Cu. The wavelength region is a region at longer wavelengths than a wavelength (392 nm) of an absorption edge on the long wavelength side of the absorption spectrum of the single film 2 including 6,6′(P-Bqn)2BPy, which can be read from FIG. 26A.

This indicates that the combination of Hid2Phen, 6,6′(P-Bqn)2BPy, and Cu can form a charge-transfer complex.

The above results show that Hid2Phen, 6,6′(P-Bqn)2BPy and Cu are a combination that can be preferably used for the layer 200.

### Example 10

In this example, a light-emitting device (a device 8) of one embodiment of the present invention in which a layer including Hid2Phen, 6,6′(P-Bqn)2BPy, and Cu whose absorption spectrum was measured in Example 8 was used as the first layer of the intermediate layer was fabricated and subjected to several measurements. The measurement results are described. Since the organic compounds used in this example are the same as those used in the above example, the illustration of the structural formulae is omitted here.

As illustrated in FIG. 24A, the device 8 has a structure in which the first electrode 901, the hole-injection layer 911, the first hole-transport layer 9121, the first light-emitting layer 913_1, the first electron-transport layer 9141, the intermediate layer 960 (the first layer 961, the third layer 963, and the second layer 962), the second hole-transport layer 9122, the second light-emitting layer 9132, the second electron-transport layer 9142, the electron-injection layer 915, the second electrode 902, and the cap layer 904 are stacked in this order over the glass substrate 900. A method for fabricating the device 8 is described below.

### (Method for Fabricating Device 8)

First, in a manner similar to that of the method for fabricating the device 1 described in Example 4, formation of the first electrode 901, pretreatment, formation of the hole-injection layer 911, and formation of the first hole-transport layer 912_1 were performed. Next, in a manner similar to that of the method for fabricating the device 4 described in Example 7, formation of the first light-emitting layer 913_1 and formation of the first electron-transport layer 914_1 were performed.

After the formation of the first electron-transport layer 9141, Hid2Phen, 6,6′(P-Bqn)2BPy, and Cu were deposited by co-evaporation to a thickness of 5 nm at a volume ratio of 0.5:0.5:0.02 (=Hid2Phen: 6,6′(P-Bqn)2BPy: Cu), whereby the first layer 961 was formed.

Next, in a manner similar to that of the method for fabricating the device 1 described in Example 4, formation of the second layer 962 and formation of the second hole-transport layer 912_2 were performed. Then, in a manner similar to that of the method for fabricating the device 4 described in Example 7, formation of the second light-emitting layer 913_2 was performed. Subsequent to that, in a manner similar to that of the method for fabricating the device 1 described in Example 4, formation of the second electron-transport layer 914_2 was performed. Then, without processing of the organic compound layer by a photolithography method, the electron-injection layer, the second electrode 902, and the cap layer 904 were formed over the second electron-transport layer 914_2 in a manner similar to that of the method for fabricating the device 1 described in Example 4.

Table 19 shows the structure of the device 8.

TABLE 19

| | | Thickness | | Device 8 |
|---|---|---|---|---|
| Cap layer | | 70 | nm | DBT3P-II |
| Second electrode | | 15 | nm | Ag:Mg (1:0.1) |
| Electron-injection layer | | 1.5 | nm | LiF:Yb (2:1) |
| Second electron- | 2 | 20 | nm | mPPhen2P |
| transport layer | 1 | 20 | nm | 2mPCCzPDBq |
| Second light-emitting layer | | 40 | nm | 8mpTP-4mDBtPBfpm:βNCCP:Ir(5mppy-d₃)₂(mbfpypy-d₃) |
| | | | | (0.5:0.5:0.1) |
| Second hole-transport layer | | 50 | nm | PCBBiF |
| Second layer | | 10 | nm | PCBBiF:OCHD-003 (1:0.15) |
| First layer | | 5 | nm | Hid2Phen:6,6′(P-Bqn)2BPy:Cu (0.5:0.5:0.02) |
| First electron-transport layer | | 10 | nm | 2mPCCzPDBq |
| First light-emitting layer | | 40 | nm | 8mpTP-4mDBtPBfpm:βNCCP:Ir(5mppy-d₃)₂(mbfpypy-d₃) |
| | | | | (0.5:0.5:0.1) |
| First hole-transport layer | | 125 | nm | PCBBiF |
| Hole-injection layer | | 10 | nm | PCBBiF:OCHD-003 (1:0.03) |
| First electrode | 2 | 50 | nm | ITSO |
| | 1 | 100 | nm | APC |

| | | |
|---|---|---|
| Substrate | — | Glass |

The fabricated light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80 °C under an atmospheric pressure for 1 hour. Then, the initial characteristics of the light-emitting device were measured.

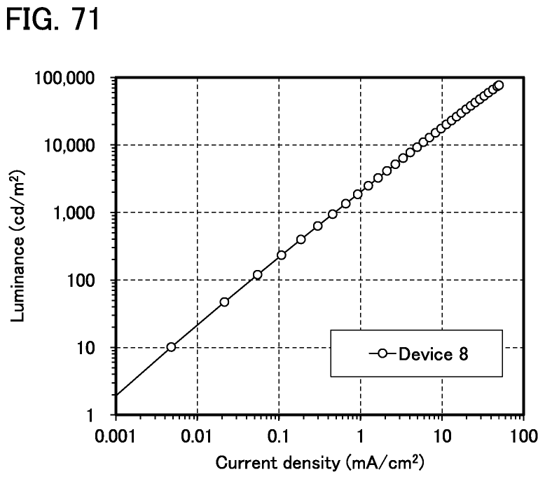

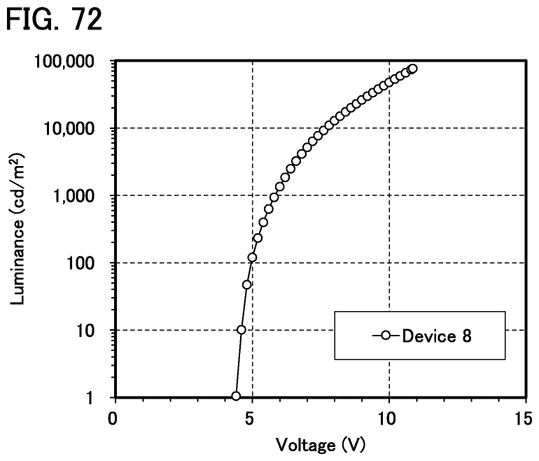

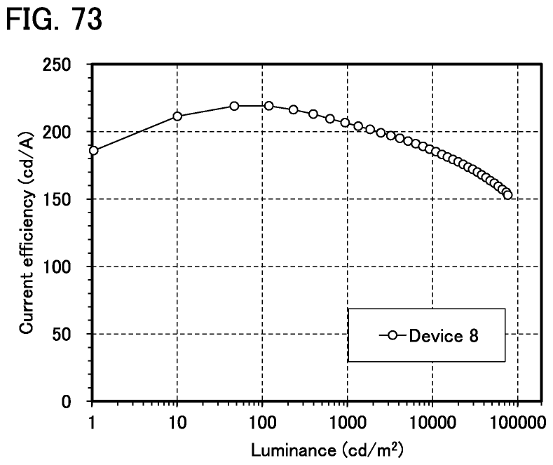

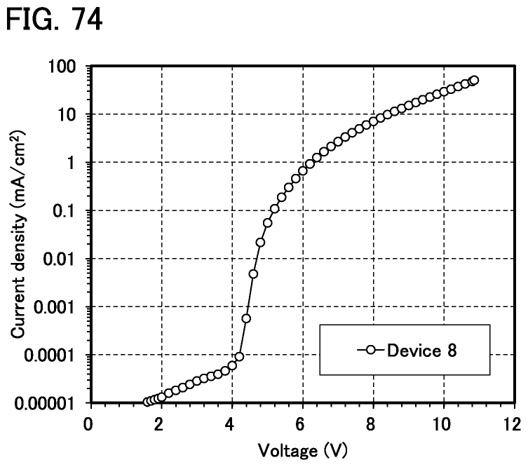

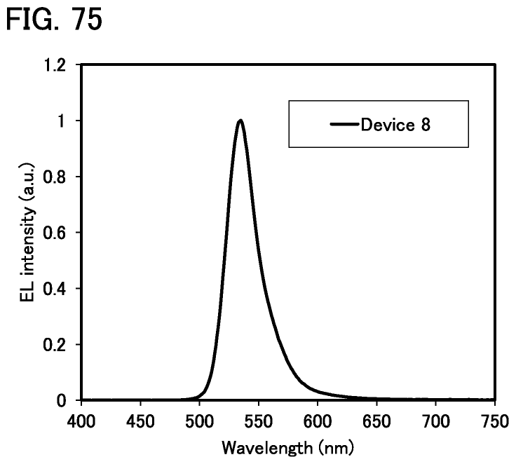

FIGS. 71, 72, 73, 74, and 75 respectively illustrate luminance-current density characteristics, luminance-voltage characteristics, current efficiency-luminance characteristics, current density-voltage characteristics, and the electroluminescence spectra of the device 8.

Table 20 shows the main characteristics of the device 8 at a luminance of approximately 1000 cd/m². The luminance, CIE chromaticity, and electroluminescence spectrum were measured at normal temperature with a spectroradiometer (SR-UL1R produced by TOPCON TECHNOHOUSE CORPORATION).

TABLE 20

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Device 8 | 5.80 | 0.0182 | 0.454 | 0.269 | 0.704 | 938 | 207 |

FIGS. 71 to 75 and Table 20 have revealed that the device 8 is a tandem light-emitting device that exhibits green light emission derived from Ir(5mppy-d₃)₂(mbfpypy-d₃) and has favorable emission characteristics.

The above results show that the light-emitting device of one embodiment of the present invention has favorable characteristics.

### Example 11

In this example, results of analyzing the metal that is preferably used as the metal material 161_M by computational chemistry are described.

### <Ease of Charge Transfer>

The ease of charge transfer between the metal material 161_M and the second organic compound 161_2 was analyzed by quantum chemical calculation. For the calculation, Li, Cu, Zn, Ag, In, or Sn was used as the metal material 161_M, and 6,6′(P-Bqn)2BPy was used as the second organic compound 161_2. In structural optimization calculation, each metal atom is placed around 6,6′(P-Bqn)2BPy to analyze whether charge transfer from each metal to 6,6′(P-Bqn)2BPy occurs.

Gaussian 16 was used as a quantum chemistry computational program. The most stable structures of organic compounds and composite materials in the ground state were calculated by a density functional theory (DFT) using Apollo 2000 produced by HPE. As basis functions, 6-311G(d,p) and LanL2DZ were used, and as a functional, CAM-B3LYP was used. Furthermore, the solvent effect of toluene was taken into consideration by an integral equation formalism polarizable continuum model (IEFPCM) method. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

As a result of the structural optimization calculation, in the case where the metal material 161_M is Li, Cu, In, or Sn, charge transfer occurs between the metal and 6,6′(P-Bqn)2BPy; specifically, Li, Cu, In, and Sn form monovalent cations and 6,6′(P-Bqn)2BPy forms a radical anion.

Meanwhile, in the case where the metal material 161_M is Ag or Zn, charge transfer between the metal and 6,6′(P-Bqn)2BPy does not spontaneously occur in the structural optimization calculation. Here, the calculated activation energy of charge transfer between Zn and 6,6′(P-Bqn)2BPy is as high as approximately 0.63 eV. Thus, it was found that in the case of Zn, the high activation energy was the reason for not causing charge transfer in the structural optimization calculation. The calculated activation energy of charge transfer between Ag and 6,6′(P-Bqn)2BPy is 0.17 eV, which is lower than that between Zn and 6,6′(P-Bqn)2BPy. Thus, Ag can be regarded as a metal atom that is more likely to cause charge transfer than Zn, and it can be presumed that charge transfer might occur in part even in the case where the metal material 161_M is Ag.

The above results show that charge transfer to the second organic compound 161_2 is likely to occur in the case where Li, Cu, In, Sn, or Ag is used as the metal material 161_M.

### <Analysis of Ease of Composite Material Formation>

After the charge transfer from the metal (Li, Cu, Ag, In, or Sn) to 6,6′(P-Bqn)2BPy by the above-described structural optimization calculation, Hid2Phen is placed around the metal and 6,6′(P-Bqn)2BPy as the first organic compound 161_1 and structural optimization calculation is performed. Whether a composite material of Hid2Phen, 6,6′(P-Bqn)2BPy, and the metal is formed was analyzed.

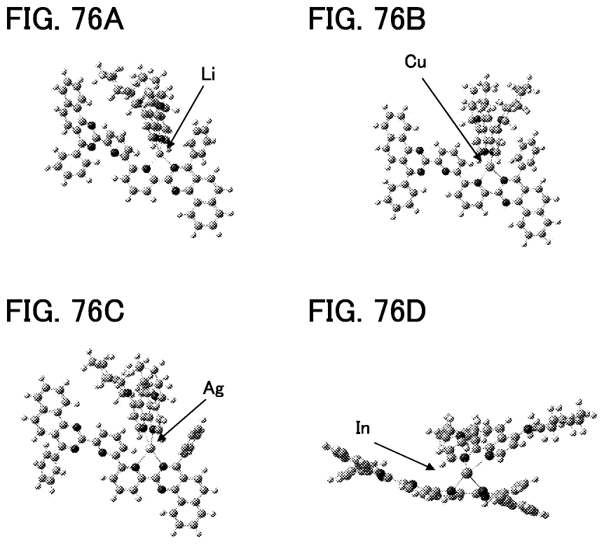

The results of the structural optimization calculation have revealed that in the case where the metal is Li, Cu, Ag, or In, a composite material of Hid2Phen, 6,6′(P-Bqn)2BPy, and the metal is formed as illustrated in FIGS. 76A to 76D. Meanwhile, in the case where the metal is Sn, Hid2Phen does not come near Sn and an energy barrier exists in formation of a composite material. The analysis of the electrostatic potential map has revealed that in the case where the metal is Sn, a negatively charged region spreads around the monovalent Sn; thus, Sn is repelled by a negative charged nitrogen atom of Hid2Phen, making it difficult to form a composite material.

The above results show that in the case where Li, Cu, Ag, or In is used as the metal material 161_M, a composite material of Hid2Phen, 6,6′(P-Bqn)2BPy, and the metal is likely to be formed.

### <Analysis of Resistance to Acid Treatment>

Next, to analyze the resistance of the first layer of the intermediate layer to acid treatment, an oxonium ion (H₃O⁺) is placed around the composite material of Hid2Phen, 6,6′(P-Bqn)2BPy, and the metal (In or Li) and structural optimization calculation is performed.

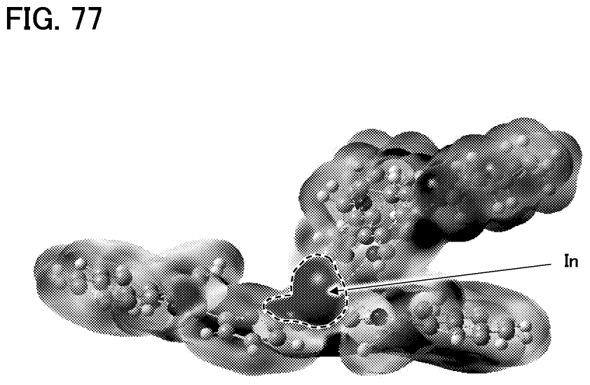

As a result, in the case of the composite material of Hid2Phen, 6,6′(P-Bqn)2BPy, and In, a reaction in which an oxonium ion interacts with In to move a proton to In and move two electrons of indium to the proton (H⁺), so that In changes from monovalent to trivalent and the proton becomes hydride (H⁻) occurs (see Scheme (a-1)). In the composite material, as indicated by a region surrounded by a dotted line in FIG. 77, an electron-rich region derived from 5s² electrons exists around indium, whereby an oxonium ion is likely to interact with indium. This indicates that the coordinate bond between indium and the organic compound is likely to be maintained even when the composite material of Hid2Phen, 6,6′(P-Bqn)2BPy, and In is affected by acid treatment. Thus, it was found that the use of Hid2Phen, 6,6′(P-Bqn)2BPy, and In as the first layer of the intermediate layer enables the organic compound layer to be highly resistant to acid treatment.

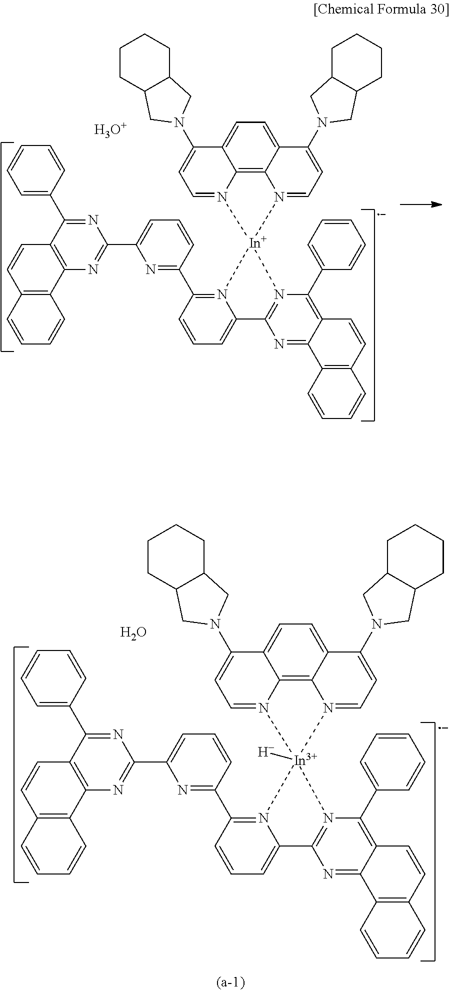

Meanwhile, in the case of a composite material of Hid2Phen, 6,6′(P-Bqn)2BPy, and Li, interaction between an oxonium ion and 6,6′(P-Bqn)2BPy, which is a radical anion, occurs to cause a reaction in which a proton moves to a nitrogen atom of 6,6′(P-Bqn)2BPy, so that one of the coordinate bonds between Li and 6,6′(P-Bqn)2BPy is cleaved (see Scheme (b-1)). This indicates that the composite material of Hid2Phen, 6,6′(P-Bqn)2BPy, and Li is likely to be affected by acid treatment.

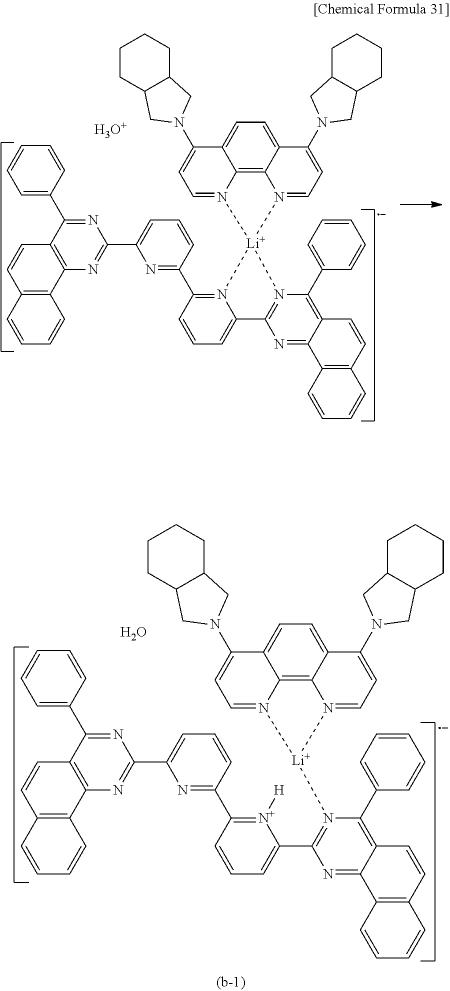

The above results show that a layer highly resistant to acid treatment can be formed in the case where In is used as the metal material 161_M.

Putting the above calculation results together, Li, Cu, In, Sn, or Ag is preferably used as the metal material 161_M in the light-emitting device of one embodiment of the present invention in terms of ease of charge transfer. Furthermore, it has also been revealed that using Li, Cu, Ag, or In is further preferable in terms of ease of formation of a composite material. Furthermore, it has been found that using In is the most preferable in terms of ease of charge transfer, ease of formation of a composite material, and resistance to acid treatment.

This application is based on Japanese Patent Application Serial No. 2025-065794 filed with Japan Patent Office on Apr. 11, 2025 and Japanese Patent Application Serial No. 2025-124768 filed with Japan Patent Office on Jul. 25, 2025, the entire contents of which are hereby incorporated by reference.

What is claimed is:

1. A light-emitting device comprising:
a first electrode;
a second electrode;
a light-emitting layer; and
a first layer,
wherein the light-emitting layer is between the first electrode and the second electrode,
wherein the first layer is between the light-emitting layer and the second electrode,
wherein the first layer comprises a first organic compound, a second organic compound, and at least one of a metal and a metal compound, and
wherein an absorption spectrum of a first mixed film comprising the first organic compound, the second organic compound, and the at least one of the metal and the metal compound comprises a wavelength region having a higher absorption intensity than an absorption spectrum of a second mixed film comprising one of the first organic compound and the second organic compound and the at least one of the metal and the metal compound and having a difference in thickness of less than or equal to 10% from a thickness of the first mixed film.

2. A light-emitting device comprising:
a first electrode;
a second electrode;
a light-emitting layer; and
a first layer,
wherein the light-emitting layer is between the first electrode and the second electrode,
wherein the first layer is between the light-emitting layer and the second electrode,
wherein the first layer comprises a first organic compound, a second organic compound, and at least one of a metal and a metal compound,
wherein an absorption spectrum of a first mixed film comprising the first organic compound, the second organic compound, and the at least one of the metal and the metal compound comprises a wavelength region having a higher absorption intensity than an absorption spectrum of a second mixed film comprising the first organic compound and the at least one of the metal and the metal compound and having a difference in thickness of less than or equal to 10% from a thickness of the first mixed film, and
wherein the absorption spectrum of the first mixed film comprises a wavelength region having a higher absorption intensity than an absorption spectrum of a third mixed film comprising the second organic compound and the at least one of the metal and the metal compound and having a difference in thickness of less than or equal to 10% from the thickness of the first mixed film.

3. A light-emitting device comprising:
a first electrode;
a second electrode;
a first light-emitting layer;
a first layer; and
a second light-emitting layer,
wherein the first light-emitting layer and the second light-emitting layer are between the first electrode and the second electrode,
wherein the first layer is between the first light-emitting layer and the second light-emitting layer,
wherein the first layer comprises a first organic compound, a second organic compound, and at least one of a metal and a metal compound, and
wherein an absorption spectrum of a first mixed film comprising the first organic compound, the second organic compound, and the at least one of the metal and the metal compound comprises a wavelength region having a higher absorption intensity than an absorption spectrum of a second mixed film comprising one of the first organic compound and the second organic compound and the at least one of the metal and the metal compound and having a difference in thickness of less than or equal to 10% from a thickness of the first mixed film.

4. The light-emitting device according to claim 3,
wherein the second mixed film comprises the first organic compound and the at least one of the metal and the metal compound, and
wherein the absorption spectrum of the first mixed film comprises a wavelength region having a higher absorption intensity than an absorption spectrum of a third mixed film comprising the second organic compound and the at least one of the metal and the metal compound and having a difference in thickness of less than or equal to 10% from the thickness of the first mixed film.

5. The light-emitting device according to claim 1, wherein the absorption spectrum of the first mixed film comprises the wavelength region having the higher absorption intensity than the absorption spectrum of the second mixed film in a region at longer wavelengths than an absorption edge on the long wavelength side of an absorption spectrum of a film of an organic compound included in the second mixed film.

6. The light-emitting device according to claim 2,
wherein the absorption spectrum of the first mixed film comprises the wavelength region having the higher absorption intensity than the absorption spectrum of the second mixed film in a region at longer wavelengths than an absorption edge on the long wavelength side of an absorption spectrum of a film comprising the first organic compound, and
wherein the absorption spectrum of the first mixed film comprises the wavelength region having the higher absorption intensity than the absorption spectrum of the third mixed film in a region at longer wavelengths than an absorption edge on the long wavelength side of an absorption spectrum of a film comprising the second organic compound.

7. The light-emitting device according to claim 1, wherein the at least one of the metal and the metal compound comprises a metal element belonging to any of Group 3 to Group 14 of the periodic table.

8. The light-emitting device according to claim 7, wherein the at least one of the metal and the metal compound comprises a metal element belonging to Group 3, Group 11, or Group 13 of the periodic table.

9. The light-emitting device according to claim 1, further comprising a second layer,
wherein the second layer is between the first layer and the second electrode,
wherein the second layer comprises a third organic compound and a fourth organic compound,
wherein the third organic compound is an organic compound comprising a π-electron rich heteroaromatic ring or an aromatic amine, and
wherein the fourth organic compound comprises at least one of a halogen group and a cyano group.

10. The light-emitting device according to claim 1, wherein a LUMO level of the first organic compound is higher than a LUMO level of the second organic compound.

11. The light-emitting device according to claim 1, wherein a HOMO level of the first organic compound is higher than a HOMO level of the second organic compound.

12. The light-emitting device according to claim 1, wherein each of the first organic compound and the second organic compound comprises a heteroaromatic ring.

13. The light-emitting device according to claim 12, wherein the heteroaromatic ring included in the first organic compound and the heteroaromatic ring included in the second organic compound each independently comprise at least one of a pyridine ring, a pyrazine ring, a pyrimidine ring, a pyridazine ring, a triazine ring, an imidazole ring, a pyrazole ring, an oxazole ring, a thiazole ring, and a triazole ring.

14. The light-emitting device according to claim 12, wherein the first organic compound comprises an electron-donating group.

15. The light-emitting device according to claim 14, wherein the electron-donating group is at least one of an alkyl group, an alkoxy group, an aryloxy group, an alkylamino group, an arylamino group, and a heterocyclic amino group.

16. The light-emitting device according to claim 2, wherein the at least one of the metal and the metal compound comprises a metal element belonging to any of Group 3 to Group 14 of the periodic table.

17. The light-emitting device according to claim 16, wherein the at least one of the metal and the metal compound comprises a metal element belonging to Group 3, Group 11, or Group 13 of the periodic table.

18. The light-emitting device according to claim 3, wherein the at least one of the metal and the metal compound comprises a metal element belonging to any of Group 3 to Group 14 of the periodic table.

19. The light-emitting device according to claim 18, wherein the at least one of the metal and the metal compound comprises a metal element belonging to Group 3, Group 11, or Group 13 of the periodic table.
